(19) United States
(12) Patent Application Publication
(10) Pub. No.: US 2025/0212676 A1
(43) Pub. Date: Jun. 26, 2025

(54) DISPLAY DEVICE, LASER DEVICE FOR FABRICATING THE DISPLAY DEVICE, METHOD OF FABRICATING THE DISPLAY DEVICE USING THE LASER DEVICE, AND ELECTRONIC DEVICE INCLUDING THE DISPLAY DEVICE

(71) Applicant: Samsung Display Co., LTD., Yongin-si (KR)

(72) Inventors: Hyung Sik KIM, Yongin-si (KR); Konstantin MISHCHIK, Yongin-si (KR); Jeong Ho Kim, Yongin-si (KR); Cheol Lae Roh, Yongin-si (KR); Je Kil Ryu, Yongin-si (KR); Jung Hwa You, Yongin-si (KR); Seung Hoon Jang, Yongin-si (KR); Seong Ho Jeong, Yongin-si (KR); Woo Hyun Jung, Yongin-si (KR); Se Yeon Hwang, Yongin-si (KR)

(21) Appl. No.: 18/806,294

(22) Filed: Aug. 15, 2024

(30) Foreign Application Priority Data
Dec. 21, 2023 (KR) 10-2023-0188883

(51) Int. Cl. H10K 71/00; B23K 26/06; B23K 26/082; B23K 26/362; B23K 101/36; H10K 59/12; H10K 59/127

(52) U.S. Cl. CPC H10K 71/621; B23K 26/0648; B23K 26/0652; B23K 26/082; B23K 26/362; H10K 59/1201; H10K 59/127; B23K 2101/36

(57) ABSTRACT

A display device, a laser device for fabricating the display device, a method of fabricating the display device using the laser device, and an electronic device including the display device are provided. The display device includes a glass substrate including first and second surfaces opposite each other, first and second side surfaces located therebetween, and a light emitting element layer on the first surface and including light emitting elements to emit light. A radius of curvature of a curve through a center, an upper end, and an upper center of the first side surface is a first upper radius of curvature, a radius of curvature of a curve through a center, an upper end, and an upper center of the second side surface is a second upper radius of curvature, and a difference between the first and second upper radii of curvature is about 30 μm or less.

### CROSS-REFERENCE TO RELATED APPLICATION

The present application claims priority to and the benefit of Korean Patent Application No. 10-2023-0188883, filed on Dec. 21, 2023, in the Korean Intellectual Property Office, the entire disclosure of which is incorporated by reference herein.

### BACKGROUND

### 1. Field

One or more embodiments of the present disclosure relate to a display device, a laser device for fabricating the display device, a method of fabricating the display device using the laser device, and an electronic device including the display device.

### 2. Description of the Related Art

As the information society develops, demands for display devices for displaying images are increasing in various forms. The display devices may be flat panel display devices such as liquid crystal displays, field emission displays, and light emitting displays.

A display device includes a display area for displaying images and a non-display area disposed around the display area, for example, surrounding the display area. Recently, a width of the non-display area has been gradually reduced to increase immersion in the display area and enhance aesthetic appearance of the display device.

In a display device fabrication process, display devices may be formed by cutting a plurality of display cells formed on a mother substrate including the display cells. Here, in order to improve the mechanical strength of a substrate, side surfaces of the substrate of each of the display cells are processed to have round cross sections using a computer numerical control (CNC) polishing device. Here, it is difficult to process the side surfaces of the substrate to have cross sections with substantially the same radius of curvature.

### SUMMARY

Aspects and features of embodiments of the present disclosure provide a display device that can reduce or minimize a difference in curvature between side surfaces of a substrate.

Aspects and features of embodiments of the present disclosure also provide a laser device for fabricating the display device that can reduce or minimize a difference in curvature between side surfaces of a substrate.

Aspects and features of embodiments of the present disclosure also provide a method of fabricating a display device using a laser device that can reduce or minimize a difference in curvature between side surfaces of a substrate.

Aspects and features of embodiments of the present disclosure also provide an electronic device including a display device that can reduce or minimize a difference in curvature between side surfaces of a substrate.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to an aspect of one or more embodiments of the present disclosure, there is provided a display device including a glass substrate comprising a first surface, a second surface opposite the first surface, and a plurality of side surfaces located between the first surface and the second surface, and a light emitting element layer on the first surface of the glass substrate and including light emitting elements configured to emit light. The side surfaces of the glass substrate include a first side surface and a second side surface, the first side surface including a first upper part extending from a first center at a center of the first side surface to an upper end of the first side surface, the first upper part having a first upper center at a center between the first center and the upper end of the first side surface, the second side surface including a second upper part extending from a second center at a center of the second side surface to an upper end of the second side surface, the second upper part having a second upper center at a center between the second center and the upper end of the second side surface. A radius of curvature of a curve passing through the first center, the first upper center, and the upper end of the first side surface is defined as a first upper radius of curvature, a radius of curvature of a curve passing through the second center, the second upper center, and the upper end of the second side surface is defined as a second upper radius of curvature, and a difference between the first upper radius of curvature and the second upper radius of curvature is about 30 μm or less.

According to an aspect of one or more embodiments of the present disclosure, there is provided a display device including a glass substrate including a first surface, a second surface opposite the first surface, and a plurality of side surfaces located between the first surface and the second surface, and a light emitting element layer on the first surface of the glass substrate and including light emitting elements configured to emit light. Each of the side surfaces of the glass substrate includes a first sub-side surface having a flat shape and a second sub-side surface having a curved shape, a length of the second sub-side surface is greater than a length of the first sub-side surface, the first sub-side surface is in contact with the first surface, and the second sub-side surface is in contact with the second surface.

According to one or more embodiments of an aspect of the present disclosure, there is provided a display device including a first substrate including a first surface and a second surface opposite the first surface, a second substrate on the first surface of the first substrate, and a light emitting element layer on a surface of the second substrate and including light emitting elements configured to emit light. The first substrate is made of glass, the second substrate is made of polymer resin, and the first substrate includes a first sub-substrate and a second sub-substrate spaced from each other. The first sub-substrate includes a first side surface and a second side surface located between the first surface and the second surface, the first side surface including a first upper part extending from a first center at a center of the first side surface to an upper end of the first side surface, the first upper part having a first upper center at a center between the first center and the upper end of the first side surface, the second side surface including a second upper part extending from a second center at a center of the second side surface to an upper end of the second side surface, the second upper part having a second upper center at a center between the second center and the upper end of the second side surface. A radius of curvature of a curve passing through the first center, the first upper center, and the upper end of the first side surface is defined as a first upper radius of curvature, a radius of curvature of a curve passing through the second center, the second upper center, and the upper end of the second side surface is defined as a second upper radius of curvature, and a difference between the first upper radius of curvature and the second upper radius of curvature is about 30 μm or less.

According to one or more embodiments of an aspect of the present disclosure, there is provided a display device including a first substrate comprising a first surface and a second surface opposite the first surface, a second substrate on the first surface of the first substrate, and a light emitting element layer on a surface of the second substrate and including light emitting elements configured to emit light. The first substrate includes glass, the second substrate includes polymer resin, the first substrate includes a first sub-substrate and a second sub-substrate spaced from each other, each of a plurality of side surfaces of the first sub-substrate includes a first sub-side surface having a flat shape and a second sub-side surface having a curved shape, a length of the second sub-side surface is greater than a length of the first sub-side surface, the first sub-side surface is in contact with the first surface, and the second sub-side surface is in contact with the second surface.

According to one or more embodiments of an aspect of the present disclosure, there is provided a laser device including a light source configured to output a laser beam, a diffractive element comprising diffractive patterns configured to diffract the laser beam, a phase retardation plate configured to retard a phase of the laser beam incident from the diffractive element, and an objective lens configured to focus the laser beam incident from the phase retardation plate. The diffractive element is configured to rotate. In one or more embodiments, the diffractive element may rotate at a predetermined angle. The laser device may further include a relay lens configured to relay the laser beam diffracted by the diffractive patterns. In one or more embodiments, the relay lens may relay the laser beam diffracted by the diffracted patterns at a predetermined ratio.

According to an aspect of one or more embodiments of the present disclosure, there is provided a laser device including a light source configured to output a laser beam, a diffractive element including diffractive patterns configured to diffract the laser beam, a prism configured to rotate to rotate the laser beam incident from the diffractive element, a phase retardation plate configured to retard a phase of the laser beam incident from the prism, and an objective lens configured to focus the laser beam incident from the phase retardation plate. The prism and the phase retardation plate rotate concurrently. In one or more embodiments, the prism and the phase retardation plate may rotate concurrently or simultaneously at a predetermined angle.

According to an aspect of one or more embodiments of the present disclosure, there is provided a method of fabricating a display device, the method including forming a plurality of display cells on a first surface of a mother substrate, forming a plurality of laser spots along edges of the display cells by irradiating a laser beam using a laser device on a second surface opposite the first surface of the mother substrate, reducing a thickness of the mother substrate by spraying an etchant onto the second surface of the mother substrate at a first rate without a mask, and reducing the thickness of the mother substrate by spraying the etchant onto the second surface of the mother substrate at a second rate without the mask. The first rate is faster than the second rate.

According to an aspect of one or more embodiments of the present disclosure, there is provided an electronic device including a display device for displaying an image. The display device includes a glass substrate including a first surface, a second surface opposite the first surface, and a plurality of side surfaces located between the first surface and the second surface, and a light emitting element layer on the first surface of the glass substrate and including light emitting elements configured to emit light. The side surfaces of the glass substrate include a first side surface and a second side surface. The first side surface includes a first upper part extending from a first center at a center of the first side surface to an upper end of the first side surface, the first upper part having a first upper center at a center between the first center and the upper end of the first side surface, the second side surface includes a second upper part extending from a second center at a center of the second side surface to an upper end of the second side surface, the second upper part having a second upper center at a center between the second center and the upper end of the second side surface. A radius of curvature of a curve passing through the first center, the first upper center, and the upper end of the first side surface is defined as a first upper radius of curvature, a radius of curvature of a curve passing through the second center, the second upper center, and the upper end of the second side surface is defined as a second upper radius of curvature, and a difference between the first upper radius of curvature and the second upper radius of curvature is about 30 μm or less.

According to the aforementioned and other embodiments of the present disclosure, it is possible to improve or increase the mechanical strength of a substrate of the display device.

Furthermore, according to the aforementioned and other embodiments of the present disclosure, it is possible to cut a substrate while reducing a thickness of the substrate.

Furthermore, according to the aforementioned and other embodiments of the present disclosure, it is possible to reduce or minimize a difference in radius of curvature between side surfaces of a substrate of each of a plurality of display cells.

### BRIEF DESCRIPTION OF THE DRAWINGS

The above and other embodiments and features of the present disclosure will become more apparent by describing embodiments thereof with reference to the attached drawings, in which:

FIG. 1 is a perspective view of a display device according to one or more embodiments;

FIG. 2 is a plan view illustrating a display panel and driving circuits according to one or more embodiments;

FIG. 3 is a block diagram of the display device according to one or more embodiments;

FIG. 4 is a circuit diagram of a pixel of the display device according to one or more embodiments;

FIG. 5 is a circuit diagram of a pixel of a display device according to one or more embodiments;

FIG. 6 is a circuit diagram of a pixel of a display device according to one or more embodiments;

FIG. 7A is a cross-sectional view of an example of a display device taken along the line X1-X1′ of FIG. 1;

FIG. 7B is a cross-sectional view of an example of the display device in which a circuit board in FIG. 7A is bent;

FIG. 8A is a cross-sectional view of an example of a display device taken along the line X1-X1′ of FIG. 1;

FIG. 8B is a cross-sectional view of an example of the display device in which a circuit board in FIG. 8A is bent;

FIG. 9A is a cross-sectional view of an example of a display area of a display panel according to one or more embodiments;

FIG. 9B is a cross-sectional view of an example of a display area of a display panel according to one or more embodiments;

FIG. 10 is a cross-sectional view of an example of a display area of a display panel according to one or more embodiments;

FIG. 11 is a detailed cross-sectional view of a light emitting diode element of FIG. 10;

FIG. 12 is a cross-sectional view of an example of a display area of a display panel according to one or more embodiments;

FIG. 13 is a detailed layout view of an example of an area A in FIG. 2;

FIG. 14 is a detailed layout view of an example of an area B in FIG. 2;

FIG. 15 is a detailed layout view of an example of an area C in FIG. 2;

FIG. 16 is a detailed layout view of an example of an area D in FIG. 2;

FIG. 17 is a cross-sectional view of an example of a display panel taken along the line X2-X2′ of FIG. 13;

FIG. 18 is a cross-sectional view of an example of the display panel taken along the line X3-X3′ of FIG. 14;

FIG. 19 is a cross-sectional view of an example of the display panel taken along the line X4-X4′ of FIG. 15;

FIG. 20 is a cross-sectional view of an example of the display panel taken along the line X5-X5′ of FIG. 16;

FIG. 21 is a detailed cross-sectional view of an example of an area E in FIG. 17;

FIG. 22 is a detailed cross-sectional view of an example of an area F in FIG. 18;

FIG. 23 is a detailed cross-sectional view of an example of an area G in FIG. 19;

FIG. 24 is a detailed cross-sectional view of an example of an area H in FIG. 20;

FIGS. 25A through 25D are enlarged cross-sectional views of examples of first through fourth side surfaces of a substrate in FIGS. 17 through 20;

FIGS. 26A through 26D are enlarged cross-sectional views of examples of the first through fourth side surfaces of the substrate in FIGS. 17 through 20;

FIG. 27 is a perspective view of a display device according to one or more embodiments;

FIG. 28 is a plan view illustrating a display panel and driving circuits according to one or more embodiments;

FIG. 29 is a cross-sectional view of an example of the display panel taken along the line X6-X6′ of FIG. 27;

FIG. 30 is a cross-sectional view of an example of the display device in which a circuit board in FIG. 29 is bent;

FIG. 31 is a detailed layout view of an example of an area I in FIG. 28;

FIG. 32 is a cross-sectional view of an example of the display panel taken along the line X7-X7′ of FIG. 31;

FIG. 33 is a cross-sectional view of an example of the display panel taken along the line X8-X8′ of FIG. 31;

FIG. 34 is a detailed cross-sectional view of an example of an area J in FIG. 32;

FIGS. 35A through 35D are enlarged cross-sectional views of examples of first through fourth hole side surfaces illustrated in FIGS. 32 and 33;

FIGS. 36A through 36D are enlarged cross-sectional views of examples of the first through fourth hole side surfaces illustrated in FIGS. 32 and 33;

FIG. 37 is a perspective view of a display device according to one or more embodiments;

FIG. 38 is a plan view illustrating a display panel and driving circuits according to one or more embodiments;

FIG. 39 is a cross-sectional view of an example of the display panel taken along the line X9-X9′ of FIG. 37;

FIG. 40 is a cross-sectional view of an example of the display device in which a bending area in FIG. 39 is bent;

FIG. 41 is a cross-sectional view of an example of the display panel taken along the line X10-X10′ of FIG. 37;

FIG. 42 is a cross-sectional view of an example of the display panel taken along the line X11-X11′ of FIG. 37;

FIGS. 43A through 43D are enlarged cross-sectional views of examples of first through fourth side surfaces of a first sub-substrate in FIGS. 39 and 41;

FIGS. 44A through 44D are enlarged cross-sectional views of examples of first through fourth side surfaces of a second sub-substrate in FIGS. 39 and 42;

FIGS. 45A through 45D are enlarged cross-sectional views of examples of the first through fourth side surfaces of the first sub-substrate in FIGS. 39 and 41;

FIGS. 46A through 46D are enlarged cross-sectional views of examples of the first through fourth side surfaces of the second sub-substrate in FIGS. 39 and 42;

FIG. 47 is a perspective view of a laser device according to one or more embodiments;

FIGS. 48A and 48B are example diagrams for explaining light output from a prism when the prism is rotated by @;

FIG. 49 is an example diagram illustrating the polarization of output light according to the rotation of the laser device in the embodiment of FIG. 47;

FIG. 50 is an example diagram illustrating the polarization of output light according to the rotation of the laser device in the one or more embodiments of FIG. 47;

FIGS. 51A through 51C are example views of laser processing patterns according to the traveling direction and polarization direction of a laser beam;

FIG. 52 is a perspective view of a laser device according to one or more embodiments;

FIG. 53 is an example diagram illustrating the polarization of output light according to the rotation of the laser device in the one or more embodiments of FIG. 52;

FIG. 54 is an example diagram illustrating the polarization of output light according to the rotation of the laser device in the one or more embodiments of FIG. 52;

FIG. 55 is a perspective view of a laser device according to one or more embodiments;

FIG. 56 is an example diagram illustrating the polarization of output light according to the rotation of the laser device in the one or more embodiments of FIG. 55;

FIG. 57 is a perspective view of a laser device according to one or more embodiments;

FIG. 58 is a flowchart illustrating a method of fabricating a display device according to one or more embodiments;

FIGS. 59 through 63 are perspective views for explaining the method of fabricating the display device according to one or more embodiments;

FIGS. 64 through 68 are cross-sectional views taken along the line X12-X12′ of FIGS. 59 through 62 to explain the method of fabricating the display device according to the one or more embodiments;

FIG. 69 is a flowchart illustrating operation S120 of FIG. 58 in detail according to one or more embodiments;

FIGS. 70 through 77 are example views illustrating the rotation of the laser device according to the one or more embodiments of FIGS. 52 through 54 for a laser sketch surrounding edges of a display cell;

FIG. 78 is a side view illustrating an arrangement of laser spots formed along a scanning direction of a laser beam;

FIGS. 79 through 86 are example views illustrating the rotation of the laser device according to the one or more embodiments of FIGS. 55 and 56 for a laser sketch surrounding edges of a display cell;

FIGS. 87A through 87D are example diagrams illustrating an arrangement of laser spots irradiated by a laser device according to one or more embodiments in an XYZ plane, an XY plane, an XZ plane, and a YZ plane;

FIG. 88 is an example diagram for explaining an arrangement of laser spots irradiated by a laser device according to one or more embodiments in the XZ plane in detail;

FIGS. 89 and 90 are cross-sectional views taken along the line X12-X12′ of FIGS. 59 through 62 to explain a method of fabricating a display device according to one or more embodiments;

FIG. 91 is an example diagram illustrating laser spots irradiated by a laser device according to one or more embodiments;

FIGS. 92 and 93 are cross-sectional views taken along the line X12-X12′ of FIGS. 59 through 62 to explain a method of fabricating a display device according to one or more embodiments;

FIG. 94 is an example diagram illustrating laser spots irradiated by a laser device according to one or more embodiments;

FIG. 95 is a flowchart illustrating a method of fabricating a display device according to one or more embodiments;

FIGS. 96 through 101 are perspective views for explaining the method of fabricating the display device according to the one or more embodiments of FIG. 95;

FIGS. 102 through 105 are cross-sectional views taken along the line X13-X13′ of FIGS. 96 through 100 to explain the method of fabricating the display device according to the one or more embodiments of FIG. 95;

FIGS. 106 through 109 are example views illustrating the rotation of the laser device according to the one or more embodiments of FIGS. 52 through 54 for a laser sketch surrounding edges of a through hole of a display cell;

FIGS. 110 through 113 are example views illustrating the rotation of the laser device according to the one or more embodiments of FIGS. 55 and 56 for a laser sketch surrounding edges of a through hole of a display cell;

FIGS. 114 and 115 are cross-sectional views taken along the line X13-X13′ of FIGS. 96 through 100 to explain a method of fabricating a display device according to one or more embodiments;

FIGS. 116 and 117 are cross-sectional views taken along the line X13-X13′ of FIGS. 96 through 100 to explain a method of fabricating a display device according to one or more embodiments;

FIG. 118 is a flowchart illustrating a method of fabricating a display device according to one or more embodiments;

FIGS. 119 through 124 are perspective views for explaining the method of fabricating the display device according to the one or more embodiments of FIG. 118;

FIGS. 125 through 128 are cross-sectional views taken along the line X14-X14′ of FIGS. 120 through 123 to explain the method of fabricating the display device according to the one or more embodiments of FIG. 118;

FIGS. 129 and 130 are example views illustrating the rotation of the laser device according to the one or more embodiments of FIGS. 52 through 54 for laser sketching of a bending area of a display cell;

FIGS. 131 and 132 are example views illustrating the rotation of the laser device according to the one or more embodiments of FIGS. 55 and 56 for laser sketching of a bending area of a display cell;

FIGS. 133 and 134 are cross-sectional views taken along the line X14-X14′ of FIGS. 120 through 123 to explain a method of fabricating a display device according to one or more embodiments;

FIGS. 135 and 136 are cross-sectional views taken along the line X14-X14′ to explain a method of fabricating a display device according to one or more embodiments;

FIG. 137 is an example view of an electronic device including a display device according to one or more embodiments;

FIG. 138 is an example view of an electronic device including a display device according to one or more embodiments;

FIG. 139 is an example view of an electronic device including a display device according to one or more embodiments;

FIG. 140 is an example view of an electronic device including a display device according to one or more embodiments;

FIG. 141 is an example view of an electronic device including a display device according to one or more embodiments;

FIG. 142 is an example view of an electronic device including a display device according to one or more embodiments;

FIG. 143 is an example view illustrating a vehicle dashboard and a center fascia to which an electronic device including a display device according to one or more embodiments has been applied; and

FIG. 144 is an example view of an electronic device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It would be apparent to a person having ordinary skill in the art, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of the present disclosure, expressions such as “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the present disclosure refers to “one or more embodiments of the present disclosure”.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

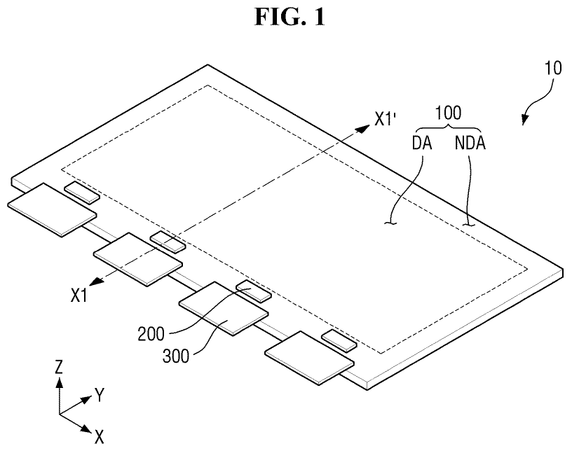

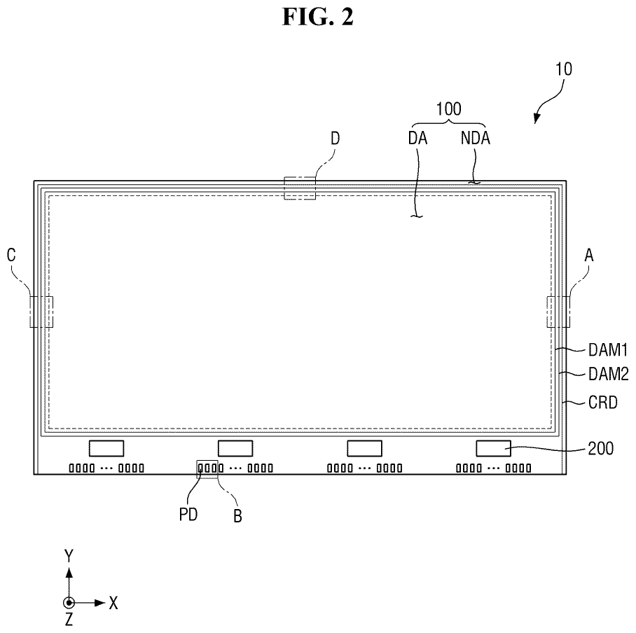

FIG. 1 is a perspective view of a display device 10 according to one or more embodiments of the present disclosure. FIG. 2 is a plan view illustrating a display panel 100 and driving circuits 200 according to one or more embodiments of the present disclosure.

Referring to FIGS. 1 and 2, the display device 10 according to the one or more embodiments is a device for displaying moving images and/or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and/or ultra-mobile PCs (UMPCs), as well as in various products such as televisions, notebook computers, monitors, billboards, and/or Internet of things (IoT) devices.

The display device 10 according to the one or more embodiments may be a light emitting display device such as an organic light emitting display device using organic light emitting diodes, a quantum dot light emitting display device including a quantum dot light emitting layer, an inorganic light emitting display device including an inorganic semiconductor, or a micro- or nano-light emitting display device using a micro- or nano-light emitting diodes. A case where the display device 10 is an organic light emitting display device will be primarily described below, but embodiments of the present disclosure are not limited thereto.

The display device 10 according to the one or more embodiments includes the display panel 100, the driving circuits 200, and circuit boards 300.

The display panel 100 may be shaped like a rectangular plane having long sides in a first direction (X-axis direction) and short sides in a second direction (Y-axis direction) crossing the first direction (X-axis direction). Each corner where a long side extending in the first direction (X-axis direction) meets a short side extending in the second direction (Y-axis direction) may be right-angled or may be rounded with a curvature. In one or more embodiments, the X-axis direction and the Y-axis direction may be in a plane that is parallel to the display area DA, and may be perpendicular to each other. The planar shape of the display panel 100 is not limited to a quadrangular shape but may also be other polygonal shapes, a circular shape, or an elliptical shape.

The display panel 100 may be formed flat, but embodiments of the present disclosure are not limited thereto. For example, the display panel 100 may include a curved portion formed at left and right ends and having a constant or varying curvature. In addition, the display panel 100 may be formed to be flexible so that it can be curved, bent, folded, and/or rolled.

The display panel 100 may include a display area DA for displaying an image and a non-display area NDA disposed around (e.g., surrounding) the display area DA.

The display area DA may occupy most of the area of the display panel 100. The display area DA may be disposed in (or at) a center of the display panel 100. Each of the pixels including a plurality of light-emitting areas, may be disposed in the display area DA to display an image.

The non-display area NDA may neighbor the display area DA. The non-display area NDA may be an area outside the display area DA. The non-display area NDA may be around (e.g., may surround) the display area DA. The non-display area NDA may be an edge area of the display panel 100.

Display pads PD to be connected to the circuit boards 300 may be disposed in the non-display area NDA. The display pads PD may be disposed at an edge of the display panel 100. For example, the display pads PD may be disposed at a lower edge of the display panel 100.

The display pads PD may be outermost structures disposed at an outermost position on a lower side of the display panel 100. An outermost structure may be a structure disposed closest to an edge of the display panel 100. The outermost structure may be a structure for driving the display panel 100 or a structure for improving the function of the display panel 100.

The display panel 100 may include a first dam DAM1, a second dam DAM2, and a crack dam CRD.

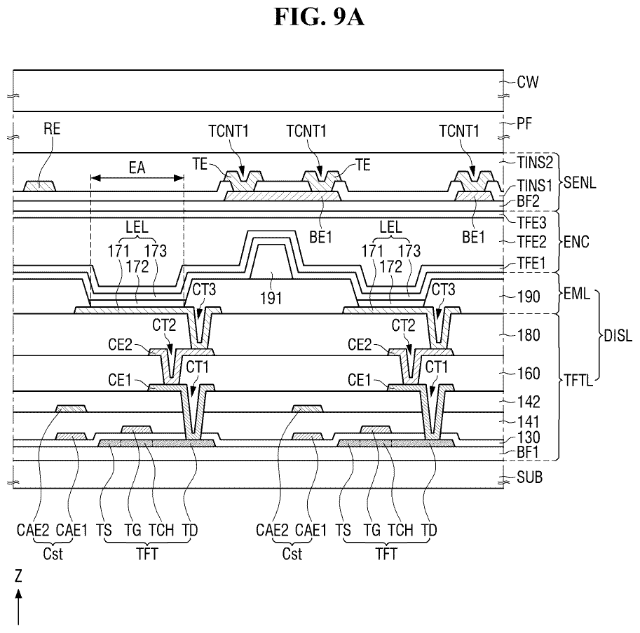

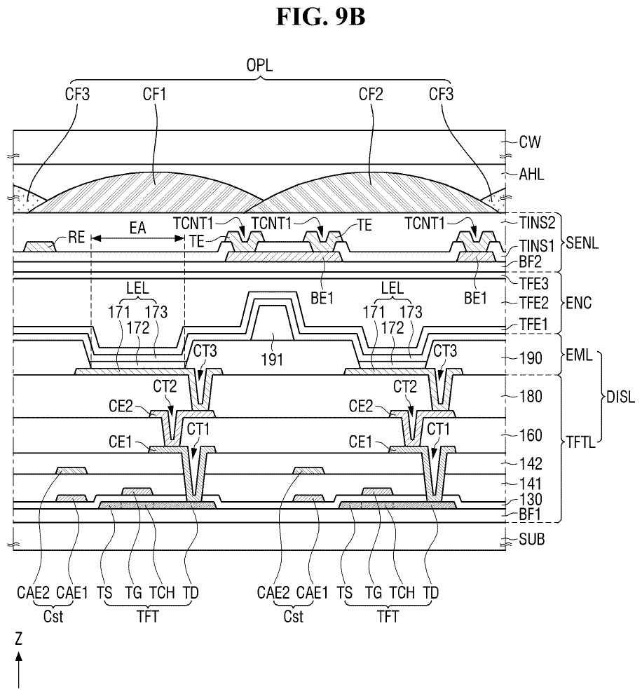

The first dam DAM1 and the second dam DAM2 may be structures for preventing an encapsulating organic layer TFE2 (see FIG. 9A) of an encapsulation layer ENC (see FIG. 9A) from overflowing. The first dam DAM1 may surround the display area DA, and the second dam DAM2 may surround the first dam DAM1.

The crack dam CRD may be a structure for preventing cracks in inorganic layers of the encapsulation layer ENC from propagating in a process of cutting a substrate SUB during a process of fabricating the display device 10. The crack dam CRD may be disposed along left, upper, and right edges of the display panel 100. The crack dam CRD may not be disposed at the lower edge of the display panel 100. The crack dam CRD may be an outermost structure disposed at an outermost position on left, upper, and right sides of the display panel 100.

The driving circuits 200 may generate data voltages, power supply voltages, scan timing signals, etc. The driving circuits 200 may output the data voltages, the power supply voltages, the scan timing signals, etc. The driving circuits 200 may be disposed in the non-display area NDA between the display pads PD and the display area DA.

Each of the driving circuits 200 may be formed as an integrated circuit (IC). Each of the driving circuits 200 may be attached to the non-display area NDA of the display panel 100 using a chip-on-glass (COG) method. Alternatively, each of the driving circuits 200 may be attached to a circuit board 300 using a chip-on-plastic (COP) method.

The circuit boards 300 may be disposed on the display pads PD disposed at an edge of the display panel 100. The circuit boards 300 may be attached to the display pads PD using a conductive adhesive member such as an anisotropic conductive film or an anisotropic conductive adhesive. Accordingly, the circuit boards 300 may be electrically connected to signal lines of the display panel 100. Each of the circuit boards 300 may be a flexible printed circuit board or a flexible film such as a chip on film.

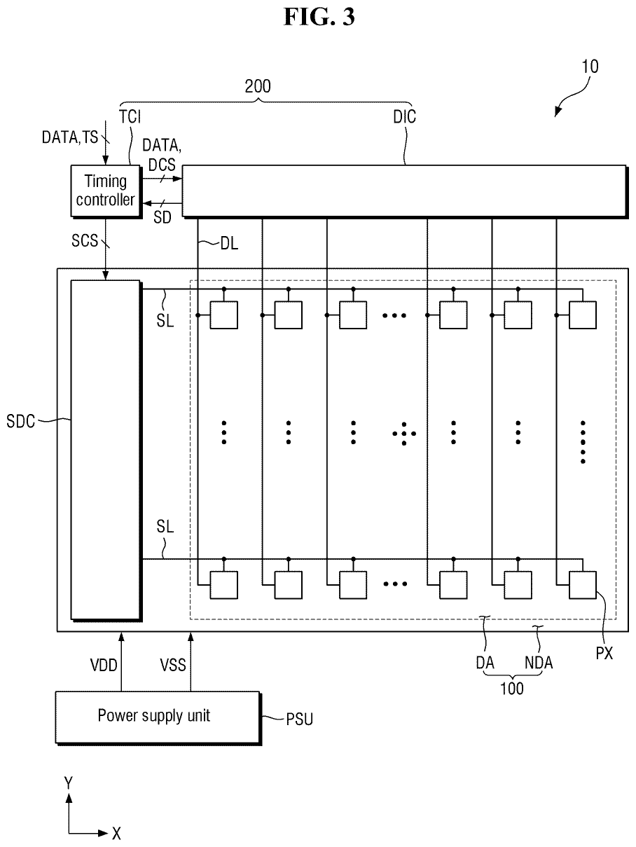

FIG. 3 is a block diagram of the display device 10 according to one or more embodiments of the present disclosure.

Referring to FIG. 3, the display device 10 according to the one or more embodiments includes the display panel 100, a scan driving circuit unit (e.g., a scan driving circuit or a scan driver) SDC, a driving circuit 200, and a power supply unit PSU.

The display panel 100 includes data lines DL, scan lines SL, and pixels PX. The scan lines SL may extend in the first direction (e.g., an X-axis direction) and may be arranged in the second direction (e.g., a Y-axis direction). The data lines DL may extend in the second direction (e.g., the Y-axis direction) and may be arranged in the first direction (e.g., the X-axis direction).

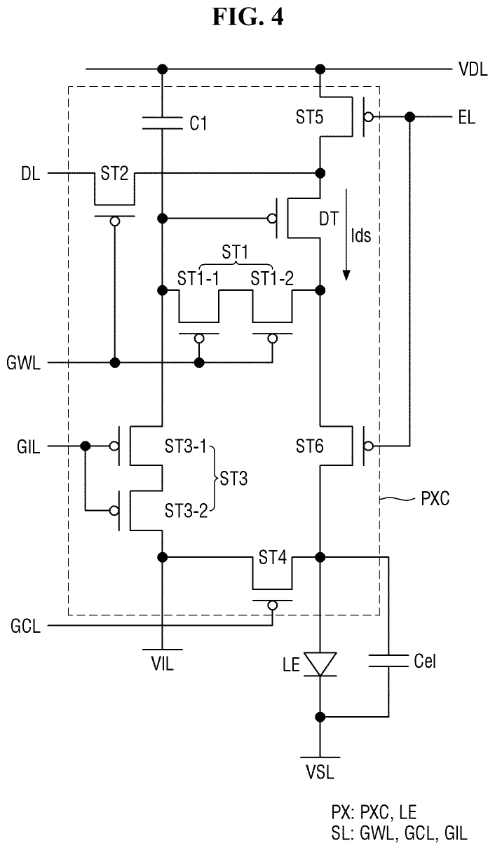

Each of the pixels PX may be connected to at least one of the data lines DL and at least one of the scan lines SL. Each of the pixels PX may include a light emitting element LE and a pixel circuit unit PXC including a plurality of transistors for supplying a driving current to the light emitting element LE, as illustrated in FIGS. 4 through 6. The pixels PX will be described in detail later with reference to FIGS. 4 through 6.

The scan driving circuit unit SDC and the driving circuit 200 may be referred to as a display panel driving unit. The driving circuit 200 may include a timing control circuit unit (e.g., a timing control circuit or a timing controller) TCI and a data driving circuit unit DIC.

The scan driving circuit unit SDC is connected to the scan lines SL to transmit (e.g., transfer or supply) scan signals. The scan driving circuit unit SDC may generate scan signals according to a scan timing control signal SCS input from the timing control circuit unit TCI and output the scan signals to the scan lines SL.

The scan driving circuit unit SDC may include a plurality of transistors. In this case, the scan driving circuit unit SDC may be disposed in the non-display area NDA on the left and right sides of the display panel 100.

The data driving circuit unit DIC is connected to the data lines DL to supply (e.g., transmit or transfer) data voltages. The data driving circuit unit DIC receives digital video data DATA and a data timing control signal DCS from the timing control circuit unit TIC. The data driving circuit unit DIC converts the digital video data DATA into data voltages according to the data timing control signal DCS and outputs the data voltages to the data lines DL.

The timing control circuit unit TCI receives the digital video data DATA and timing signals TS. The timing signals TS may include a vertical sync signal, a horizontal sync signal, a data enable signal, and a clock signal such as a dot clock.

The timing control circuit unit TCI generates control signals for controlling the operation timing of the data driving circuit unit DIC and the scan driving circuit unit SDC. The control signals may include the data timing control signal DCS for controlling the operation timing of the data driving circuit unit DIC and the scan timing control signal SCS for controlling the operation timing of the scan driving circuit unit SDC.

The timing control circuit unit TCI outputs the digital video data DATA and the data timing control signal DCS to the data driving circuit unit DIC and outputs the scan timing control signal SCS to the scan driving circuit unit SDC.

The power supply unit PSU may generate a first power supply voltage VSS corresponding to a low potential voltage and a second power supply voltage VDD corresponding to a high potential voltage from main power applied from the outside. In addition, the power supply unit PSU may supply various driving voltages to the data driving circuit unit DIC, the scan driving circuit unit SDC, and the timing control circuit unit TIC.

FIG. 4 is a circuit diagram of a pixel PX of the display device 10 according to one or more embodiments of the present disclosure.

Referring to FIG. 4, a pixel PX according to the one or more embodiments may include a pixel circuit unit PXC and a light emitting element LE.

The light emitting element LE emits light according to a driving current Ids. The amount of light emitted from the light emitting element LE may be proportional to the driving current Ids.

The light emitting element LE may be an organic light emitting element including an anode, a cathode, and an organic light emitting layer disposed between the anode and the cathode. Alternatively, the light emitting element LE may be an inorganic light emitting element including an anode, a cathode, and an inorganic semiconductor disposed between the anode and the cathode.

The anode of the light emitting element LE may be connected to a second electrode of a fourth transistor ST4 and a second electrode of a sixth transistor ST6, and the cathode of the light emitting element LE may be connected to a first power line VSL (e.g., for supplying the first power supply voltage VSS). A parasitic capacitance Cel may be formed between the anode and the cathode of the light emitting element LE.

The pixel circuit unit PXC includes a driving transistor DT, switch elements (or switching elements), and a capacitor C1. The switch elements include first through sixth transistors ST1 through ST6.

The driving transistor DT includes a gate electrode, a first electrode, and a second electrode. The driving transistor DT controls a drain-source current Ids (hereinafter, referred to as a “driving current”) flowing between the first electrode and the second electrode (e.g., flowing from the first electrode to the second electrode) according to a data voltage applied to the gate electrode.

The capacitor C1 is formed between the first electrode of the driving transistor DT and a second power line VDL (e.g., for supplying the first power supply voltage VDD). One electrode of the capacitor C1 may be connected to the first electrode of the driving transistor DT, and the other electrode may be connected to the second power line VDL.

When a first electrode of each of the first through sixth transistors ST1 through ST6 and the driving transistor DT is a source electrode, a second electrode may be a drain electrode. Alternatively, when the first electrode of each of the first through sixth transistors ST1 through ST6 and the driving transistor DT is a drain electrode, the second electrode may be a source electrode.

An active layer of each of the first through sixth transistors ST1 through ST6 and the driving transistor DT may be made of polysilicon, amorphous silicon, or an oxide semiconductor. When the active layer of each of the first through sixth transistors ST1 through ST6 and the driving transistor DT is made of polysilicon, a process for forming the active layer may be a low-temperature polysilicon (LTPS) process.

In addition, although a case where the first through sixth transistors ST1 through ST6 and the driving transistor DT are formed as P-type metal oxide semiconductor field effect transistors (MOSFETs) has been primarily described in reference to FIG. 4, embodiments of the present disclosure are not limited to this case, and one or more of these transistors may also be formed as N-type MOSFETs.

Furthermore, the first power supply voltage VSS of the first power line VSL, the second power supply voltage VDD of the second power line VDL, and a third power supply voltage (or initialization voltage) of a third power line VIL may be set in consideration of the characteristics of the driving transistor DT, the characteristics of the light emitting element LE, etc.

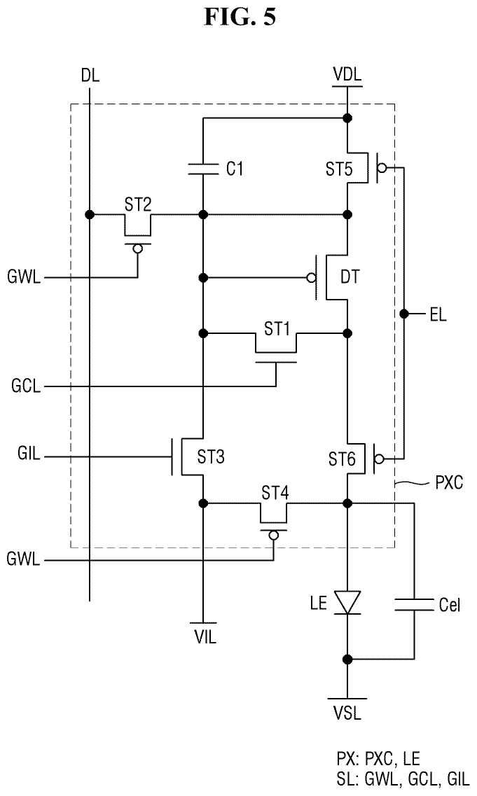

FIG. 5 is a circuit diagram of a pixel of a display device according to one or more embodiments of the present disclosure.

The one or more embodiments of FIG. 5 are different from the one or more embodiments of FIG. 4 in that a driving transistor DT, a second transistor ST2, a fourth transistor ST4, a fifth transistor ST5 and a sixth transistor ST6 are formed as P-type MOSFETs, and a first transistor ST1 and a third transistor ST3 are formed as N-type MOSFETS.

Referring to FIG. 5, an active layer of each of the driving transistor DT, the second transistor ST2, the fourth transistor ST4, the fifth transistor ST5 and the sixth transistor ST6 formed as P-type MOSFETs may be made of polysilicon, and an active layer of each of the first transistor ST1 and the third transistor ST3 formed as N-type MOSFETs may be made of an oxide semiconductor.

The one or more embodiments of FIG. 5 are different from the one or more embodiments of FIG. 4 in that a gate electrode of the second transistor ST2 and a gate electrode of the fourth transistor ST4 are connected to a write scan line GWL, and a gate electrode of the first transistor ST1 is connected to a control scan line GCL. In addition, in FIG. 5, because the first transistor ST1 and the third transistor ST3 are formed as N-type MOSFETs, a scan signal of a gate high voltage may be transmitted to the control scan line GCL and an initialization scan line GIL. On the other hand, because the second transistor ST2, the fourth transistor ST4, the fifth transistor ST5, and the sixth transistor ST6 are formed as P-type MOSFETs, a scan signal of a gate low voltage may be transmitted to the write scan line GWL and an emission line EL.

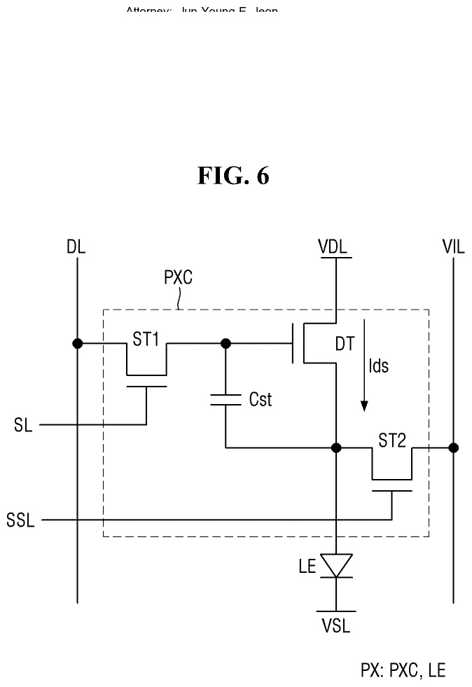

FIG. 6 is a circuit diagram of a pixel of a display device according to one or more embodiments of the present disclosure.

Referring to FIG. 6, a light emitting element LE emits light according to a driving current Ids. The amount of light emitted from the light emitting element LE may be proportional to the driving current Ids. An anode of the light emitting element LE may be connected to a source electrode of a driving transistor DT, and a cathode may be connected to a first power line VSL to which a first power supply voltage VSS, which is lower than a second power supply voltage VDD, is supplied.

The driving transistor DT adjusts a current flowing from a second power line VDL, to which the second power supply voltage VDD is supplied, to the light emitting element LE according to a voltage difference between a gate electrode and the source electrode. The gate electrode of the driving transistor DT may be connected to a first electrode of a first transistor ST1, the source electrode may be connected to the anode of the light emitting element LE, and a drain electrode may be connected to the first power line VSL.

The first transistor ST1 is turned on by a scan signal of a scan line SL to connect a data line DL to the gate electrode of the driving transistor DT. A gate electrode of the first transistor ST1 may be connected to the scan line SL, the first electrode may be connected to the gate electrode of the driving transistor DT, and a second electrode may be connected to the data line DL.

A second transistor ST2 is turned on by a sensing signal of a sensing signal line SSL to connect an initialization voltage line VIL to the source electrode of the driving transistor DT. A gate electrode of the second transistor ST2 may be connected to the sensing signal line SSL, a first electrode may be connected to the initialization voltage line VIL, and a second electrode may be connected to the source electrode of the driving transistor DT.

The first electrode of each of the first and second transistors ST1 and ST2 may be a source electrode, and the second electrode may be a drain electrode. However, it should be noted that embodiments of the present disclosure are not limited thereto. That is, the first electrode of each of the first and second transistors ST1 and ST2 may also be a drain electrode, and the second electrode may also be a source electrode.

A capacitor Cst is formed between the gate electrode and the source electrode of the driving transistor DT. The capacitor Cst stores a difference voltage between a gate voltage and a source voltage of the driving transistor DT.

Although a case where the driving transistor DT and the first and second transistors ST1 and ST2 are formed as N-type MOSFETs has been primarily described in reference to FIG. 6, it should be noted that embodiments of the present disclosure are not limited thereto. The driving transistor DT and the first and second transistors ST1 and ST2 may also be formed as P-type MOSFETs.

It should be noted that a pixel PX according to embodiments of the present disclosure are not limited to those illustrated in FIGS. 4 through 6. The pixel PX according to one or more other embodiments of the present disclosure may have other known circuit structures that can be adopted by those skilled in the art, in addition to the embodiments illustrated in FIGS. 4 through 6.

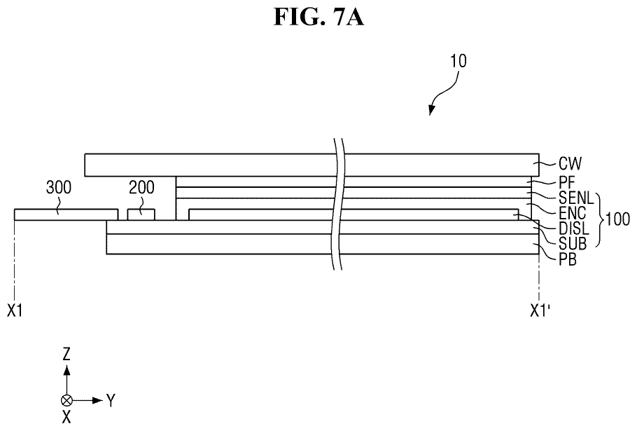

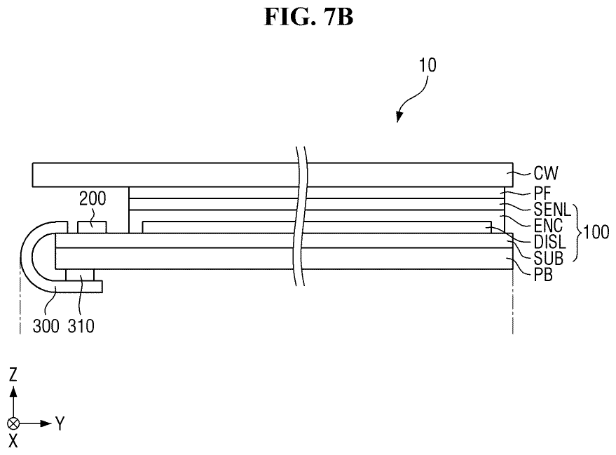

FIG. 7A is a cross-sectional view of an example of a display device 10 taken along the line X1-X1′ of FIG. 1. FIG. 7B is a cross-sectional view of an example of the display device 10 in which a circuit board 300 in FIG. 7A is bent.

Referring to FIGS. 7A and 7B, a display device 10 according to one or more embodiments may include a display panel 100, a polarizing film PF, a cover window CW, and an under-panel cover PB. The display panel 100 may include a substrate SUB, a display layer DISL, an encapsulation layer ENC, and a sensor electrode layer SENL.

The substrate SUB may have a rigid material. For example, the substrate SUB may be made of glass. In other words, the substrate SUB may be a glass substrate. The substrate SUB may be made of ultra-thin glass (UTG) having a thickness of about 200 μm or less.

The display layer DISL may be disposed on a first surface of the substrate SUB. The display layer DISL may be a layer that displays an image. The display layer DISL may include a thin-film transistor layer TFTL (e.g., see FIG. 9A) in which thin-film transistors are formed and a light emitting element layer EML (e.g., see FIG. 9A) in which light emitting elements emitting light are disposed in light-emitting areas.

In a display area DA of the display layer DISL, scan lines, data lines, power lines, etc. may be disposed so that the light-emitting areas can emit light. In a non-display area NDA of the display layer DISL, a scan driving circuit unit for outputting scan signals to the scan lines and fan-out lines connecting the data lines and a driving circuit 200 may be disposed.

The encapsulation layer ENC may be a layer for encapsulating the light emitting element layer EML of the display layer DISL to prevent or reduce penetration of oxygen or moisture into the light emitting element layer EML of the display layer DISL. The encapsulation layer ENC may be disposed on the display layer DISL. The encapsulation layer ENC may be disposed on upper and side surfaces of the display layer DISL. The encapsulation layer ENC may cover the display layer DISL.

The sensor electrode layer SENL may be disposed on the display layer DISL. The sensor electrode layer SENL may include sensor electrodes. The sensor electrode layer SENL may sense a user's touch using the sensor electrodes.

The polarizing film PF may be disposed on the display panel 100 to prevent the visibility of an image displayed on the display panel 100 from being reduced by external light reflected from the display panel 100. The polarizing film PF may include a first base member, a linear polarizer, a phase retardation film such as a quarter-wave (4) plate, and a second base member. The first base member, the phase retardation film, the linear polarizer, and the second base member of the polarizing film PF may be sequentially stacked on the display panel 100.

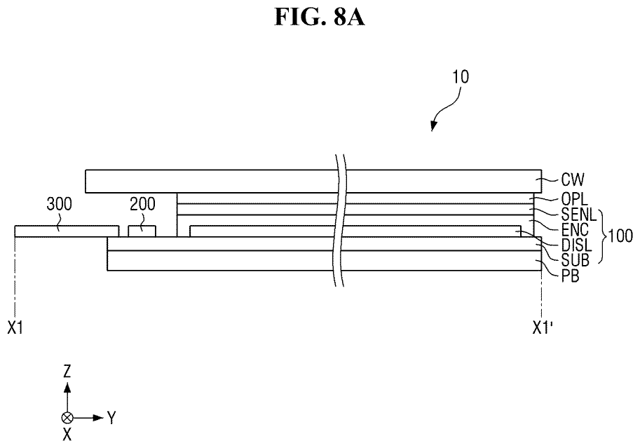

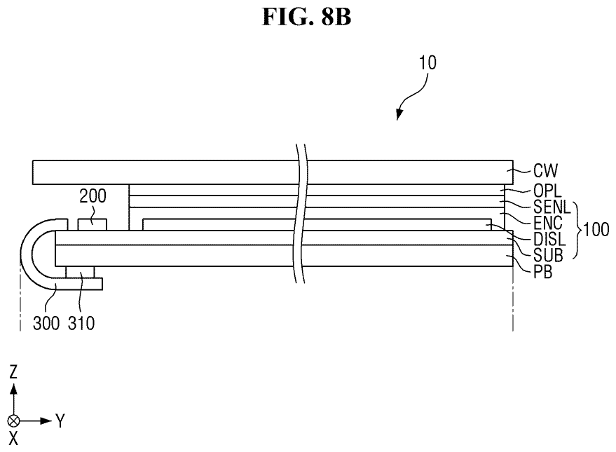

However, embodiments of the present disclosure are not limited thereto, and the polarizing film PF may be omitted. In this case, as illustrated in FIGS. 8A, 8B and 9B, an optical layer OPL including a plurality of color filters CF1 through CF3 may be disposed instead of the polarizing film PF. A planarization layer and/or an adhesive layer AHL may be disposed between the optical layer OPL and the cover window CW. Although the optical layer OPL is disposed on the sensor electrode layer SENL of the display panel 100 in FIGS. 8A, 8B and 9B, embodiments of the present disclosure are not limited thereto. For example, the optical layer OPL may also be disposed between the encapsulation layer ENC and the sensor electrode layer SENL.

The cover window CW may be disposed on the polarizing film PF. The cover window CW may be attached onto the polarizing film PF by a transparent adhesive member such as an optically clear adhesive (OCA) film.

The under-panel cover PB may be disposed on a second surface of the substrate SUB of the display panel 100. The second surface of the substrate SUB may be a surface opposite the first surface. The under-panel cover PB may be attached to the second surface of the substrate SUB of the display panel 100 through an adhesive member. The adhesive member may be a pressure sensitive adhesive.

The under-panel cover PB may include at least one of a light blocking member for absorbing light incident from the outside, a buffer member for absorbing external shock, or a heat dissipation member for efficiently dissipating the heat of the display panel 100.

The light blocking member may be disposed under the display panel 100. The light blocking member blocks transmission of light to prevent elements disposed under the light blocking member, for example, the circuit board 300 from being seen from above the display panel 100. The light blocking member may include a light absorbing material such as a black pigment or dye.

The buffer member may be disposed under the light blocking member. The buffer member absorbs external shock to prevent the display panel 100 from being damaged. The buffer member may be composed of a single layer or a plurality of layers. For example, the buffer member may be made of polymer resin such as polyurethane, polycarbonate, polypropylene and/or polyethylene or may be made of an elastic material such as rubber, a urethane-based material and/or a sponge formed by foaming an acryl-based material.

The heat dissipation member may be disposed under the buffer member. The heat dissipation member may include a first heat dissipation layer including graphite or carbon nanotubes and a second heat dissipation layer formed of a thin metal film such as copper, nickel, ferrite and/or silver that can shield electromagnetic waves and has excellent thermal conductivity.

The circuit board 300 may be bent toward the bottom of the display panel 100 as illustrated in FIG. 7B. The circuit board 300 may be attached to a lower surface of the under-panel cover PB by an adhesive member 310. The adhesive member 310 may be a pressure sensitive adhesive.

FIG. 9A is a cross-sectional view of an example of a display area of a display panel 100 according to one or more embodiments of the present disclosure.

Referring to FIG. 9A, the display panel 100 according to the one or more embodiments may be an organic light emitting display panel including light emitting elements LEL, each including an organic light emitting layer 172.

A display layer DISL may include a thin-film transistor layer TFTL including a plurality of thin-film transistors and a light emitting element layer EML including a plurality of light emitting elements.

A first buffer layer BF1 may be disposed on a substrate SUB. The first buffer layer BF1 may be made of an inorganic material such as a silicon nitride layer, a silicon oxynitride layer, a silicon oxide layer, a titanium oxide layer, and/or an aluminum oxide layer. Alternatively, the first buffer layer BF1 may be a multilayer in which a plurality of layers selected from a silicon nitride layer, a silicon oxynitride layer, a silicon oxide layer, a titanium oxide layer, and/or an aluminum oxide layer are alternately stacked.

An active layer including a channel region TCH, a source region TS, and a drain region TD of each thin-film transistor TFT may be disposed on the first buffer layer BF1. The active layer may be made of polycrystalline silicon, monocrystalline silicon, low-temperature polycrystalline silicon, amorphous silicon, and/or an oxide semiconductor material. When the active layer includes polycrystalline silicon or an oxide semiconductor material, the source region TS and the drain region TD in the active layer may be conductive regions doped with ions or impurities to have conductivity.

A gate insulating layer 130 may be disposed on the active layers of the thin-film transistors TFT. The gate insulating layer 130 may be made of an inorganic layer, for example, a silicon nitride layer, a silicon oxynitride layer, a silicon oxide layer, a titanium oxide layer, and/or an aluminum oxide layer.

A first gate metal layer including gate electrodes TG of the thin-film transistors TFT, first capacitor electrodes CAE1 of capacitors Cst, and scan lines may be disposed on the gate insulating layer 130. The gate electrode TG of each thin-film transistor TFT may overlap the channel region TCH in a third direction (Z-axis direction). In one or more embodiments, the Z-axis direction may be a thickness direction of the display panel 100 or the substrate SUB, and may be perpendicular to a plane that is parallel to the display area DA of the display panel 100. The first gate metal layer may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

A first interlayer insulating layer 141 may be disposed on the first gate metal layer. The first interlayer insulating layer 141 may be made of an inorganic layer, for example, a silicon nitride layer, a silicon oxynitride layer, a silicon oxide layer, a titanium oxide layer, and/or an aluminum oxide layer. The first interlayer insulating layer 141 may include a plurality of inorganic layers, for example.

A second gate metal layer including second capacitor electrodes CAE2 of the capacitors Cst may be disposed on the first interlayer insulating layer 141. The second capacitor electrodes CAE2 may overlap the first capacitor electrodes CAE1 in the third direction (Z-axis direction). Therefore, the first capacitor electrodes CAE1, the second capacitor electrodes CAE2, and inorganic insulating dielectric layers disposed between the first and second capacitor electrodes CAE1 and CAE2 to serve as dielectric layers may form the capacitors Cst. The second gate metal layer may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

A second interlayer insulating layer 142 may be disposed on the second gate metal layer and the first interlayer insulating layer 141. The second interlayer insulating layer 142 may be made of an inorganic layer, for example, a silicon nitride layer, a silicon oxynitride layer, a silicon oxide layer, a titanium oxide layer, and/or an aluminum oxide layer. The second interlayer insulating layer 142 may include a plurality of inorganic layers.

A first data metal layer including first connection electrodes CE1 and data lines may be disposed on the second interlayer insulating layer 142. The first connection electrodes CE1 may be connected to the drain regions TD through first contact holes CT1 penetrating the gate insulating layer 130, the first interlayer insulating layer 141, and the second interlayer insulating layer 142. The first data metal layer may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

A first organic layer 160 may be disposed on the first connection electrodes CE1 and the second interlayer insulating layer 142 to flatten steps caused by the thin-film transistors TFT. The first organic layer 160 may be made of an organic layer such as acryl resin, epoxy resin, phenolic resin, polyamide resin, and/or polyimide resin.

A second data metal layer including second connection electrodes CE2 may be disposed on the first organic layer 160. The second data metal layer may be connected to the first connection electrodes CE1 through second contact holes CT2 penetrating the first organic layer 160. The second data metal layer may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

A second organic layer 180 may be disposed on the second connection electrodes CE2 and the first organic layer 160. The second organic layer 180 may be made of an organic layer such as acryl resin, epoxy resin, phenolic resin, polyamide resin, and/or polyimide resin.

The second data metal layer including the second connection electrodes CE2 and the second organic layer 180 may be omitted.

The light emitting element layer EML is disposed on the thin-film transistor layer TFTL. The light emitting element layer EML may include the light emitting elements LEL and a bank 190.

Each of the light emitting elements LEL may include a pixel electrode 171, a light emitting layer 172, and a common electrode 173. Each light-emitting area EA refers to an area in which the pixel electrode 171, the light emitting layer 172, and the common electrode 173 are sequentially stacked so that holes from the pixel electrode 171 and electrons from the common electrode 173 are combined with each other in the light emitting layer 172 to emit light. In this case, the pixel electrode 171 may be an anode, and the common electrode 173 may be a cathode.

A pixel electrode layer including the pixel electrodes 171 may be formed on the second organic layer 180. The pixel electrodes 171 may be connected to the second connection electrodes CE2 through third contact holes CT3 penetrating the second organic layer 180. The pixel electrode layer may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

In a top emission structure in which light is emitted in a direction from the light emitting layers 172 toward the common electrode 173, each of the pixel electrodes 171 may be formed as a single layer of molybdenum (Mo), titanium (Ti), copper (Cu) and/or aluminum (Al) or, in order to increase reflectivity, may be formed as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The bank 190 defines the light-emitting areas EA of pixels. To this end, the bank 190 may be formed on the second organic layer 180 to partially expose the pixel electrodes 171. The bank 190 may cover edges of the pixel electrodes 171. The bank 190 may be disposed in the third contact holes CT3. That is, the third contact holes CT3 may be filled with the bank 190. In other words, the third contact holes CT3 may be filed with respective portions of the bank 190 that extends into the third contact holes CT3. The bank 190 may be made of an organic layer such as acryl resin, epoxy resin, phenolic resin, polyamide resin, and/or polyimide resin.

A spacer 191 may be disposed on the bank 190. The spacer 191 may support a mask during a process of fabricating the light emitting layers 172. The spacer 191 may be made of an organic layer such as acryl resin, epoxy resin, phenolic resin, polyamide resin, and/or polyimide resin.

The light emitting layers 172 are formed on the pixel electrodes 171. The light emitting layers 172 may include an organic material to emit light of a suitable color (e.g., a predetermined color). For example, each of the light emitting layers 172 may include a hole transporting layer, an organic material layer, and/or an electron transporting layer. The organic material layer may include a host and a dopant. The organic material layer may include a material that emits suitable light (e.g., predetermined light) and may be formed using a phosphorescent material or a fluorescent material.

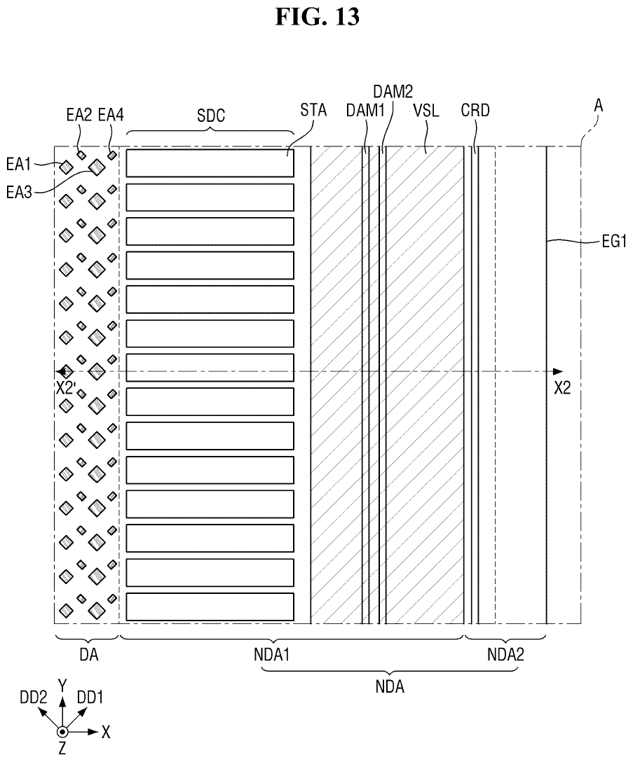

The common electrode 173 is formed on the light emitting layers 172, the bank 190 and the spacer 191. The common electrode 173 may be formed to cover the light emitting layers 172, the bank 190 and the spacer 191. The common electrode 173 may be a common layer commonly formed in light-emitting areas EA. Light-emitting areas EA1 through EA4 are shown in FIG. 13, for example. A capping layer may be formed on the common electrode 173.

In the top emission structure, the common electrode 173 may be made of a transparent conductive material (TCO) that can transmit light, such as indium tin oxide (ITO) or indium zinc oxide (IZO), or may be made of a semi-transmissive conductive material such as magnesium (Mg), silver (Ag) and/or or an alloy of Mg and Ag. When the common electrode 173 is made of a semi-transmissive conductive material, light output efficiency may be increased by utilizing a microcavity, for example.

The encapsulation layer ENC may be formed on the light emitting element layer EML. The encapsulation layer ENC may include at least one inorganic layer TFE1 and/or TFE3 to prevent oxygen or moisture from penetrating into the light emitting element layer EML. In addition, the encapsulation layer ENC may include at least one organic layer TFE2 to protect the light emitting element layer EML from foreign substances such as dust. For example, the encapsulation layer ENC may include a first encapsulating inorganic layer TFE1, an encapsulating organic layer TFE2, and a second encapsulating inorganic layer TFE3.

The first encapsulating inorganic layer TFE1 may be disposed on the common electrode 173, the encapsulating organic layer TFE2 may be disposed on the first encapsulating inorganic layer TFE1, and the second encapsulating inorganic layer TFE3 may be disposed on the encapsulating organic layer TFE2. Each of the first encapsulating inorganic layer TFE1 and the second encapsulating inorganic layer TFE3 may be a multilayer in which one or more inorganic layers selected from a silicon nitride layer, a silicon oxynitride layer, a silicon oxide layer, a titanium oxide layer, and/or an aluminum oxide layer are alternately stacked. The encapsulating organic layer TFE2 may be an organic layer such as acryl resin, epoxy resin, phenolic resin, polyamide resin, and/or polyimide resin.

A sensor electrode layer SENL is disposed on the encapsulation layer ENC. The sensor electrode layer SENL may include sensor electrodes TE and RE.

A second buffer layer BF2 may be disposed on the encapsulation layer ENC. The second buffer layer BF2 may include at least one inorganic layer. For example, the second buffer layer BF2 may be a multilayer in which one or more inorganic layers selected from a silicon nitride layer, a silicon oxynitride layer, a silicon oxide layer, a titanium oxide layer, and/or an aluminum oxide layer are alternately stacked. The second buffer layer BF2 may be omitted in one or more embodiments.

First connection portions BE1 may be disposed on the second buffer layer BF2. Each of the first connection portions BE1 may be formed as a single layer of molybdenum (Mo), titanium (Ti), copper (Cu) and/or aluminum (Al) or may be formed as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

A first sensor insulating layer TINS1 may be disposed on the first connection portions BE1 and the second buffer layer BF2. The first sensor insulating layer TINS1 may be made of an inorganic layer, for example, a silicon nitride layer, a silicon oxynitride layer, a silicon oxide layer, a titanium oxide layer, and/or an aluminum oxide layer.

Sensor electrodes, that are, driving electrodes TE and sensing electrodes RE. may be disposed on the first sensor insulating layer TNIS1. In addition, dummy patterns may be disposed on the first sensor insulating layer TNIS1. The driving electrodes TE, the sensing electrodes RE, and the dummy patterns do not overlap the light-emitting areas EA. Each of the driving electrodes TE, the sensing electrodes RE, and the dummy patterns may be formed as a single layer of molybdenum (Mo), titanium (Ti), copper (Cu) and/or aluminum (Al) or may be formed as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

A second sensor insulating layer TINS2 may be disposed on the driving electrodes TE, the sensing electrodes RE, the dummy patterns and the first sensor insulating layer TINS1. The second sensor insulating layer TINS2 may include at least one of an inorganic layer or an organic layer. The inorganic layer may be a silicon nitride layer, a silicon oxynitride layer, a silicon oxide layer, a titanium oxide layer, and/or an aluminum oxide layer. The organic layer may be acryl resin, epoxy resin, phenolic resin, polyamide resin, and/or polyimide resin.

A polarizing plate POL may be disposed on the sensor electrode layer SENL. The polarizing plate POL may be a structure for preventing visibility degradation caused by reflection of external light. The polarizing plate POL may include a linear polarizing plate and a phase retardation film. For example, the phase retardation film may be a λ/4 plate (quarter-wave plate), but embodiments of the present disclosure are not limited thereto.

Alternatively, referring to FIG. 9B, when visibility degradation caused by reflection of external light is sufficiently overcome by the first to third color filters CF1, CF2, and CF3, the polarizing plate POL may be omitted.

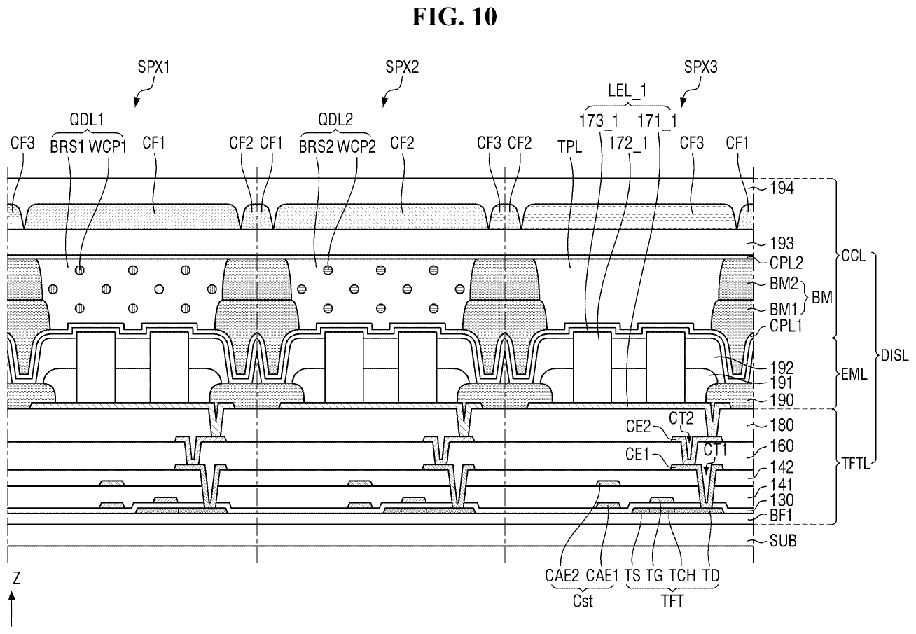

FIG. 10 is a cross-sectional view of an example of a display area of a display panel 100 according to one or more embodiments of the present disclosure.

Referring to FIG. 10, the display panel 100 according to the one or more embodiments may be a light emitting diode display panel including light emitting elements LEL_1 which include light emitting diode elements 172_1 extending in the third direction (Z-axis direction). Each of the light emitting diode elements 172_1 may be a micro-light emitting diode having a length or size in micrometers and made of an inorganic material. In this case, the display panel 100 according to the one or more embodiments may be a micro-light emitting diode display panel.

Because the display panel 100 according to the one or more embodiments includes the light emitting diode elements 172_1 made of an inorganic material, an encapsulation structure may not be required and is not utilized. Therefore, the display panel 100 according to the one or more embodiments may not include an encapsulation layer ENC.

In addition, when the light emitting diode elements 172_1 of the display panel 100 according to the one or more embodiments emit the same light, a color control layer CCL may be included. When the light emitting diode elements 172_1 of the display panel 100 according to the one or more embodiments are elements that emit light of a plurality of colors, the color control layer CCL may be omitted.

Furthermore, in FIG. 10, a polarizing film PF and a cover window CW (e.g., as shown in FIG. 9A) are not illustrated for ease of description. The polarizing film PF may be disposed on the color control layer CCL, and the cover window CW may be disposed on the polarizing film PF.

A display layer DISL of the display panel 100 according to the one or more embodiments includes a thin-film transistor layer TFTL, a light emitting element layer EML, and the color control layer CCL. Because the thin-film transistor layer TFTL illustrated in FIG. 10 is substantially the same as the thin-film transistor layer TFTL described with reference to FIG. 9A, a description of the thin-film transistor layer TFTL is omitted in FIG. 10.

The light emitting element layer EML may include the light emitting elements LEL_1, a bank 190, a third organic layer 191, and a fourth organic layer 192.

Each of the light emitting elements LEL_1 may include a pixel electrode 171_1, the light emitting diode elements 172_1, and a common electrode 173_1. Because the pixel electrode 171_1 is substantially the same as the pixel electrode 171 described with reference to FIG. 9A, a description of the pixel electrode 171_1 is omitted in reference to FIG. 10.

The bank 190 may cover edges of the pixel electrodes 171_1. The bank 190 may be made of an organic layer such as acryl resin, epoxy resin, phenolic resin, polyamide resin, and/or polyimide resin. The bank 190 may include a light-blocking material to prevent light of the light emitting diode elements 172_1 of any one subpixel from traveling to a neighboring subpixel. For example, the bank 190 may include an inorganic black pigment such as carbon black or an organic black pigment.

A plurality of light emitting diode elements 172_1 may be disposed on each pixel electrode 171_1 exposed without being covered by the bank 190. Each of the light emitting diode elements 172_1 may be a vertical micro-light emitting diode extending in the third direction (Z-axis direction). In this case, each of the light emitting diode elements 172_1 may have a rectangular or inverse tapered cross-sectional shape. However, each of the light emitting diode elements 172_1 is not limited to a vertical micro-light emitting diode and may also be a flip-type micro-light emitting diode.

Each of the light emitting diode elements 172_1 may be made of an inorganic material such as gallium nitride (GaN). Each of the light emitting diode elements 172_1 may have a length of several to hundreds of μm in each of the first direction (X-axis direction), the second direction (Y-axis direction), and the third direction (Z-axis direction). For example, each of the light emitting diode elements 172_1 may have a length of about 100 μm or less in each of the first direction (X-axis direction), the second direction (Y-axis direction), and the third direction (Z-axis direction). The light emitting diode elements 172_1 may have other sizes (e.g., nanometer sizes) in one or more directions according to one or more embodiments of the present disclosure.

Each of the light emitting diode elements 172_1 may be grown on a semiconductor substrate such as a silicon wafer. Each of the light emitting diode elements 172_1 may be directly transferred from the silicon wafer to a pixel electrode 171_1 of the substrate SUB. Alternatively, each of the light emitting diode elements 172_1 may be transferred onto a pixel electrode 171_1 of the substrate SUB through an electrostatic method using an electrostatic head or a stamp method using an elastic polymer material such as PDMS or silicon as a transfer substrate.

Each of the light emitting diode elements 172_1 may be an inorganic light emitting diode having a length or size in micrometers or nanometers and made of an inorganic material. The light emitting diode elements 172_1 may extend in a direction. Each of the light emitting diode elements 172_1 may be shaped like a cylinder, a rod, a wire, or a tube. However, the shape of each of the light emitting diode elements 172_1 is not limited thereto, and each of the light emitting diode elements 172_1 may also have various shapes including polygonal prisms, such as a cube, a rectangular parallelepiped or a hexagonal prism, and a shape extending in a direction and having a partially inclined outer surface.

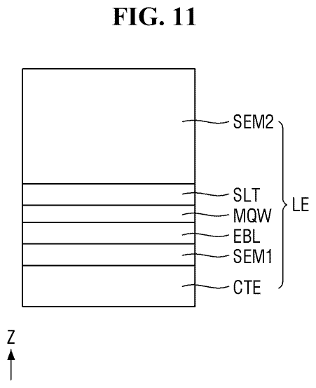

As illustrated in FIG. 11, each of the light emitting diode elements 172_1 may include a contact electrode CTE, a first semiconductor layer SEM1, an electron blocking layer EBL, an active layer MQW, a superlattice layer SLT, and a second semiconductor layer SEM2.

The contact electrode CTE may be disposed on a pixel electrode 171_1. The contact electrode CTE and the pixel electrode 171_1 may be melt-bonded by heat and pressure. Alternatively, the contact electrode CTE and the pixel electrode 171_1 may be bonded to each other through a conductive adhesive member such as an anisotropic conductive film or an anisotropic conductive adhesive. Alternatively, the contact electrode CTE and the pixel electrode 171_1 may be bonded to each other through a soldering process. For example, the contact electrode CTE may include at least any one of gold (Au), copper (Cu), aluminum (Al), or tin (Sn).

The first semiconductor layer SEM1 may be disposed on the contact electrode CTE. The first semiconductor layer SEM1 may be made of GaN doped with a first conductivity type dopant (e.g., p-type dopant) such as Mg, Zn, Ca, Se, and/or Ba.

The electron blocking layer EBL may be disposed on the first semiconductor layer SEM1. The electron blocking layer EBL may be a layer for suppressing or preventing too many electrons from flowing into the active layer MQW. For example, the electron blocking layer EBL may be p-AlGaN doped with p-type Mg. The electron blocking layer EBL may be omitted.

The active layer MQW may be disposed on the electron blocking layer EBL. The active layer MQW may emit light through combination of electron-hole pairs according to electrical signals received through the first semiconductor layer SEM1 and the second semiconductor layer SEM2.

The active layer MQW may include a material having a single or multiple quantum well structure. When the active layer MQW includes a material having a multiple quantum well structure, it may be a structure in which a plurality of well layers and a plurality of barrier layers are alternately stacked. Here, the well layers may be made of InGaN, and the barrier layers may be made of GaN or AlGaN, but embodiments of the present disclosure are not limited thereto. Alternatively, the active layer MQW may be a structure in which a semiconductor material having a large band gap energy and a semiconductor material having a small band gap energy are alternately stacked or may include different group III to V semiconductor materials depending on the wavelength band of light that it emits.

When the active layer MQW includes InGaN, the color of light that it emits may vary according to indium content. For example, as the indium content increases, the wavelength band of light emitted from the active layer MQW may move to a red wavelength band, and as the indium content decreases, the wavelength band of light emitted from the active layer MQW may move to a blue wavelength band. For example, the indium content of the active layer MQW of the light emitting diode element 172_1 which emits light in the blue wavelength band may be about 10 to 20 wt %.

The superlattice layer SLT may be disposed on the active layer MQW. The superlattice layer SLT may be a layer for relieving stress between the second semiconductor layer SEM2 and the active layer MQW. For example, the superlattice layer SLT may be made of InGaN or GaN. The superlattice layer SLT may be omitted.

The second semiconductor layer SEM2 may be disposed on the superlattice layer SLT. The second semiconductor layer SEM2 may be doped with a second conductivity type dopant (e.g., n-type dopant) such as Si, Ge, and/or Sn. For example, the second semiconductor layer SEM2 may be n-GaN doped with n-type Si.

The third organic layer 191 may be disposed on the pixel electrodes 171_1 not covered by the bank 190 and the light emitting diode elements 172_1. The third organic layer 191 may cover side surfaces of the bank 190 and partially cover an upper surface of the bank 190. A height of the third organic layer 191 may be greater than a height of the bank 190. The third organic layer 191 may be disposed on a portion of each side surface of each of the light emitting diode elements 172_1. The height of the third organic layer 191 may be smaller than a height of each of the light emitting diode elements 172_1. The third organic layer 191 may be made of an organic layer such as acryl resin, epoxy resin, phenolic resin, polyamide resin, and/or polyimide resin.

The fourth organic layer 192 may be disposed on the third organic layer 191 to partially cover an upper surface and side surfaces of the third organic layer 191.

The fourth organic layer 192 may be disposed on a portion of each side surface of each of the light emitting diode elements 172_1. The fourth organic layer 192 may partially cover an upper surface of the bank 190. The sum of the height of the third organic layer 191 and a height of the fourth organic layer 192 may be smaller than the height of each of the light emitting diode elements 172_1. The fourth organic layer 192 may be made of an organic layer such as acryl resin, epoxy resin, phenolic resin, polyamide resin, and/or polyimide resin.

The third organic layer 191 and the fourth organic layer 192 are layers for flattening steps caused by the light emitting diode elements 172_1. When the height of each of the light emitting diode elements 172_1 is similar to the height of the third organic layer 191, the fourth organic layer 192 may be omitted.

The common electrode 173_1 may be disposed on an upper surface of each of the light emitting diode elements 172_1 and an upper surface of the fourth organic layer 192. The common electrode 173_1 may be disposed on the bank 190 exposed without being covered by the third organic layer 191 and the fourth organic layer 192. The common electrode 173_1 may be a common layer commonly formed in a first subpixel SPX1, a second subpixel SPX2, and a third subpixel SPX3. The common electrode 173_1 may be made of a transparent conductive material (TCO) that can transmit light, such as indium tin oxide (ITO) or indium zinc oxide (IZO).

The color control layer CCL may include a first capping layer CPL1, a light blocking layer BM, a first light conversion layer QDL1, a second light conversion layer QDL2, a light transmission layer TPL, a second capping layer CPL2, a fifth organic layer 193, a plurality of color filters CF1 through CF3, and a sixth organic layer 194.

The first capping layer CPL1 may be disposed on the common electrode 173_1. The first capping layer CPL1 may be made of an inorganic layer, for example, a silicon nitride layer, a silicon oxynitride layer, a silicon oxide layer, a titanium oxide layer, and/or an aluminum oxide layer.

The light blocking layer BM, the first light conversion layer QDL1, the second light conversion layer QDL2, and the light transmission layer TPL may be disposed on the first capping layer CPL1. The first light conversion layer QDL1, the second light conversion layer QDL2, and the light transmission layer TPL may be separated by the light blocking layer BM. Therefore, the first light conversion layer QDL1 may be disposed on the first capping layer CPL1 in the first subpixel SPX1 that outputs first light, the second light conversion layer QDL2 may be disposed on the first capping layer CPL1 in the second subpixel SPX2 that outputs second light, and the light transmission layer TPL may be disposed on the first capping layer CPL1 in the third subpixel SPX3 that outputs third light. The light blocking layer BM may overlap the bank 190 in the third direction (Z-axis direction) and may not overlap the light emitting diode elements 172_2.

The first light conversion layer QDL1 may convert a portion of light in a blue wavelength band incident from the light emitting diode elements 172_2 into light in a red wavelength band. The first light conversion layer QDL1 may include a first base resin BRS1 and first wavelength conversion particles WCP1. The first base resin BRS1 may include a light-transmitting organic material. For example, the first base resin BRS1 may include epoxy resin, acrylic resin, cardo resin, and/or imide resin. The first wavelength conversion particles WCP1 may convert a portion of light in the blue wavelength band incident from the light emitting diode elements 172_2 into light in the red wavelength band. The first wavelength conversion particles WCP1 may include quantum dots, quantum rods, fluorescent materials, and/or phosphorescent materials.

The second light conversion layer QDL2 may convert a portion of light in the blue wavelength band incident from the light emitting diode elements 172_2 into light in a green wavelength band. The second light conversion layer QDL2 may include a second base resin BRS2 and second wavelength conversion particles WCP2. The second base resin BRS2 may include a light-transmitting organic material. For example, the second base resin BRS2 may include epoxy resin, acrylic resin, cardo resin, and/or imide resin. The second wavelength conversion particles WCP2 may convert a portion of light in the blue wavelength band incident from the light emitting diode elements 172_2 into light in the green wavelength band. The second wavelength conversion particles WCP2 may include quantum dots, quantum rods, fluorescent materials, and/or phosphorescent materials.

The light transmitting layer TPL may include a light-transmitting organic material. For example, the light transmitting layer TPL may include epoxy resin, acrylic resin, cardo resin, and/or imide resin.

The light blocking layer BM may include a first light blocking layer BM1 and a second light blocking layer BM2 stacked sequentially. A length of the first light blocking layer BM1 in the first direction (X-axis direction) or a length of the first light blocking layer BM1 in the second direction (Y-axis direction) may be greater than a length of the second light blocking layer BM2 in the first direction (X-axis direction) or a length of the second light blocking layer BM2 in the second direction (Y-axis direction). The first light blocking layer BM1 and the second light blocking layer BM2 may be made of an organic layer such as acryl resin, epoxy resin, phenolic resin, polyamide resin, and/or polyimide. The first light blocking layer BM1 and the second light blocking layer BM2 may include a light blocking material to prevent light of the light emitting diode elements 172_2 of any one subpixel from traveling to a neighboring subpixel. For example, the first light blocking layer BM1 and the second light blocking layer BM2 may include an inorganic black pigment such as carbon black and/or an organic black pigment.

The second capping layer CPL2 may be disposed on the light blocking layer BM, the first light conversion layer QDL1, the second light conversion layer QDL2, and the light transmission layer TPL. The second capping layer CPL2 may be made of an inorganic layer, for example, a silicon nitride layer, a silicon oxynitride layer, a silicon oxide layer, a titanium oxide layer, and/or an aluminum oxide layer. The light blocking layer BM, the first light conversion layer QDL1, the second light conversion layer QDL2, and the light transmission layer TPL may be encapsulated by the first capping layer CPL1 and the second capping layer CPL2.

The fifth organic layer 193 may be disposed on the second capping layer CPL2. The fifth organic layer 193 may be made of acryl resin, epoxy resin, phenolic resin, polyamide resin, and/or polyimide resin.

A plurality of color filters CF1 through CF3 may be disposed on the fifth organic layer 193. The color filters CF1 through CF3 may include a first color filter CF1, a second color filter CF2, and a third color filter CF3.

The first color filter CF1 disposed in the first subpixel SPX1 may transmit light in the red wavelength band and absorb or block light in the blue wavelength band. Therefore, the first color filter CF1 may transmit light in the red wavelength band into which light in the blue wavelength band has been converted by the first light conversion layer QDL1 among light in the blue wavelength band emitted from the light emitting diode elements 172_2 and may absorb or block light in the blue wavelength band that has not been converted by the first light conversion layer QDL1. Accordingly, the first subpixel SPX1 may emit light in the red wavelength band.

The second color filter CF2 disposed in the second subpixel SPX2 may transmit light in the green wavelength band and absorb or block light in the blue wavelength band. Therefore, the second color filter CF2 may transmit light in the green wavelength band into which light in the blue wavelength band has been converted by the second light conversion layer QDL2 among light in the blue wavelength band emitted from the light emitting diode elements 172_2 and may absorb or block light in the blue wavelength band that has not been converted by the second light conversion layer QDL2. Accordingly, the second subpixel SPX2 may emit light in the green wavelength band.

The third color filter CF3 disposed in the third subpixel SPX3 may transmit light in the blue wavelength band. Therefore, the third color filter CF3 may transmit light in the blue wavelength band passing through the light transmission layer TPL after being emitted from the light emitting diode elements 172_2. Accordingly, the third subpixel SPX3 may emit light in the blue wavelength band.

The sixth organic layer 194 for planarization may be disposed on the color filters CF1 through CF3. The sixth organic layer 194 may be made of acryl resin, epoxy resin, phenolic resin, polyamide resin, and/or polyimide resin.

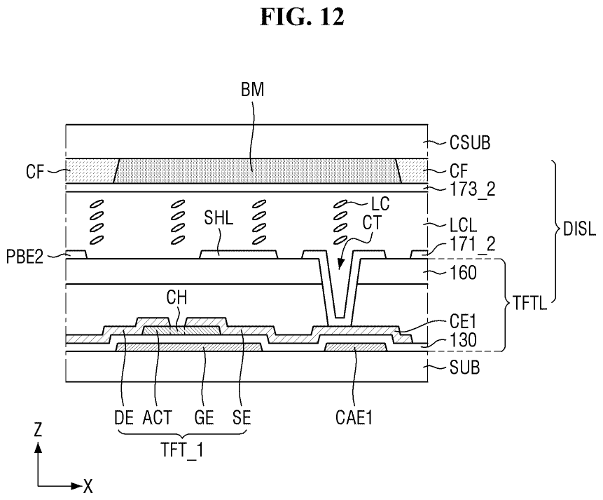

FIG. 12 is a cross-sectional view of an example of a display area of a display panel 100 according to one or more embodiments of the present disclosure.

Referring to FIG. 12, the display panel 100 according to the one or more embodiments may be a liquid crystal display panel having a liquid crystal layer LCL that includes liquid crystals LC.

A gate metal layer including a scan line, a first capacitor electrode CAE1, and a gate electrode GE may be disposed on a substrate SUB. The gate metal layer may include molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W) and/or copper (Cu) and/or an alloy thereof. Alternatively, the gate metal layer may have a two-layer structure of molybdenum/aluminum-neodymium, molybdenum/aluminum, or copper/titanium.

A gate insulating layer 130 may be disposed on the gate metal layer and the substrate SUB. The gate insulating layer 130 may include silicon oxide, silicon nitride, silicon oxynitride, aluminum oxide, tantalum oxide, hafnium oxide, zirconium oxide, titanium oxide, and/or a combination thereof.

An active layer ACT may be disposed on the gate insulating layer GI. The active layer ACT may include a channel region CH disposed between a source electrode SE and a drain electrode DE in the first direction (X-axis direction). The channel region CH may overlap the gate electrode GE.

The active layer ACT may include a silicon-based semiconductor material such as amorphous silicon, polycrystalline silicon, and/or monocrystalline silicon. Alternatively, the active layer ACT may include an oxide semiconductor.

An ohmic contact layer may be disposed on the active layer ACT. Specifically, the ohmic contact layer may be disposed between the source electrode SE and the active layer ACT and between the drain electrode DE and the active layer ACT. The ohmic contact layer may lower contact resistance by lowering a Schottky barrier, that is, a work function between metal and silicon. The ohmic contact layer may be made of amorphous silicon doped with a high concentration of n-type impurities.

A data metal layer including a data line, the source electrode SE, the drain electrode DE and a first connection electrode CE1 may be disposed on the gate insulating layer 130. The source electrode SE and the drain electrode DE may be disposed on the active layer ACT. The source electrode SE and the first connection electrode CE1 may be formed integrally with each other. The data metal layer may include molybdenum (Mo), aluminum (Al), platinum (Pt), palladium (Pd), silver (Ag), magnesium (Mg), gold (Au), nickel (Ni), neodymium (Nd), iridium (Ir), chromium (Cr), titanium (Ti), tantalum (Ta), tungsten (W) and/or copper (Cu) and/or an alloy thereof. Alternatively, the data metal layer may have a two-layer structure of molybdenum/aluminum-neodymium, molybdenum/aluminum or copper/titanium or may have a three-layer structure of molybdenum/titanium/molybdenum or molybdenum/aluminum/molybdenum.

A first organic layer 160 may be disposed on the data metal layer and the active layer ACT. The first organic layer 160 may include an organic insulating material and/or an inorganic insulating material. For example, the first organic layer 160 may be an overcoat layer made of an organic insulating material.

A pixel electrode layer including a pixel electrode 171_2 may be disposed on the first organic layer 160. The pixel electrode 171_2 may be connected to the first connection electrode CE1 through a contact hole CT penetrating the first organic layer 160. The pixel electrode layer may be made of a transparent material that allows light to pass therethrough. For example, the pixel electrode layer may be made of indium tin oxide (ITO), indium zinc oxide (IZO), or indium tin zinc oxide (ITZO). However, embodiments of the preset disclosure are not limited thereto, and any suitable material that is transparent and conductive can be used.

A color filter substrate CSUB facing (or opposing) the substrate SUB may be a transparent insulating substrate similar to the substrate SUB. For example, the color filter substrate CSUB may be made of glass.

A light blocking layer BM may be disposed on a surface of the color filter substrate CSUB which faces (or opposes) the substrate SUB. The light blocking layer BM may overlap a thin-film transistor TFT_1 and the contact hole CT. The light blocking layer BM may include a light blocking pigment such as carbon black and/or an opaque metal material such as chromium (Cr). Alternatively, the light blocking layer BM may include a photosensitive organic material. The light blocking layer BM may also be disposed on the substrate SUB.

A common electrode 173_2 may be disposed on a surface of the light blocking layer BM that faces (or opposes) the substrate SUB. The common electrode 173 may be made of a transparent conductive material such as indium tin oxide (ITO), indium zinc oxide (IZO), or indium tin zinc oxide (ITZO). The common electrode 173 may be formed over the entire surface of the color filter substrate CSUB.

The liquid crystal layer LCL may be disposed between the substrate SUB and the color filter substrate CSUB. The liquid crystal layer LCL may include the liquid crystals LC having dielectric anisotropy. When a data voltage is applied to the pixel electrode 171_2 and a common voltage is applied to the common electrode 173_2, an electric field may be formed between the pixel electrode 171_2 and the common electrode 173_2. The arrangement of the liquid crystals LC in the liquid crystal layer LCL may be changed according to the electric field between the pixel electrode 171_2 and the common electrode 173_2. Accordingly, the transmittance of light passing through the liquid crystal layer LCL may be controlled.

By way of example, when an electric field is formed between the pixel electrode 171_2 and the common electrode 173_2, the liquid crystals LC may rotate in a specific direction to adjust a phase retardation value of light passing through the liquid crystal layer LCL. The amount of light passing through an upper polarizing film disposed on an upper surface of the color filter substrate CSUB among light passing through a lower polarizing film disposed on a lower surface of the substrate SUB may vary according to how much the phase retardation value is changed by the rotation of the liquid crystals LC. Therefore, the transmittance of light passing through the liquid crystal layer LCL can be controlled.

As described in FIGS. 9, 10 and 12, a display panel 100 according to one or more embodiments may be an organic light emitting display panel, a micro-light emitting diode display panel, a nano-light emitting diode display panel, or a liquid crystal display panel. Alternatively, the display panel 100 according to one or more embodiments may be an electroluminescent display panel using an electroluminescent element or an electrochromic display panel using an electrochromic element. For ease of description, a case where the display panel 100 according to one or more embodiments is an organic light emitting display panel will be primarily described below. However, the present disclosure is not limited thereto.

FIG. 13 is a detailed layout view of an example of an area A in FIG. 2. FIG. 13 is a layout view illustrating a display area DA and a non-display area NDA disposed on a first side, for example, a right side of a display panel 100 according to one or more embodiments of the present disclosure.

Referring to FIG. 13, the display area DA may include a plurality of light-emitting areas EA1 through EA4. The light-emitting areas EA1 through EA4 may include first light-emitting areas EA1 which emit light of a first color, second light-emitting areas EA2 and fourth light-emitting areas EA4 which emit light of a second color, and third light-emitting areas EA3 which emit light of a third color. For example, the light of the first color may be light in a red wavelength band of about 600 to 750 nm, the light of the second color may be light in a green wavelength band of about 480 to 560 nm, and the light of the third color may be light in a blue wavelength band of about 370 to 460 nm. However, embodiments of the present disclosure are not limited thereto.

Although a case where the second light-emitting areas EA2 and the fourth light-emitting areas EA4 emit light of the same color, that is, light of the second color, is illustrated in FIG. 13, embodiments of the present disclosure are not limited thereto. The second light-emitting areas EA2 and the fourth light-emitting areas EA4 may also emit light of different colors. For example, the second light-emitting areas EA2 may emit light of the second color, and the fourth light-emitting areas EA4 may emit light of a fourth color.

In addition, although each of the first light-emitting areas EA1, the second light-emitting areas EA2, the third light-emitting areas EA3, and the fourth light-emitting areas EA4 has a rectangular planar shape in FIG. 13, embodiments of the present disclosure are not limited thereto. Each of the first light-emitting areas EA1, the second light-emitting areas EA2, the third light-emitting areas EA3, and the fourth light-emitting areas EA4 may also have a polygonal shape other than a quadrangular shape, a circular shape, or an elliptical shape in plan view. Further, the first light-emitting areas EA1, the second light-emitting areas EA2, the third light-emitting areas EA3, and the fourth light-emitting areas EA4 may have the same or different shapes from each other. By way of example, the second and fourth light-emitting areas EA2 and EA4 may have the same size as each other, but the first and third light-emitting areas EA1 and EA3 may have different sizes and shapes from each other and also from the second and fourth light-emitting areas EA2 and EA4.

In addition, as illustrated in FIG. 13, the area of each third light-emitting area EA3 may be the largest, and the area of each second light-emitting area EA2 and the area of each fourth light-emitting area EA4 may be the smallest. The area of each second light-emitting area EA2 and the area of each fourth light-emitting area EA4 may be equal (e.g., may be the same as each other).

The second light-emitting areas EA2 and the fourth light-emitting areas EA4 may be alternately arranged along the first direction (X-axis direction). The second light-emitting areas EA2 may be arranged along the second direction (Y-axis direction). The fourth light-emitting areas EA4 may be arranged along the second direction (Y-axis direction). While each of the fourth light-emitting areas EA4 has long sides in a first diagonal direction DD1 and short sides in a second diagonal direction DD2, each of the second light-emitting areas EA2 may have long sides in the second diagonal direction DD2 and short sides in the first diagonal direction DD1. The first diagonal direction DD1 may refer to a diagonal direction between the first direction (X-axis direction) and the second direction (Y-axis direction), and the second diagonal direction DD2 may be a direction orthogonal to the first diagonal direction DD1.

The first light-emitting areas EA1 and the third light-emitting areas EA3 may be alternately arranged along the first direction (X-axis direction). The first light-emitting areas EA1 may be arranged along the second direction (Y-axis direction). The third light-emitting areas EA3 may be arranged along the second direction (Y-axis direction). Each of the first light-emitting areas EA1 and the third light-emitting areas EA3 may have a square planar shape, but embodiments of the present disclosure are not limited thereto. In this case, each of the first light-emitting areas EA1 and the third light-emitting areas EA3 may include two sides parallel to each other in the first diagonal direction DD1 and two sides parallel to each other in the second diagonal direction DD2.

The non-display area NDA includes a first non-display area NDA1 and a second non-display area NDA2. The first non-display area NDA1 may be an area where structures for driving pixels of the display area DA are disposed. The second non-display area NDA2 may be disposed outside the first non-display area NDA1. The second non-display area NDA2 may be an edge area of the non-display area NDA. In addition, the second non-display area NDA2 may be an edge area of the display panel 100.

The first non-display area NDA1 may include a scan driving circuit unit SDC, a first power line VSL, a first dam DAM1, and a second dam DAM2 (e.g., also see FIGS. 2, 3 and 4).

The scan driving circuit unit SDC may include a plurality of stages STA. The stages STA may be respectively connected to scan lines SL of the display area DA which extend in the first direction (X-axis direction). That is, the stages STA may be connected one-to-one to the scan lines SL of the display area DA which extend in the first direction (X-axis direction). The stages STA may sequentially transmit scan signals to the scan lines SL.

The first power line VSL may be disposed outside the scan driving circuit unit SDC. That is, the first power line VSL may be disposed closer to a first side edge EG1 of the display panel 100 than the scan driving circuit unit SDC is. The first power line VSL may extend in the second direction (Y-axis direction) in the non-display area NDA on the right side of the display panel 100.

The first power line VSL may be electrically connected to a common electrode 173. Accordingly, the common electrode 173 may receive a first power supply voltage from the first power line VSL.

The first dam DAM1 and the second dam DAM2 are structures for preventing an encapsulating organic layer TFE2 of an encapsulation layer ENC from overflowing to the first side edge EG1 of the display panel 100. The first dam DAM1 and the second dam DAM2 may extend in the second direction (Y-axis direction) in the non-display area NDA on the right side of the display panel 100. The second dam DAM2 may be disposed outside the first dam DAM1. The first dam DAM1 may be disposed closer to the scan driving circuit unit SDC than the second dam DAM2 is, and the second dam DAM2 may be disposed closer to the first side edge EG1 of the display panel 100 than the first dam DAM1 is.

Although the first dam DAM1 and the second dam DAM2 are disposed on the first power line VSL in FIG. 13, embodiments of the present disclosure are not limited thereto. For example, any one of the first dam DAM1 and the second dam DAM2 may not be disposed on the first power line VSL. Alternatively, neither the first dam DAM1 nor the second dam DAM2 may be disposed on the first power line VSL. In this case, the first dam DAM1 and the second dam DAM2 may be disposed outside the first power line VSL.

Although the display panel 100 according to the one or more embodiments includes two dams DAM1 and DAM2 in FIG. 13, embodiments of the present disclosure are not limited thereto. That is, the display panel 100 according to one or more embodiments may also include three or more dams.

The second non-display area NDA2 may include a crack dam CRD. The crack dam CRD may extend in the second direction (Y-axis direction) in the non-display area NDA on the first side, for example, the right side of the display panel 100. A width of the crack dam CRD may be about 30 μm or less.

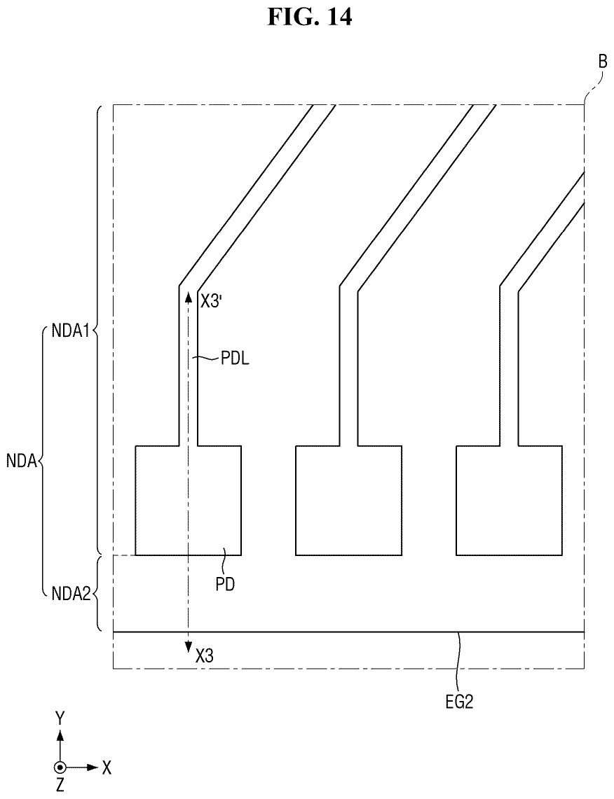

FIG. 14 is a detailed layout view of an example of an area B in FIG. 2. FIG. 14 is a layout view illustrating the non-display area NDA disposed on a second side, for example, a lower side of the display panel 100 according to one or more embodiments of the present disclosure.

Referring to FIG. 14, the first non-display area NDA1 may include a plurality of display pads PD and a plurality of pad lines PDL.

The display pads PD may be electrically connected to a circuit board 300 through a conductive adhesive member such as an anisotropic conductive film or an anisotropic conductive adhesive. The display pads PD may be connected to the pad lines PDL, respectively. The pad lines PDL may connect the display pads PD and driving pads connected to a driving circuit 200. The driving pads may be electrically connected to the driving circuit 200 through a conductive adhesive member such as an anisotropic conductive film or an anisotropic conductive adhesive.

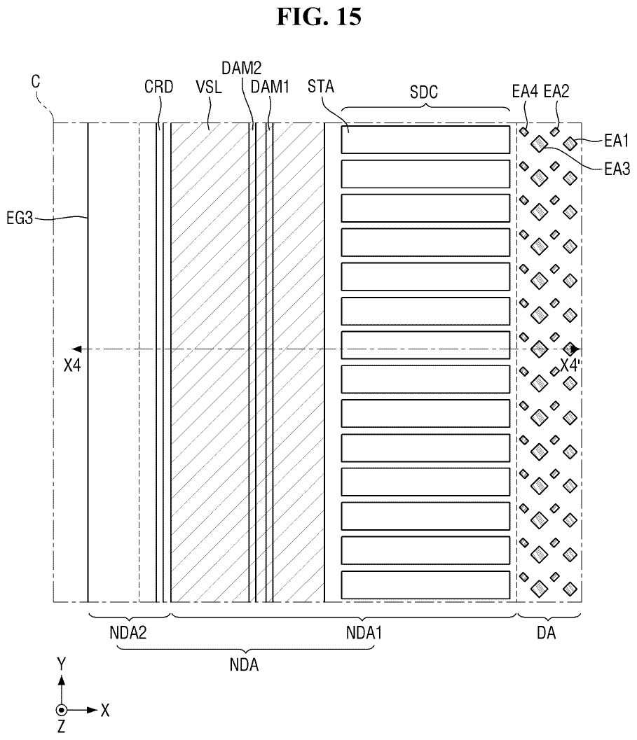

FIG. 15 is a detailed layout view of an example of an area C in FIG. 2. FIG. 15 is a layout view illustrating the display area DA and the non-display area NDA disposed on a third side, for example, a left side of the display panel 100 according to one or more embodiments of the present disclosure.

Because the area C of FIG. 15 is substantially vertically symmetrical to the area A (e.g., the area A and the area C are symmetric with respect to an imaginary line that extends through the center of the display area DA in the Y-axis direction) illustrated in FIG. 13, a detailed description of FIG. 15 is omitted.

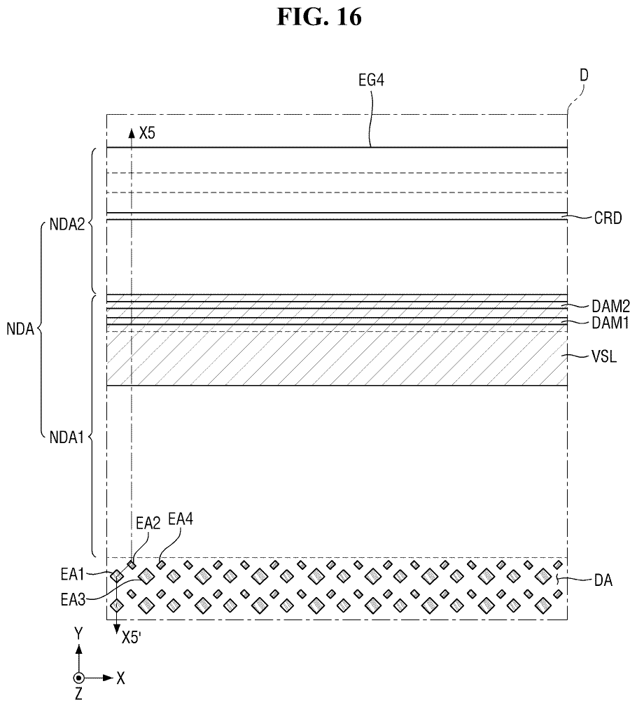

FIG. 16 is a detailed layout view of an example of an area D in FIG. 2. FIG. 16 is a layout view illustrating the display area DA and the non-display area NDA disposed on a fourth side, for example, an upper side of the display panel 100 according to one or more embodiments of the present disclosure.

Referring to FIG. 16, the first non-display area NDA1 may include the first power line VSL, the first dam DAM1, and the second dam DAM2. The first non-display area NDA1 may not include the scan driving circuit unit SDC.

The first power line VSL may extend in the first direction (X-axis direction) in the non-display area NDA on the upper side of the display panel 100. The first power line VSL may be electrically connected to the common electrode 173 (e.g., see FIG. 9A). Accordingly, the common electrode 173 may receive the first power supply voltage from the first power line VSL.

The first dam DAM1 and the second dam DAM2 may extend in the first direction (X-axis direction) in the non-display area NDA on the upper side of the display panel 100. The second dam DAM2 may be disposed outside the first dam DAM1. The first dam DAM1 may be disposed closer to the display area DA than the second dam DAM2 is, and the second dam DAM2 may be disposed closer to a fourth side edge EG4 of the display panel 100 than the first dam DAM1 is.

Although the first dam DAM1 and the second dam DAM2 are disposed on the first power line VSL in FIG. 16, embodiments of the present disclosure are not limited thereto. For example, any one of the first dam DAM1 and the second dam DAM2 may not be disposed on the first power line VSL. Alternatively, neither the first dam DAM1 nor the second dam DAM2 may be disposed on the first power line VSL. In this case, the first dam DAM1 and the second dam DAM2 may be disposed outside the first power line VSL1.

The second non-display area NDA2 may include the crack dam CRD. The crack dam CRD may be an outermost structure disposed at an outermost position on the fourth side, for example, the upper side of the display panel 100. The crack dam CRD may extend in the first direction (X-axis direction) in the non-display area NDA on the fourth side of the display panel 100.

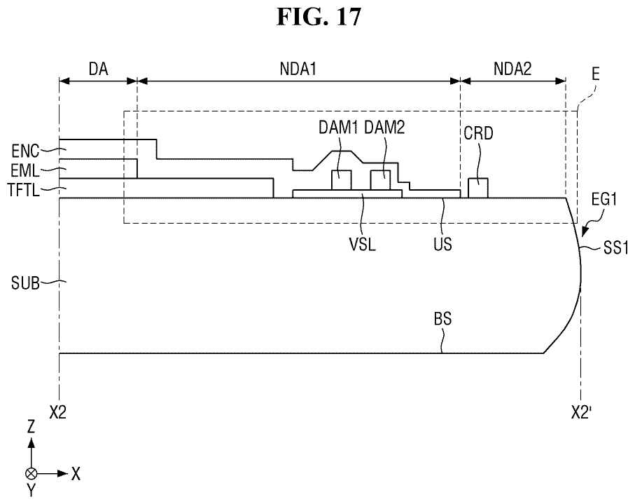

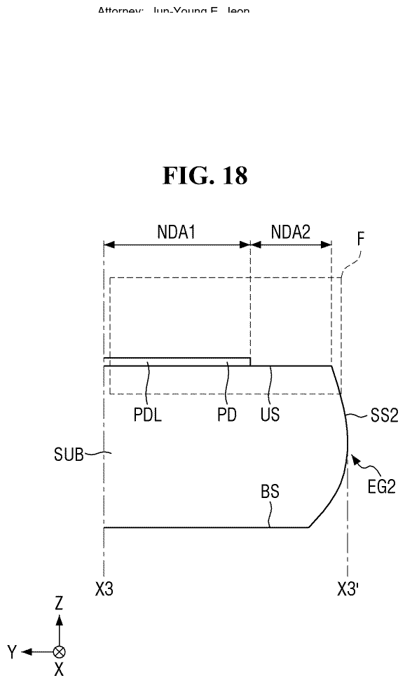

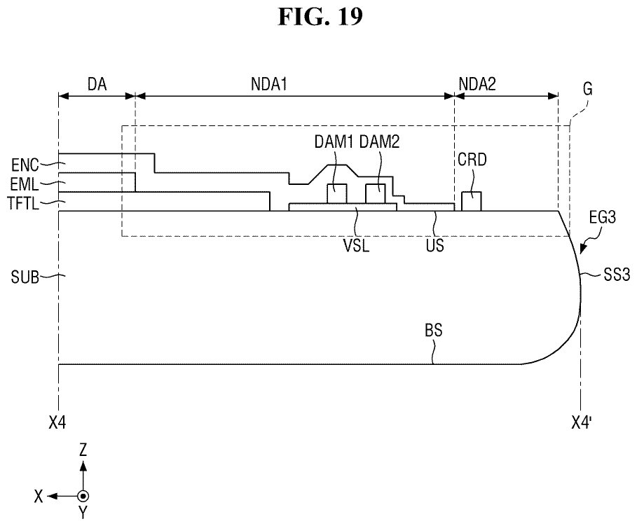

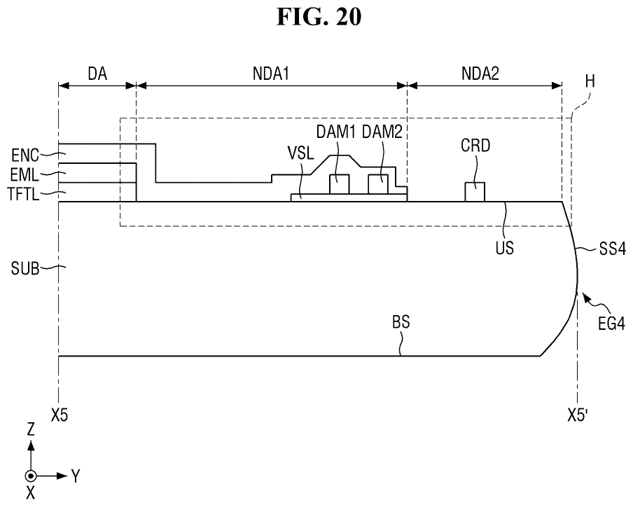

FIG. 17 is a cross-sectional view of an example of the display panel 100 taken along the line X2-X2′ of FIG. 13. FIG. 18 is a cross-sectional view of an example of the display panel 100 taken along the line X3-X3′ of FIG. 14. FIG. 19 is a cross-sectional view of an example of the display panel 100 taken along the line X4-X4′ of FIG. 15. FIG. 20 is a cross-sectional view of an example of the display panel 100 taken along the line X5-X5′ of FIG. 16.

FIG. 17 illustrates an example of a cross section of the first side edge EG1 corresponding to a right edge of the display panel 100, and FIG. 18 illustrates an example of a second side edge EG2 corresponding to a lower edge of the display panel 100. FIG. 19 illustrates an example of a cross section of a third side edge EG3 corresponding to a left edge of the display panel 100, and FIG. 20 illustrates an example of the fourth side edge EG4 corresponding to an upper edge of the display panel 100.

Referring to FIGS. 17 through 20, the crack dam CRD may be a structure for preventing the formation of cracks in a process of cutting a substrate SUB during a process of fabricating a display device 10. The crack dam CRD may be an outermost structure disposed at the outermost position on each of the first side edge EG1, the third side edge EG3 and the fourth side edge EG4 of the display panel 100. A minimum distance from the crack dam CRD to the first side edge EG1 of the display panel 100 may be about 130 μm or less. In addition, a minimum distance from the crack dam CRD to the third side edge EG3 of the display panel 100 may be about 130 μm or less. In addition, a minimum distance from the crack dam CRD to the fourth side edge EG4 of the display panel 100 may be about 130 μm or less.

A display pad PD may be an outermost structure disposed at the outermost position on the second side edge EG2 of the display panel 100. A minimum distance from the display pad PD to the second side edge EG2 of the display panel 100 may be about 80 μm or less.

When the substrate SUB of the display panel 100 is cut by spraying an etchant after irradiating a laser beam during a process of fabricating the display panel 100, at least a portion of each of a first side surface SS1, a second side surface SS2, a third side surface SS3 and a fourth side surface SS4 of the display panel 100 may be etched by the etchant. Accordingly, the roughness of the at least a portion of each of the first side surface SS1, the second side surface SS2, the third side surface SS3 and the fourth side surface SS4 of the display panel 100 may be smaller than the roughness of the other portion not etched by the etchant.

At least a portion of the first side surface SS1 of the display panel 100 that is etched by the etchant may be a lower area of the first side surface SS1. A length of the at least a portion of the first side surface SS1 of the display panel 100 that is etched by the etchant may be 0.5 to 0.8 times a total length of the first side surface SS1.

The first power line VSL may be a first outer structure disposed in the first non-display area NDA1. The first outer structure may be disposed further away from the first side edge EG1, the third side edge EG3 and the fourth side edge EG4 of the display panel 100 than an outermost structure. That is, a distance from the first power line VSL, which is the first outer structure, to the first side edge EG1 of the display panel 100 may be greater than a distance from the crack dam CRD, which is the outermost structure, to the first side edge EG1 of the display panel 100. In addition, a distance from the first power line VSL, which is the first outer structure, to the third side edge EG3 of the display panel 100 may be greater than a distance from the crack dam CRD, which is the outermost structure, to the third side edge EG3 of the display panel 100. In addition, a distance from the first power line VSL, which is the first outer structure, to the fourth side edge EG4 of the display panel 100 may be greater than a distance from the crack dam CRD, which is the outermost structure, to the fourth side edge EG4 of the display panel 100.

A distance from the first power line VSL to the crack dam CRD at the first side edge EG1 and the third side edge EG3 of the display panel 100 may be smaller than a distance from the first power line VSL to the crack dam CRD at the fourth side edge EG4 of the display panel 100. Therefore, a distance from the first power line VSL to the first side edge EG1 of the display panel 100 may be smaller than a distance from the first power line VSL to the fourth side edge EG4 of the display panel 100. In addition, a distance from the first power line VSL to the third side edge EG3 of the display panel 100 may be smaller than the distance from the first power line VSL to the fourth side edge EG4 of the display panel 100. For example, the distance from the first power line VSL to the first side edge EG1 of the display panel 100 and the distance from the first power line VSL to the third side edge EG3 of the display panel 100 may be about 160 μm or less. On the other hand, the distance from the first power line VSL to the fourth side edge EG4 of the display panel 100 may be about 445 μm or less.

The second dam DAM2 may be a second outer structure disposed in the first non-display area NDA1. The second outer structure may be disposed further away from the first side edge EG1, the third side edge EG3 and the fourth side edge EG4 of the display panel 100 than the first outer structure. That is, a distance from the second dam DAM2, which is the second outer structure, to the first side edge EG1 of the display panel 100 may be greater than the distance from the first power line VSL, which is the first outer structure, to the first side edge EG1 of the display panel 100. In addition, a distance from the second dam DAM2 to the third side edge EG3 of the display panel 100 may be greater than the distance from the first power line VSL to the third side edge EG3 of the display panel 100. In addition, a distance from the second dam DAM2 to the fourth side edge EG4 of the display panel 100 may be greater than the distance from the first power line VSL to the fourth side edge EG4 of the display panel 100.

A distance from the second dam DAM2 to the crack dam CRD at the first side edge EG1 or the third side edge EG3 of the display panel 100 may be smaller than a distance from the second dam DAM2 to the crack dam CRD at the fourth side edge EG4 of the display panel 100. Therefore, the distance from the second dam DAM2 to the first side edge EG1 or the third side edge EG3 of the display panel 100 may be smaller than the distance from the second dam DAM2 to the fourth side edge EG4 of the display panel 100. For example, the distance from the second dam DAM2 to the first side edge EG1 or the third side edge EG3 of the display panel 100 may be about 220 μm or less. In addition, the distance from the second dam DAM2 to the fourth side edge EG4 of the display panel 100 may be about 445 μm or less.

In FIGS. 17 through 20, the crack dam CRD is illustrated as the outermost structure of each of the first side edge EG1, the third side edge EG3 and the fourth side edge EG4 of the display panel 100, and the display pad PD is illustrated as the outermost structure of the second side edge EG2 of the display panel 100. However, embodiments of the present disclosure are not limited thereto. The outermost structure may be a structure disposed closest to the first side edge EG1, the second side edge EG2, the third side edge EG3 and the fourth side edge EG4 of the display panel 100 and may be a structure for driving the display panel 100 or a structure for improving the function of the display panel 100. The outermost structure may be a structure spaced (e.g., spaced apart) from the first side edge EG1, the second side edge EG2, the third side edge EG3, and the fourth side edge EG4 of the display panel 100. That is, the outermost structure is not a structure disposed at the first side edge EG1, the second side edge EG2, the third side edge EG3, and the fourth side edge EG4 of the display panel 100.

When the crack dam CRD is omitted or removed, the outermost structure may be a power line (e.g., the first power line VSL) for driving the display panel 100. Alternatively, when the crack dam CRD is omitted or removed, the outermost structure may be a signal line. The signal line may be a signal line for driving the scan driving circuit unit SDC. Alternatively, when the crack dam CRD is omitted or removed, the outermost structure may be a line or an organic layer structure (e.g., the first dam DAM1 and the second dam DAM2) for improving the function of the display panel 100.

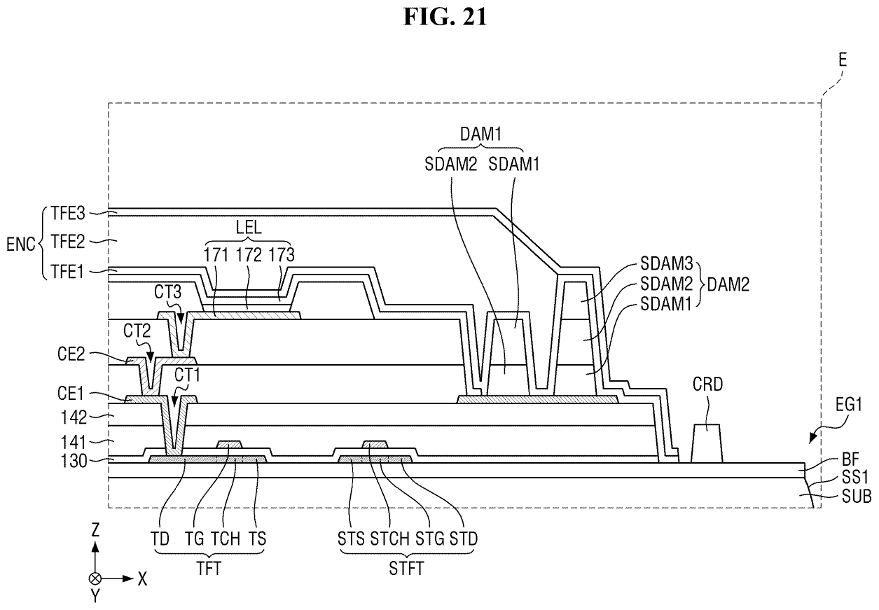

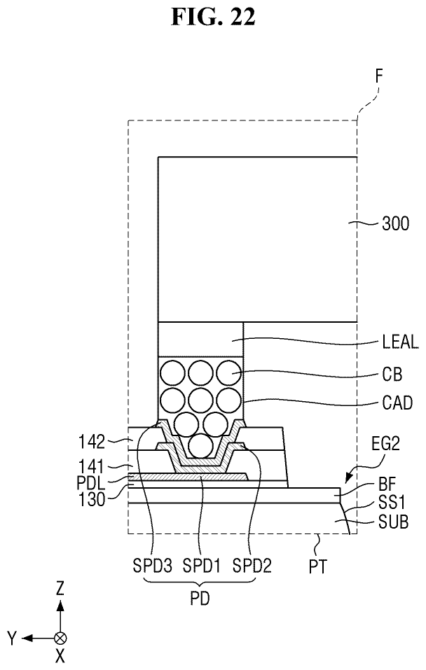

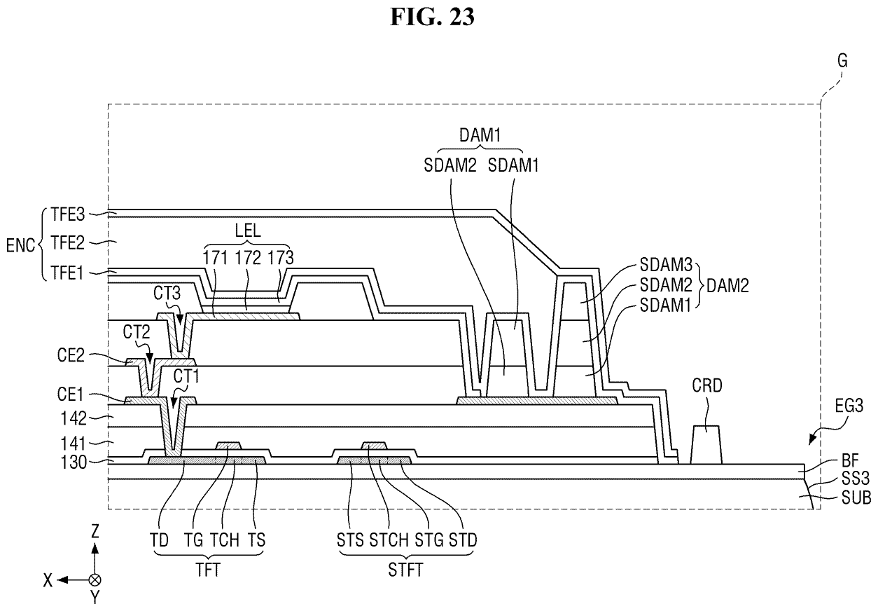

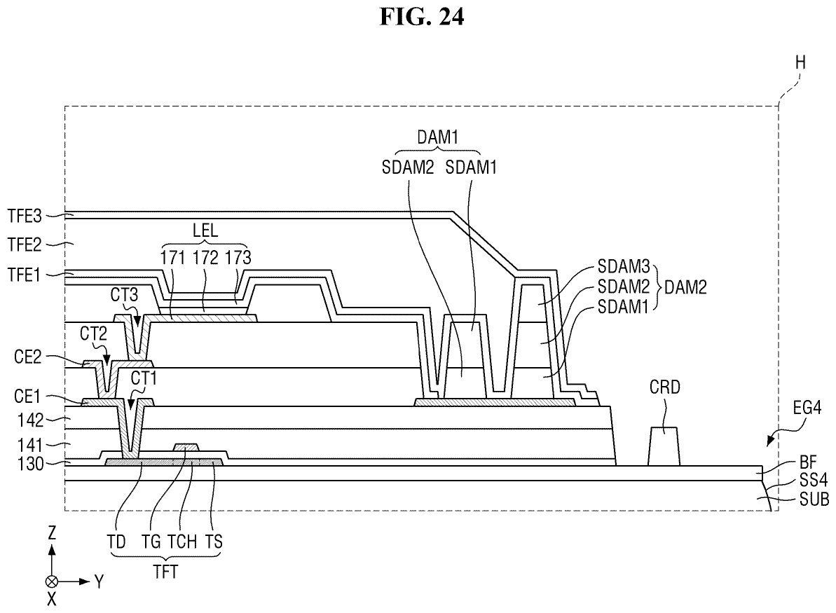

FIG. 21 is a detailed cross-sectional view of an example of an area E in FIG. 17. FIG. 22 is a detailed cross-sectional view of an example of an area F in FIG. 18. FIG. 23 is a detailed cross-sectional view of an example of an area G in FIG. 19. FIG. 24 is a detailed cross-sectional view of an example of an area H in FIG. 20.

Referring to FIGS. 9A and 21 through 24, the crack dam CRD may include the same material as a first organic layer 160 and may be disposed on the same layer as the first organic layer 160. The crack dam CRD may be disposed on a second interlayer insulating layer 142. The crack dam CRD may be made an organic layer such as acryl resin, epoxy resin, phenolic resin, polyamide resin, and/or polyimide resin.

Although the crack dam CRD includes one organic layer in FIG. 21, embodiments of the present disclosure are not limited thereto. For example, the crack dam CRD may further include another organic layer including the same material as a second organic layer 180. Alternatively, the crack dam CRD may further include another organic layer including the same material as a bank 190. Alternatively, the crack dam CRD may further include another organic layer including the same material as a spacer 191.

The first power line VSL may include the same material as a first data metal layer including first connection electrodes CE1 and data lines and may be disposed on the same layer as the first data metal layer. The first power line VSL may be disposed on the second interlayer insulating layer 142. The first power line VSL may be a single layer or a multilayer made of molybdenum (Mo), aluminum (Al), chromium (Cr), gold (Au), titanium (Ti), nickel (Ni), neodymium (Nd), copper (Cu), and/or alloys thereof.

The first dam DAM1 and the second dam DAM2 may be disposed on the first power line VSL. The first dam DAM1 may include a first sub-dam SDAM1 and a second sub-dam SDAM2, and the second dam DAM2 may include a first sub-dam SDAM1, a second sub-dam SDAM2 and a third sub-dam SDAM3. The first sub-dam SDAM1 may include the same material as the first organic layer 160 and may be disposed on the same layer as the first organic layer 160. The second sub-dam SDAM2 may include the same material as the second organic layer 180 and may be disposed on the same layer as the second organic layer 180. The third sub-dam SDAM3 may include the same material as the bank 190 and may be disposed on the same layer as the bank 190.

A height of the first dam DAM1 may be lower than a height of the second dam DAM2. However, embodiments of the present disclosure are not limited thereto. The height of the first dam DAM1 may also be substantially equal to the height of the second dam DAM2 or may also be higher than the height of the second dam DAM2.

The common electrode 173 may be connected to the first power line VSL exposed without being covered by the first organic layer 160, the second organic layer 180, and the first dam DAM1. Accordingly, the common electrode 173 may receive the first power supply voltage of the first power line VSL.

A first encapsulating inorganic layer TFE1 may cover the first dam DAM1 and the second dam DAM2 in the non-display area NDA of the display panel 100. An encapsulating organic layer TFE2 may cover an upper surface of the first dam DAM1 and may not cover an upper surface of the second dam DAM2. However, embodiments of the present disclosure are not limited thereto. The encapsulating organic layer TFE2 may also not cover both the upper surface of the first dam DAM1 and the upper surface of the second dam DAM2. Due to the first dam DAM1 and the second dam DAM2, the encapsulating organic layer TFE2 may not overflow to the first side edge EG1, the third side edge EG3 and the fourth side edge EG4 of the display panel 100 and may not overflow to the display pads PD of the display panel 100. A second encapsulating inorganic layer TFE3 may cover the first dam DAM1 and the second dam DAM2 in the non-display area NDA of the display panel 100.

An inorganic encapsulation area in which the first encapsulating inorganic layer TFE1 and the second encapsulating inorganic layer TFE3 contact each other may be formed in an area adjacent to the second dam DAM2. The inorganic encapsulation area may surround (e.g., may encapsulate) the second dam DAM2.

In addition, a scan thin-film transistor STFT of the scan driving circuit unit SDC is illustrated in FIGS. 21 and 23. Because the scan thin-film transistor STFT is substantially the same as each thin-film transistor TFT described with reference to FIG. 9, a description of the scan thin-film transistor STFT is omitted.

The display pad PD may include a first sub-pad SPD1, a second sub-pad SPD2, and a third sub-pad SPD3 as illustrated in FIG. 22.

The first sub-pad SPD1 may include the same material as a first gate metal layer including gate electrodes TG, first capacitor electrodes CAE1 of capacitors Cst and scan lines and may be disposed on (e.g., may be at) the same layer as the first gate metal layer. The first sub-pad SPD1 may be disposed on a gate insulating layer 130. The first sub-pad SPD1 may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

The second sub-pad SPD2 may include the same material as a second gate metal layer including second capacitor electrodes CAE2 and may be disposed on (e.g., may be at) the same layer as the second gate metal layer. The second sub-pad SPD2 may be disposed on a first interlayer insulating layer 141. The second sub-pad SPD2 may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

The third sub-pad SPD3 may include the same material as the first data metal layer including the first connection electrodes CE1 and the data lines and may be disposed on (e.g., may be at) the same layer as the first data metal layer. The third sub-pad SPD3 may be disposed on the second interlayer insulating layer 142. The third sub-pad SPD3 may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

The third sub-pad SPD3 may be electrically connected to a lead line LEAL of a circuit board 300 through a conductive adhesive member CAD such as an anisotropic conductive film or an anisotropic conductive adhesive.

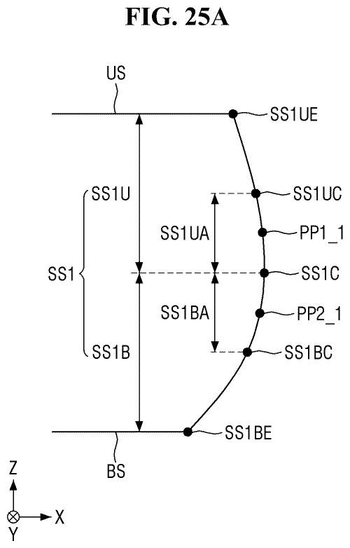

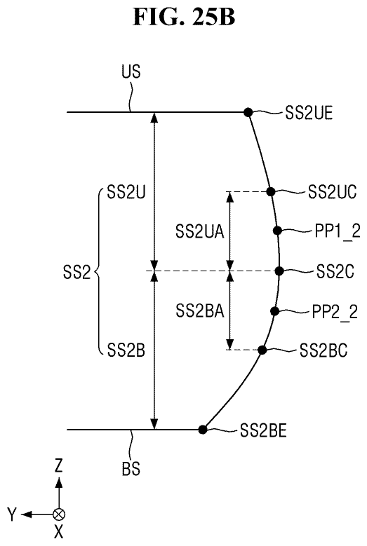

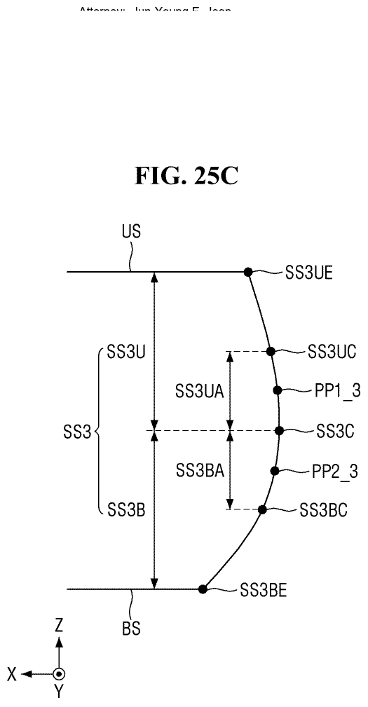

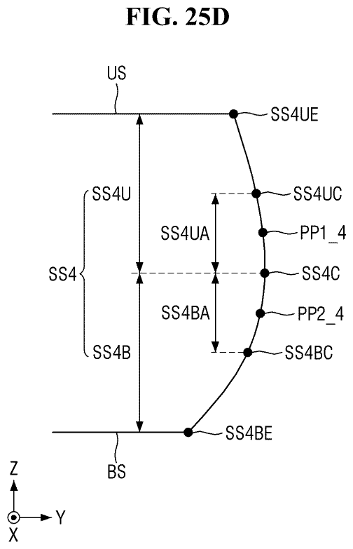

FIGS. 25A through 25D are enlarged cross-sectional views of examples of the first through fourth side surfaces SS1 through SS4 of the substrate SUB in FIGS. 17 through 20. FIG. 25A illustrates a cross section of the first side surface SS1, FIG. 25B illustrates a cross section of the second side surface SS2, FIG. 25C illustrates a cross section of the third side surface SS3, and FIG. 25D illustrates a cross section of the fourth side surface SS4.

Referring to FIG. 25A, the first side surface SS1 may have a curved shape with a varying radius of curvature. A curved shape of an upper part SS1U (e.g., a first upper part) of the first side surface SS1 and a curved shape of a lower part SS1B (e.g., a first lower part) of the first side surface SS1 may be different from each other. The upper part SS1U of the first side surface SS1 refers to an area disposed above a center SS1C (e.g., a first center) of the first side surface SS1. The lower part SS1B of the first side surface SS1 refers to an area disposed below the center SS1C of the first side surface SS1.

A radius of curvature of the upper part SS1U of the first side surface SS1 and a radius of curvature of the lower part SS1B of the first side surface SS1 may be different from each other. For example, the radius of curvature of the lower part SS1B of the first side surface SS1 may be smaller than the radius of curvature of the upper part SS1U of the first side surface SS1.

The radius of curvature of the upper part SS1U of the first side surface SS1 may be defined as a radius of curvature of a curve passing through the center SS1C of the first side surface SS1, an upper end SS1UE of the first side surface SS1, and an upper center SS1UC of the first side surface SS1. The radius of curvature of the lower part SS1B of the first side surface SS1 may be defined as a radius of curvature of a curve passing through the center SS1C of the first side surface SS1, a lower end SS1BE of the first side surface SS1, and a lower center SS1BC of the first side surface SS1.

In addition, a radius of curvature of a central area of the first side surface SS1 may be different from the radius of curvature of the upper part SS1U of the first side surface SS1 and the radius of curvature of the lower part SS1B of the first side surface SS1. The radius of curvature of the central area of the first side surface SS1 may be defined as a radius of curvature of a curve passing through the center SS1C of the first side surface SS1, the upper center SS1UC (e.g., a first upper center) of the first side surface SS1, and the lower center SS1BC (e.g., a first lower center) of the first side surface SS1.

In addition, a difference between a radius of curvature of an upper central area SS1UA of the first side surface SS1 and a radius of curvature of a lower central area SS1BA of the first side surface SS1 may be smaller than a difference between the radius of curvature of the upper part SS1U of the first side surface SS1 and the radius of curvature of the lower part SS1B of the first side surface SS1. The radius of curvature of the upper central area SS1UA of the first side surface SS1 and the radius of curvature of the lower central area SS1BA of the first side surface SS1 may be substantially equal to each other. Alternatively, the difference between the radius of curvature of the upper central area SS1UA of the first side surface SS1 and the radius of curvature of the lower central area SS1BA of the first side surface SS1 may be within 30 μm (e.g., may be about 30 μm or less).

The radius of curvature of the upper central area SS1UA of the first side surface SS1 may be defined as a radius of curvature of a curve passing through the center SS1C of the first side surface SS1, the upper center SS1UC of the first side surface SS1, and a first point PP1_1 of the first side surface SS1. The radius of curvature of the lower central area SS1BA of the first side surface SS1 may be defined as a radius of curvature of a curve passing through the center SS1C of the first side surface SS1, the lower center SS1BC of the first side surface SS1, and a second point PP2_1 of the first side surface SS1. The first point PP1_1 of the first side surface SS1 may be defined as a midpoint between the center SS1C of the first side surface SS1 and the upper center SS1UC of the first side surface SS1. The second point PP2_1 of the first side surface SS1 may be defined as a midpoint between the center SS1C of the first side surface SS1 and the lower center SS1BC of the first side surface SS1.

Referring to FIG. 25B, the second side surface SS2 may have a curved shape with a varying radius of curvature. A curved shape of an upper part SS2U (e.g., a second upper part) of the second side surface SS2 and a curved shape of a lower part SS2B (e.g., a second lower part) of the second side surface SS2 may be different from each other. The upper part SS2U of the second side surface SS2 refers to an area disposed above a center SS2C (e.g., a second center) of the second side surface SS2. The lower part SS2B of the second side surface SS2 refers to an area disposed below the center SS2C of the second side surface SS2.

A radius of curvature of the upper part SS2U of the second side surface SS2 and a radius of curvature of the lower part SS2B of the second side surface SS2 may be different from each other. For example, the radius of curvature of the lower part SS2B of the second side surface SS2 may be smaller than the radius of curvature of the upper part SS2U of the second side surface SS2.

The radius of curvature of the upper part SS2U of the second side surface SS2 may be defined as a radius of curvature of a curve passing through the center SS2C of the second side surface SS2, an upper end SS2UE of the second side surface SS2, and an upper center SS2UC (e.g., a second upper center) of the second side surface SS2. The radius of curvature of the lower part SS2B of the second side surface SS2 may be defined as a radius of curvature of a curve passing through the center SS2C of the second side surface SS2, a lower end SS2BE of the second side surface SS2, and a lower center SS2BC (e.g., a second lower center) of the second side surface SS2.

In addition, a radius of curvature of a central area of the second side surface SS2 may be different from the radius of curvature of the upper part SS2U of the second side surface SS2 and the radius of curvature of the lower part SS2B of the second side surface SS2. The radius of curvature of the central area of the second side surface SS2 may be defined as a radius of curvature of a curve passing through the center SS2C of the second side surface SS2, the upper center SS2UC of the second side surface SS2, and the lower center SS2BC of the second side surface SS2.

In addition, a difference between a radius of curvature of an upper central area SS2UA of the second side surface SS2 and a radius of curvature of a lower central area SS2BA of the second side surface SS2 may be smaller than a difference between the radius of curvature of the upper part SS2U of the second side surface SS2 and the radius of curvature of the lower part SS2B of the second side surface SS2. The radius of curvature of the upper central area SS2UA of the second side surface SS2 and the radius of curvature of the lower central area SS2BA of the second side surface SS2 may be substantially equal to each other. Alternatively, the difference between the radius of curvature of the upper central area SS2UA of the second side surface SS2 and the radius of curvature of the lower central area SS2BA of the second side surface SS2 may be within 30 μm (e.g., may be about 30 μm or less).

The radius of curvature of the upper central area SS2UA of the second side surface SS2 may be defined as a radius of curvature of a curve passing through the center SS2C of the second side surface SS2, the upper center SS2UC of the second side surface SS2, and a first point PP1_2 of the second side surface SS2. The radius of curvature of the lower central area SS2BA of the second side surface SS2 may be defined as a radius of curvature of a curve passing through the center SS2C of the second side surface SS2, the lower center SS2BC of the second side surface SS2, and a second point PP2_2 of the second side surface SS2. The first point PP1_2 of the second side surface SS2 may be defined as a midpoint between the center SS2C of the second side surface SS2 and the upper center SS2UC of the second side surface SS2. The second point PP2_2 of the second side surface SS2 may be defined as a midpoint between the center SS2C of the second side surface SS2 and the lower center SS2BC of the second side surface SS2.

Referring to FIG. 25C, the third side surface SS3 may have a curved shape with a varying radius of curvature. A curved shape of an upper part SS3U (e.g., a third upper part) of the third side surface SS3 and a curved shape of a lower part SS3B (e.g., a third lower part) of the third side surface SS3 may be different from each other. The upper part SS3U of the third side surface SS3 refers to an area disposed above a center SS3C (e.g., a third center) of the third side surface SS3. The lower part SS3B of the third side surface SS3 refers to an area disposed below the center SS3C of the third side surface SS3.

A radius of curvature of the upper part SS3U of the third side surface SS3 and a radius of curvature of the lower part SS3B of the third side surface SS3 may be different from each other. For example, the radius of curvature of the lower part SS3B of the third side surface SS3 may be smaller than the radius of curvature of the upper part SS3U of the third side surface SS3.

The radius of curvature of the upper part SS3U of the third side surface SS3 may be defined as a radius of curvature of a curve passing through the center SS3C of the third side surface SS3, an upper end SS3UE of the third side surface SS3, and an upper center SS3UC (e.g., a third upper center) of the third side surface SS3. The radius of curvature of the lower part SS3B of the third side surface SS3 may be defined as a radius of curvature of a curve passing through the center SS3C of the third side surface SS3, a lower end SS3BE of the third side surface SS3, and a lower center SS3BC (e.g., a third lower center) of the third side surface SS3.

In addition, a radius of curvature of a central area of the third side surface SS3 may be different from the radius of curvature of the upper part SS3U of the third side surface SS3 and the radius of curvature of the lower part SS3B of the third side surface SS3. The radius of curvature of the central area of the third side surface SS3 may be defined as a radius of curvature of a curve passing through the center SS3C of the third side surface SS3, the upper center SS3UC of the third side surface SS3, and the lower center SS3BC of the third side surface SS3.

In addition, a difference between a radius of curvature of an upper central area SS3UA of the third side surface SS3 and a radius of curvature of a lower central area SS3BA of the third side surface SS3 may be smaller than a difference between the radius of curvature of the upper part SS3U of the third side surface SS3 and the radius of curvature of the lower part SS3B of the third side surface SS3. The radius of curvature of the upper central area SS3UA of the third side surface SS3 and the radius of curvature of the lower central area SS3BA of the third side surface SS3 may be substantially equal to each other. Alternatively, the difference between the radius of curvature of the upper central area SS3UA of the third side surface SS3 and the radius of curvature of the lower central area SS3BA of the third side surface SS3 may be within 30 μm (e.g., may be about 30 μm or less).

The radius of curvature of the upper central area SS3UA of the third side surface SS3 may be defined as a radius of curvature of a curve passing through the center SS3C of the third side surface SS3, the upper center SS3UC of the third side surface SS3, and a first point PP1_3 of the third side surface SS3. The radius of curvature of the lower central area SS3BA of the third side surface SS3 may be defined as a radius of curvature of a curve passing through the center SS3C of the third side surface SS3, the lower center SS3BC of the third side surface SS3, and a second point PP2_3 of the third side surface SS3. The first point PP1_3 of the third side surface SS3 may be defined as a midpoint between the center SS3C of the third side surface SS3 and the upper center SS3UC of the third side surface SS3. The second point PP2_3 of the third side surface SS3 may be defined as a midpoint between the center SS3C of the third side surface SS3 and the lower center SS3BC of the third side surface SS3.

Referring to FIG. 25D, the fourth side surface SS4 may have a curved shape with a varying radius of curvature. A curved shape of an upper part SS4U (e.g., a fourth upper part) of the fourth side surface SS4 and a curved shape of a lower part SS4B (e.g., a fourth lower part) of the fourth side surface SS4 may be different from each other. The upper part SS4U of the fourth side surface SS4 refers to an area disposed above a center SS4C (e.g., a fourth center) of the fourth side surface SS4. The lower part SS4B of the fourth side surface SS4 refers to an area disposed below the center SS4C of the fourth side surface SS4.

A radius of curvature of the upper part SS4U of the fourth side surface SS4 and a radius of curvature of the lower part SS4B of the fourth side surface SS4 may be different from each other. For example, the radius of curvature of the lower part SS4B of the fourth side surface SS4 may be smaller than the radius of curvature of the upper part SS4U of the fourth side surface SS4.

The radius of curvature of the upper part SS4U of the fourth side surface SS4 may be defined as a radius of curvature of a curve passing through the center SS4C of the fourth side surface SS4, an upper end SS4UE of the fourth side surface SS4, and an upper center SS4UC (e.g., fourth upper center) of the fourth side surface SS4. The radius of curvature of the lower part SS4B of the fourth side surface SS4 may be defined as a radius of curvature of a curve passing through the center SS4C of the fourth side surface SS4, a lower end SS4BE of the fourth side surface SS4, and a lower center SS4BC (e.g., a fourth lower center) of the fourth side surface SS4.

In addition, a radius of curvature of a central area of the fourth side surface SS4 may be different from the radius of curvature of the upper part SS4U of the fourth side surface SS4 and the radius of curvature of the lower part SS4B of the fourth side surface SS4. The radius of curvature of the central area of the fourth side surface SS4 may be defined as a radius of curvature of a curve passing through the center SS4C of the fourth side surface SS4, the upper center SS4UC of the fourth side surface SS4, and the lower center SS4BC of the fourth side surface SS4.

In addition, a difference between a radius of curvature of an upper central area SS4UA of the fourth side surface SS4 and a radius of curvature of a lower central area SS4BA of the fourth side surface SS4 may be smaller than a difference between the radius of curvature of the upper part SS4U of the fourth side surface SS4 and the radius of curvature of the lower part SS4B of the fourth side surface SS4. The radius of curvature of the upper central area SS4UA of the fourth side surface SS4 and the radius of curvature of the lower central area SS4BA of the fourth side surface SS4 may be substantially equal to each other. Alternatively, the difference between the radius of curvature of the upper central area SS4UA of the fourth side surface SS4 and the radius of curvature of the lower central area SS4BA of the fourth side surface SS4 may be within 30 μm (e.g., may be about 30 μm or less).

The radius of curvature of the upper central area SS4UA of the fourth side surface SS4 may be defined as a radius of curvature of a curve passing through the center SS4C of the fourth side surface SS4, the upper center SS4UC of the fourth side surface SS4, and a first point PP1_4 of the fourth side surface SS4. The radius of curvature of the lower central area SS4BA of the fourth side surface SS4 may be defined as a radius of curvature of a curve passing through the center SS4C of the fourth side surface SS4, the lower center SS4BC of the fourth side surface SS4, and a second point PP2_4 of the fourth side surface SS4. The first point PP1_4 of the fourth side surface SS4 may be defined as a midpoint between the center SS4C of the fourth side surface SS4 and the upper center SS4UC of the fourth side surface SS4. The second point PP2_4 of the fourth side surface SS4 may be defined as a midpoint between the center SS4C of the fourth side surface SS4 and the lower center SS4BC of the fourth side surface SS4.

Referring to FIGS. 25A through 25D, the radius of curvature of the upper part SS1U of the first side surface SS1, the radius of curvature of the upper part SS2U of the second side surface SS2, the radius of curvature of the upper part SS3U of the third side surface SS3, and the radius of curvature of the upper part SS4U of the fourth side surface SS4 may be similar to each other. For example, the radius of curvature of the upper part SS1U of the first side surface SS1, the radius of curvature of the upper part SS2U of the second side surface SS2, the radius of curvature of the upper part SS3U of the third side surface SS3, and the radius of curvature of the upper part SS4U of the fourth side surface SS4 may be in a range of 150 μm to 350 μm.

A difference between the radius of curvature of the upper part SS1U of the first side surface SS1 and the radius of curvature of the upper part SS2U of the second side surface SS2 may be less than about 30 μm. A difference between the radius of curvature of the upper part SS1U of the first side surface SS1 and the radius of curvature of the upper part SS3U of the third side surface SS3 may be less than about 30 μm. A difference between the radius of curvature of the upper part SS1U of the first side surface SS1 and the radius of curvature of the upper part SS4U of the fourth side surface SS4 may be less than about 30 μm. A difference between the radius of curvature of the upper part SS2U of the second side surface SS2 and the radius of curvature of the upper part SS3U of the third side surface SS3 may be less than about 30 μm. A difference between the radius of curvature of the upper part SS2U of the second side surface SS2 and the radius of curvature of the upper part SS4U of the fourth side surface SS4 may be less than about 30 μm. A difference between the radius of curvature of the upper part SS3U of the third side surface SS3 and the radius of curvature of the upper part SS4U of the fourth side surface SS4 may be less than about 30 μm.

As illustrated in FIGS. 25A through 25D, a difference in radius of curvature between the side surfaces SS1 through SS4 of the substrate SUB of the display panel 100 may be insignificant. Therefore, uniform mechanical strength can be maintained according to the positions of the side surfaces SS1 through SS4 of the substrate SUB of the display panel 100.

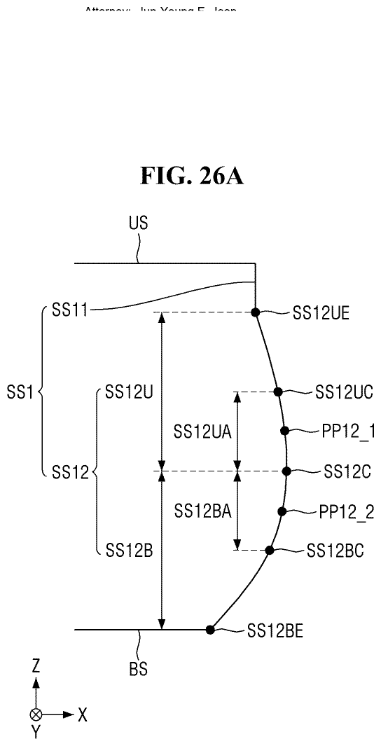

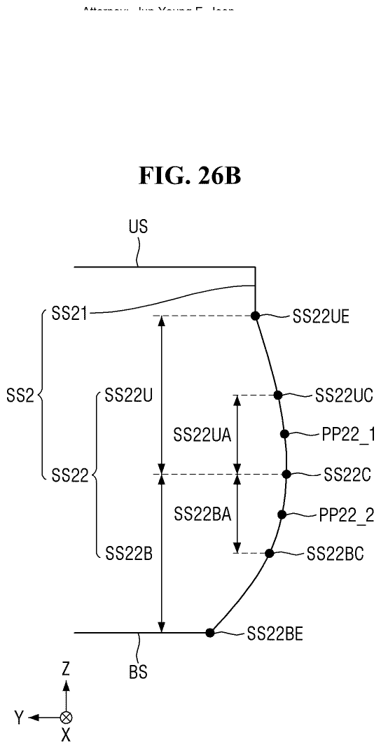

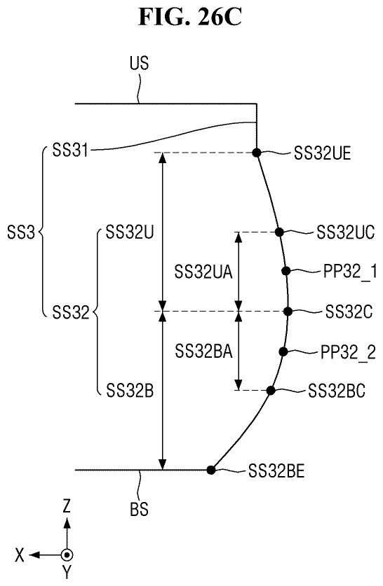

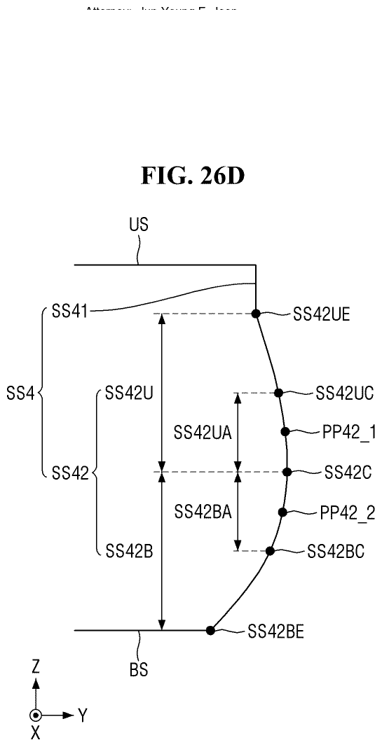

FIGS. 26A through 26D are enlarged cross-sectional views of examples of the first through fourth side surfaces SS1 through SS4 of the substrate SUB in FIGS. 17 through 20. FIG. 26A illustrates a cross section of the first side surface SS1, FIG. 26B illustrates a cross section of the second side surface SS2, FIG. 26C illustrates a cross section of the third side surface SS3, and FIG. 26D illustrates a cross section of the fourth side surface SS4.

Referring to FIG. 26A, the first side surface SS1 may have a first sub-side surface SS11 in a flat or curved shape and a second sub-side surface SS12 in a curved shape with a varying radius of curvature. A length of the first sub-side surface SS11 may be smaller than a length of the second sub-side surface SS12.

The first sub-side surface SS11 may be connected to an upper surface US, and the second sub-side surface SS12 may be connected to a lower surface BS. An angle between the first sub-side surface SS11 and the upper surface US may be a right angle or an obtuse angle close to a right angle.

A curved shape of an upper part SS12U of the second sub-side surface SS12 and a curved shape of a lower part SS12B of the second sub-side surface SS12 may be different from each other. The upper part SS12U of the second sub-side surface SS12 refers to an area disposed above a center SS12C of the second sub-side surface SS12. The lower part SS12B of the second sub-side surface SS12 refers to an area disposed below the center SS12C of the second sub-side surface SS12.

A radius of curvature of the upper part SS12U of the second sub-side surface SS12 and a radius of curvature of the lower part SS12B of the second sub-side surface SS12 may be different from each other. For example, the radius of curvature of the lower part SS12B of the second sub-side surface SS12 may be smaller than the radius of curvature of the upper part SS12U of the second sub-side surface SS12.

The radius of curvature of the upper part SS12U of the second sub-side surface SS12 may be defined as a radius of curvature of a curve passing through the center SS12C of the second sub-side surface SS12, an upper end SS12UE of the second sub-side surface SS12, and an upper center SS12UC of the second sub-side surface SS12. The radius of curvature of the lower part SS12B of the second sub-side surface SS12 may be defined as a radius of curvature of a curve passing through the center SS12C of the second sub-side surface SS12, a lower end SS12BE of the second sub-side surface SS12, and a lower center SS12BC of the second sub-side surface SS12.

In addition, a radius of curvature of a central area of the second sub-side surface SS12 may be different from the radius of curvature of the upper part SS12U of the second sub-side surface SS12 and the radius of curvature of the lower part SS12B of the second sub-side surface SS12. The radius of curvature of the central area of the second sub-side surface SS12 may be defined as a radius of curvature of a curve passing through the center SS12C of the second sub-side surface SS12, the upper center SS12UC of the second sub-side surface SS12, and the lower center SS12BC of the second sub-side surface SS12.

In addition, a difference between a radius of curvature of an upper central area SS12UA of the second sub-side surface SS12 and a radius of curvature of a lower central area SS12BA of the second sub-side surface SS12 may be smaller than a difference between the radius of curvature of the upper part SS12U of the second sub-side surface SS12 and the radius of curvature of the lower part SS12B of the second sub-side surface SS12. The radius of curvature of the upper central area SS12UA of the second sub-side surface SS12 and the radius of curvature of the lower central area SS12BA of the second sub-side surface SS12 may be substantially equal to each other. Alternatively, the difference between the radius of curvature of the upper central area SS12UA of the second sub-side surface SS12 and the radius of curvature of the lower central area SS12BA of the second sub-side surface SS12 may be within 30 μm (e.g., may be about 30 μm or less).

The radius of curvature of the upper central area SS12UA of the second sub-side surface SS12 may be defined as a radius of curvature of a curve passing through the center SS12C of the second sub-side surface SS12, the upper center SS12UC of the second sub-side surface SS12, and a first point PP12_1 of the second sub-side surface SS12. The radius of curvature of the lower central area SS12BA of the second sub-side surface SS12 may be defined as a radius of curvature of a curve passing through the center SS12C of the second sub-side surface SS12, the lower center SS12BC of the second sub-side surface SS12, and a second point PP12_2 of the second sub-side surface SS12. The first point PP12_1 of the second sub-side surface SS12 may be defined as a midpoint between the center SS12C of the second sub-side surface SS12 and the upper center SS12UC of the second sub-side surface SS12. The second point PP12_2 of the second sub-side surface SS12 may be defined as a midpoint between the center SS12C of the second sub-side surface SS12 and the lower center SS12BC of the second sub-side surface SS12.

Referring to FIG. 26B, the second side surface SS2 may have a third sub-side surface SS21 in a flat or curved shape and a fourth sub-side surface SS22 in a curved shape with a varying radius of curvature. A length of the third sub-side surface SS21 may be smaller than a length of the fourth sub-side surface SS22.

The third sub-side surface SS21 may be connected to the upper surface US, and the fourth sub-side surface SS22 may be connected to the lower surface BS. An angle between the third sub-side surface SS21 and the upper surface US may be a right angle or an obtuse angle close to a right angle.

A curved shape of an upper part SS22U of the fourth sub-side surface SS22 and a curved shape of a lower part SS22B of the fourth sub-side surface SS22 may be different from each other. The upper part SS22U of the fourth sub-side surface SS22 refers to an area disposed above a center SS22C of the fourth sub-side surface SS22. The lower part SS22B of the fourth sub-side surface SS22 refers to an area disposed below the center SS22C of the fourth sub-side surface SS22.

A radius of curvature of the upper part SS22U of the fourth sub-side surface SS22 and a radius of curvature of the lower part SS22B of the fourth sub-side surface SS22 may be different from each other. For example, the radius of curvature of the lower part SS22B of the fourth sub-side surface SS22 may be smaller than the radius of curvature of the upper part SS22U of the fourth sub-side surface SS22.

The radius of curvature of the upper part SS22U of the fourth sub-side surface SS22 may be defined as a radius of curvature of a curve passing through the center SS22C of the fourth sub-side surface SS22, an upper end SS22UE of the fourth sub-side surface SS22, and an upper center SS22UC of the fourth sub-side surface SS22. The radius of curvature of the lower part SS22B of the fourth sub-side surface SS22 may be defined as a radius of curvature of a curve passing through the center SS22C of the fourth sub-side surface SS22, a lower end SS22BE of the fourth sub-side surface SS22, and a lower center SS22BC of the fourth sub-side surface SS22.

In addition, a radius of curvature of a central area of the fourth sub-side surface SS22 may be different from the radius of curvature of the upper part SS22U of the fourth sub-side surface SS22 and the radius of curvature of the lower part SS22B of the fourth sub-side surface SS22. The radius of curvature of the central area of the fourth sub-side surface SS22 may be defined as a radius of curvature of a curve passing through the center SS22C of the fourth sub-side surface SS22, the upper center SS22UC of the fourth sub-side surface SS22, and the lower center SS22BC of the fourth sub-side surface SS22.

In addition, a difference between a radius of curvature of an upper central area SS22UA of the fourth sub-side surface SS22 and a radius of curvature of a lower central area SS22BA of the fourth sub-side surface SS22 may be smaller than a difference between the radius of curvature of the upper part SS22U of the fourth sub-side surface SS22 and the radius of curvature of the lower part SS22B of the fourth sub-side surface SS22. The radius of curvature of the upper central area SS22UA of the fourth sub-side surface SS22 and the radius of curvature of the lower central area SS22BA of the fourth sub-side surface SS22 may be substantially equal to each other. Alternatively, the difference between the radius of curvature of the upper central area SS22UA of the fourth sub-side surface SS22 and the radius of curvature of the lower central area SS22BA of the fourth sub-side surface SS22 may be within 30 μm (e.g., may be about 30 μm or less).

The radius of curvature of the upper central area SS22UA of the fourth sub-side surface SS22 may be defined as a radius of curvature of a curve passing through the center SS22C of the fourth sub-side surface SS22, the upper center SS22UC of the fourth sub-side surface SS22, and a first point PP22_1 of the fourth sub-side surface SS22. The radius of curvature of the lower central area SS22BA of the fourth sub-side surface SS22 may be defined as a radius of curvature of a curve passing through the center SS22C of the fourth sub-side surface SS22, the lower center SS22BC of the fourth sub-side surface SS22, and a second point PP22_2 of the fourth sub-side surface SS22. The first point PP22_1 of the fourth sub-side surface SS22 may be defined as a midpoint between the center SS22C of the fourth sub-side surface SS22 and the upper center SS22UC of the fourth sub-side surface SS22. The second point PP22_2 of the fourth sub-side surface SS22 may be defined as a midpoint between the center SS22C of the fourth sub-side surface SS22 and the lower center SS22BC of the fourth sub-side surface SS22.

Referring to FIG. 26C, the third side surface SS3 may have a fifth sub-side surface SS31 in a flat or curved shape and a sixth sub-side surface SS32 in a curved shape with a varying radius of curvature. A length of the fifth sub-side surface SS31 may be smaller than a length of the sixth sub-side surface SS32.

The fifth sub-side surface SS31 may be connected to the upper surface US, and the sixth sub-side surface SS32 may be connected to the lower surface BS. An angle between the fifth sub-side surface SS31 and the upper surface US may be a right angle or an obtuse angle close to a right angle.

A curved shape of an upper part SS32U of the sixth sub-side surface SS32 and a curved shape of a lower part SS32B of the sixth sub-side surface SS32 may be different from each other. The upper part SS32U of the sixth sub-side surface SS32 refers to an area disposed above a center SS32C of the sixth sub-side surface SS32. The lower part SS32B of the sixth sub-side surface SS32 refers to an area disposed below the center SS32C of the sixth sub-side surface SS32.

A radius of curvature of the upper part SS32U of the sixth sub-side surface SS32 and a radius of curvature of the lower part SS32B of the sixth sub-side surface SS32 may be different from each other. For example, the radius of curvature of the lower part SS32B of the sixth sub-side surface SS32 may be smaller than the radius of curvature of the upper part SS32U of the sixth sub-side surface SS32.

The radius of curvature of the upper part SS32U of the sixth sub-side surface SS32 may be defined as a radius of curvature of a curve passing through the center SS32C of the sixth sub-side surface SS32, an upper end SS32UE of the sixth sub-side surface SS32, and an upper center SS32UC of the sixth sub-side surface SS32. The radius of curvature of the lower part SS32B of the sixth sub-side surface SS32 may be defined as a radius of curvature of a curve passing through the center SS32C of the sixth sub-side surface SS32, a lower end SS32BE of the sixth sub-side surface SS32, and a lower center SS32BC of the sixth sub-side surface SS32.

In addition, a radius of curvature of a central area of the sixth sub-side surface SS32 may be different from the radius of curvature of the upper part SS32U of the sixth sub-side surface SS32 and the radius of curvature of the lower part SS32B of the sixth sub-side surface SS32. The radius of curvature of the central area of the sixth sub-side surface SS32 may be defined as a radius of curvature of a curve passing through the center SS32C of the sixth sub-side surface SS32, the upper center SS32UC of the sixth sub-side surface SS32, and the lower center SS32BC of the sixth sub-side surface SS32.

In addition, a difference between a radius of curvature of an upper central area SS32UA of the sixth sub-side surface SS32 and a radius of curvature of a lower central area SS32BA of the sixth sub-side surface SS32 may be smaller than a difference between the radius of curvature of the upper part SS32U of the sixth sub-side surface SS32 and the radius of curvature of the lower part SS32B of the sixth sub-side surface SS32. The radius of curvature of the upper central area SS32UA of the sixth sub-side surface SS32 and the radius of curvature of the lower central area SS32BA of the sixth sub-side surface SS32 may be substantially equal to each other. Alternatively, the difference between the radius of curvature of the upper central area SS32UA of the sixth sub-side surface SS32 and the radius of curvature of the lower central area SS32BA of the sixth sub-side surface SS32 may be within 30 μm (e.g., may be about 30 μm or less).

The radius of curvature of the upper central area SS32UA of the sixth sub-side surface SS32 may be defined as a radius of curvature of a curve passing through the center SS32C of the sixth sub-side surface SS32, the upper center SS32UC of the sixth sub-side surface SS32, and a first point PP32_1 of the sixth sub-side surface SS32. The radius of curvature of the lower central area SS32BA of the sixth sub-side surface SS32 may be defined as a radius of curvature of a curve passing through the center SS32C of the sixth sub-side surface SS32, the lower center SS32BC of the sixth sub-side surface SS32, and a second point PP32_2 of the sixth sub-side surface SS32.

The first point PP32_1 of the sixth sub-side surface SS32 may be defined as a midpoint between the center SS32C of the sixth sub-side surface SS32 and the upper center SS32UC of the sixth sub-side surface SS32. The second point PP32_2 of the sixth sub-side surface SS32 may be defined as a midpoint between the center SS32C of the sixth sub-side surface SS32 and the lower center SS32BC of the sixth sub-side surface SS32.

Referring to FIG. 26D, the fourth side surface SS4 may have a seventh sub-side surface SS41 in a flat or curved shape and an eighth sub-side surface SS42 in a curved shape with a varying radius of curvature. A length of the seventh sub-side surface SS41 may be smaller than a length of the eighth sub-side surface SS42.

The seventh sub-side surface SS41 may be connected to the upper surface US, and the eighth sub-side surface SS42 may be connected to the lower surface BS. An angle between the seventh sub-side surface SS41 and the upper surface US may be a right angle or an obtuse angle close to a right angle.

A curved shape of an upper part SS42U of the eighth sub-side surface SS42 and a curved shape of a lower part SS42B of the eighth sub-side surface SS42 may be different from each other. The upper part SS42U of the eighth sub-side surface SS42 refers to an area disposed above a center SS42C of the eighth sub-side surface SS42. The lower part SS42B of the eighth sub-side surface SS42 refers to an area disposed below the center SS42C of the eighth sub-side surface SS42.

A radius of curvature of the upper part SS42U of the eighth sub-side surface SS42 and a radius of curvature of the lower part SS42B of the eighth sub-side surface SS42 may be different from each other. For example, the radius of curvature of the lower part SS42B of the eighth sub-side surface SS42 may be smaller than the radius of curvature of the upper part SS42U of the eighth sub-side surface SS42.

The radius of curvature of the upper part SS42U of the eighth sub-side surface SS42 may be defined as a radius of curvature of a curve passing through the center SS42C of the eighth sub-side surface SS42, an upper end SS42UE of the eighth sub-side surface SS42, and an upper center SS42UC of the eighth sub-side surface SS42. The radius of curvature of the lower part SS42B of the eighth sub-side surface SS42 may be defined as a radius of curvature of a curve passing through the center SS42C of the eighth sub-side surface SS42, a lower end SS42BE of the eighth sub-side surface SS42, and a lower center SS42BC of the eighth sub-side surface SS42.

In addition, a radius of curvature of a central area of the eighth sub-side surface SS42 may be different from the radius of curvature of the upper part SS42U of the eighth sub-side surface SS42 and the radius of curvature of the lower part SS42B of the eighth sub-side surface SS42. The radius of curvature of the central area of the eighth sub-side surface SS42 may be defined as a radius of curvature of a curve passing through the center SS42C of the eighth sub-side surface SS42, the upper center SS42UC of the eighth sub-side surface SS42, and the lower center SS42BC of the eighth sub-side surface SS42.

In addition, a difference between a radius of curvature of an upper central area SS42UA of the eighth sub-side surface SS42 and a radius of curvature of a lower central area SS42BA of the eighth sub-side surface SS42 may be smaller than a difference between the radius of curvature of the upper part SS42U of the eighth sub-side surface SS42 and the radius of curvature of the lower part SS42B of the eighth sub-side surface SS42. The radius of curvature of the upper central area SS42UA of the eighth sub-side surface SS42 and the radius of curvature of the lower central area SS42BA of the eighth sub-side surface SS42 may be substantially equal to each other. Alternatively, the difference between the radius of curvature of the upper central area SS42UA of the eighth sub-side surface SS42 and the radius of curvature of the lower central area SS42BA of the eighth sub-side surface SS42 may be within 30 μm (e.g., may be about 30 μm or less).

The radius of curvature of the upper central area SS42UA of the eighth sub-side surface SS42 may be defined as a radius of curvature of a curve passing through the center SS42C of the eighth sub-side surface SS42, the upper center SS42UC of the eighth sub-side surface SS42, and a first point PP42_1 of the eighth sub-side surface SS42. The radius of curvature of the lower central area SS42BA of the eighth sub-side surface SS42 may be defined as a radius of curvature of a curve passing through the center SS42C of the eighth sub-side surface SS42, the lower center SS42BC of the eighth sub-side surface SS42, and a second point PP42_2 of the eighth sub-side surface SS42. The first point PP42_1 of the eighth sub-side surface SS42 may be defined as a midpoint between the center SS42C of the eighth sub-side surface SS42 and the upper center SS42UC of the eighth sub-side surface SS42. The second point PP42_2 of the eighth sub-side surface SS42 may be defined as a midpoint between the center SS42C of the eighth sub-side surface SS42 and the lower center SS42BC of the eighth sub-side surface SS42.

Referring to FIGS. 26A through 26D, the length of the first sub-side surface SS11 of the first side surface SS1, the length of the third sub-side surface SS21 of the second side surface SS2, the length of the fifth sub-side surface SS31 of the third side surface SS3, and the length of the seventh sub-side surface SS41 of the fourth side surface SS4 may be similar to each other. For example, the length of the first sub-side surface SS11 of the first side surface SS1, the length of the third sub-side surface SS21 of the second side surface SS2, the length of the fifth sub-side surface SS31 of the third side surface SS3, and the length of the seventh sub-side surface SS41 of the fourth side surface SS4 may each be greater than 10 μm and less than 30 μm.

For example, a difference between the length of the first sub-side surface SS11 of the first side surface SS1 and the length of the third sub-side surface SS21 of the second side surface SS2 may be less than about 10 μm. A difference between the length of the first sub-side surface SS11 of the first side surface SS1 and the length of the fifth sub-side surface SS31 of the third side surface SS3 may be less than about 10 μm. A difference between the length of the first sub-side surface SS11 of the first side surface SS1 and the length of the seventh sub-side surface SS41 of the fourth side surface SS4 may be less than about 10 μm. A difference between the length of the third sub-side surface SS21 of the second side surface SS2 and the length of the fifth sub-side surface SS31 of the third side surface SS3 may be less than about 10 μm. A difference between the length of the third sub-side surface SS21 of the second side surface SS2 and the length of the seventh sub-side surface SS41 of the fourth side surface SS4 may be less than about 10 μm. A difference between the length of the fifth sub-side surface SS31 of the third side surface SS3 and the length of the seventh sub-side surface SS41 of the fourth side surface SS4 may be less than about 10 μm.

The radius of curvature of the upper part SS12U of the second sub-side surface SS12 of the first side surface SS1, the radius of curvature of the upper part SS22U of the fourth sub-side surface SS22 of the second side surface SS2, the radius of curvature of the upper part SS32U of the sixth sub-side surface SS32 of the third side surface SS3, and the radius of curvature of the upper part SS42U of the eighth sub-side surface SS42 of the fourth side surface SS4 may be similar to each other.

For example, a difference between the radius of curvature of the upper part SS12U of the second sub-side surface SS12 of the first side surface SS1 and the radius of curvature of the upper part SS22U of the fourth sub-side surface SS22 of the second side surface SS2 may be less than about 30 μm. A difference between the radius of curvature of the upper part SS12U of the second sub-side surface SS12 of the first side surface SS1 and the radius of curvature of the upper part SS32U of the sixth sub-side surface SS32 of the third side surface SS3 may be less than about 30 μm. A difference between the radius of curvature of the upper part SS12U of the second sub-side surface SS12 of the first side surface SS1 and the radius of curvature of the upper part SS42U of the eighth sub-side surface SS42 of the fourth side surface SS4 may be less than about 30 μm. A difference between the radius of curvature of the upper part SS22U of the fourth sub-side surface SS22 of the second side surface SS2 and the radius of curvature of the upper part SS32U of the sixth sub-side surface SS32 of the third side surface SS3 may be less than about 30 μm. A difference between the radius of curvature of the upper part SS22U of the fourth sub-side surface SS22 of the second side surface SS2 and the radius of curvature of the upper part SS42U of the eighth sub-side surface SS42 of the fourth side surface SS4 may be less than about 30 μm. A difference between the radius of curvature of the upper part SS32U of the sixth sub-side surface SS32 of the third side surface SS3 and the radius of curvature of the upper part SS42U of the eighth sub-side surface SS42 of the fourth side surface SS4 may be less than about 30 μm.

As illustrated in FIGS. 26A through 26D, a difference in radius of curvature between the side surfaces SS1 through SS4 of the substrate SUB of the display panel 100 may be insignificant. Therefore, uniform mechanical strength can be maintained according to the positions of the side surfaces SS1 through SS4 of the substrate SUB of the display panel 100.

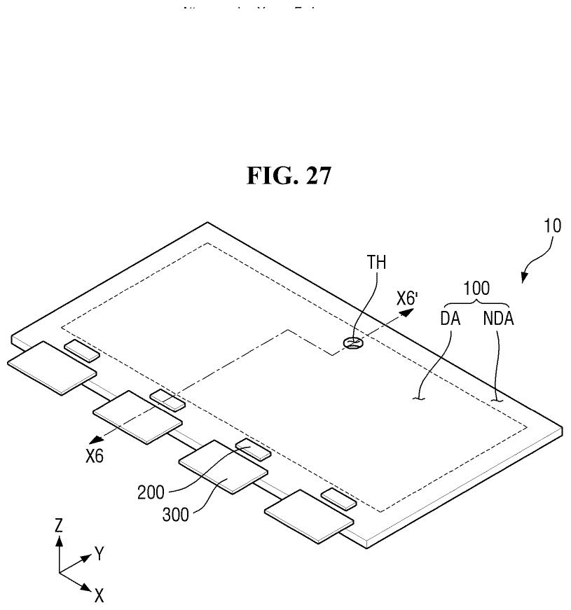

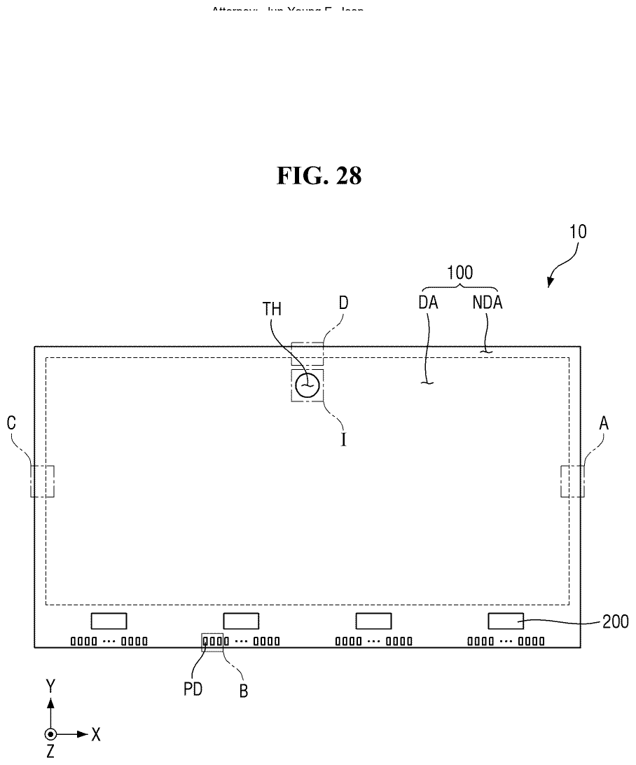

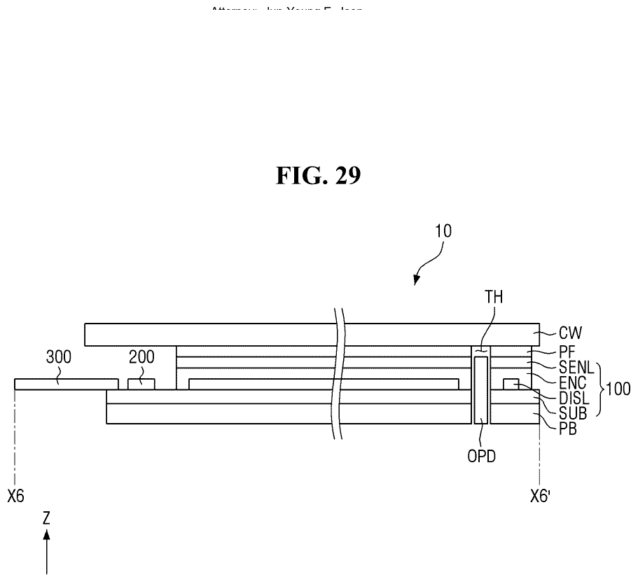

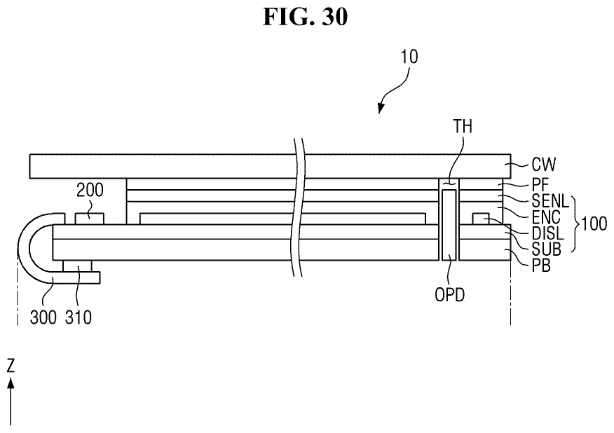

FIG. 27 is a perspective view of a display device 10 according to one or more embodiments of the present disclosure. FIG. 28 is a plan view illustrating a display panel 100 and driving circuits 200 according to one or more embodiments of the present disclosure. FIG. 29 is a cross-sectional view of an example of the display panel 100 taken along the line X6-X6′ of FIG. 27. FIG. 30 is a cross-sectional view of an example of the display device 10 in which a circuit board 300 of FIG. 29 is bent.

Referring to FIGS. 27 through 30, the display device 10 according to the one or more embodiments may include a through hole TH. The through hole TH is a hole that can transmit light. The through hole TH may be a physical hole that penetrates not only the display panel 100 but also an under-panel cover PB and a polarizing film PF (e.g., see FIGS. 29 and 30). However, embodiments of the present disclosure are not limited thereto, and the through hole TH may also be a light-transmitting optical hole that penetrates the under-panel cover PB but does not penetrate the display panel 100 and the polarizing film PF. A cover window CW may cover the through hole TH.

The through hole TH may penetrate a substrate SUB, a thin-film transistor layer TFTL, an encapsulation layer ENC, and a sensor electrode layer SENL of the display panel 100.

An electronic device including the display device 10 according to the one or more embodiments may further include an optical device OPD disposed in the through hole TH (e.g., see FIGS. 29 and 30). An electronic device according to one or more embodiments of the present disclosure may be a portable electronic device such as a mobile phone, a smartphone, a tablet PC, a smart watch, a watch phone, a mobile communication terminal, an electronic notebook, an electronic book, a PMP, a navigation device and/or a UMPC, as well as a television, a notebook computer, a monitor, a billboard and/or an IoT device.

The optical device OPD may be spaced (e.g., spaced apart) from the display panel 100, the under-panel cover PB, and the polarizing film PF. The optical device OPD may be an optical sensor that detects light incident through the through hole TH, such as a proximity sensor, an illuminance sensor, and/or a camera sensor.

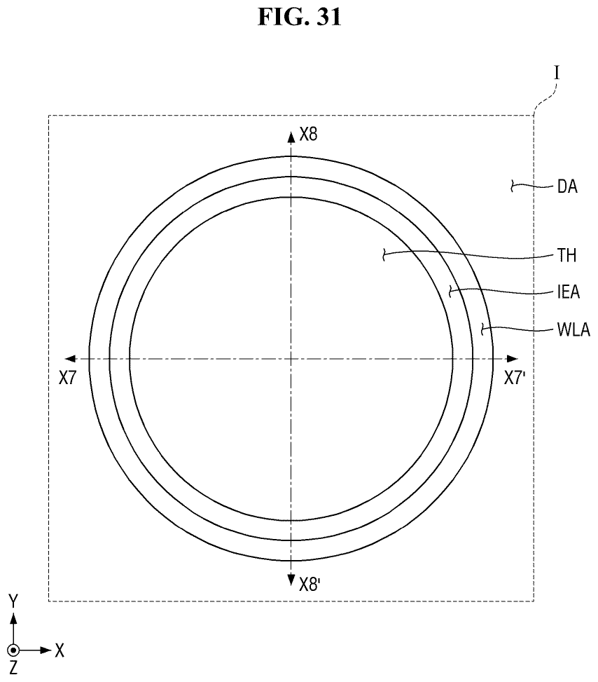

FIG. 31 is a detailed layout view of an example of an area I in FIG. 28. FIG. 31 illustrates an example of the layout of a through hole TH, an inorganic encapsulation area IEA, a wiring area WLA, and a display area DA of a display panel 100 according to one or more embodiments of the present disclosure.

Referring to FIG. 31, the display panel 100 according to the one or more embodiments includes the inorganic encapsulation area IEA surrounding the through hole TH and the wiring area WLA surrounding the inorganic encapsulation area IEA.

The inorganic encapsulation area IEA may be a layer in which a first encapsulating inorganic layer TFE1 and a second encapsulating inorganic layer TFE3 of the encapsulation layer ENC contact each other to prevent oxygen or moisture from penetrating into a light emitting element layer EML of a display layer DISL due to the through hole TH.

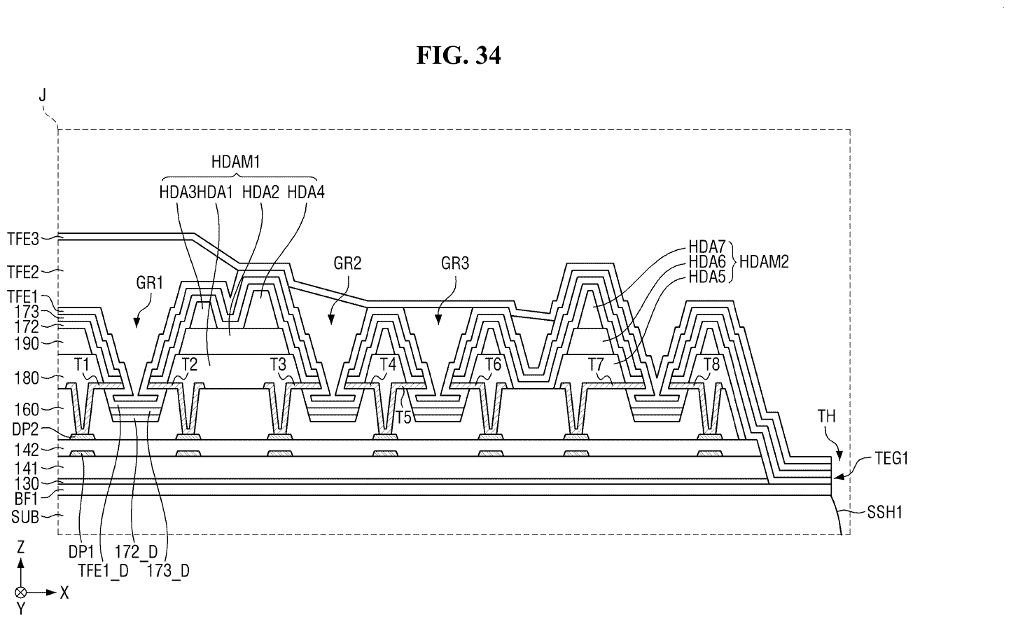

The inorganic encapsulation area IEA may include at least one dam, at least one tip, and at least one groove. For example, as illustrated in FIG. 34, the inorganic encapsulation area IEA may include a first dam HDAM1, a second dam HDAM2, first through eighth tips T1 through T8, and first through third grooves GR1 through GR3.

The first tip T1 and the second tip T2 may be disposed closer to the wiring area WLA than the first dam HDAM1 is. The first tip T1 may be disposed closer to the wiring area WLA than the second tip T2 is. The second tip T2 may be disposed between the first tip T1 and the first dam HDAM1.

The third tip T3, the fourth tip T4, the fifth tip T5, and the sixth tip T6 may be disposed between the first dam HDAM1 and the second dam HDAM2. At least a portion of the third tip T3 may overlap the first dam HDAM1 in the third direction (Z-axis direction).

The seventh tip T7 and the eighth tip T8 may be disposed closer to the through hole TH than the second dam HDAM2 is. At least a portion of the seventh tip T7 may overlap the second dam HDAM2 in the third direction (Z-axis direction). A distance between the eighth tip T8 and the through hole TH may be about 50 μm.

The first groove GR1 may be disposed between the first tip T1 and the second tip T2. The second groove GR2 may be disposed between the third tip T3 and the fourth tip T4. The third groove GR3 may be disposed between the fifth tip T5 and the sixth tip T6.

The wiring area WLA may be an area where bypass lines due to the through hole TH are disposed. Some of the bypass lines may be connected to data lines, and some other ones of the bypass lines may be connected to a second power line to which a second power supply voltage higher than a first power supply voltage is applied. Some other ones of the bypass lines may be connected to scan lines. The wiring area WLA may be surrounded by the display area DA.

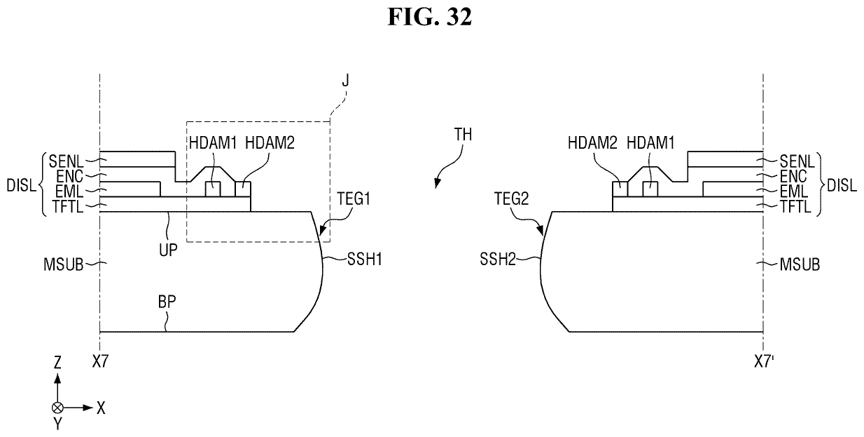

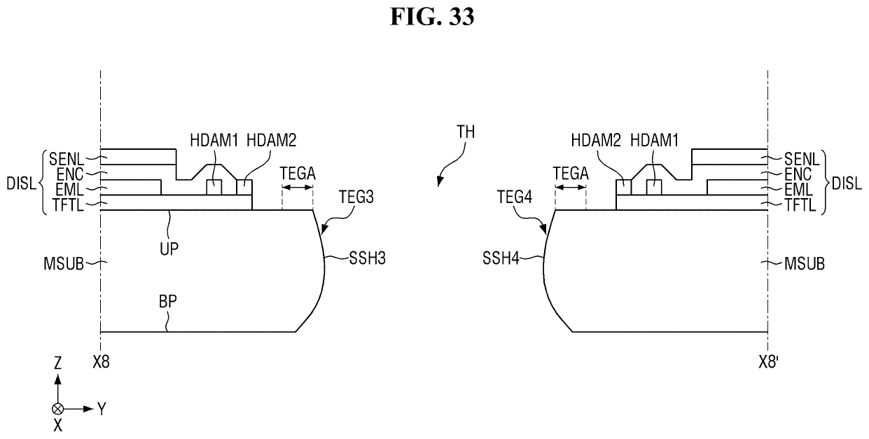

FIG. 32 is a cross-sectional view of an example of the display panel 100 taken along the line X7-X7′ of FIG. 31. FIG. 33 is a cross-sectional view of an example of the display panel 100 taken along the line X8-X8′ of FIG. 31. FIG. 34 is a detailed cross-sectional view of an example of an area J in FIG. 32.

FIG. 32 illustrates a first side edge TEG1 and a second side edge TEG2 of the through hole TH that face (or oppose) each other in the first direction (X-axis direction). FIG. 33 illustrates a third side edge TEG3 and a fourth side edge TEG4 of the through hole TH which face (or oppose) each other in the second direction (Y-axis direction).

Referring to FIGS. 32 and 33, a first hole side surface SSH1 formed at the first side edge TEG1 of the through hole TH, a second hole side surface SSH2 formed at the second side edge TEG2 of the through hole TH, a third hole side surface SSH3 formed at the third side edge TEG3 of the through hole TH, and a fourth hole side surface SSH4 formed at the fourth side edge TEG4 of the through hole TH may have a curved shape. Here, the first side edge TEG1 of the through hole TH may refer to a left edge of the through hole TH, and the second side edge TEG2 of the through hole TH may refer to a right edge of the through hole TH. In addition, the third side edge TEG3 of the through hole TH may refer to an upper edge of the through hole TH, and the fourth side edge TEG4 of the through hole TH may refer to a lower edge of the through hole TH. While the through hole TH is described in the present disclosure as having a plurality of side edges including the first through fourth side edges TEG1, TEG2, TEG3 and TEG4 as well as a plurality of hole side surfaces including first through fourth hole side surfaces SSH1, SSH2, SSH3 and SSH4, when the through hole is elliptical or circular (e.g., see FIG. 31), the through hole TH may be viewed as being defined by one continuous side surface. However, for the purposes of the present disclosure, each inner edge of the through hole at a cross-section taken along a diameter or an axis (e.g., a major axis or a minor axis) may be referred to as a side edge (e.g., TEG1, TEG2, TEG3 or TEG4) at which a corresponding hole side surface (e.g., SSH1, SSH2, SSH3 or SSH4) is formed (e.g., see FIGS. 32 and 33).

Referring to FIGS. 9A and 34, first dummy patterns DP1 may include the same material as a second gate metal layer including second capacitor electrodes CAE2 of capacitors Cst and may be disposed on (or at) the same layer as the second gate metal layer. For example, the first dummy patterns DP1 may be disposed on a first interlayer insulating layer 141. Each of the first dummy patterns DP1 may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

Second dummy patterns DP2 may include the same material as a first data metal layer including first connection electrodes CE1 and data lines and may be disposed on (or at) the same layer as the first data metal layer. For example, the second dummy patterns DP2 may be disposed on a second interlayer insulating layer 142. Each of the second dummy patterns DP2 may be a single layer or a multilayer made of one or more of molybdenum (Mo), aluminum (Al), chromium (Cr), gold (Au), titanium (Ti), nickel (Ni), neodymium (Nd), copper (Cu), and/or alloys thereof.

The second dummy patterns DP2 may overlap the first dummy patterns DP1 in the third direction (Z-axis direction).

The first through eighth tips T1 through T8 may include the same material as a second data metal layer including second connection electrodes CE2 and may be disposed on (or at) the same layer as the second data metal layer. For example, the first through eighth tips T1 through T8 may be disposed on a first organic layer 160. Each of the first through eighth tips T1 through T8 may be a single layer or a multilayer made of any one or more of molybdenum (Mo), aluminum (Al), chromium (Cr), gold (Au), titanium (Ti), nickel (Ni), neodymium (Nd), copper (Cu), and/or alloys thereof.

Each of the first through eighth tips T1 through T8 may be connected to a second dummy pattern DP2 through a contact hole penetrating the first organic layer 160. Each of the first through eighth tips T1 through T8 may have an eaves structure whose upper and lower surfaces are exposed without being covered by the first organic layer 160, a second organic layer 180, the first dam HDAM1, and/or the second dam HDAM2. The fourth tip T4 and the fifth tip T5 may be formed integrally with each other. Each of the first through eighth tips T1 through T8 may be a protrusion pattern or a trench pattern for forming a groove (or a trench).

The eighth tip T8 may be an outermost structure adjacent to the first side edge TEG1 of the through hole TH. A distance from the eighth tip T8, which is the outermost structure, to the first side edge TEG1 of the through hole TH may be about 300 μm.

In FIG. 34, the eighth tip T8 is illustrated as the outermost structure adjacent to the first side edge TEG1 of the through hole TH. However, embodiments of the present disclosure are not limited thereto. For example, when the seventh tip T7 and the eighth tip T8 are omitted, the outermost structure adjacent to the first side edge TEG1 of the through hole TH may be the second dam HDAM2 for preventing an encapsulating organic layer TFE2 of the encapsulation layer ENC from overflowing. Alternatively, when the seventh tip T7 and the eighth tip T8 are omitted, the outermost structure adjacent to the first edge TEG1 of the through hole TH may be a groove for breaking a light emitting layer 172 and a common electrode 173.

The first groove GR1 may be formed between the first tip T1 and the second tip T2, the second groove GR2 may be formed between the third tip T3 and the fourth tip T4, and the third groove GR3 may be formed between the fifth tip T5 and the sixth tip T6. The first groove GR1 may have eaves structures formed by the first tip T1 and the second tip T2, the second groove GR2 may have eaves structures formed by the third tip T3 and the fourth tip T4, and the third groove GR3 may have eaves structures formed by the fifth tip T5 and the sixth tip T6.

The light emitting layer 172 may be deposited by evaporation, and the common electrode 173 may be deposited by sputtering. Therefore, the light emitting layer 172 and the common electrode 173 may have low step coverage and thus may be broken in each of the first through third grooves GR1 through GR3. On the other hand, the first encapsulating inorganic layer TFE1 and the third encapsulating inorganic layer TFE3 may be deposited by chemical vapor deposition or atomic layer deposition. Therefore, the first encapsulating inorganic layer TFE1 and the third encapsulating inorganic layer TFE3 may have high step coverage and thus may be continuous without being broken in each of the first through third grooves GR1 through GR3. The step coverage refers to the ratio of the extent to which a thin layer is applied to an inclined portion to the extent to which the thin layer is applied to a flat portion. A light emitting layer residue 172_D broken off from the light emitting layer 172 and a common electrode residue 173_D broken off from the common electrode 173 may be disposed in each of the first through third grooves GR1 through GR3. A portion of the first encapsulating inorganic layer TFE1 that is disposed in each of the first through third grooves GR1 through GR3 is also labeled as TFE1_D in FIG. 34.

The first dam HDAM1 may include first through fourth sub-dams HDA1 through HDA4. The first sub-dam HDA1 may be disposed on the first organic layer 160 and may include the same material as the second organic layer 180. The first sub-dam HDA1 may be disposed on the second tip T2 and the third tip T3. The second sub-dam HDA2 may be disposed on the first sub-dam HDA1 and may include the same material as a bank 190. The third sub-dam HDA3 and the fourth sub-dam HDA4 may be disposed on the second sub-dam HDA2 and may include the same material as a spacer 191, but embodiments of the present disclosure are not limited thereto. The fourth sub-dam HDA4 may be disposed closer to the through hole TH than the third sub-dam HDA3 is. A thickness of the fourth sub-dam HDA4 may be greater than a thickness of the third sub-dam HDA3.

The second dam HDAM2 may include fifth through seventh sub-dams HDA5 through HDA7. The fifth sub-dam HDA5 may be disposed on the first organic layer 160 and may include the same material as the second organic layer 180. The fifth sub-dam HDA5 may be disposed on the seventh tip T7. The sixth sub-dam HDA6 may be disposed on the fifth sub-dam HDA5 and may include the same material as the bank 190. The seventh sub-dam HDA7 may be disposed on the sixth sub-dam HDA6 and may include the same material as the spacer 191. However, embodiments of the present disclosure are not limited thereto.

The first dam HDAM1 and the second dam HDAM2 can prevent the encapsulating organic layer TFE2 from overflowing into the through hole TH.

The light emitting layer residue 172_D, the common electrode residue 173_D, the first encapsulating inorganic layer TFE1, and the second encapsulating inorganic layer TFE3 may extend to the edge TEG of the through hole TH. An end of the light emitting layer residue 172_D, an end of the common electrode residue 173_D, an end of the first encapsulating inorganic layer TFE1, or an end of the second encapsulating inorganic layer TFE3 may coincide with the edge TEG of the through hole TH.

As illustrated in FIG. 34, because the light emitting layer 172 and the common electrode 173 are broken in each of the first through third grooves GR1 through GR3 formed by the first through eighth tips T1 through T8, it is possible to prevent the light emitting layer 172 and the common electrode 173 exposed to the through hole TH from serving as a path through which oxygen and moisture are introduced.

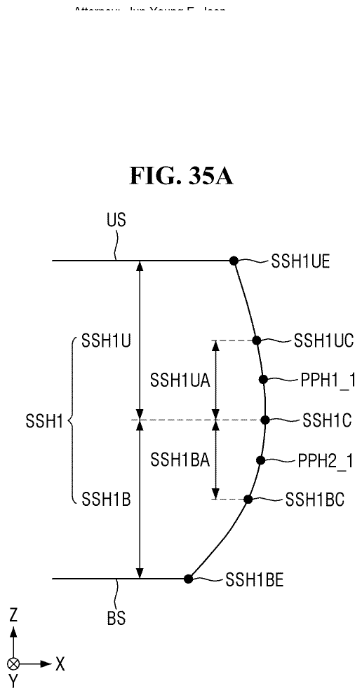

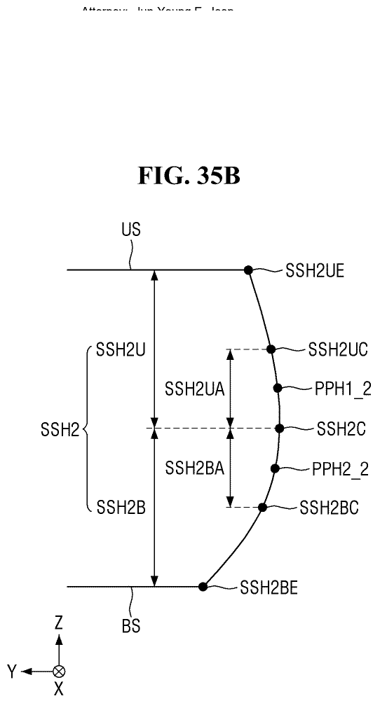

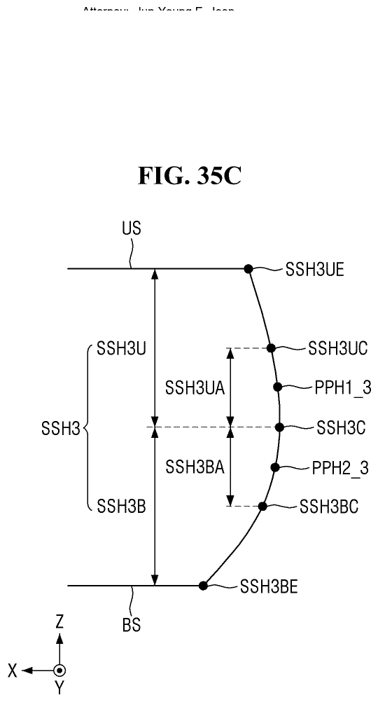

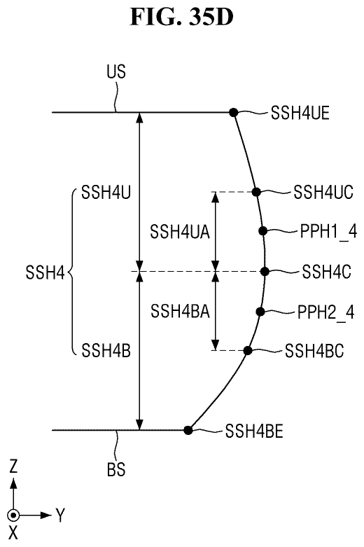

FIGS. 35A through 35D are enlarged cross-sectional views of examples of the first through fourth hole side surfaces SSH1 through SSH4 illustrated in FIGS. 32 and 33. FIG. 35A illustrates a cross section of the first hole side surface SSH1 disposed at the first side edge TEG1 of the through hole TH. FIG. 35B illustrates a cross section of the second hole side surface SSH2 disposed at the second side edge TEG2 of the through hole TH. FIG. 35C illustrates a cross section of the third hole side surface SSH3 disposed at the third side edge TEG3 of the through hole TH. FIG. 35D illustrates a cross section of the fourth hole side surface SSH4 disposed at the first side edge TEG4 of the through hole TH.

Referring to FIG. 35A, the first hole side surface SSH1 may have a curved shape with a varying radius of curvature. A curved shape of an upper part SSH1U (e.g., a first hole upper part) of the first hole side surface SSH1 and a curved shape of a lower part SSH1B (e.g., a first hole lower part) of the first hole side surface SSH1 may be different from each other. The upper part SSH1U of the first hole side surface SSH1 refers to an area disposed above a center SSH1C (e.g., a first hole center) of the first hole side surface SSH1. The lower part SSH1B of the first hole side surface SSH1 refers to an area disposed below the center SSH1C of the first hole side surface SSH1.

A radius of curvature of the upper part SSH1U of the first hole side surface SSH1 and a radius of curvature of the lower part SSH1B of the first hole side surface SSH1 may be different from each other. For example, the radius of curvature of the lower part SSH1B of the first hole side surface SSH1 may be smaller than the radius of curvature of the upper part SSH1U of the first hole side surface SSH1.

The radius of curvature of the upper part SSH1U of the first hole side surface SSH1 may be defined as a radius of curvature of a curve passing through the center SSH1C of the first hole side surface SSH1, an upper end SSH1UE of the first hole side surface SSH1, and an upper center SSH1UC (e.g., a first hole upper center) of the first hole side surface SSH1. The radius of curvature of the lower part SSH1B of the first hole side surface SSH1 may be defined as a radius of curvature of a curve passing through the center SSH1C of the first hole side surface SSH1, a lower end SSH1BE of the first hole side surface SSH1, and a lower center SSH1BC (e.g., a first hole lower center) of the first hole side surface SSH1.

In addition, a radius of curvature of a central area of the first hole side surface SSH1 may be different from the radius of curvature of the upper part SSH1U of the first hole side surface SSH1 and the radius of curvature of the lower part SSH1B of the first hole side SSH1. The radius of curvature of the central area of the first hole side surface SSH1 may be defined as a radius of curvature of a curve passing through the center SSH1C of the first hole side surface SSH1, the upper center SSH1UC of the first hole side surface SSH1, and the lower center SSH1BC of the first hole side surface SSH1.

In addition, a difference between a radius of curvature of an upper central area SSH1UA of the first hole side surface SSH1 and a radius of curvature of a lower central area SSH1BA of the first hole side surface SSH1 may be smaller than a difference between the radius of curvature of the upper part SSH1U of the first hole side surface SSH1 and the radius of curvature of the lower part SSH1B of the first hole side surface SSH1. The radius of curvature of the upper central area SSH1UA of the first hole side surface SSH1 and the radius of curvature of the lower central area SSH1BA of the first hole side surface SSH1 may be substantially equal to each other. Alternatively, the difference between the radius of curvature of the upper central area SSH1UA of the first hole side surface SSH1 and the radius of curvature of the lower central area SSH1BA of the first hole side surface SSH1 may be within 30 μm (e.g., may be about 30 μm or less).

The radius of curvature of the upper central area SSH1UA of the first hole side surface SSH1 may be defined as a radius of curvature of a curve passing through the center SSH1C of the first hole side surface SSH1, the upper center SSH1UC of the first hole side surface SSH1, and a first point PPH1_1 of the first hole side surface SSH1. The radius of curvature of the lower central area SSH1BA of the first hole side surface SSH1 may be defined as a radius of curvature of a curve passing through the center SSH1C of the first hole side surface SSH1, the lower center SSH1BC of the first hole side surface SSH1, and a second point PPH2_1 of the first hole side surface SSH1. The first point PPH1_1 of the first hole side surface SSH1 may be defined as a midpoint between the center SSH1C of the first hole side surface SSH1 and the upper center SSH1UC of the first hole side surface SSH1. The second point PPH2_1 of the first hole side surface SSH1 may be defined as a midpoint between the center SSH1C of the first hole side surface SSH1 and the lower center SSH1BC of the first hole side surface SSH1.

Referring to FIG. 35B, the second hole side surface SSH2 may have a curved shape with a varying radius of curvature. A curved shape of an upper part SSH2U (e.g., a second hole upper part) of the second hole side surface SSH2 and a curved shape of a lower part SSH2B (e.g., a second hole lower part) of the second hole side surface SSH2 may be different from each other. The upper part SSH2U of the second hole side surface SSH2 refers to an area disposed above a center SSH2C (e.g., a second hole center) of the second hole side surface SSH2. The lower part SSH2B of the second hole side surface SSH2 refers to an area disposed below the center SSH2C of the second hole side surface SSH2.

A radius of curvature of the upper part SSH2U of the second hole side surface SSH2 and a radius of curvature of the lower part SSH2B of the second hole side surface SSH2 may be different from each other. For example, the radius of curvature of the lower part SSH2B of the second hole side surface SSH2 may be smaller than the radius of curvature of the upper part SSH2U of the second hole side surface SSH2.

The radius of curvature of the upper part SSH2U of the second hole side surface SSH2 may be defined as a radius of curvature of a curve passing through the center SSH2C of the second hole side surface SSH2, an upper end SSH2UE of the second hole side surface SSH2, and an upper center SSH2UC (e.g., a second hole upper center) of the second hole side surface SSH2. The radius of curvature of the lower part SSH2B of the second hole side surface SSH2 may be defined as a radius of curvature of a curve passing through the center SSH2C of the second hole side surface SSH2, a lower end SSH2BE of the second hole side surface SSH2, and a lower center SSH2BC (e.g., a second hole lower center) of the second hole side surface SSH2.

In addition, a radius of curvature of a central area of the second hole side surface SSH2 may be different from the radius of curvature of the upper part SSH2U of the second hole side surface SSH2 and the radius of curvature of the lower part SSH2B of the second hole side surface SSH2. The radius of curvature of the central area of the second hole side surface SSH2 may be defined as a radius of curvature of a curve passing through the center SSH2C of the second hole side surface SSH2, the upper center SSH2UC of the second hole side surface SSH2, and the lower center SSH2BC of the second hole side surface SSH2.

In addition, a difference between a radius of curvature of an upper central area SSH2UA of the second hole side surface SSH2 and a radius of curvature of a lower central area SSH2BA of the second hole side surface SSH2 may be smaller than a difference between the radius of curvature of the upper part SSH2U of the second hole side surface SSH2 and the radius of curvature of the lower part SSH2B of the second hole side surface SSH2. The radius of curvature of the upper central area SSH2UA of the second hole side surface SSH2 and the radius of curvature of the lower central area SSH2BA of the second hole side surface SSH2 may be substantially equal to each other. Alternatively, the difference between the radius of curvature of the upper central area SSH2UA of the second hole side surface SSH2 and the radius of curvature of the lower central area SSH2BA of the second hole side surface SSH2 may be within 30 μm (e.g., may be about 30 μm or less).

The radius of curvature of the upper central area SSH2UA of the second hole side surface SSH2 may be defined as a radius of curvature of a curve passing through the center SSH2C of the second hole side surface SSH2, the upper center SSH2UC of the second hole side surface SSH2, and a first point PPH1_2 of the second hole side surface SSH2. The radius of curvature of the lower central area SSH2BA of the second hole side surface SSH2 may be defined as a radius of curvature of a curve passing through the center SSH2C of the second hole side surface SSH2, the lower center SSH2BC of the second hole side surface SSH2, and a second point PPH2_2 of the second hole side surface SSH2. The first point PPH1_2 of the second hole side surface SSH2 may be defined as a midpoint between the center SSH2C of the second hole side surface SSH2 and the upper center SSH2UC of the second hole side surface SSH2. The second point PPH2_2 of the second hole side surface SSH2 may be defined as a midpoint between the center SSH2C of the second hole side surface SSH2 and the lower center SSH2BC of the second hole side surface SSH2.

Referring to FIG. 35C, the third hole side surface SSH3 may have a curved shape with a varying radius of curvature. A curved shape of an upper part SSH3U (e.g., a third hole upper part) of the third hole side surface SSH3 and a curved shape of a lower part SSH3B (e.g., a third hole lower part) of the third hole side surface SSH3 may be different from each other. The upper part SSH3U of the third hole side surface SSH3 refers to an area disposed above a center SSH3C (e.g., a third hole center) of the third hole side surface SSH3. The lower part SSH3B of the third hole side surface SSH3 refers to an area disposed below the center SSH3C of the third hole side surface SSH3.

A radius of curvature of the upper part SSH3U of the third hole side surface SSH3 and a radius of curvature of the lower part SSH3B of the third hole side surface SSH3 may be different from each other. For example, the radius of curvature of the lower part SSH3B of the third hole side surface SSH3 may be smaller than the radius of curvature of the upper part SSH3U of the third hole side surface SSH3.

The radius of curvature of the upper part SSH3U of the third hole side surface SSH3 may be defined as a radius of curvature of a curve passing through the center SSH3C of the third hole side surface SSH3, an upper end SSH3UE of the third hole side surface SSH3, and an upper center SSH3UC (e.g., a third hole upper center) of the third hole side surface SSH3. The radius of curvature of the lower part SSH3B of the third hole side surface SSH3 may be defined as a radius of curvature of a curve passing through the center SSH3C of the third hole side surface SSH3, a lower end SSH3BE of the third hole side surface SSH3, and a lower center SSH3BC (e.g., a third hole lower center) of the third hole side surface SSH3.

In addition, a radius of curvature of a central area of the third hole side surface SSH3 may be different from the radius of curvature of the upper part SSH3U of the third hole side surface SSH3 and the radius of curvature of the lower part SSH3B of the third hole side surface SSH3. The radius of curvature of the central area of the third hole side surface SSH3 may be defined as a radius of curvature of a curve passing through the center SSH3C of the third hole side surface SSH3, the upper center SSH3UC of the third hole side surface SSH3, and the lower center SSH3BC of the third hole side surface SSH3.

In addition, a difference between a radius of curvature of an upper central area SSH3UA of the third hole side surface SSH3 and a radius of curvature of a lower central area SSH3BA of the third hole side surface SSH3 may be smaller than a difference between the radius of curvature of the upper part SSH3U of the third hole side surface SSH3 and the radius of curvature of the lower part SSH3B of the third hole side surface SSH3. The radius of curvature of the upper central area SSH3UA of the third hole side surface SSH3 and the radius of curvature of the lower central area SSH3BA of the third hole side surface SSH3 may be substantially equal to each other. Alternatively, the difference between the radius of curvature of the upper central area SSH3UA of the third hole side surface SSH3 and the radius of curvature of the lower central area SSH3BA of the third hole side surface SSH3 may be within 30 μm (e.g., may be about 30 μm or less).

The radius of curvature of the upper central area SSH3UA of the third hole side surface SSH3 may be defined as a radius of curvature of a curve passing through the center SSH3C of the third hole side surface SSH3, the upper center SSH3UC of the third hole side surface SSH3, and a first point PPH1_3 of the third hole side surface SSH3. The radius of curvature of the lower central area SSH3BA of the third hole side surface SSH3 may be defined as a radius of curvature of a curve passing through the center SSH3C of the third hole side surface SSH3, the lower center SSH3BC of the third hole side surface SSH3, and a second point PPH2_3 of the third hole side surface SSH3. The first point PPH1_3 of the third hole side surface SSH3 may be defined as a midpoint between the center SSH3C of the third hole side surface SSH3 and the upper center SSH3UC of the third hole side surface SSH3. The second point PPH2_3 of the third hole side surface SSH3 may be defined as a midpoint between the center SSH3C of the third hole side surface SSH3 and the lower center SSH3BC of the third hole side surface SSH3.

Referring to FIG. 35D, the fourth hole side surface SSH4 may have a curved shape with a varying radius of curvature. A curved shape of an upper part SSH4U (e.g., a fourth hole upper part) of the fourth hole side surface SSH4 and a curved shape of a lower part SSH4B (e.g., a fourth hole lower part) of the fourth hole side surface SSH4 may be different from each other. The upper part SSH4U of the fourth hole side surface SSH4 refers to an area disposed above a center SSH4C (e.g., a fourth hole center) of the fourth hole side surface SSH4. The lower part SSH4B of the fourth hole side surface SSH4 refers to an area disposed below the center SSH4C of the fourth hole side surface SSH4.

A radius of curvature of the upper part SSH4U of the fourth hole side surface SSH4 and a radius of curvature of the lower part SSH4B of the fourth hole side surface SSH4 may be different from each other. For example, the radius of curvature of the lower part SSH4B of the fourth hole side surface SSH4 may be smaller than the radius of curvature of the upper part SSH4U of the fourth hole side surface SSH4.

The radius of curvature of the upper part SSH4U of the fourth hole side surface SSH4 may be defined as a radius of curvature of a curve passing through the center SSH4C of the fourth hole side surface SSH4, an upper end SSH4UE of the fourth hole side surface SSH4, and an upper center SSH4UC (e.g., a fourth hole upper center) of the fourth hole side surface SSH4. The radius of curvature of the lower part SSH4B of the fourth hole side surface SSH4 may be defined as a radius of curvature of a curve passing through the center SSH4C of the fourth hole side surface SSH4, a lower end SSH4BE of the fourth hole side surface SSH4, and a lower center SSH4BC (e.g., a fourth hole lower center) of the fourth hole side surface SSH4.

In addition, a radius of curvature of a central area of the fourth hole side surface SSH4 may be different from the radius of curvature of the upper part SSH4U of the fourth hole side surface SSH4 and the radius of curvature of the lower part SSH4B of the fourth hole side surface SSH4. The radius of curvature of the central area of the fourth hole side surface SSH4 may be defined as a radius of curvature of a curve passing through the center SSH4C of the fourth hole side surface SSH4, the upper center SSH4UC of the fourth hole side surface SSH4, and the lower center SSH4BC of the fourth hole side surface SSH4.

In addition, a difference between a radius of curvature of an upper central area SSH4UA of the fourth hole side surface SSH4 and a radius of curvature of a lower central area SSH4BA of the fourth hole side surface SSH4 may be smaller than a difference between the radius of curvature of the upper part SSH4U of the fourth hole side surface SSH4 and the radius of curvature of the lower part SSH4B of the fourth hole side surface SSH4. The radius of curvature of the upper central area SSH4UA of the fourth hole side surface SSH4 and the radius of curvature of the lower central area SSH4BA of the fourth hole side surface SSH4 may be substantially equal to each other. Alternatively, the difference between the radius of curvature of the upper central area SSH4UA of the fourth hole side surface SSH4 and the radius of curvature of the lower central area SSH4BA of the fourth hole side surface SSH4 may be within 30 μm (e.g., may be about 30 μm or less).

The radius of curvature of the upper central area SSH4UA of the fourth hole side surface SSH4 may be defined as a radius of curvature of a curve passing through the center SSH4C of the fourth hole side surface SSH4, the upper center SSH4UC of the fourth hole side surface SSH4, and a first point PPH1_4 of the fourth hole side surface SSH4. The radius of curvature of the lower central area SSH4BA of the fourth hole side surface SSH4 may be defined as a radius of curvature of a curve passing through the center SSH4C of the fourth hole side surface SSH4, the lower center SSH4BC of the fourth hole side surface SSH4, and a second point PPH2_4 of the fourth hole side surface SSH4. The first point PPH1_4 of the fourth hole side surface SSH4 may be defined as a midpoint between the center SSH4C of the fourth hole side surface SSH4 and the upper center SSH4UC of the fourth hole side surface SSH4. The second point PPH2_4 of the fourth hole side surface SSH4 may be defined as a midpoint between the center SSH4C of the fourth hole side surface SSH4 and the lower center SSH4BC of the fourth hole side surface SSH4.

Referring to FIGS. 35A through 35D, the radius of curvature of the upper part SSH1U of the first hole side surface SSH1, the radius of curvature of the upper part SSH2U of the second hole side surface SSH2, the radius of curvature of the upper part SSH3U of the third hole side surface SSH3, and the radius of curvature of the upper part SSH4U of the fourth hole side surface SSH4 may be similar to each other. For example, the radius of curvature of the upper part SSH1U of the first hole side surface SSH1, the radius of curvature of the upper part SSH2U of the second hole side surface SSH2, the radius of curvature of the upper part SSH3U of the third hole side surface SSH3, and the radius of curvature of the upper part SSH4U of the fourth hole side surface SSH4 may be in a range of 150 μm to 350 μm.

A difference between the radius of curvature of the upper part SSH1U of the first hole side surface SSH1 and the radius of curvature of the upper part SSH2U of the second hole side surface SSH2 may be less than about 30 μm. A difference between the radius of curvature of the upper part SSH1U of the first hole side surface SSH1 and the radius of curvature of the upper part SSH3U of the third hole side surface SSH3 may be less than about 30 μm. A difference between the radius of curvature of the upper part SSH1U of the first hole side surface SSH1 and the radius of curvature of the upper part SSH4U of the fourth hole side surface SSH4 may be less than about 30 μm. A difference between the radius of curvature of the upper part SSH2U of the second hole side surface SSH2 and the radius of curvature of the upper part SSH3U of the third hole side surface SSH3 may be less than about 30 μm. A difference between the radius of curvature of the upper part SSH2U of the second hole side surface SSH2 and the radius of curvature of the upper part SSH4U of the fourth hole side surface SSH4 may be less than about 30 μm. A difference between the radius of curvature of the upper part SSH3U of the third hole side surface SSH3 and the radius of curvature of the upper part SSH4U of the fourth hole side surface SSH4 may be less than about 30 μm.

In addition, referring to FIGS. 25A through 25D and 35A through 35D, each of the radius of curvature of the upper part SSH1U of the first hole side surface SSH1, the radius of curvature of the upper part SSH2U of the second hole side surface SSH2, the radius of curvature of the upper part SSH3U of the third hole side surface SSH3 and the radius of curvature of the upper part SSH4U of the fourth hole side surface SSH4 may be similar to the radius of curvature of the upper part SS1U of the first side surface SS1, the radius of curvature of the upper part SS2U of the second side surface SS2, the radius of curvature of the upper part SS3U of the third side surface SS3, and the radius of curvature of the upper part SS4U of the fourth side surface SS4. For example, a difference between each of the radius of curvature of the upper part SSH1U of the first hole side surface SSH1, the radius of curvature of the upper part SSH2U of the second hole side surface SSH2, the radius of curvature of the upper part SSH3U of the third hole side surface SSH3 and the radius of curvature of the upper part SSH4U of the fourth hole side surface SSH4 and any one of the radius of curvature of the upper part SS1U of the first side surface SS1, the radius of curvature of the upper part SS2U of the second side surface SS2, the radius of curvature of the upper part SS3U of the third side surface SS3 and the radius of curvature of the upper part SS4U of the fourth side surface SS4 may be less than about 30 μm.

As illustrated in FIGS. 35A through 35D, a difference in radius of curvature between the hole side surfaces SSH1 through SSH4 of the substrate SUB of the display panel 100 may be insignificant. Therefore, uniform mechanical strength can be maintained according to the positions of the hole side surfaces SSH1 through SSH4 of the substrate SUB of the display panel 100.

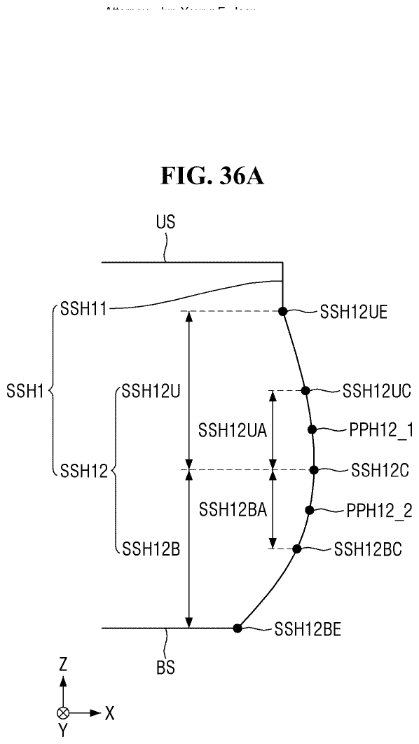

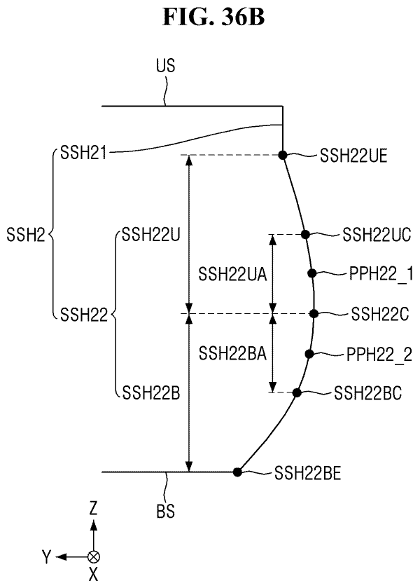

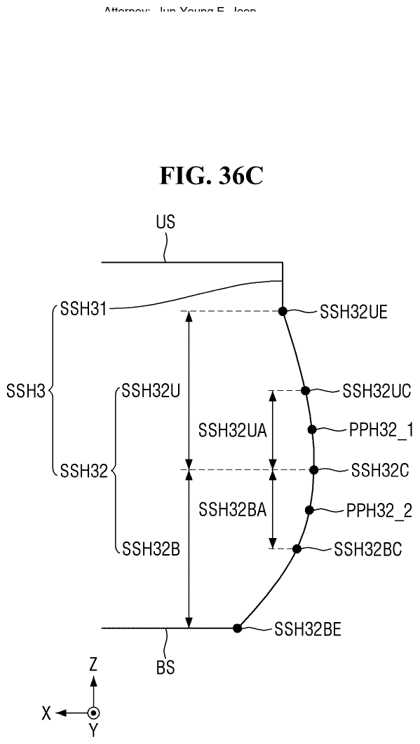

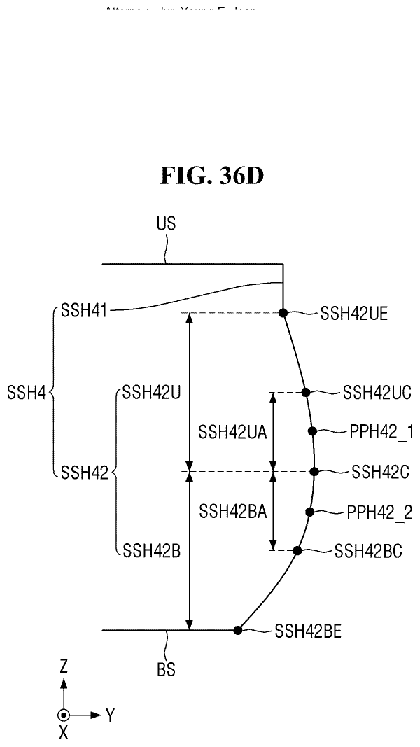

FIGS. 36A through 36D are enlarged cross-sectional views of examples of the first through fourth hole side surfaces SSH1 through SSH4 illustrated in FIGS. 32 and 33. FIG. 36A illustrates a cross section of the first hole side surface SSH1, FIG. 36B illustrates a cross section of the second hole side surface SSH2, FIG. 36C illustrates a cross section of the third hole side surface SSH3, and FIG. 36D illustrates a cross section of the fourth hole side surface SSH4.

Referring to FIG. 36A, the first hole side surface SSH1 may have a first sub-hole side surface SSH11 in a flat or curved shape and a second sub-hole side surface SSH12 in a curved shape with a varying radius of curvature. A length of the first sub-hole side surface SSH11 may be smaller than a length of the second sub-hole side surface SSH12.

The first sub-hole side surface SSH11 may be connected to an upper surface US, and the second sub-hole side surface SSH12 may be connected to a lower surface BS. An angle between the first sub-hole side surface SSH11 and the upper surface US may be a right angle or an obtuse angle close to a right angle.

A curved shape of an upper part SSH12U of the second sub-hole side surface SSH12 and a curved shape of a lower part SSH12B of the second sub-hole side surface SSH12 may be different from each other. The upper part SSH12U of the second sub-hole side surface SSH12 refers to an area disposed above a center SSH12C of the second sub-hole side surface SSH12. The lower part SSH12B of the second sub-hole side surface SSH12 refers to an area disposed below the center SSH12C of the second sub-hole side surface SSH12.

A radius of curvature of the upper part SSH12U of the second sub-hole side surface SSH12 and a radius of curvature of the lower part SSH12B of the second sub-hole side surface SSH12 may be different from each other. For example, the radius of curvature of the lower part SSH12B of the second sub-hole side surface SSH12 may be smaller than the radius of curvature of the upper part SSH12U of the second sub-hole side surface SSH12.

The radius of curvature of the upper part SSH12U of the second sub-hole side surface SSH12 may be defined as a radius of curvature of a curve passing through the center SSH12C of the second sub-hole side surface SSH12, an upper end SSH12UE of the second sub-hole side surface SSH12, and an upper center SSH12UC of the second sub-hole side surface SSH12. The radius of curvature of the lower part SSH12B of the second sub-hole side surface SSH12 may be defined as a radius of curvature of a curve passing through the center SSH12C of the second sub-hole side surface SSH12, a lower end SSH12BE of the second sub-hole side surface SSH12, and a lower center SSH12BC of the second sub-hole side surface SSH12.

In addition, a radius of curvature of a central area of the second sub-hole side surface SSH12 may be different from the radius of curvature of the upper part SSH12U of the second sub-hole side surface SSH12 and the radius of curvature of the lower part SSH12B of the second sub-hole side surface SSH12. The radius of curvature of the central area of the second sub-hole side surface SSH12 may be defined as a radius of curvature of a curve passing through the center SSH12C of the second sub-hole side surface SSH12, the upper center SSH12UC of the second sub-hole side surface SSH12, and the lower center SSH12BC of the second sub-hole side surface SSH12.

In addition, a difference between a radius of curvature of an upper central area SSH12UA of the second sub-hole side surface SSH12 and a radius of curvature of a lower central area SSH12BA of the second sub-hole side surface SSH12 may be smaller than a difference between the radius of curvature of the upper part SSH12U of the second sub-hole side surface SSH12 and the radius of curvature of the lower part SSH12B of the second sub-hole side surface SSH12. The radius of curvature of the upper central area SSH12UA of the second sub-hole side surface SSH12 and the radius of curvature of the lower central area SSH12BA of the second sub-hole side surface SSH12 may be substantially equal to each other. Alternatively, the difference between the radius of curvature of the upper central area SSH12UA of the second sub-hole side surface SSH12 and the radius of curvature of the lower central area SSH12BA of the second sub-hole side surface SSH12 may be within 30 μm (e.g., may be about 30 μm or less).

The radius of curvature of the upper central area SSH12UA of the second sub-hole side surface SSH12 may be defined as a radius of curvature of a curve passing through the center SSH12C of the second sub-hole side surface SSH12, the upper center SSH12UC of the second sub-hole side surface SSH12, and a first point PPH12_1 of the second sub-hole side surface SSH12. The radius of curvature of the lower central area SSH12BA of the second sub-hole side surface SSH12 may be defined as a radius of curvature of a curve passing through the center SSH12C of the second sub-hole side surface SSH12, the lower center SSH12BC of the second sub-hole side surface SSH12, and a second point PPH12_2 of the second sub-hole side surface SSH12. The first point PPH12_1 of the second sub-hole side surface SSH12 may be defined as a midpoint between the center SSH12C of the second sub-hole side surface SSH12 and the upper center SSH12UC of the second sub-hole side surface SSH12. The second point PPH12_2 of the second sub-hole side surface SSH12 may be defined as a midpoint between the center SSH12C of the second sub-hole side surface SSH12 and the lower center SSH12BC of the second sub-hole side surface SSH12.

Referring to FIG. 36B, the second hole side surface SSH2 may have a third sub-hole side surface SSH21 in a flat or curved shape and a fourth sub-hole side surface SSH22 in a curved shape with a varying radius of curvature. A length of the third sub-hole side surface SSH21 may be smaller than a length of the fourth sub-hole side surface SSH22.

The third sub-hole side surface SSH21 may be connected to the upper surface US, and the fourth sub-hole side surface SSH22 may be connected to the lower surface BS. An angle between the third sub-hole side surface SSH21 and the upper surface US may be a right angle or an obtuse angle close to a right angle.

A curved shape of an upper part SSH22U of the fourth sub-hole side surface SSH22 and a curved shape of a lower part SSH22B of the fourth sub-hole side surface SSH22 may be different from each other. The upper part SSH22U of the fourth sub-hole side surface SSH22 refers to an area disposed above a center SSH22C of the fourth sub-hole side surface SSH22. The lower part SSH22B of the fourth sub-hole side surface SSH22 refers to an area disposed below the center SSH22C of the fourth sub-hole side surface SSH22.

A radius of curvature of the upper part SSH22U of the fourth sub-hole side surface SSH22 and a radius of curvature of the lower part SSH22B of the fourth sub-hole side surface SSH22 may be different from each other. For example, the radius of curvature of the lower part SSH22B of the fourth sub-hole side surface SSH22 may be smaller than the radius of curvature of the upper part SSH22U of the fourth sub-hole side surface SSH22.

The radius of curvature of the upper part SSH22U of the fourth sub-hole side surface SSH22 may be defined as a radius of curvature of a curve passing through the center SSH22C of the fourth sub-hole side surface SSH22, an upper end SSH22UE of the fourth sub-hole side surface SSH22, and an upper center SSH22UC of the fourth sub-hole side surface SSH22. The radius of curvature of the lower part SSH22B of the fourth sub-hole side surface SSH22 may be defined as a radius of curvature of a curve passing through the center SSH22C of the fourth sub-hole side surface SSH22, a lower end SSH22BE of the fourth sub-hole side surface SSH22, and a lower center SSH22BC of the fourth sub-hole side surface SSH22.

In addition, a radius of curvature of a central area of the fourth sub-hole side surface SSH22 may be different from the radius of curvature of the upper part SSH22U of the fourth sub-hole side surface SSH22 and the radius of curvature of the lower part SSH22B of the fourth sub-hole side surface SSH22. The radius of curvature of the central area of the fourth sub-hole side surface SSH22 may be defined as a radius of curvature of a curve passing through the center SSH22C of the fourth sub-hole side surface SSH22, the upper center SSH22UC of the fourth sub-hole side surface SSH22, and the lower center SSH22BC of the fourth sub-hole side surface SSH22.

In addition, a difference between a radius of curvature of an upper central area SSH22UA of the fourth sub-hole side surface SSH22 and a radius of curvature of a lower central area SSH22BA of the fourth sub-hole side surface SSH22 may be smaller than a difference between the radius of curvature of the upper part SSH22U of the fourth sub-hole side surface SSH22 and the radius of curvature of the lower part SSH22B of the fourth sub-hole side surface SSH22. The radius of curvature of the upper central area SSH22UA of the fourth sub-hole side surface SSH22 and the radius of curvature of the lower central area SSH22BA of the fourth sub-hole side surface SSH22 may be substantially equal to each other. Alternatively, the difference between the radius of curvature of the upper central area SSH22UA of the fourth sub-hole side surface SSH22 and the radius of curvature of the lower central area SSH22BA of the fourth sub-hole side surface SSH22 may be within 30 μm (e.g., may be about 30 μm or less).

The radius of curvature of the upper central area SSH22UA of the fourth sub-hole side surface SSH22 may be defined as a radius of curvature of a curve passing through the center SSH22C of the fourth sub-hole side surface SSH22, the upper center SSH22UC of the fourth sub-hole side surface SSH22, and a first point PPH22_1 of the fourth sub-hole side surface SSH22. The radius of curvature of the lower central area SSH22BA of the fourth sub-hole side surface SSH22 may be defined as a radius of curvature of a curve passing through the center SSH22C of the fourth sub-hole side surface SSH22, the lower center SSH22BC of the fourth sub-hole side surface SSH22, and a second point PPH22_2 of the fourth sub-hole side surface SSH22. The first point PPH22_1 of the fourth sub-hole side surface SSH22 may be defined as a midpoint between the center SSH22C of the fourth sub-hole side surface SSH22 and the upper center SSH22UC of the fourth sub-hole side surface SSH22. The second point PPH22_2 of the fourth sub-hole side surface SSH22 may be defined as a midpoint between the center SSH22C of the fourth sub-hole side surface SSH22 and the lower center SSH22BC of the fourth sub-hole side surface SSH22.

Referring to FIG. 36C, the third hole side surface SSH3 may have a fifth sub-hole side surface SSH31 in a flat or curved shape and a sixth sub-hole side surface SSH32 in a curved shape with a varying radius of curvature. A length of the fifth sub-hole side surface SSH31 may be smaller than a length of the sixth sub-hole side surface SSH32.

The fifth sub-hole side surface SSH31 may be connected to the upper surface US, and the sixth sub-hole side surface SSH32 may be connected to the lower surface BS. An angle between the fifth sub-hole side surface SSH31 and the upper surface US may be a right angle or an obtuse angle close to a right angle.

A curved shape of an upper part SSH32U of the sixth sub-hole side surface SSH32 and a curved shape of a lower part SSH32B of the sixth sub-hole side surface SSH32 may be different from each other. The upper part SSH32U of the sixth sub-hole side surface SSH32 refers to an area disposed above a center SSH32C of the sixth sub-hole side surface SSH32. The lower part SSH32B of the sixth sub-hole side surface SSH32 refers to an area disposed below the center SSH32C of the sixth sub-hole side surface SSH32.

A radius of curvature of the upper part SSH32U of the sixth sub-hole side surface SSH32 and a radius of curvature of the lower part SSH32B of the sixth sub-hole side surface SSH32 may be different from each other. For example, the radius of curvature of the lower part SSH32B of the sixth sub-hole side surface SSH32 may be smaller than the radius of curvature of the upper part SSH32U of the sixth sub-hole side surface SSH32.

The radius of curvature of the upper part SSH32U of the sixth sub-hole side surface SSH32 may be defined as a radius of curvature of a curve passing through the center SSH32C of the sixth sub-hole side surface SSH32, an upper end SSH32UE of the sixth sub-hole side surface SSH32, and an upper center SSH32UC of the sixth sub-hole side surface SSH32. The radius of curvature of the lower part SSH32B of the sixth sub-hole side surface SSH32 may be defined as a radius of curvature of a curve passing through the center SSH32C of the sixth sub-hole side surface SSH32, a lower end SSH32BE of the sixth sub-hole side surface SSH32, and a lower center SSH32BC of the sixth sub-hole side surface SSH32.

In addition, a radius of curvature of a central area of the sixth sub-hole side surface SSH32 may be different from the radius of curvature of the upper part SSH32U of the sixth sub-hole side surface SSH32 and the radius of curvature of the lower part SSH32B of the sixth sub-hole side surface SSH32. The radius of curvature of the central area of the sixth sub-hole side surface SSH32 may be defined as a radius of curvature of a curve passing through the center SSH32C of the sixth sub-hole side surface SSH32, the upper center SSH32UC of the sixth sub-hole side surface SSH32, and the lower center SSH32BC of the sixth sub-hole side surface SSH32.

In addition, a difference between a radius of curvature of an upper central area SSH32UA of the sixth sub-hole side surface SSH32 and a radius of curvature of a lower central area SSH32BA of the sixth sub-hole side surface SSH32 may be smaller than a difference between the radius of curvature of the upper part SSH32U of the sixth sub-hole side surface SSH32 and the radius of curvature of the lower part SSH32B of the sixth sub-hole side surface SSH32. The radius of curvature of the upper central area SSH32UA of the sixth sub-hole side surface SSH32 and the radius of curvature of the lower central area SSH32BA of the sixth sub-hole side surface SSH32 may be substantially equal to each other. Alternatively, the difference between the radius of curvature of the upper central area SSH32UA of the sixth sub-hole side surface SSH32 and the radius of curvature of the lower central area SSH32BA of the sixth sub-hole side surface SSH32 may be within 30 μm (e.g., may be about 30 μm or less).

The radius of curvature of the upper central area SSH32UA of the sixth sub-hole side surface SSH32 may be defined as a radius of curvature of a curve passing through the center SSH32C of the sixth sub-hole side surface SSH32, the upper center SSH32UC of the sixth sub-hole side surface SSH32, and a first point PPH32_1 of the sixth sub-hole side surface SSH32. The radius of curvature of the lower central area SSH32BA of the sixth sub-hole side surface SSH32 may be defined as a radius of curvature of a curve passing through the center SSH32C of the sixth sub-hole side surface SSH32, the lower center SSH32BC of the sixth sub-hole side surface SSH32, and a second point PPH32_2 of the sixth sub-hole side surface SSH32. The first point PPH32_1 of the sixth sub-hole side surface SSH32 may be defined as a midpoint between the center SSH32C of the sixth sub-hole side surface SSH32 and the upper center SSH32UC of the sixth sub-hole side surface SSH32. The second point PPH32_2 of the sixth sub-hole side surface SSH32 may be defined as a midpoint between the center SSH32C of the sixth sub-hole side surface SSH32 and the lower center SSH32BC of the sixth sub-hole side surface SSH32.

Referring to FIG. 36D, the fourth hole side surface SSH4 may have a seventh sub-hole side surface SSH41 in a flat or curved shape and an eighth sub-hole side surface SSH42 in a curved shape with a varying radius of curvature. A length of the seventh sub-hole side surface SSH41 may be smaller than a length of the eighth sub-hole side surface SSH42.

The seventh sub-hole side surface SSH41 may be connected to the upper surface US, and the eighth sub-hole side surface SSH42 may be connected to the lower surface BS. An angle between the seventh sub-hole side surface SSH41 and the upper surface US may be a right angle or an obtuse angle close to a right angle.

A curved shape of an upper part SSH42U of the eighth sub-hole side surface SSH42 and a curved shape of a lower part SSH42B of the eighth sub-hole side surface SSH42 may be different from each other. The upper part SSH42U of the eighth sub-hole side surface SSH42 refers to an area disposed above a center SSH42C of the eighth sub-hole side surface SSH42. The lower part SSH42B of the eighth sub-hole side surface SSH42 refers to an area disposed below the center SSH42C of the eighth sub-hole side surface SSH42.

A radius of curvature of the upper part SSH42U of the eighth sub-hole side surface SSH42 and a radius of curvature of the lower part SSH42B of the eighth sub-hole side surface SSH42 may be different from each other. For example, the radius of curvature of the lower part SSH42B of the eighth sub-hole side surface SSH42 may be smaller than the radius of curvature of the upper part SSH42U of the eighth sub-hole side surface SSH42.

The radius of curvature of the upper part SSH42U of the eighth sub-hole side surface SSH42 may be defined as a radius of curvature of a curve passing through the center SSH42C of the eighth sub-hole side surface SSH42, an upper end SSH42UE of the eighth sub-hole side surface SSH42, and an upper center SSH42UC of the eighth sub-hole side surface SSH42. The radius of curvature of the lower part SSH42B of the eighth sub-hole side surface SSH42 may be defined as a radius of curvature of a curve passing through the center SSH42C of the eighth sub-hole side surface SSH42, a lower end SSH42BE of the eighth sub-hole side surface SSH42, and a lower center SSH42BC of the eighth sub-hole side surface SSH42.

In addition, a radius of curvature of a central area of the eighth sub-hole side surface SSH42 may be different from the radius of curvature of the upper part SSH42U of the eighth sub-hole side surface SSH42 and the radius of curvature of the lower part SSH42B of the eighth sub-hole side surface SSH42. The radius of curvature of the central area of the eighth sub-hole side surface SSH42 may be defined as a radius of curvature of a curve passing through the center SSH42C of the eighth sub-hole side surface SSH42, the upper center SSH42UC of the eighth sub-hole side surface SSH42, and the lower center SSH42BC of the eighth sub-hole side surface SSH42.

In addition, a difference between a radius of curvature of an upper central area SSH42UA of the eighth sub-hole side surface SSH42 and a radius of curvature of a lower central area SSH42BA of the eighth sub-hole side surface SSH42 may be smaller than a difference between the radius of curvature of the upper part SSH42U of the eighth sub-hole side surface SSH42 and the radius of curvature of the lower part SSH42B of the eighth sub-hole side surface SSH42. The radius of curvature of the upper central area SSH42UA of the eighth sub-hole side surface SSH42 and the radius of curvature of the lower central area SSH42BA of the eighth sub-hole side surface SSH42 may be substantially equal to each other. Alternatively, the difference between the radius of curvature of the upper central area SSH42UA of the eighth sub-hole side surface SSH42 and the radius of curvature of the lower central area SSH42BA of the eighth sub-hole side surface SSH42 may be within 30 μm (e.g., may be about 30 μm or less).

The radius of curvature of the upper central area SSH42UA of the eighth sub-hole side surface SSH42 may be defined as a radius of curvature of a curve passing through the center SSH42C of the eighth sub-hole side surface SSH42, the upper center SSH42UC of the eighth sub-hole side surface SSH42, and a first point PPH42_1 of the eighth sub-hole side surface SSH42. The radius of curvature of the lower central area SSH42BA of the eighth sub-hole side surface SSH42 may be defined as a radius of curvature of a curve passing through the center SSH42C of the eighth sub-hole side surface SSH42, the lower center SSH42BC of the eighth sub-hole side surface SSH42, and a second point PPH42_2 of the eighth sub-hole side surface SSH42. The first point PPH42_1 of the eighth sub-hole side surface SSH42 may be defined as a midpoint between the center SSH42C of the eighth sub-hole side surface SSH42 and the upper center SSH42UC of the eighth sub-hole side surface SSH42. The second point PPH42_2 of the eighth sub-hole side surface SSH42 may be defined as a midpoint between the center SSH42C of the eighth sub-hole side surface SSH42 and the lower center SSH42BC of the eighth sub-hole side surface SSH42.

Referring to FIGS. 36A through 36D, the length of the first sub-hole side surface SSH11 of the first hole side surface SSH1, the length of the third sub-hole side surface SSH21 of the second hole side surface SSH2, the length of the fifth sub-hole side surface SSH31 of the third hole side surface SSH3, and the length of the seventh sub-hole side surface SSH41 of the fourth hole side surface SSH4 may be similar to each other. For example, the length of the first sub-hole side surface SSH11 of the first hole side surface SSH1, the length of the third sub-hole side surface SSH21 of the second hole side surface SSH2, the length of the fifth sub-hole side SSH31 of the third hole side surface SSH3, and the length of the seventh sub-hole side surface SSH41 of the fourth hole side surface SSH4 may each be greater than 10 μm and less than 30 μm.

For example, a difference between the length of the first sub-hole side surface SSH11 of the first hole side surface SSH1 and the length of the third sub-hole side surface SSH21 of the second hole side surface SSH2 may be less than about 10 μm. A difference between the length of the first sub-hole side surface SSH11 of the first hole side surface SSH1 and the length of the fifth sub-hole side surface SSH31 of the third hole side surface SSH3 may be less than about 10 μm. A difference between the length of the first sub-hole side surface SSH11 of the first hole side surface SSH1 and the length of the seventh sub-hole side surface SSH41 of the fourth hole side surface SSH4 may be less than about 10 μm. A difference between the length of the third sub-hole side surface SSH21 of the second hole side surface SSH2 and the length of the fifth sub-hole side surface SSH31 of the third hole side surface SSH3 may be less than about 10 μm. A difference between the length of the third sub-hole side surface SSH21 of the second hole side surface SSH2 and the length of the seventh sub-hole side surface SSH41 of the fourth hole side surface SSH4 may be less than about 10 μm. A difference between the length of the fifth sub-hole side surface SSH31 of the third hole side surface SSH3 and the length of the seventh sub-hole side surface SSH41 of the fourth hole side surface SSH4 may be less than about 10 μm.

The radius of curvature of the upper part SSH12U of the second sub-hole side surface SSH12 of the first hole side surface SSH1, the radius of curvature of the upper part SSH22U of the fourth sub-hole side surface SSH22 of the second hole side surface SSH2, the radius of curvature of the upper part SSH32U of the sixth sub-hole side surface SSH32 of the third hole side surface SSH3, and the radius of curvature of the upper part SSH42U of the eighth sub-hole side surface SSH42 of the fourth hole side surface SSH4 may be similar to each other. For example, the radius of curvature of the upper part SSH12U of the second sub-hole side surface SSH12 of the first hole side surface SSH1, the radius of curvature of the upper part SSH22U of the fourth sub-hole side surface SSH22 of the second hole side surface SSH2, the radius of curvature of the upper part SSH32U of the sixth sub-hole side surface SSH32 of the third hole side surface SSH3, and the radius of curvature of the upper part SSH42U of the eighth sub-hole side surface SSH42 of the fourth hole side surface SSH4 may be in a range of 150 μm to 350 μm.

A difference between the radius of curvature of the upper part SSH12U of the second sub-hole side surface SSH12 of the first hole side surface SSH1 and the radius of curvature of the upper part SSH22U of the fourth sub-hole side surface SSH22 of the second hole side surface SSH2 may be less than about 30 μm. A difference between the radius of curvature of the upper part SSH12U of the second sub-hole side surface SSH12 of the first hole side surface SSH1 and the radius of curvature of the upper part SSH32U of the sixth sub-hole side surface SSH32 of the third hole side surface SSH3 may be less than about 30 μm. A difference between the radius of curvature of the upper part SSH12U of the second sub-hole side surface SSH12 of the first hole side surface SSH1 and the radius of curvature of the upper part SSH42U of the eighth sub-hole side surface SSH42 of the fourth hole side surface SSH4 may be less than about 30 μm. A difference between the radius of curvature of the upper part SSH22U of the fourth sub-hole side surface SSH22 of the second hole side surface SSH2 and the radius of curvature of the upper part SSH32U of the sixth sub-hole side surface SSH32 of the third hole side surface SSH3 may be less than about 30 μm. A difference between the radius of curvature of the upper part SSH22U of the fourth sub-hole side surface SSH22 of the second hole side surface SSH2 and the radius of curvature of the upper part SSH42U of the eighth sub-hole side surface SSH42 of the fourth hole side surface SSH4 may be less than about 30 μm. A difference between the radius of curvature of the upper part SSH32U of the sixth sub-hole side surface SSH32 of the third hole side surface SSH3 and the radius of curvature of the upper part SSH42U of the eighth sub-hole side surface SSH42 of the fourth hole side surface SSH4 may be less than about 30 μm.

In addition, referring to FIGS. 26A through 26D and 36A through 36D, each of the radius of curvature of the upper part SSH12U of the second sub-hole side surface SSH12 of the first hole side surface SSH1, the radius of curvature of the upper part SSH22U of the fourth sub-hole side surface SSH22 of the second hole side surface SSH2, the radius of curvature of the upper part SSH32U of the sixth sub-hole side surface SSH32 of the third hole side surface SSH3, and the radius of curvature of the upper part SSH42U of the eighth sub-hole side surface SSH42 of the fourth hole side surface SSH4 may be similar to the radius of curvature of the upper part SS12U of the second sub-side surface SS12 of the first side surface SS1, the radius of curvature of the upper part SS22U of the fourth sub-side surface SS22 of the second side surface SS2, the radius of curvature of the upper part SS32U of the sixth sub-side surface SS32 of the third side surface SS3, and the radius of curvature of the upper part SS42U of the eighth sub-side surface SS42 of the fourth side surface SS4. For example, a difference between each of the radius of curvature of the upper part SSH12U of the second sub-hole side surface SSH12 of the first hole side surface SSH1, the radius of curvature of the upper part SSH22U of the fourth sub-hole side surface SSH22 of the second hole side surface SSH2, the radius of curvature of the upper part SSH32U of the sixth sub-hole side surface SSH32 of the third hole side surface SSH3, and the radius of curvature of the upper part SSH42U of the eighth sub-hole side surface SSH42 of the fourth hole side surface SSH4 and any one of the radius of curvature of the upper part SS12U of the second sub-side surface SS12 of the first side surface SS1, the radius of curvature of the upper part SS22U of the fourth sub-side surface SS22 of the second side surface SS2, the radius of curvature of the upper part SS32U of the sixth sub-side surface SS32 of the third side surface SS3, and the radius of curvature of the upper part SS42U of the eighth sub-side surface SS42 of the fourth side surface SS4 may be less than about 30 μm.

As illustrated in FIGS. 36A through 36D, a difference in radius of curvature between the hole side surfaces SSH1 through SSH4 of the substrate SUB of the display panel 100 may be insignificant. Therefore, uniform mechanical strength can be maintained according to the positions of the hole side surfaces SSH1 through SSH4 of the substrate SUB of the display panel 100.

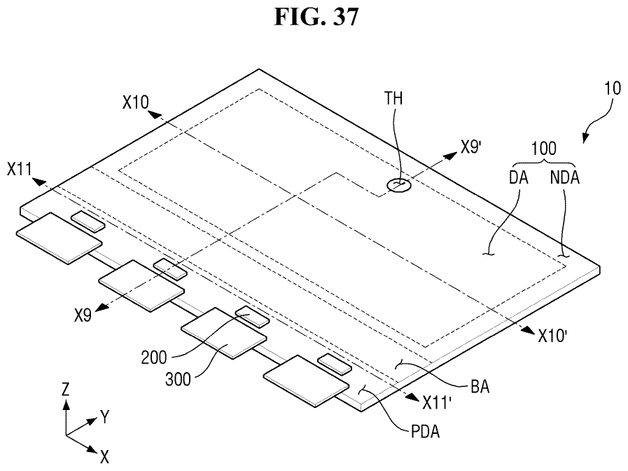

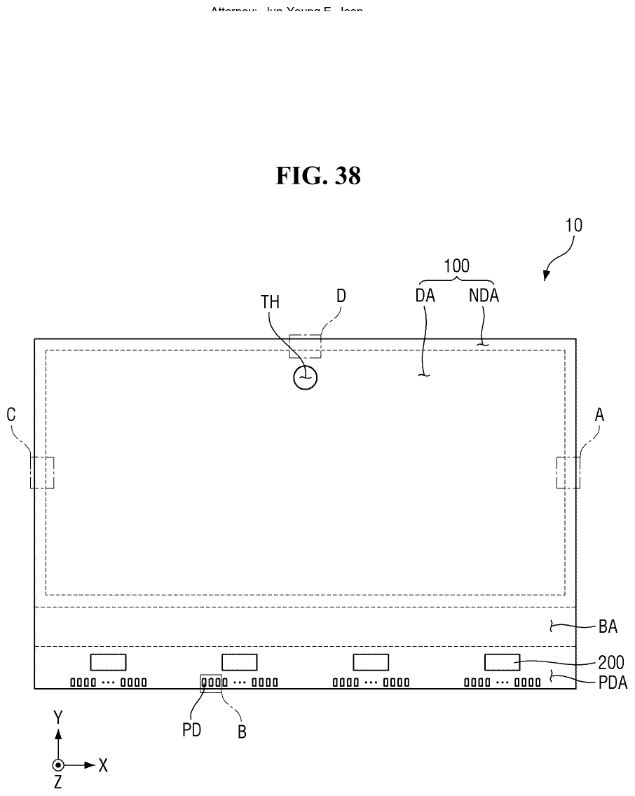

FIG. 37 is a perspective view of a display device 10 according to one or more embodiments of the present disclosure. FIG. 38 is a plan view illustrating a display panel 100 and driving circuits 200 according to one or more embodiments of the present disclosure.

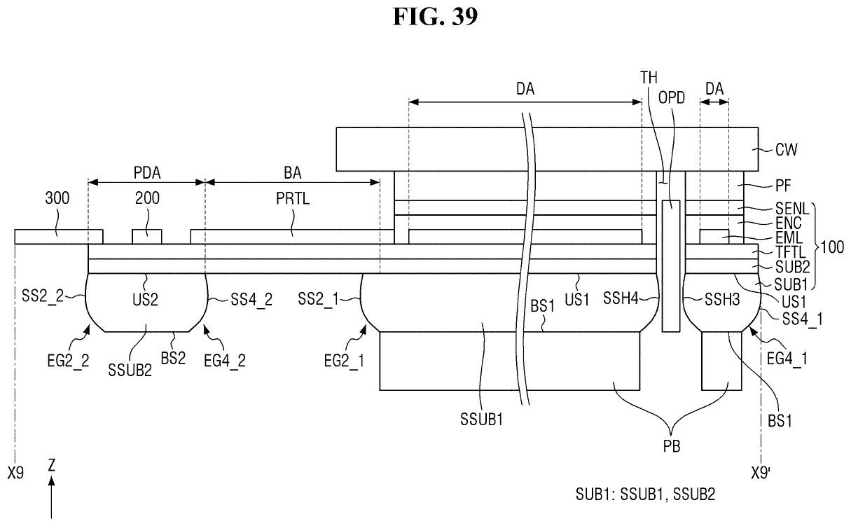

Referring to FIGS. 38 and 39, the display device 10 according to the one or more embodiments may include a bending area BA and a pad area PDA disposed in a non-display area NDA.

The bending area BA may be disposed between a display area DA and the pad area PDA in the second direction (Y-axis direction). The bending area BA may extend in the first direction (X-axis direction). The bending area BA refers to an area that is bent toward the bottom of the display panel 100. When the bending area BA is bent toward the bottom of the display panel 100, a plurality of driving ICs 200 and circuit boards 300 may be disposed under the display panel 100.

The pad area PDA may be a lower edge area of the display panel 100. The pad area PDA may be an area where display pads PD connected to the circuit boards 300 and first and second driving pads DPD1 and DPD2 connected to the driving ICs 200 are disposed.

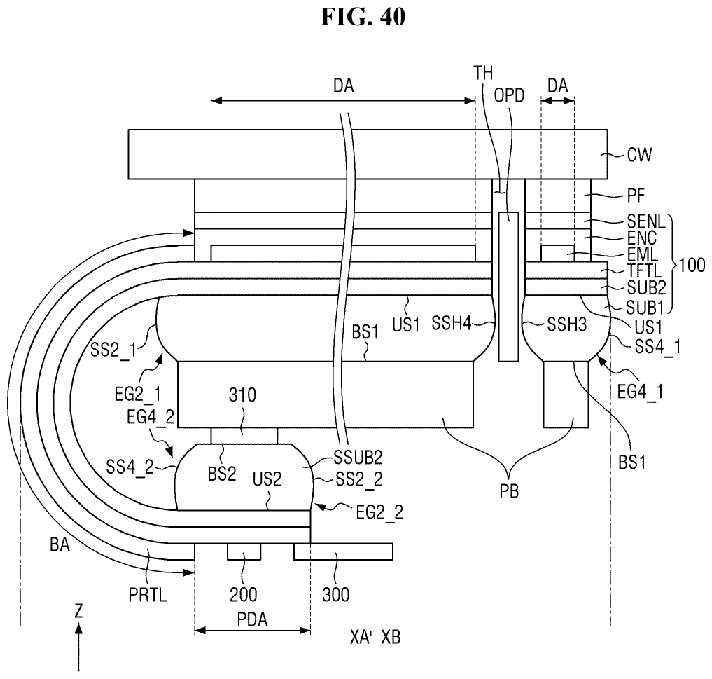

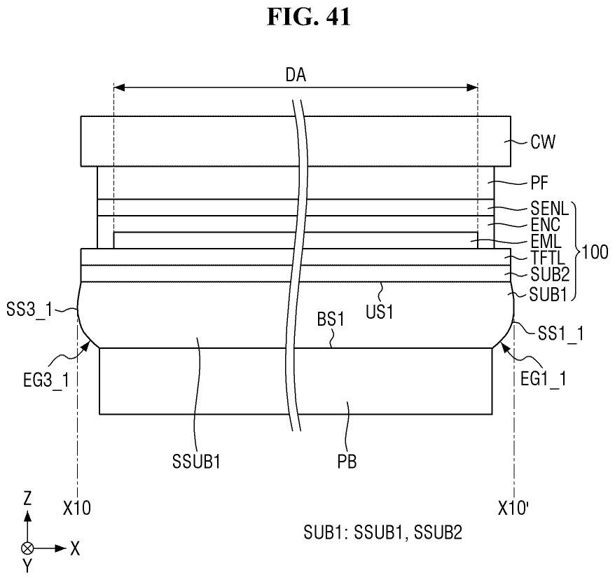

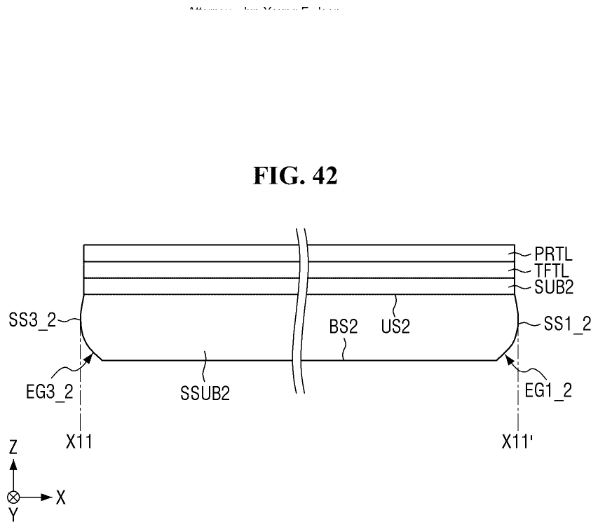

FIG. 39 is a cross-sectional view of an example of the display panel 100 taken along the line X9-X9′ of FIG. 37. FIG. 40 is a cross-sectional view of an example of the display device 10 in which the bending area BA in FIG. 39 is bent. FIG. 41 is a cross-sectional view of an example of the display panel 100 taken along the line X10-X10′ of FIG. 37. FIG. 42 is a cross-sectional view of an example of the display panel 100 taken along the line X11-X11′ of FIG. 37.

Referring to FIGS. 39 through 42, the display panel 100 may include a rigid first substrate SUB1 and a ductile (e.g., flexible) second substrate SUB2 made of polymer resin.

The first substrate SUB1 may be made of ultra-thin glass (UTG) with a thickness of about 500 μm or less, but embodiments of the present disclosure are not limited thereto. The first substrate SUB1 may include a first sub-substrate SSUB1 disposed in the display area DA and a second sub-substrate SSUB2 disposed in the pad area PDA. The area of the first sub-substrate SSUB1 may be larger than the area of the second sub-substrate SSUB2.

The second substrate SUB2 may be made of polymer resin with a thickness smaller than that of the first substrate SUB1. For example, the second substrate SUB2 may be made of an organic material such as acryl resin, epoxy resin, phenolic resin, polyamide resin, and/or polyimide resin. Because the second substrate SUB2 is made of polymer resin, it may be referred to as a plastic substrate. Alternatively, because the second substrate SUB2 is made of an organic material, it may be referred to as an organic layer.

The first substrate SUB1 may not be disposed in the bending area BA. That is, because the bending area BA includes only the second substrate SUB2 having a ductile material (e.g., a flexible material), it can be bent (e.g., bent easily).

A thin-film transistor layer TFTL may be disposed in the display area DA, the bending area BA, and the pad area PDA.

A protective layer PRTL may be disposed on the thin-film transistor layer TFTL in the bending area BA. The protective layer PRTL may be a layer for protecting the thin-film transistor layer TFTL exposed to the outside in the bending area BA. The protective layer PRTL may be made of an organic material such as acryl resin, epoxy resin, phenolic resin, polyamide resin, and/or polyimide resin.

The first sub-substrate SSUB1 includes an upper surface US1, a lower surface BS1, and first through fourth side surfaces SS1_1, SS2_1, SS3_1 and SS4_1.

The second sub-substrate SSUB2 includes an upper surface US2, a lower surface BS2, and first through fourth side surfaces SS1_2, SS2_2, SS3_2 and SS4_2.

The first side surface SS1_1 of the first sub-substrate SSUB1 refers to a side surface disposed at a first side edge EG1_1 of the first sub-substrate SSUB1, and the second side surface SS2_1 of the first sub-substrate SSUB1 refers to a side surface disposed at a second side edge EG2_1 of the first sub-substrate SSUB1. The third side surface SS3_1 of the first sub-substrate SSUB1 refers to a side surface disposed at a third side edge EG3_1 of the first sub-substrate SSUB1, and the fourth side surface SS4_1 of the first sub-substrate SSUB1 refers to a side surface disposed at a fourth side edge EG4_1 of the first sub-substrate SSUB1.

The first side surface SS1_2 of the second sub-substrate SSUB2 refers to a side surface disposed at a first side edge EG1_2 of the second sub-substrate SSUB2, and the second side surface SS2_2 of the second sub-substrate SSUB2 refers to a side surface disposed at a second side edge EG2_2 of the second sub-substrate SSUB2. The third side surface SS3_2 of the second sub-substrate SSUB2 refers to a side surface disposed at a third side edge EG3_2 of the second sub-substrate SSUB2, and the fourth side surface SS4_2 of the second sub-substrate SSUB2 refers to a side surface disposed at a fourth side edge EG4_2 of the second sub-substrate SSUB2.

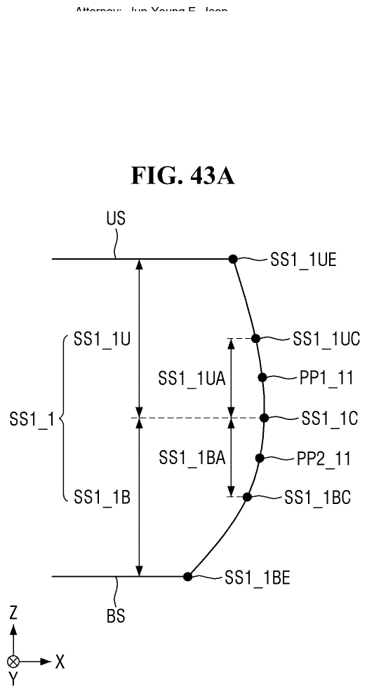

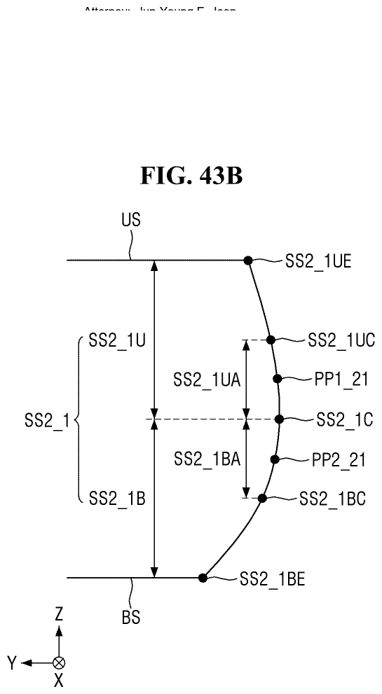

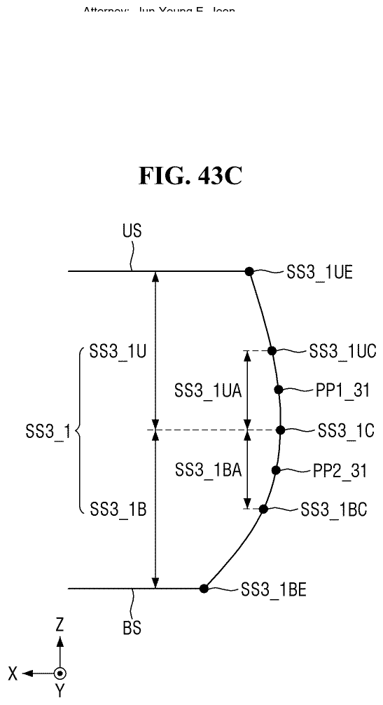

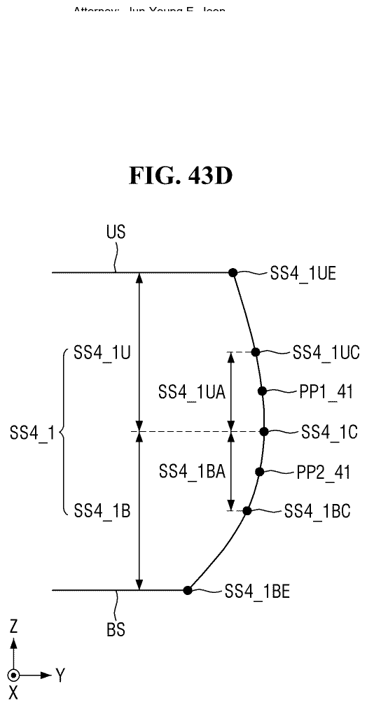

The first through fourth side surfaces SS1_1, SS2_1, SS3_1 and SS4_1 of the first sub-substrate SSUB1 and the first through fourth side surfaces SS1_2, SS2_2, SS3_2 and SS4_2 of the second sub-substrate SSUB2 will now be described in detail with reference to FIGS. 43A through 43D, 44A through 44D, 45A through 45D, and 46A through 46D.

FIGS. 43A through 43D are enlarged cross-sectional views of examples of the first through fourth side surfaces SS1_1, SS2_1, SS3_1 and SS4_1 of the first sub-substrate SSUB1 in FIGS. 39 and 41. FIG. 43A illustrates a cross section of the first side surface SS1_1 of the first sub-substrate SSUB1, FIG. 43B illustrates a cross section of the second side surface SS2_1 of the first sub-substrate SSUB1, FIG. 43C illustrates a cross section of the third side surface SS3_1 of the first sub-substrate SSUB1, and FIG. 43D illustrates a cross section of the fourth side surface SS4_1 of the first sub-substrate SSUB1.

Referring to FIG. 43A, the first side surface SS1_1 of the first sub-substrate SSUB1 may have a curved shape with a varying radius of curvature. A curved shape of an upper part SS1_1U of the first side surface SS1_1 of the first sub-substrate SSUB1 and a curved shape of a lower part SS1_1B may be different from each other. The upper part SS1_1U of the first side surface SS1_1 of the first sub-substrate SSUB1 refers to an area disposed above a center SS1_1C of the first side surface SS1_1 of the first sub-substrate SSUB1. The lower part SS1_1B of the first side surface SS1_1 of the first sub-substrate SSUB1 refers to an area disposed below the center SS1_1C of the first side surface SS1_1 of the first sub-substrate SSUB1.

A radius of curvature of the upper part SS1_1U of the first side surface SS1_1 of the first sub-substrate SSUB1 and a radius of curvature of the lower part SS1_1B of the first side surface SS1_1 of the first sub-substrate SSUB1 may be different from each other. For example, the radius of curvature of the lower part SS1_1B of the first side surface SS1_1 of the first sub-substrate SSUB1 may be smaller than the radius of curvature of the upper part SS1_1U of the first side surface SS1_1 of the first sub-substrate SSUB1.

The radius of curvature of the upper part SS1_1U of the first side surface SS1_1 of the first sub-substrate SSUB1 may be defined as a radius of curvature of a curve passing through the center SS1_1C of the first side surface SS1_1 of the first sub-substrate SSUB1, an upper end SS1_1UE of the first side surface SS1_1 of the first sub-substrate SSUB1, and an upper center SS1_1UC of the first side surface SS1_1 of the first sub-substrate SSUB1. The radius of curvature of the lower part SS1_1B of the first side surface SS1_1 of the first sub-substrate SSUB1 may be defined as a radius of curvature of a curve passing through the center SS1_1C of the first side surface SS1_1 of the first sub-substrate SSUB1, a lower end SS1_1BE of the first side surface SS1_1 of the first sub-substrate SSUB1, and a lower center SS1_1BC of the first side surface SS1_1 of the first sub-substrate SSUB1.

In addition, a radius of curvature of a central area of the first side surface SS1_1 of the first sub-substrate SSUB1 may be different from the radius of curvature of the upper part SS1_1U of the first side surface SS1_1 of the first sub-substrate SSUB1 and the radius of curvature of the lower part SS1_1B of the first side surface SS1_1 of the first sub-substrate SSUB1. The radius of curvature of the central area of the first side surface SS1_1 of the first sub-substrate SSUB1 may be defined as a radius of curvature of a curve passing through the center SS1_1C, the upper center SS1_1UC and the lower center SS1_1BC of the first side surface SS1_1 of the first sub-substrate SSUB1.

In addition, a difference between a radius of curvature of an upper central area SS1_1UA of the first side surface SS1_1 of the first sub-substrate SSUB1 and a radius of curvature of a lower central area SS1_1BA of the first side surface SS1_1 of the first sub-substrate SSUB1 may be smaller than a difference between the radius of curvature of the upper part SS1_1U of the first side surface SS1_1 of the first sub-substrate SSUB1 and the radius of curvature of the lower part SS1_1B of the first side surface SS1_1 of the first sub-substrate SSUB1. The radius of curvature of the upper central area SS1_1UA of the first side surface SS1_1 of the first sub-substrate SSUB1 and the radius of curvature of the lower central area SS1_1BA of the first side surface SS1_1 of the first sub-substrate SSUB1 may be substantially equal to each other. Alternatively, the difference between the radius of curvature of the upper central area SS1_1UA of the first side surface SS1_1 of the first sub-substrate SSUB1 and the radius of curvature of the lower central area SS1_1BA of the first side surface SS1_1 of the first sub-substrate SSUB1 may be within 30 μm (e.g., may be about 30 μm or less).

The radius of curvature of the upper central area SS1_1UA of the first side surface SS1_1 of the first sub-substrate SSUB1 may be defined as a radius of curvature of a curve passing through the center SS1_1C, the upper center SS1_1UC and a first point PP1_11 of the first side surface SS1_1 of the first sub-substrate SSUB1. The radius of curvature of the lower central area SS1_1BA of the first side surface SS1_1 of the first sub-substrate SSUB1 may be defined as a radius of curvature of a curve passing through the center SS1_1C, the lower center SS1_1BC and a second point PP2_11 of the first side surface SS1_1 of the first sub-substrate SSUB1. The first point PP1_11 of the first side surface SS1_1 of the first sub-substrate SSUB1 may be defined as a midpoint between the center SS1_1C and the upper center SS1_1UC of the first side surface SS1_1 of the first sub-substrate SSUB1. The second point PP2_11 of the first side surface SS1_1 of the first sub-substrate SSUB1 may be defined as a midpoint between the center SS1_1C and the lower center SS1_1BC of the first side surface SS1_1 of the first sub-substrate SSUB1.

Referring to FIG. 43B, the second side surface SS2_1 of the first sub-substrate SSUB1 may have a curved shape with a varying radius of curvature. A curved shape of an upper part SS2_1U of the second side surface SS2_1 of the first sub-substrate SSUB1 and a curved shape of a lower part SS2_1B may be different from each other. The upper part SS2_1U of the second side surface SS2_1 of the first sub-substrate SSUB1 refers to an area disposed above a center SS2_1C of the second side surface SS2_1 of the first sub-substrate SSUB1. The lower part SS2_1B of the second side surface SS2_1 of the first sub-substrate SSUB1 refers to an area disposed below the center SS2_1C of the second side surface SS2_1 of the first sub-substrate SSUB1.

A radius of curvature of the upper part SS2_1U of the second side surface SS2_1 of the first sub-substrate SSUB1 and a radius of curvature of the lower part SS2_1B of the second side surface SS2_1 of the first sub-substrate SSUB1 may be different from each other. For example, the radius of curvature of the lower part SS2_1B of the second side surface SS2_1 of the first sub-substrate SSUB1 may be smaller than the radius of curvature of the upper part SS2_1U of the second side surface SS2_1 of the first sub-substrate SSUB1.

The radius of curvature of the upper part SS2_1U of the second side surface SS2_1 of the first sub-substrate SSUB1 may be defined as a radius of curvature of a curve passing through the center SS2_1C of the second side surface SS2_1 of the first sub-substrate SSUB1, an upper end SS2_1UE of the second side surface SS2_1 of the first sub-substrate SSUB1, and an upper center SS2_1UC of the second side surface SS2_1 of the first sub-substrate SSUB1. The radius of curvature of the lower part SS2_1B of the second side surface SS2_1 of the first sub-substrate SSUB1 may be defined as a radius of curvature of a curve passing through the center SS2_1C of the second side surface SS2_1 of the first sub-substrate SSUB1, a lower end SS2_1BE of the second side surface SS2_1 of the first sub-substrate SSUB1, and a lower center SS2_1BC of the second side surface SS2_1 of the first sub-substrate SSUB1.

In addition, a radius of curvature of a central area of the second side surface SS2_1 of the first sub-substrate SSUB1 may be different from the radius of curvature of the upper part SS2_1U of the second side surface SS2_1 of the first sub-substrate SSUB1 and the radius of curvature of the lower part SS2_1B of the second side surface SS2_1 of the first sub-substrate SSUB1. The radius of curvature of the central area of the second side surface SS2_1 of the first sub-substrate SSUB1 may be defined as a radius of curvature of a curve passing through the center SS2_1C, the upper center SS2_1UC and the lower center SS2_1BC of the second side surface SS2_1 of the first sub-substrate SSUB1.

In addition, a difference between a radius of curvature of an upper central area SS2_1UA of the second side surface SS2_1 of the first sub-substrate SSUB1 and a radius of curvature of a lower central area SS2_1BA of the second side surface SS2_1 of the first sub-substrate SSUB1 may be smaller than a difference between the radius of curvature of the upper part SS2_1U of the second side surface SS2_1 of the first sub-substrate SSUB1 and the radius of curvature of the lower part SS2_1B of the second side surface SS2_1 of the first sub-substrate SSUB1. The radius of curvature of the upper central area SS2_1UA of the second side surface SS2_1 of the first sub-substrate SSUB1 and the radius of curvature of the lower central area SS2_1BA of the second side surface SS2_1 of the first sub-substrate SSUB1 may be substantially equal to each other. Alternatively, the difference between the radius of curvature of the upper central area SS2_1UA of the second side surface SS2_1 of the first sub-substrate SSUB1 and the radius of curvature of the lower central area SS2_1BA of the second side surface SS2_1 of the first sub-substrate SSUB1 may be within 30 μm (e.g., may be about 30 μm or less).

The radius of curvature of the upper central area SS2_1UA of the second side surface SS2_1 of the first sub-substrate SSUB1 may be defined as a radius of curvature of a curve passing through the center SS2_1C, the upper center SS2_1UC and a first point PP1_21 of the second side surface SS2_1 of the first sub-substrate SSUB1. The radius of curvature of the lower central area SS2_1BA of the second side surface SS2_1 of the first sub-substrate SSUB1 may be defined as a radius of curvature of a curve passing through the center SS2_1C, the lower center SS2_1BC and a second point PP2_21 of the second side surface SS2_1 of the first sub-substrate SSUB1. The first point PP1_21 of the second side surface SS2_1 of the first sub-substrate SSUB1 may be defined as a midpoint between the center SS2_1C and the upper center SS2_1UC of the second side surface SS2_1 of the first sub-substrate SSUB1. The second point PP2_21 of the second side surface SS2_1 of the first sub-substrate SSUB1 may be defined as a midpoint between the center SS2_1C and the lower center SS2_1BC of the second side surface SS2_1 of the first sub-substrate SSUB1.

Referring to FIG. 43C, the third side surface SS3_1 of the first sub-substrate SSUB1 may have a curved shape with a varying radius of curvature. A curved shape of an upper part SS3_1U of the third side surface SS3_1 of the first sub-substrate SSUB1 and a curved shape of a lower part SS3_1B may be different from each other. The upper part SS3_1U of the third side surface SS3_1 of the first sub-substrate SSUB1 refers to an area disposed above a center SS3_1C of the third side surface SS3_1 of the first sub-substrate SSUB1. The lower part SS3_1B of the third side surface SS3_1 of the first sub-substrate SSUB1 refers to an area disposed below the center SS3_1C of the third side surface SS3_1 of the first sub-substrate SSUB1.

A radius of curvature of the upper part SS3_1U of the third side surface SS3_1 of the first sub-substrate SSUB1 and a radius of curvature of the lower part SS3_1B of the third side surface SS3_1 of the first sub-substrate SSUB1 may be different from each other. For example, the radius of curvature of the lower part SS3_1B of the third side surface SS3_1 of the first sub-substrate SSUB1 may be smaller than the radius of curvature of the upper part SS3_1U of the third side surface SS3_1 of the first sub-substrate SSUB1.

The radius of curvature of the upper part SS3_1U of the third side surface SS3_1 of the first sub-substrate SSUB1 may be defined as a radius of curvature of a curve passing through the center SS3_1C of the third side surface SS3_1 of the first sub-substrate SSUB1, an upper end SS3_1UE of the third side surface SS3_1 of the first sub-substrate SSUB1, and an upper center SS3_1UC of the third side surface SS3_1 of the first sub-substrate SSUB1. The radius of curvature of the lower part SS3_1B of the third side surface SS3_1 of the first sub-substrate SSUB1 may be defined as a radius of curvature of a curve passing through the center SS3_1C of the third side surface SS3_1 of the first sub-substrate SSUB1, a lower end SS3_1BE of the third side surface SS3_1 of the first sub-substrate SSUB1, and a lower center SS3_1BC of the third side surface SS3_1 of the first sub-substrate SSUB1.

In addition, a radius of curvature of a central area of the third side surface SS3_1 of the first sub-substrate SSUB1 may be different from the radius of curvature of the upper part SS3_1U of the third side surface SS3_1 of the first sub-substrate SSUB1 and the radius of curvature of the lower part SS3_1B of the third side surface SS3_1 of the first sub-substrate SSUB1. The radius of curvature of the central area of the third side surface SS3_1 of the first sub-substrate SSUB1 may be defined as a radius of curvature of a curve passing through the center SS3_1C, the upper center SS3_1UC and the lower center SS3_1BC of the third side surface SS3_1 of the first sub-substrate SSUB1.

In addition, a difference between a radius of curvature of an upper central area SS3_1UA of the third side surface SS3_1 of the first sub-substrate SSUB1 and a radius of curvature of a lower central area SS3_1BA of the third side surface SS3_1 of the first sub-substrate SSUB1 may be smaller than a difference between the radius of curvature of the upper part SS3_1U of the third side surface SS3_1 of the first sub-substrate SSUB1 and the radius of curvature of the lower part SS3_1B of the third side surface SS3_1 of the first sub-substrate SSUB1. The radius of curvature of the upper central area SS3_1UA of the third side surface SS3_1 of the first sub-substrate SSUB1 and the radius of curvature of the lower central area SS3_1BA of the third side surface SS3_1 of the first sub-substrate SSUB1 may be substantially equal to each other. Alternatively, the difference between the radius of curvature of the upper central area SS3_1UA of the third side surface SS3_1 of the first sub-substrate SSUB1 and the radius of curvature of the lower central area SS3_1BA of the third side surface SS3_1 of the first sub-substrate SSUB1 may be within 30 μm (e.g., may be about 30 μm or less).

The radius of curvature of the upper central area SS3_1UA of the third side surface SS3_1 of the first sub-substrate SSUB1 may be defined as a radius of curvature of a curve passing through the center SS3_1C, the upper center SS3_1UC and a first point PP1_31 of the third side surface SS3_1 of the first sub-substrate SSUB1. The radius of curvature of the lower central area SS3_1BA of the third side surface SS3_1 of the first sub-substrate SSUB1 may be defined as a radius of curvature of a curve passing through the center SS3_1C, the lower center SS3_1BC and a second point PP2_31 of the third side surface SS3_1 of the first sub-substrate SSUB1. The first point PP1_31 of the third side surface SS3_1 of the first sub-substrate SSUB1 may be defined as a midpoint between the center SS3_1C and the upper center SS3_1UC of the third side surface SS3_1 of the first sub-substrate SSUB1. The second point PP2_31 of the third side surface SS3_1 of the first sub-substrate SSUB1 may be defined as a midpoint between the center SS3_1C and the lower center SS3_1BC of the third side surface SS3_1 of the first sub-substrate SSUB1.

Referring to FIG. 43D, the fourth side surface SS4_1 of the first sub-substrate SSUB1 may have a curved shape with a varying radius of curvature. A curved shape of an upper part SS4_1U of the fourth side surface SS4_1 of the first sub-substrate SSUB1 and a curved shape of a lower part SS4_1B may be different from each other. The upper part SS4_1U of the fourth side surface SS4_1 of the first sub-substrate SSUB1 refers to an area disposed above a center SS4_1C of the fourth side surface SS4_1 of the first sub-substrate SSUB1. The lower part SS4_1B of the fourth side surface SS4_1 of the first sub-substrate SSUB1 refers to an area disposed below the center SS4_1C of the fourth side surface SS4_1 of the first sub-substrate SSUB1.

A radius of curvature of the upper part SS4_1U of the fourth side surface SS4_1 of the first sub-substrate SSUB1 and a radius of curvature of the lower part SS4_1B of the fourth side surface SS4_1 of the first sub-substrate SSUB1 may be different from each other. For example, the radius of curvature of the lower part SS4_1B of the fourth side surface SS4_1 of the first sub-substrate SSUB1 may be smaller than the radius of curvature of the upper part SS4_1U of the fourth side surface SS4_1 of the first sub-substrate SSUB1.

The radius of curvature of the upper part SS4_1U of the fourth side surface SS4_1 of the first sub-substrate SSUB1 may be defined as a radius of curvature of a curve passing through the center SS4_1C of the fourth side surface SS4_1 of the first sub-substrate SSUB1, an upper end SS4_1UE of the fourth side surface SS4_1 of the first sub-substrate SSUB1, and an upper center SS4_1UC of the fourth side surface SS4_1 of the first sub-substrate SSUB1. The radius of curvature of the lower part SS4_1B of the fourth side surface SS4_1 of the first sub-substrate SSUB1 may be defined as a radius of curvature of a curve passing through the center SS4_1C of the fourth side surface SS4_1 of the first sub-substrate SSUB1, a lower end SS4_1BE of the fourth side surface SS4_1 of the first sub-substrate SSUB1, and a lower center SS4_1BC of the fourth side surface SS4_1 of the first sub-substrate SSUB1.

In addition, a radius of curvature of a central area of the fourth side surface SS4_1 of the first sub-substrate SSUB1 may be different from the radius of curvature of the upper part SS4_1U of the fourth side surface SS4_1 of the first sub-substrate SSUB1 and the radius of curvature of the lower part SS4_1B of the fourth side surface SS4_1 of the first sub-substrate SSUB1. The radius of curvature of the central area of the fourth side surface SS4_1 of the first sub-substrate SSUB1 may be defined as a radius of curvature of a curve passing through the center SS4_1C, the upper center SS4_1UC and the lower center SS4_1BC of the fourth side surface SS4_1 of the first sub-substrate SSUB1.

In addition, a difference between a radius of curvature of an upper central area SS4_1UA of the fourth side surface SS4_1 of the first sub-substrate SSUB1 and a radius of curvature of a lower central area SS4_1BA of the fourth side surface SS4_1 of the first sub-substrate SSUB1 may be smaller than a difference between the radius of curvature of the upper part SS4_1U of the fourth side surface SS4_1 of the first sub-substrate SSUB1 and the radius of curvature of the lower part SS4_1B of the fourth side surface SS4_1 of the first sub-substrate SSUB1. The radius of curvature of the upper central area SS4_1UA of the fourth side surface SS4_1 of the first sub-substrate SSUB1 and the radius of curvature of the lower central area SS4_1BA of the fourth side surface SS4_1 of the first sub-substrate SSUB1 may be substantially equal to each other. Alternatively, the difference between the radius of curvature of the upper central area SS4_1UA of the fourth side surface SS4_1 of the first sub-substrate SSUB1 and the radius of curvature of the lower central area SS4_1BA of the fourth side surface SS4_1 of the first sub-substrate SSUB1 may be within 30 μm (e.g., may be about 30 μm or less).

The radius of curvature of the upper central area SS4_1UA of the fourth side surface SS4_1 of the first sub-substrate SSUB1 may be defined as a radius of curvature of a curve passing through the center SS4_1C, the upper center SS4_1UC and a first point PP1_41 of the fourth side surface SS4_1 of the first sub-substrate SSUB1. The radius of curvature of the lower central area SS4_1BA of the fourth side surface SS4_1 of the first sub-substrate SSUB1 may be defined as a radius of curvature of a curve passing through the center SS4_1C, the lower center SS4_1BC and a second point PP2_41 of the fourth side surface SS4_1 of the first sub-substrate SSUB1. The first point PP1_41 of the fourth side surface SS4_1 of the first sub-substrate SSUB1 may be defined as a midpoint between the center SS4_1C and the upper center SS4_1UC of the fourth side surface SS4_1 of the first sub-substrate SSUB1. The second point PP2_41 of the fourth side surface SS4_1 of the first sub-substrate SSUB1 may be defined as a midpoint between the center SS4_1C and the lower center SS4_1BC of the fourth side surface SS4_1 of the first sub-substrate SSUB1.

Referring to FIGS. 43A through 43D, the radius of curvature of the upper part SS1_1U of the first side surface SS1_1 of the first sub-substrate SSUB1, the radius of curvature of the upper part SS2_1U of the second side surface SS2_1, the radius of curvature of the upper part SS3_1U of the third side surface SS3_1, and the radius of curvature of the upper part SS4_1U of the fourth side surface SS4_1 may be similar to each other. For example, the radius of curvature of the upper part SS1_1U of the first side surface SS1_1 of the first sub-substrate SSUB1, the radius of curvature of the upper part SS2_1U of the second side surface SS2_1, the radius of curvature of the upper part SS3_1U of the third side surface SS3_1, and the radius of curvature of the upper part SS4_1U of the fourth side surface SS4_1 may be in a range of 150 μm to 350 μm.

A difference between the radius of curvature of the upper part SS1_1U of the first side surface SS1_1 of the first sub-substrate SSUB1 and the radius of curvature of the upper part SS2_1U of the second side surface SS2_1 may be less than about 30 μm. A difference between the radius of curvature of the upper part SS1_1U of the first side surface SS1_1 of the first sub-substrate SSUB1 and the radius of curvature of the upper part SS3_1U of the third side surface SS3_1 may be less than about 30 μm. A difference between the radius of curvature of the upper part SS1_1U of the first side surface SS1_1 of the first sub-substrate SSUB1 and the radius of curvature of the upper part SS4_1U of the fourth side surface SS4_1 may be less than about 30 μm. A difference between the radius of curvature of the upper part SS2_1U of the second side surface SS2_1 of the first sub-substrate SSUB1 and the radius of curvature of the upper part SS3_1U of the third side surface SS3_1 may be less than about 30 μm. A difference between the radius of curvature of the upper part SS2_1U of the second side surface SS2_1 of the first sub-substrate SSUB1 and the radius of curvature of the upper part SS4_1U of the fourth side surface SS4_1 may be less than about 30 μm. A difference between the radius of curvature of the upper part SS3_1U of the third side surface SS3_1 of the first sub-substrate SSUB1 and the radius of curvature of the upper part SS4_1U of the fourth side surface SS4_1 may be less than about 30 μm.

In addition, referring to FIGS. 25A through 25D and 43A through 43D, each of the radius of curvature of the upper part SS1_1U of the first side surface SS1_1 of the first sub-substrate SSUB1, the radius of curvature of the upper part SS2_1U of the second side surface SS2_1, the radius of curvature of the upper part SS3_1U of the third side surface SS3_1, and the radius of curvature of the upper part SS4_1U of the fourth side surface SS4_1 may be similar to the radius of curvature of the upper part SS1U of the first side surface SS1, the radius of curvature of the upper part SS2U of the second side surface SS2, the radius of curvature of the upper part SS3U of the third side surface SS3, and the radius of curvature of the upper part SS4U of the fourth side surface SS4. For example, a difference between each of the radius of curvature of the upper part SS1_1U of the first side surface SS1_1 of the first sub-substrate SSUB1, the radius of curvature of the upper part SS2_1U of the second side surface SS2_1, the radius of curvature of the upper part SS3_1U of the third side surface SS3_1, and the radius of curvature of the upper part SS4_1U of the fourth side surface SS4_1 and any one of the radius of curvature of the upper part SS1U of the first side surface SS1, the radius of curvature of the upper part SS2U of the second side surface SS2, the radius of curvature of the upper part SS3U of the third side surface SS3, and the radius of curvature of the upper part SS4U of the fourth side surface SS4 may be less than about 30 μm.

In addition, referring to FIGS. 35A through 35D and 43A through 43D, each of the radius of curvature of the upper part SS1_1U of the first side surface SS1_1 of the first sub-substrate SSUB1, the radius of curvature of the upper part SS2_1U of the second side surface SS2_1, the radius of curvature of the upper part SS3_1U of the third side surface SS3_1, and the radius of curvature of the upper part SS4_1U of the fourth side surface SS4_1 may be similar to the radius of curvature of the upper part SSH1U of the first hole side surface SSH1, the radius of curvature of the upper part SSH2U of the second hole side surface SSH2, the radius of curvature of the upper part SSH3U of the third hole side surface SSH3, and the radius of curvature of the upper part SSH4U of the fourth hole side surface SSH4. For example, a difference between each of the radius of curvature of the upper part SS1_1U of the first side surface SS1_1 of the first sub-substrate SSUB1, the radius of curvature of the upper part SS2_1U of the second side surface SS2_1, the radius of curvature of the upper part SS3_1U of the third side surface SS3_1, and the radius of curvature of the upper part SS4_1U of the fourth side surface SS4_1 and any one of the radius of curvature of the upper part SSH1U of the first hole side surface SSH1, the radius of curvature of the upper part SSH2U of the second hole side surface SSH2, the radius of curvature of the upper part SSH3U of the third hole side surface SSH3, and the radius of curvature of the upper part SSH4U of the fourth hole side surface SSH4 may be less than about 30 μm.

As illustrated in FIGS. 43A through 43D, a difference in radius of curvature between the side surfaces SS1_1, SS2_1, SS3_1 and SS4_1 of the first sub-substrate SSUB1 of the display panel 100 may be insignificant. Therefore, uniform mechanical strength can be maintained according to the positions of the side surfaces SS1_1, SS2_1, SS3_1 and SS4_1 of the first sub-substrate SSUB1 of the display panel 100.

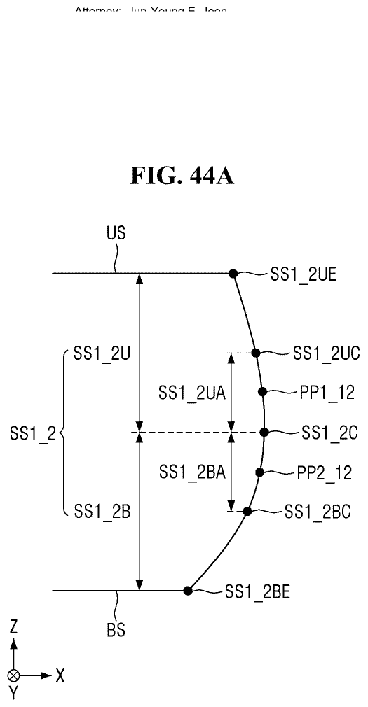

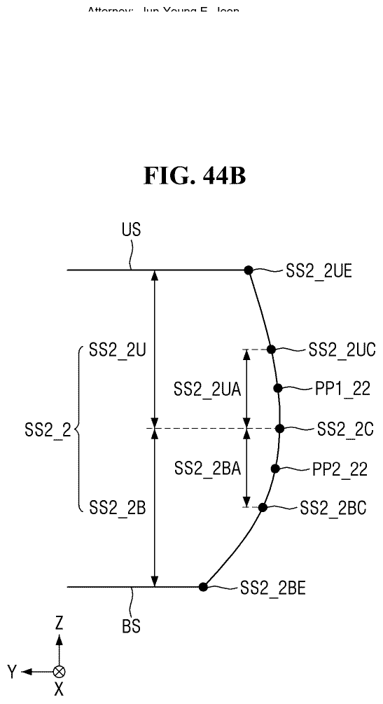

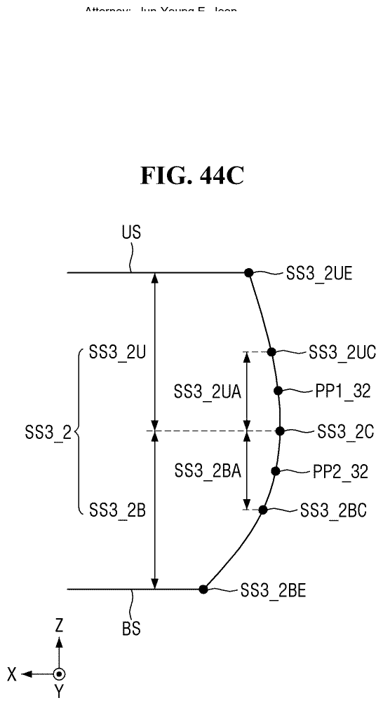

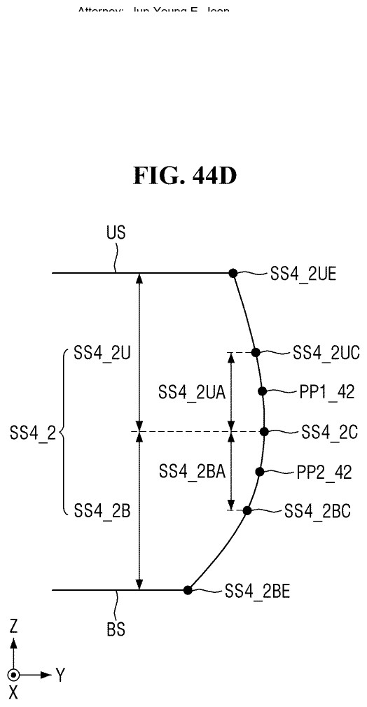

FIGS. 44A through 44D are enlarged cross-sectional views of examples of the first through fourth side surfaces SS1_2, SS2_2, SS3_2 and SS4_2 of the second sub-substrate SSUB2 in FIGS. 39 and 42. FIG. 44A illustrates a cross section of the first side surface SS1_2 of the second sub-substrate SSUB2, FIG. 44B illustrates a cross section of the second side surface SS2_2 of the second sub-substrate SSUB2, FIG. 44C illustrates a cross section of the third side surface SS3_2 of the second sub-substrate SSUB2, and FIG. 44D illustrates a cross section of the fourth side surface SS4_2 of the second sub-substrate SSUB2.

Referring to FIG. 44A, the first side surface SS1_2 of the second sub-substrate SSUB2 may have a curved shape with a varying radius of curvature. A curved shape of an upper part SS1_2U of the first side surface SS1_2 of the second sub-substrate SSUB2 and a curved shape of a lower part SS1_2B may be different from each other. The upper part SS1_2U of the first side surface SS1_2 of the second sub-substrate SSUB2 refers to an area disposed above a center SS1_2C of the first side surface SS1_2 of the second sub-substrate SSUB2. The lower part SS1_2B of the first side surface SS1_2 of the second sub-substrate SSUB2 refers to an area disposed below the center SS1_2C of the first side surface SS1_2 of the second sub-substrate SSUB2.

A radius of curvature of the upper part SS1_2U of the first side surface SS1_2 of the second sub-substrate SSUB2 and a radius of curvature of the lower part SS1_2B of the first side surface SS1_2 of the second sub-substrate SSUB2 may be different from each other. For example, the radius of curvature of the lower part SS1_2B of the first side surface SS1_2 of the second sub-substrate SSUB2 may be smaller than the radius of curvature of the upper part SS1_2U of the first side surface SS1_2 of the second sub-substrate SSUB2.

The radius of curvature of the upper part SS1_2U of the first side surface SS1_2 of the second sub-substrate SSUB2 may be defined as a radius of curvature of a curve passing through the center SS1_2C of the first side surface SS1_2 of the second sub-substrate SSUB2, an upper end SS1_2UE of the first side surface SS1_2 of the second sub-substrate SSUB2, and an upper center SS1_2UC of the first side surface SS1_2 of the second sub-substrate SSUB2. The radius of curvature of the lower part SS1_2B of the first side surface SS1_2 of the second sub-substrate SSUB2 may be defined as a radius of curvature of a curve passing through the center SS1_2C of the first side surface SS1_2 of the second sub-substrate SSUB2, a lower end SS1_2BE of the first side surface SS1_2 of the second sub-substrate SSUB2, and a lower center SS1_2BC of the first side surface SS1_2 of the second sub-substrate SSUB2.

In addition, a radius of curvature of a central area of the first side surface SS1_2 of the second sub-substrate SSUB2 may be different from the radius of curvature of the upper part SS1_2U of the first side surface SS1_2 of the second sub-substrate SSUB2 and the radius of curvature of the lower part SS1_2B of the first side surface SS1_2 of the second sub-substrate SSUB2. The radius of curvature of the central area of the first side surface SS1_2 of the second sub-substrate SSUB2 may be defined as a radius of curvature of a curve passing through the center SS1_2C, the upper center SS1_2UC and the lower center SS1_2BC of the first side surface SS1_2 of the second sub-substrate SSUB2.

In addition, a difference between a radius of curvature of an upper central area SS1_2UA of the first side surface SS1_2 of the second sub-substrate SSUB2 and a radius of curvature of a lower central area SS1_2BA of the first side surface SS1_2 of the second sub-substrate SSUB2 may be smaller than a difference between the radius of curvature of the upper part SS1_2U of the first side surface SS1_2 of the second sub-substrate SSUB2 and the radius of curvature of the lower part SS1_2B of the first side surface SS1_2 of the second sub-substrate SSUB2. The radius of curvature of the upper central area SS1_2UA of the first side surface SS1_2 of the second sub-substrate SSUB2 and the radius of curvature of the lower central area SS1_2BA of the first side surface SS1_2 of the second sub-substrate SSUB2 may be substantially equal to each other. Alternatively, the difference between the radius of curvature of the upper central area SS1_2UA of the first side surface SS1_2 of the second sub-substrate SSUB2 and the radius of curvature of the lower central area SS1_2BA of the first side surface SS1_2 of the second sub-substrate SSUB2 may be within 30 μm (e.g., may be about 30 μm or less).

The radius of curvature of the upper central area SS1_2UA of the first side surface SS1_2 of the second sub-substrate SSUB2 may be defined as a radius of curvature of a curve passing through the center SS1_2C, the upper center SS1_2UC and a first point PP1_12 of the first side surface SS1_2 of the second sub-substrate SSUB2. The radius of curvature of the lower central area SS1_2BA of the first side surface SS1_2 of the second sub-substrate SSUB2 may be defined as a radius of curvature of a curve passing through the center SS1_2C, the lower center SS1_2BC and a second point PP2_12 of the first side surface SS1_2 of the second sub-substrate SSUB2. The first point PP1_12 of the first side surface SS1_2 of the second sub-substrate SSUB2 may be defined as a midpoint between the center SS1_2C and the upper center SS1_2UC of the first side surface SS1_2 of the second sub-substrate SSUB2. The second point PP2_12 of the first side surface SS1_2 of the second sub-substrate SSUB2 may be defined as a midpoint between the center SS1_2C and the lower center SS1_2BC of the first side surface SS1_2 of the second sub-substrate SSUB2.

Referring to FIG. 44B, the second side surface SS2_2 of the second sub-substrate SSUB2 may have a curved shape with a varying radius of curvature. A curved shape of an upper part SS2_2U of the second side surface SS2_2 of the second sub-substrate SSUB2 and a curved shape of a lower part SS2_2B may be different from each other. The upper part SS2_2U of the second side surface SS2_2 of the second sub-substrate SSUB2 refers to an area disposed above a center SS2_2C of the second side surface SS2_2 of the second sub-substrate SSUB2. The lower part SS2_2B of the second side surface SS2_2 of the second sub-substrate SSUB2 refers to an area disposed below the center SS2_2C of the second side surface SS2_2 of the second sub-substrate SSUB2.

A radius of curvature of the upper part SS2_2U of the second side surface SS2_2 of the second sub-substrate SSUB2 and a radius of curvature of the lower part SS2_2B of the second side surface SS2_2 of the second sub-substrate SSUB2 may be different from each other. For example, the radius of curvature of the lower part SS2_2B of the second side surface SS2_2 of the second sub-substrate SSUB2 may be smaller than the radius of curvature of the upper part SS2_2U of the second side surface SS2_2 of the second sub-substrate SSUB2.

The radius of curvature of the upper part SS2_2U of the second side surface SS2_2 of the second sub-substrate SSUB2 may be defined as a radius of curvature of a curve passing through the center SS2_2C of the second side surface SS2_2 of the second sub-substrate SSUB2, an upper end SS2_2UE of the second side surface SS2_2 of the second sub-substrate SSUB2, and an upper center SS2_2UC of the second side surface SS2_2 of the second sub-substrate SSUB2. The radius of curvature of the lower part SS2_2B of the second side surface SS2_2 of the second sub-substrate SSUB2 may be defined as a radius of curvature of a curve passing through the center SS2_2C of the second side surface SS2_2 of the second sub-substrate SSUB2, a lower end SS2_2BE of the second side surface SS2_2 of the second sub-substrate SSUB2, and a lower center SS2_2BC of the second side surface SS2_2 of the second sub-substrate SSUB2.

In addition, a radius of curvature of a central area of the second side surface SS2_2 of the second sub-substrate SSUB2 may be different from the radius of curvature of the upper part SS2_2U of the second side surface SS2_2 of the second sub-substrate SSUB2 and the radius of curvature of the lower part SS2_2B of the second side surface SS2_2 of the second sub-substrate SSUB2. The radius of curvature of the central area of the second side surface SS2_2 of the second sub-substrate SSUB2 may be defined as a radius of curvature of a curve passing through the center SS2_2C, the upper center SS2_2UC and the lower center SS2_2BC of the second side surface SS2_2 of the second sub-substrate SSUB2.

In addition, a difference between a radius of curvature of an upper central area SS2_2UA of the second side surface SS2_2 of the second sub-substrate SSUB2 and a radius of curvature of a lower central area SS2_2BA of the second side surface SS2_2 of the second sub-substrate SSUB2 may be smaller than a difference between the radius of curvature of the upper part SS2_2U of the second side surface SS2_2 of the second sub-substrate SSUB2 and the radius of curvature of the lower part SS2_2B of the second side surface SS2_2 of the second sub-substrate SSUB2. The radius of curvature of the upper central area SS2_2UA of the second side surface SS2_2 of the second sub-substrate SSUB2 and the radius of curvature of the lower central area SS2_2BA of the second side surface SS2_2 of the second sub-substrate SSUB2 may be substantially equal to each other. Alternatively, the difference between the radius of curvature of the upper central area SS2_2UA of the second side surface SS2_2 of the second sub-substrate SSUB2 and the radius of curvature of the lower central area SS2_2BA of the second side surface SS2_2 of the second sub-substrate SSUB2 may be within 30 μm (e.g., may be about 30 μm or less).

The radius of curvature of the upper central area SS2_2UA of the second side surface SS2_2 of the second sub-substrate SSUB2 may be defined as a radius of curvature of a curve passing through the center SS2_2C, the upper center SS2_2UC and a first point PP1_22 of the second side surface SS2_2 of the second sub-substrate SSUB2. The radius of curvature of the lower central area SS2_2BA of the second side surface SS2_2 of the second sub-substrate SSUB2 may be defined as a radius of curvature of a curve passing through the center SS2_2C, the lower center SS2_2BC and a second point PP2_22 of the second side surface SS2_2 of the second sub-substrate SSUB2. The first point PP1_22 of the second side surface SS2_2 of the second sub-substrate SSUB2 may be defined as a midpoint between the center SS2_2C and the upper center SS2_2UC of the second side surface SS2_2 of the second sub-substrate SSUB2. The second point PP2_22 of the second side surface SS2_2 of the second sub-substrate SSUB2 may be defined as a midpoint between the center SS2_2C and the lower center SS2_2BC of the second side surface SS2_2 of the second sub-substrate SSUB2.

Referring to FIG. 44C, the third side surface SS3_2 of the second sub-substrate SSUB2 may have a curved shape with a varying radius of curvature. A curved shape of an upper part SS3_2U of the third side surface SS3_2 of the second sub-substrate SSUB2 and a curved shape of a lower part SS3_2B may be different from each other. The upper part SS3_2U of the third side surface SS3_2 of the second sub-substrate SSUB2 refers to an area disposed above a center SS3_2C of the third side surface SS3_2 of the second sub-substrate SSUB2. The lower part SS3_2B of the third side surface SS3_2 of the second sub-substrate SSUB2 refers to an area disposed below the center SS3_2C of the third side surface SS3_2 of the second sub-substrate SSUB2.

A radius of curvature of the upper part SS3_2U of the third side surface SS3_2 of the second sub-substrate SSUB2 and a radius of curvature of the lower part SS3_2B of the third side surface SS3_2 of the second sub-substrate SSUB2 may be different from each other. For example, the radius of curvature of the lower part SS3_2B of the third side surface SS3_2 of the second sub-substrate SSUB2 may be smaller than the radius of curvature of the upper part SS3_2U of the third side surface SS3_2 of the second sub-substrate SSUB2.

The radius of curvature of the upper part SS3_2U of the third side surface SS3_2 of the second sub-substrate SSUB2 may be defined as a radius of curvature of a curve passing through the center SS3_2C of the third side surface SS3_2 of the second sub-substrate SSUB2, an upper end SS3_2UE of the third side surface SS3_2 of the second sub-substrate SSUB2, and an upper center SS3_2UC of the third side surface SS3_2 of the second sub-substrate SSUB2. The radius of curvature of the lower part SS3_2B of the third side surface SS3_2 of the second sub-substrate SSUB2 may be defined as a radius of curvature of a curve passing through the center SS3_2C of the third side surface SS3_2 of the second sub-substrate SSUB2, a lower end SS3_2BE of the third side surface SS3_2 of the second sub-substrate SSUB2, and a lower center SS3_2BC of the third side surface SS3_2 of the second sub-substrate SSUB2.

In addition, a radius of curvature of a central area of the third side surface SS3_2 of the second sub-substrate SSUB2 may be different from the radius of curvature of the upper part SS3_2U of the third side surface SS3_2 of the second sub-substrate SSUB2 and the radius of curvature of the lower part SS3_2B of the third side surface SS3_2 of the second sub-substrate SSUB2. The radius of curvature of the central area of the third side surface SS3_2 of the second sub-substrate SSUB2 may be defined as a radius of curvature of a curve passing through the center SS3_2C, the upper center SS3_2UC and the lower center SS3_2BC of the third side surface SS3_2 of the second sub-substrate SSUB2.

In addition, a difference between a radius of curvature of an upper central area SS3_2UA of the third side surface SS3_2 of the second sub-substrate SSUB2 and a radius of curvature of a lower central area SS3_2BA of the third side surface SS3_2 of the second sub-substrate SSUB2 may be smaller than a difference between the radius of curvature of the upper part SS3_2U of the third side surface SS3_2 of the second sub-substrate SSUB2 and the radius of curvature of the lower part SS3_2B of the third side surface SS3_2 of the second sub-substrate SSUB2. The radius of curvature of the upper central area SS3_2UA of the third side surface SS3_2 of the second sub-substrate SSUB2 and the radius of curvature of the lower central area SS3_2BA of the third side surface SS3_2 of the second sub-substrate SSUB2 may be substantially equal to each other. Alternatively, the difference between the radius of curvature of the upper central area SS3_2UA of the third side surface SS3_2 of the second sub-substrate SSUB2 and the radius of curvature of the lower central area SS3_2BA of the third side surface SS3_2 of the second sub-substrate SSUB2 may be within 30 μm (e.g., may be about 30 μm or less).

The radius of curvature of the upper central area SS3_2UA of the third side surface SS3_2 of the second sub-substrate SSUB2 may be defined as a radius of curvature of a curve passing through the center SS3_2C, the upper center SS3_2UC and a first point PP1_32 of the third side surface SS3_2 of the second sub-substrate SSUB2. The radius of curvature of the lower central area SS3_2BA of the third side surface SS3_2 of the second sub-substrate SSUB2 may be defined as a radius of curvature of a curve passing through the center SS3_2C, the lower center SS3_2BC and a second point PP2_32 of the third side surface SS3_2 of the second sub-substrate SSUB2. The first point PP1_32 of the third side surface SS3_2 of the second sub-substrate SSUB2 may be defined as a midpoint between the center SS3_2C and the upper center SS3_2UC of the third side surface SS3_2 of the second sub-substrate SSUB2. The second point PP2_32 of the third side surface SS3_2 of the second sub-substrate SSUB2 may be defined as a midpoint between the center SS3_2C and the lower center SS3_2BC of the third side surface SS3_2 of the second sub-substrate SSUB2.

Referring to FIG. 44D, the fourth side surface SS4_2 of the second sub-substrate SSUB2 may have a curved shape with a varying radius of curvature. A curved shape of an upper part SS4_2U of the fourth side surface SS4_2 of the second sub-substrate SSUB2 and a curved shape of a lower part SS4_2B may be different from each other. The upper part SS4_2U of the fourth side surface SS4_2 of the second sub-substrate SSUB2 refers to an area disposed above a center SS4_2C of the fourth side surface SS4_2 of the second sub-substrate SSUB2. The lower part SS4_2B of the fourth side surface SS4_2 of the second sub-substrate SSUB2 refers to an area disposed below the center SS4_2C of the fourth side surface SS4_2 of the second sub-substrate SSUB2.

A radius of curvature of the upper part SS4_2U of the fourth side surface SS4_2 of the second sub-substrate SSUB2 and a radius of curvature of the lower part SS4_2B of the fourth side surface SS4_2 of the second sub-substrate SSUB2 may be different from each other. For example, the radius of curvature of the lower part SS4_2B of the fourth side surface SS4_2 of the second sub-substrate SSUB2 may be smaller than the radius of curvature of the upper part SS4_2U of the fourth side surface SS4_2 of the second sub-substrate SSUB2.

The radius of curvature of the upper part SS4_2U of the fourth side surface SS4_2 of the second sub-substrate SSUB2 may be defined as a radius of curvature of a curve passing through the center SS4_2C of the fourth side surface SS4_2 of the second sub-substrate SSUB2, an upper end SS4_2UE of the fourth side surface SS4_2 of the second sub-substrate SSUB2, and an upper center SS4_2UC of the fourth side surface SS4_2 of the second sub-substrate SSUB2. The radius of curvature of the lower part SS4_2B of the fourth side surface SS4_2 of the second sub-substrate SSUB2 may be defined as a radius of curvature of a curve passing through the center SS4_2C of the fourth side surface SS4_2 of the second sub-substrate SSUB2, a lower end SS4_2BE of the fourth side surface SS4_2 of the second sub-substrate SSUB2, and a lower center SS4_2BC of the fourth side surface SS4_2 of the second sub-substrate SSUB2.

In addition, a radius of curvature of a central area of the fourth side surface SS4_2 of the second sub-substrate SSUB2 may be different from the radius of curvature of the upper part SS4_2U of the fourth side surface SS4_2 of the second sub-substrate SSUB2 and the radius of curvature of the lower part SS4_2B of the fourth side surface SS4_2 of the second sub-substrate SSUB2. The radius of curvature of the central area of the fourth side surface SS4_2 of the second sub-substrate SSUB2 may be defined as a radius of curvature of a curve passing through the center SS4_2C, the upper center SS4_2UC and the lower center SS4_2BC of the fourth side surface SS4_2 of the second sub-substrate SSUB2.

In addition, a difference between a radius of curvature of an upper central area SS4_2UA of the fourth side surface SS4_2 of the second sub-substrate SSUB2 and a radius of curvature of a lower central area SS4_2BA of the fourth side surface SS4_2 of the second sub-substrate SSUB2 may be smaller than a difference between the radius of curvature of the upper part SS4_2U of the fourth side surface SS4_2 of the second sub-substrate SSUB2 and the radius of curvature of the lower part SS4_2B of the fourth side surface SS4_2 of the second sub-substrate SSUB2. The radius of curvature of the upper central area SS4_2UA of the fourth side surface SS4_2 of the second sub-substrate SSUB2 and the radius of curvature of the lower central area SS4_2BA of the fourth side surface SS4_2 of the second sub-substrate SSUB2 may be substantially equal to each other. Alternatively, the difference between the radius of curvature of the upper central area SS4_2UA of the fourth side surface SS4_2 of the second sub-substrate SSUB2 and the radius of curvature of the lower central area SS4_2BA of the fourth side surface SS4_2 of the second sub-substrate SSUB2 may be within 30 μm (e.g., may be about 30 μm or less).

The radius of curvature of the upper central area SS4_2UA of the fourth side surface SS4_2 of the second sub-substrate SSUB2 may be defined as a radius of curvature of a curve passing through the center SS4_2C, the upper center SS4_2UC and a first point PP1_42 of the fourth side surface SS4_2 of the second sub-substrate SSUB2. The radius of curvature of the lower central area SS4_2BA of the fourth side surface SS4_2 of the second sub-substrate SSUB2 may be defined as a radius of curvature of a curve passing through the center SS4_2C, the lower center SS4_2BC and a second point PP2_42 of the fourth side surface SS4_2 of the second sub-substrate SSUB2. The first point PP1_42 of the fourth side surface SS4_2 of the second sub-substrate SSUB2 may be defined as a midpoint between the center SS4_2C and the upper center SS4_2UC of the fourth side surface SS4_2 of the second sub-substrate SSUB2. The second point PP2_42 of the fourth side surface SS4_2 of the second sub-substrate SSUB2 may be defined as a midpoint between the center SS4_2C and the lower center SS4_2BC of the fourth side surface SS4_2 of the second sub-substrate SSUB2.

Referring to FIGS. 44A through 44D, the radius of curvature of the upper part SS1_2U of the first side surface SS1_2 of the second sub-substrate SSUB2, the radius of curvature of the upper part SS2_2U of the second side surface SS2_2, the radius of curvature of the upper part SS3_2U of the third side surface SS3_2 and the radius of curvature of the upper part SS4_2U of the fourth side surface SS4_2 may be similar to each other. For example, the radius of curvature of the upper part SS1_2U of the first side surface SS1_2 of the second sub-substrate SSUB2, the radius of curvature of the upper part SS2_2U of the second side surface SS2_2, the radius of curvature of the upper part SS3_2U of the third side surface SS3_2 and the radius of curvature of the upper part SS4_2U of the fourth side surface SS4_2 may be in a range of 150 μm to 350 μm.

A difference between the radius of curvature of the upper part SS1_2U of the first side surface SS1_2 of the second sub-substrate SSUB2 and the radius of curvature of the upper part SS2_2U of the second side surface SS2_2 may be less than about 30 μm. A difference between the radius of curvature of the upper part SS1_2U of the first side surface SS1_2 of the second sub-substrate SSUB2 and the radius of curvature of the upper part SS3_2U of the third side surface SS3_2 may be less than about 30 μm. A difference between the radius of curvature of the upper part SS1_2U of the first side surface SS1_2 of the second sub-substrate SSUB2 and the radius of curvature of the upper part SS4_2U of the fourth side surface SS4_2 may be less than about 30 μm. A difference between the radius of curvature of the upper part SS2_2U of the second side surface SS2_2 of the second sub-substrate SSUB2 and the radius of curvature of the upper part SS3_2U of the third side surface SS3_2 may be less than about 30 μm. A difference between the radius of curvature of the upper part SS2_2U of the second side surface SS2_2 of the second sub-substrate SSUB2 and the radius of curvature of the upper part SS4_2U of the fourth side surface SS4_2 may be less than about 30 μm. A difference between the radius of curvature of the upper part SS3_2U of the third side surface SS3_2 of the second sub-substrate SSUB2 and the radius of curvature of the upper part SS4_2U of the fourth side surface SS4_2 may be less than about 30 μm.

In addition, referring to FIGS. 25A through 25D and 44A through 44D, each of the radius of curvature of the upper part SS1_2U of the first side surface SS1_2 of the second sub-substrate SSUB2, the radius of curvature of the upper part SS2_2U of the second side surface SS2_2, the radius of curvature of the upper part SS3_2U of the third side surface SS3_2, and the radius of curvature of the upper part SS4_2U of the fourth side surface SS4_2 may be similar to the radius of curvature of the upper part SS1U of the first side surface SS1, the radius of curvature of the upper part SS2U of the second side surface SS2, the radius of curvature of the upper part SS3U of the third side surface SS3, and the radius of curvature of the upper part SS4U of the fourth side surface SS4. For example, a difference between each of the radius of curvature of the upper part SS1_2U of the first side surface SS1_2 of the second sub-substrate SSUB2, the radius of curvature of the upper part SS2_2U of the second side surface SS2_2, the radius of curvature of the upper part SS3_2U of the third side surface SS3_2, and the radius of curvature of the upper part SS4_2U of the fourth side surface SS4_2 and any one of the radius of curvature of the upper part SS1U of the first side surface SS1, the radius of curvature of the upper part SS2U of the second side surface SS2, the radius of curvature of the upper part SS3U of the third side surface SS3, and the radius of curvature of the upper part SS4U of the fourth side surface SS4 may be less than about 30 μm.

In addition, referring to FIGS. 35A through 35D and 44A through 44D, each of the radius of curvature of the upper part SS1_2U of the first side surface SS1_2 of the second sub-substrate SSUB2, the radius of curvature of the upper part SS2_2U of the second side surface SS2_2, the radius of curvature of the upper part SS3_2U of the third side surface SS3_2, and the radius of curvature of the upper part SS4_2U of the fourth side surface SS4_2 may be similar to the radius of curvature of the upper part SSH1U of the first hole side surface SSH1, the radius of curvature of the upper part SSH2U of the second hole side surface SSH2, the radius of curvature of the upper part SSH3U of the third hole side surface SSH3, and the radius of curvature of the upper part SSH4U of the fourth hole side surface SSH4. For example, a difference between each of the radius of curvature of the upper part SS1_2U of the first side surface SS1_2 of the second sub-substrate SSUB2, the radius of curvature of the upper part SS2_2U of the second side surface SS2_2, the radius of curvature of the upper part SS3_2U of the third side surface SS3_2, and the radius of curvature of the upper part SS4_2U of the fourth side surface SS4_2 and any one of the radius of curvature of the upper part SSH1U of the first hole side surface SSH1, the radius of curvature of the upper part SSH2U of the second hole side surface SSH2, the radius of curvature of the upper part SSH3U of the third hole side surface SSH3, and the radius of curvature of the upper part SSH4U of the fourth hole side surface SSH4 may be less than about 30 μm.

In addition, referring to FIGS. 43A through 43D and 44A through 44D, each of the radius of curvature of the upper part SS1_2U of the first side surface SS1_2 of the second sub-substrate SSUB2, the radius of curvature of the upper part SS2_2U of the second side surface SS2_2, the radius of curvature of the upper part SS3_2U of the third side surface SS3_2, and the radius of curvature of the upper part SS4_2U of the fourth side surface SS4_2 may be similar to the radius of curvature of the upper part SS1_1U of the first side surface SS1_1 of the first sub-substrate SSUB1, the radius of curvature of the upper part SS2_1U of the second side surface SS2_1, the radius of curvature of the upper part SS3_1U of the third side surface SS3_1, and the radius of curvature of the upper part SS4_1U of the fourth side surface SS4_1. For example, a difference between each of the radius of curvature of the upper part SS1_2U of the first side surface SS1_2 of the second sub-substrate SSUB2, the radius of curvature of the upper part SS2_2U of the second side surface SS2_2, the radius of curvature of the upper part SS3_2U of the third side surface SS3_2, and the radius of curvature of the upper part SS4_2U of the fourth side surface SS4_2 and any one of the radius of curvature of the upper part SS1_1U of the first side surface SS1_1, the radius of curvature of the upper part SS2_1U of the second side surface SS2_1, the radius of curvature of the upper part SS3_1U of the third side surface SS3_1, and the radius of curvature of the upper part SS4_1U of the fourth side surface SS4_1 may be less than about 30 μm.

As illustrated in FIGS. 44A through 44D, a difference in radius of curvature between the side surfaces SS1_2, SS2_2, SS3_2 and SS4_2 of the second sub-substrate SSUB2 of the display panel 100 may be insignificant. Therefore, uniform mechanical strength can be maintained according to the positions of the side surfaces SS1_2, SS2_2, SS3_2 and SS4_2 of the second sub-substrate SSUB2 of the display panel 100.

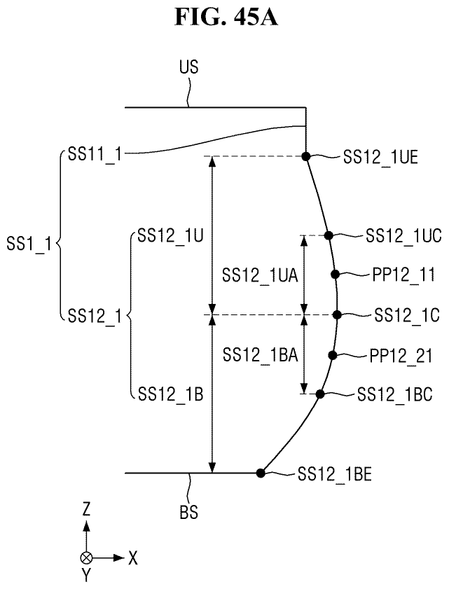

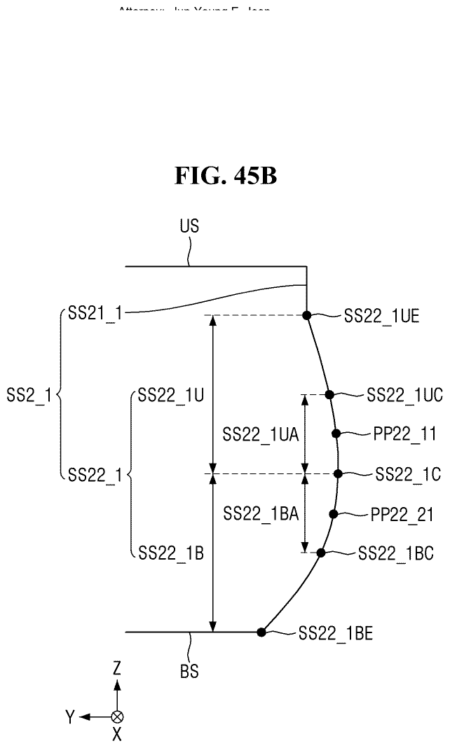

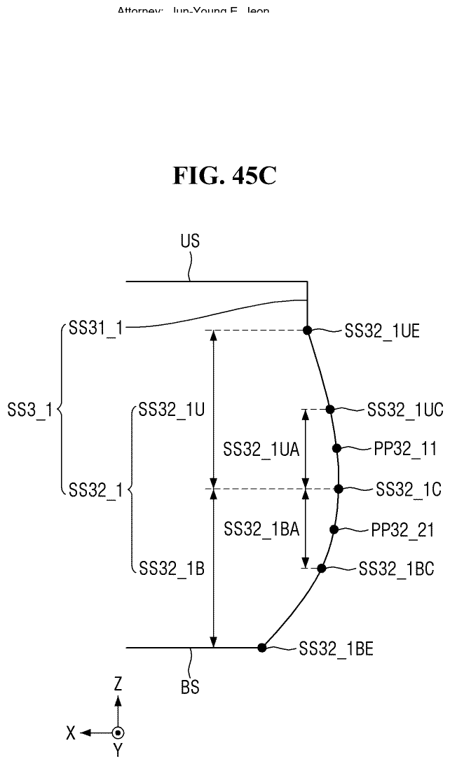

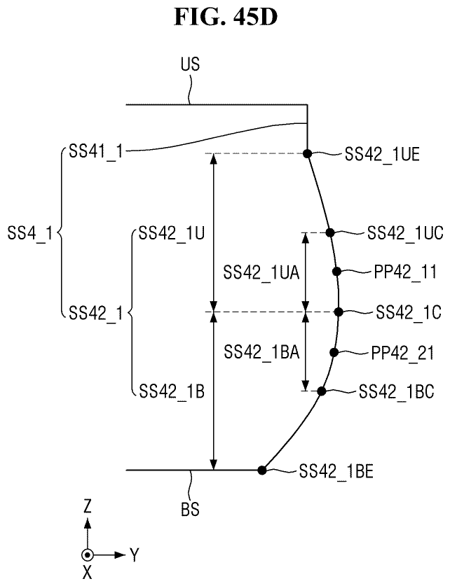

FIGS. 45A through 45D are enlarged cross-sectional views of examples of the first through fourth side surfaces SS1_1, SS2_1, SS3_1 and SS4_1 of the first sub-substrate SSUB1 in FIGS. 39 and 41. FIG. 45A illustrates a cross section of the first side surface SS1_1 of the first sub-substrate SSUB1, FIG. 45B illustrates a cross-section of the second side surface SS2_1 of the first sub-substrate SSUB1, FIG. 45C illustrates a cross section of the third side surface SS3_1 of the first sub-substrate SSUB1, and FIG. 45D illustrates a cross-section of the fourth side surface SS4_1 of the first sub-substrate SSUB1.

Referring to FIG. 45A, the first side surface SS1_1 of the first sub-substrate SSUB1 may have a first sub-side surface SS11_1 in a flat or curved shape and a second sub-side surface SS12_1 in a curved shape with a varying radius of curvature. A length of the first sub-side surface SS11_1 of the first sub-substrate SSUB1 may be smaller than a length of the second sub-side surface SS12_1.

The first sub-side surface SS11_1 of the first sub-substrate SSUB1 may be connected to the upper surface US, and the second sub-side surface SS12_1 of the first sub-substrate SSUB1 may be connected to the lower surface BS. An angle between the first sub-side surface SS11_1 and the upper surface US of the first sub-substrate SSUB1 may be a right angle or an obtuse angle close to a right angle.

A curved shape of an upper part SS12_1U of the second sub-side surface SS12_1 of the first sub-substrate SSUB1 and a curved shape of a lower part SS12_1B of the second sub-side surface SS12_1 may be different from each other. The upper part SS12_1U of the second sub-side surface SS12_1 of the first sub-substrate SSUB1 refers to an area disposed above a center SS12_1C of the second sub-side surface SS12_1. The lower part SS12_1B of the second sub-side surface SS12_1 of the first sub-substrate SSUB1 refers to an area disposed below the center SS12_1C of the second sub-side surface SS12_1.

A radius of curvature of the upper part SS12_1U of the second sub-side surface SS12_1 of the first sub-substrate SSUB1 and a radius of curvature of the lower part SS12_1B of the second sub-side surface SS12_1 may be different from each other. For example, the radius of curvature of the lower part SS12_1B of the second sub-side surface SS12_1 of the first sub-substrate SSUB1 may be smaller than the radius of curvature of the upper part SS12_1U of the second sub-side surface SS12_1.

The radius of curvature of the upper part SS12_1U of the second sub-side surface SS12_1 of the first sub-substrate SSUB1 may be defined as a radius of curvature of a curve passing through the center SS12_1C of the second sub-side surface SS12_1, an upper end SS12_1UE of the second sub-side surface SS12_1, and an upper center SS12_1UC of the second sub-side surface SS12_1. The radius of curvature of the lower part SS12_1B of the second sub-side surface SS12_1 of the first sub-substrate SSUB1 may be defined as a radius of curvature of a curve passing through the center SS12_1C of the second sub-side surface SS12_1, a lower end SS12_1BE of the second sub-side surface SS12_1, and a lower center SS12_1BC of the second sub-side surface SS12_1.

In addition, a radius of curvature of a central area of the second sub-side surface SS12_1 of the first sub-substrate SSUB1 may be different from the radius of curvature of the upper part SS12_1U of the second sub-side surface SS12_1 of the first sub-substrate SSUB1 and the radius of curvature of the lower part SS12_1B of the second sub-side surface SS12_1. The radius of curvature of the central area of the second sub-side surface SS12_1 of the first sub-substrate SSUB1 may be defined as a radius of curvature of a curve passing through the center SS12_1C, the upper center SS12_1UC and the lower center SS12_1BC of the second sub-side surface SS12_1 of the first sub-substrate SSUB1.

In addition, a difference between a radius of curvature of an upper central area SS12_1UA of the second sub-side surface SS12_1 of the first sub-substrate SSUB1 and a radius of curvature of a lower central area SS12_1BA of the second sub-side surface SS12_1 may be smaller than a difference between the radius of curvature of the upper part SS12_1U of the second sub-side surface SS12_1 of the first sub-substrate SSUB1 and the radius of curvature of the lower part SS12_1B of the second sub-side surface SS12_1. The radius of curvature of the upper central area SS12_1UA of the second sub-side surface SS12_1 of the first sub-substrate SSUB1 and the radius of curvature of the lower central area SS12_1BA of the second sub-side surface SS12_1 may be substantially equal to each other. Alternatively, the difference between the radius of curvature of the upper central area SS12_1UA of the second sub-side surface SS12_1 of the first sub-substrate SSUB1 and the radius of curvature of the lower central area SS12_1BA of the second sub-side surface SS12_1 may be within 30 μm (e.g., may be about 30 μm or less).

The radius of curvature of the upper central area SS12_1UA of the second sub-side surface SS12_1 of the first sub-substrate SSUB1 may be defined as a radius of curvature of a curve passing through the center SS12_1C, the upper center SS12_1UC and a first point PP12_11 of the second sub-side surface SS12_1 of the first sub-substrate SSUB1. The radius of curvature of the lower central area SS12_1BA of the second sub-side surface SS12_1 of the first sub-substrate SSUB1 may be defined as a radius of curvature of a curve passing through the center SS12_1C, the lower center SS12_1BC and a second point PP12_21 of the second sub-side surface SS12_1 of the first sub-substrate SSUB1. The first point PP12_11 of the second sub-side surface SS12_1 of the first sub-substrate SSUB1 may be defined as a midpoint between the center SS12_1C and the upper center SS12_1UC of the second sub-side surface SS12_1 of the first sub-substrate SSUB1. The second point PP12_21 of the second sub-side surface SS12_1 of the first sub-substrate SSUB1 may be defined as a midpoint between the center SS12_1C and the lower center SS12_1BC of the second sub-side surface SS12_1 of the first sub-substrate SSUB1.

Referring to FIG. 45B, the second side surface SS2_1 of the first sub-substrate SSUB1 may have a third sub-side surface SS21_1 in a flat or curved shape and a fourth sub-side surface SS22_1 in a curved shape with a varying radius of curvature. A length of the third sub-side surface SS21_1 of the first sub-substrate SSUB1 may be smaller than a length of the fourth sub-side surface SS22_1.

The third sub-side surface SS21_1 of the first sub-substrate SSUB1 may be connected to the upper surface US, and the fourth sub-side surface SS22_1 may be connected to the lower surface BS. An angle between the third sub-side surface SS21_1 and the upper surface US of the first sub-substrate SSUB1 may be a right angle or an obtuse angle close to a right angle.

A curved shape of an upper part SS22_1U of the fourth sub-side surface SS22_1 of the first sub-substrate SSUB1 and a curved shape of a lower part SS22_1B of the fourth sub-side surface SS22_1 may be different from each other. The upper part SS22_1U of the fourth sub-side surface SS22_1 of the first sub-substrate SSUB1 refers to an area disposed above a center SS22_1C of the fourth sub-side surface SS22_1. The lower part SS22_1B of the fourth sub-side surface SS22_1 of the first sub-substrate SSUB1 refers to an area disposed below the center SS22_1C of the fourth sub-side surface SS22_1.

A radius of curvature of the upper part SS22_1U of the fourth sub-side surface SS22_1 of the first sub-substrate SSUB1 and a radius of curvature of the lower part SS22_1B of the fourth sub-side surface SS22_1 may be different from each other. For example, the radius of curvature of the lower part SS22_1B of the fourth sub-side surface SS22_1 of the first sub-substrate SSUB1 may be smaller than the radius of curvature of the upper part SS22_1U of the fourth sub-side surface SS22_1.

The radius of curvature of the upper part SS22_1U of the fourth sub-side surface SS22_1 of the first sub-substrate SSUB1 may be defined as a radius of curvature of a curve passing through the center SS22_1C of the fourth sub-side surface SS22_1, an upper end SS22_1UE of the fourth sub-side surface SS22_1, and an upper center SS22_1UC of the fourth sub-side surface SS22_1. The radius of curvature of the lower part SS22_1B of the fourth sub-side surface SS22_1 of the first sub-substrate SSUB1 may be defined as a radius of curvature of a curve passing through the center SS22_1C of the fourth sub-side surface SS22_1, a lower end SS22_1BE of the fourth sub-side surface SS22_1, and a lower center SS22_1BC of the fourth sub-side surface SS22_1.

In addition, a radius of curvature of a central area of the fourth sub-side surface SS22_1 of the first sub-substrate SSUB1 may be different from the radius of curvature of the upper part SS22_1U of the fourth sub-side surface SS22_1 of the first sub-substrate SSUB1 and the radius of curvature of the lower part SS22_1B of the fourth sub-side surface SS22_1. The radius of curvature of the central area of the fourth sub-side surface SS22_1 of the first sub-substrate SSUB1 may be defined as a radius of curvature of a curve passing through the center SS22_1C, the upper center SS22_1UC and the lower center SS22_1BC of the fourth sub-side surface SS22_1 of the first sub-substrate SSUB1.

In addition, a difference between a radius of curvature of an upper central area SS22_1UA of the fourth sub-side surface SS22_1 of the first sub-substrate SSUB1 and a radius of curvature of a lower central area SS22_1BA of the fourth sub-side surface SS22_1 may be smaller than a difference between the radius of curvature of the upper part SS22_1U of the fourth sub-side surface SS22_1 of the first sub-substrate SSUB1 and the radius of curvature of the lower part SS22_1B of the fourth sub-side surface SS22_1. The radius of curvature of the upper central area SS22_1UA of the fourth sub-side surface SS22_1 of the first sub-substrate SSUB1 and the radius of curvature of the lower central area SS22_1BA of the fourth sub-side surface SS22_1 may be substantially equal to each other. Alternatively, the difference between the radius of curvature of the upper central area SS22_1UA of the fourth sub-side surface SS22_1 of the first sub-substrate SSUB1 and the radius of curvature of the lower central area SS22_1BA of the fourth sub-side surface SS22_1 may be within 30 μm (e.g., may be about 30 μm or less).

The radius of curvature of the upper central area SS22_1UA of the fourth sub-side surface SS22_1 of the first sub-substrate SSUB1 may be defined as a radius of curvature of a curve passing through the center SS22_1C, the upper center SS22_1UC and a first point PP22_11 of the fourth sub-side surface SS22_1 of the first sub-substrate SSUB1. The radius of curvature of the lower central area SS22_1BA of the fourth sub-side surface SS22_1 of the first sub-substrate SSUB1 may be defined as a radius of curvature of a curve passing through the center SS22_1C, the lower center SS22_1BC and a second point PP22_21 of the fourth sub-side surface SS22_1 of the first sub-substrate SSUB1. The first point PP22_11 of the fourth sub-side surface SS22_1 of the first sub-substrate SSUB1 may be defined as a midpoint between the center SS22_1C and the upper center SS22_1UC of the fourth sub-side surface SS22_1 of the first sub-substrate SSUB1. The second point PP22_21 of the fourth sub-side surface SS22_1 of the first sub-substrate SSUB1 may be defined as a midpoint between the center SS22_1C and the lower center SS22_1BC of the fourth sub-side surface SS22_1 of the first sub-substrate SSUB1.

Referring to FIG. 45C, the third side surface SS3_1 of the first sub-substrate SSUB1 may have a fifth sub-side surface SS31_1 in a flat or curved shape and a sixth sub-side surface SS32_1 in a curved shape with a varying radius of curvature. A length of the fifth sub-side surface SS31_1 may be smaller than a length of the sixth sub-side surface SS32_1.

The fifth sub-side surface SS31_1 of the first sub-substrate SSUB1 may be connected to the upper surface US, and the sixth sub-side surface SS32_1 may be connected to the lower surface BS. An angle between the fifth sub-side surface SS31_1 and the upper surface US of the first sub-substrate SSUB1 may be a right angle or an obtuse angle close to a right angle.

A curved shape of an upper part SS32_1U of the sixth sub-side surface SS32_1 of the first sub-substrate SSUB1 and a curved shape of a lower part SS32_1B of the sixth sub-side surface SS32_1 may be different from each other. The upper part SS32_1U of the sixth sub-side surface SS32_1 of the first sub-substrate SSUB1 refers to an area disposed above a center SS32_1C of the sixth sub-side surface SS32_1. The lower part SS32_1B of the sixth sub-side surface SS32_1 of the first sub-substrate SSUB1 refers to an area disposed below the center SS32_1C of the sixth sub-side surface SS32_1.

A radius of curvature of the upper part SS32_1U of the sixth sub-side surface SS32_1 of the first sub-substrate SSUB1 and a radius of curvature of the lower part SS32_1B of the sixth sub-side surface SS32_1 may be different from each other. For example, the radius of curvature of the lower part SS32_1B of the sixth sub-side surface SS32_1 of the first sub-substrate SSUB1 may be smaller than the radius of curvature of the upper part SS32_1U of the sixth sub-side surface SS32_1.

The radius of curvature of the upper part SS32_1U of the sixth sub-side surface SS32_1 of the first sub-substrate SSUB1 may be defined as a radius of curvature of a curve passing through the center SS32_1C of the sixth sub-side surface SS32_1, an upper end SS32_1UE of the sixth sub-side surface SS32_1, and an upper center SS32_1UC of the sixth sub-side surface SS32_1. The radius of curvature of the lower part SS32_1B of the sixth sub-side surface SS32_1 of the first sub-substrate SSUB1 may be defined as a radius of curvature of a curve passing through the center SS32_1C of the sixth sub-side surface SS32_1, a lower end SS32_1BE of the sixth sub-side surface SS32_1, and a lower center SS32_1BC of the sixth sub-side surface SS32_1.

In addition, a radius of curvature of a central area of the sixth sub-side surface SS32_1 of the first sub-substrate SSUB1 may be different from the radius of curvature of the upper part SS32_1U of the sixth sub-side surface SS32_1 of the first sub-substrate SSUB1 and the radius of curvature of the lower part SS32_1B of the sixth sub-side surface SS32_1. The radius of curvature of the central area of the sixth sub-side surface SS32_1 of the first sub-substrate SSUB1 may be defined as a radius of curvature of a curve passing through the center SS32_1C, the upper center SS32_1UC and the lower center SS32_1BC of the sixth sub-side surface SS32_1 of the first sub-substrate SSUB1.

In addition, a difference between a radius of curvature of an upper central area SS32_1UA of the sixth sub-side surface SS32_1 of the first sub-substrate SSUB1 and a radius of curvature of a lower central area SS32_1BA of the sixth sub-side surface SS32_1 may be smaller than a difference between the radius of curvature of the upper part SS32_1U of the sixth sub-side surface SS32_1 of the first sub-substrate SSUB1 and the radius of curvature of the lower part SS32_1B of the sixth sub-side surface SS32_1. The radius of curvature of the upper central area SS32_1UA of the sixth sub-side surface SS32_1 of the first sub-substrate SSUB1 and the radius of curvature of the lower central area SS32_1BA of the sixth sub-side surface SS32_1 may be substantially equal to each other. Alternatively, the difference between the radius of curvature of the upper central area SS32_1UA of the sixth sub-side surface SS32_1 of the first sub-substrate SSUB1 and the radius of curvature of the lower central area SS32_1BA of the sixth sub-side surface SS32_1 may be within 30 μm (e.g., may be about 30 μm or less).

The radius of curvature of the upper central area SS32_1UA of the sixth sub-side surface SS32_1 of the first sub-substrate SSUB1 may be defined as a radius of curvature of a curve passing through the center SS32_1C, the upper center SS32_1UC and a first point PP32_11 of the sixth sub-side surface SS32_1 of the first sub-substrate SSUB1. The radius of curvature of the lower central area SS32_1BA of the sixth sub-side surface SS32_1 of the first sub-substrate SSUB1 may be defined as a radius of curvature of a curve passing through the center SS32_1C, the lower center SS32_1BC and a second point PP32_21 of the sixth sub-side surface SS32_1 of the first sub-substrate SSUB1. The first point PP32_11 of the sixth sub-side surface SS32_1 of the first sub-substrate SSUB1 may be defined as a midpoint between the center SS32_1C and the upper center SS32_1UC of the sixth sub-side surface SS32_1 of the first sub-substrate SSUB1. The second point PP32_21 of the sixth sub-side surface SS32_1 of the first sub-substrate SSUB1 may be defined as a midpoint between the center SS32_1C and the lower center SS32_1BC of the sixth sub-side surface SS32_1 of the first sub-substrate SSUB1.

Referring to FIG. 45D, the fourth side surface SS4_1 of the first sub-substrate SSUB1 may have a seventh sub-side surface SS41_1 in a flat or curved shape and an eighth sub-side surface SS42_1 in a curved shape with a varying radius of curvature. A length of the seventh sub-side surface SS41_1 of the first sub-substrate SSUB1 may be smaller than a length of the eighth sub-side surface SS42_1.

The seventh sub-side surface SS41_1 of the first sub-substrate SSUB1 may be connected to the upper surface US, and the eighth sub-side surface SS42_1 may be connected to the lower surface BS. An angle between the seventh sub-side surface SS41_1 and the upper surface US of the first sub-substrate SSUB1 may be a right angle or an obtuse angle close to a right angle.

A curved shape of an upper part SS42_1U of the eighth sub-side surface SS42_1 of the first sub-substrate SSUB1 and a curved shape of a lower part SS42_1B of the eighth sub-side surface SS42_1 may be different from each other. The upper part SS42_1U of the eighth sub-side surface SS42_1 of the first sub-substrate SSUB1 refers to an area disposed above a center SS42_1C of the eighth sub-side surface SS42_1. The lower part SS42_1B of the eighth sub-side surface SS42_1 of the first sub-substrate SSUB1 refers to an area disposed below the center SS42_1C of the eighth sub-side surface SS42_1.

A radius of curvature of the upper part SS42_1U of the eighth sub-side surface SS42_1 of the first sub-substrate SSUB1 and a radius of curvature of the lower part SS42_1B of the eighth sub-side surface SS42_1 may be different from each other. For example, the radius of curvature of the lower part SS42_1B of the eighth sub-side surface SS42_1 of the first sub-substrate SSUB1 may be smaller than the radius of curvature of the upper part SS42_1U of the eighth sub-side surface SS42_1.

The radius of curvature of the upper part SS42_1U of the eighth sub-side surface SS42_1 of the first sub-substrate SSUB1 may be defined as a radius of curvature of a curve passing through the center SS42_1C of the eighth sub-side surface SS42_1, an upper end SS42_1UE of the eighth sub-side surface SS42_1, and an upper center SS42_1UC of the eighth sub-side surface SS42_1. The radius of curvature of the lower part SS42_1B of the eighth sub-side surface SS42_1 may be defined as a radius of curvature of a curve passing through the center SS42_1C of the eighth sub-side surface SS42_1, a lower end SS42_1BE of the eighth sub-side surface SS42_1, and a lower center SS42_1BC of the eighth sub-side surface SS42_1.

In addition, a radius of curvature of a central area of the eighth sub-side surface SS42_1 of the first sub-substrate SSUB1 may be different from the radius of curvature of the upper part SS42_1U of the eighth sub-side surface SS42_1 of the first sub-substrate SSUB1 and the radius of curvature of the lower part SS42_1B of the eighth sub-side surface SS42_1. The radius of curvature of the central area of the eighth sub-side surface SS42_1 of the first sub-substrate SSUB1 may be defined as a radius of curvature of a curve passing through the center SS42_1C, the upper center SS42_1UC and the lower center SS42_1BC of the eighth sub-side surface SS42_1 of the first sub-substrate SSUB1.

In addition, a difference between a radius of curvature of an upper central area SS42_1UA of the eighth sub-side surface SS42_1 of the first sub-substrate SSUB1 and a radius of curvature of a lower central area SS42_1BA of the eighth sub-side surface SS42_1 may be smaller than a difference between the radius of curvature of the upper part SS42_1U of the eighth sub-side surface SS42_1 of the first sub-substrate SSUB1 and the radius of curvature of the lower part SS42_1B of the eighth sub-side surface SS42_1. The radius of curvature of the upper central area SS42_1UA of the eighth sub-side surface SS42_1 of the first sub-substrate SSUB1 and the radius of curvature of the lower central area SS42_1BA of the eighth sub-side surface SS42_1 may be substantially equal to each other. Alternatively, the difference between the radius of curvature of the upper central area SS42_1UA of the eighth sub-side surface SS42_1 of the first sub-substrate SSUB1 and the radius of curvature of the lower central area SS42_1BA of the eighth sub-side surface SS42_1 may be within 30 μm (e.g., may be about 30 μm or less).

The radius of curvature of the upper central area SS42_1UA of the eighth sub-side surface SS42_1 of the first sub-substrate SSUB1 may be defined as a radius of curvature of a curve passing through the center SS42_1C, the upper center SS42_1UC and a first point PP42_11 of the eighth sub-side surface SS42_1 of the first sub-substrate SSUB1. The radius of curvature of the lower central area SS42_1BA of the eighth sub-side surface SS42_1 of the first sub-substrate SSUB1 may be defined as a radius of curvature of a curve passing through the center SS42_1C, the lower center SS42_1BC and a second point PP42_21 of the eighth sub-side surface SS42_1 of the first sub-substrate SSUB1. The first point PP42_11 of the eighth sub-side surface SS42_1 of the first sub-substrate SSUB1 may be defined as a midpoint between the center SS42_1C and the upper center SS42_1UC of the eighth sub-side surface SS42_1 of the first sub-substrate SSUB1. The second point PP42_21 of the eighth sub-side surface SS42_1 of the first sub-substrate SSUB1 may be defined as a midpoint between the center SS42_1C and the lower center SS42_1BC of the eighth sub-side surface SS42_1 of the first sub-substrate SSUB1.

Referring to FIGS. 45A through 45D, the length of the first sub-side surface SS11_1 of the first side surface SS1_1 of the first sub-substrate SSUB1, the length of the third sub-side surface SS21_1 of the second side surface SS2_1, the length of the fifth sub-side surface SS31_1 of the third side surface SS3_1, and the length of the seventh sub-side surface SS41_1 of the fourth side surface SS4_1 may be similar to each other. For example, the length of the first sub-side surface SS11_1 of the first side surface SS1_1 of the first sub-substrate SSUB1, the length of the third sub-side surface SS21_1 of the second side surface SS2_1, the length of the fifth sub-side surface SS31_1 of the third side surface SS3_1, and the length of the seventh sub-side surface SS41_1 of the fourth side surface SS4_1 may each be greater than about 10 μm and less than about 30 μm.

For example, a difference between the length of the first sub-side surface SS11_1 of the first side surface SS1_1 of the first sub-substrate SSUB1 and the length of the third sub-side surface SS21_1 of the second side surface SS2_1 of the first sub-substrate SSUB1 may be less than about 10 μm. A difference between the length of the first sub-side surface SS11_1 of the first side surface SS1_1 of the first sub-substrate SSUB1 and the length of the fifth sub-side surface SS31_1 of the third side surface SS3_1 of the first sub-substrate SSUB1 may be less than about 10 μm. A difference between the length of the first sub-side surface SS11_1 of the first side surface SS1_1 of the first sub-substrate SSUB1 and the length of the seventh sub-side surface SS41_1 of the fourth side surface SS4_1 of the first sub-substrate SSUB1 may be less than about 10 μm. A difference between the length of the third sub-side surface SS21_1 of the second side surface SS2_1 of the first sub-substrate SSUB1 and the length of the fifth sub-side surface SS31_1 of the third side surface SS3_1 of the first sub-substrate SSUB1 may be less than about 10 μm. A difference between the length of the third sub-side surface SS21_1 of the second side surface SS2_1 of the first sub-substrate SSUB1 and the length of the seventh sub-side surface SS41_1 of the fourth side surface SS4_1 of the first sub-substrate SSUB1 may be less than about 10 μm. A difference between the length of the fifth sub-side surface SS31_1 of the third side surface SS3_1 of the first sub-substrate SSUB1 and the length of the seventh sub-side surface SS41_1 of the fourth side surface SS4_1 of the first sub-substrate SSUB1 may be less than about 10 μm.

The radius of curvature of the upper part SS12_1U of the second sub-side surface SS12_1 of the first side surface SS1_1 of the first sub-substrate SSUB1, the radius of curvature of the upper part SS22_1U of the fourth sub-side surface SS22_1 of the second side surface SS2_1, the radius of curvature of the upper part SS32_1U of the sixth sub-side surface SS32_1 of the third side surface SS3_1, and the radius of curvature of the upper part SS42_1U of the eighth sub-side surface SS42_1 of the fourth side surface SS4_1 may be similar to each other.

For example, a difference between the radius of curvature of the upper part SS12_1U of the second sub-side surface SS12_1 of the first side surface SS1_1 of the first sub-substrate SSUB1 and the radius of curvature of the upper part SS22_1U of the fourth sub-side surface SS22_1 of the second side surface SS2_1 of the first sub-substrate SSUB1 may be less than about 30 μm. A difference between the radius of curvature of the upper part SS12_1U of the second sub-side surface SS12_1 of the first side surface SS1_1 of the first sub-substrate SSUB1 and the radius of curvature of the upper part SS32_1U of the sixth sub-side surface SS32_1 of the third side surface SS3_1 of the first sub-substrate SSUB1 may be less than about 30 μm. A difference between the radius of curvature of the upper part SS12_1U of the second sub-side surface SS12_1 of the first side surface SS1_1 of the first sub-substrate SSUB1 and the radius of curvature of the upper part SS42_1U of the eighth sub-side surface SS42_1 of the fourth side surface SS4_1 of the first sub-substrate SSUB1 may be less than about 30 μm. A difference between the radius of curvature of the upper part SS22_1U of the fourth sub-side surface SS22_1 of the second side surface SS2_1 of the first sub-substrate SSUB1 and the radius of curvature of the upper part SS32_1U of the sixth sub-side surface SS32_1 of the third side surface SS3_1 of the first sub-substrate SSUB1 may be less than about 30 μm. A difference between the radius of curvature of the upper part SS22U_1 of the fourth sub-side surface SS22_1 of the second side surface SS2_1 of the first sub-substrate SSUB1 and the radius of curvature of the upper part SS42_1U of the eighth sub-side surface SS42_1 of the fourth side surface SS4_1 of the first sub-substrate SSUB1 may be less than about 30 μm. A difference between the radius of curvature of the upper part SS32U_1 of the sixth sub-side surface SS32_1 of the third side surface SS3_1 of the first sub-substrate SSUB1 and the radius of curvature of the upper part SS42_1U of the eighth sub-side surface SS42_1 of the fourth side surface SS4_1 of the first sub-substrate SSUB1 may be less than about 30 μm.

As illustrated in FIGS. 45A through 45D, a difference in radius of curvature between the side surfaces SS1_1, SS2_1, SS3_1 and SS4_1 of the first sub-substrate SSUB1 of the display panel 100 may be insignificant. Therefore, uniform mechanical strength can be maintained according to the positions of the side surfaces SS1_1, SS2_1, SS3_1 and SS4_1 of the first sub-substrate SSUB1 of the display panel 100.

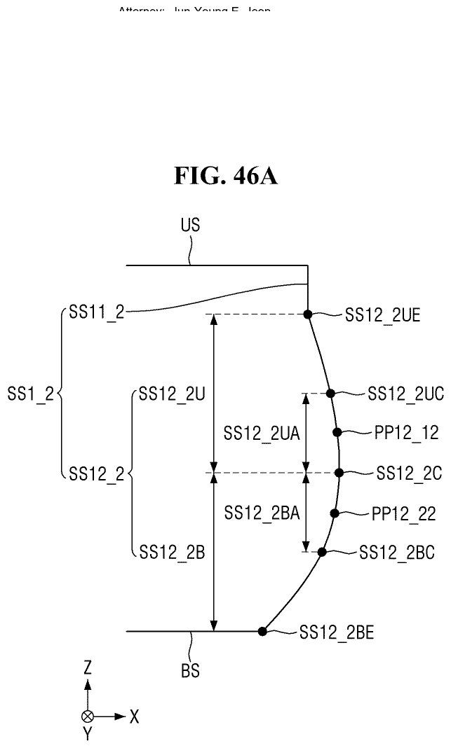

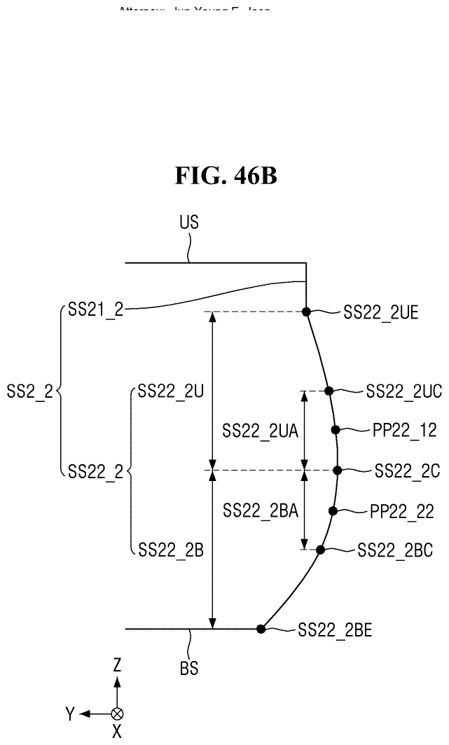

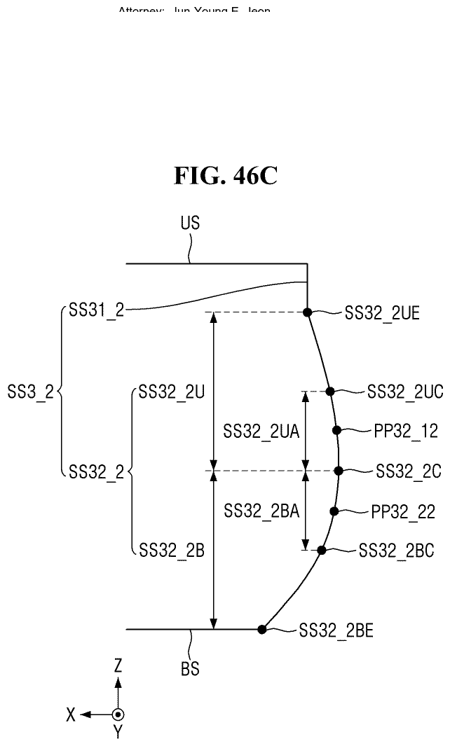

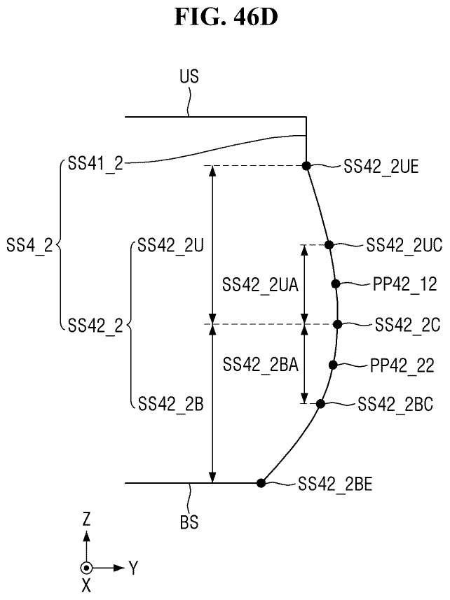

FIGS. 46A through 46D are enlarged cross-sectional views of examples of the first through fourth side surfaces SS1_2, SS2_2, SS3_2 and SS4_2 of the second sub-substrate SSUB2 in FIGS. 39 and 42. FIG. 46A illustrates a cross section of the first side surface SS1_2 of the second sub-substrate SSUB2, FIG. 46B illustrates a cross-section of the second side surface SS2_2 of the second sub-substrate SSUB2, FIG. 46C illustrates a cross section of the third side surface SS3_2 of the second sub-substrate SSUB2, and FIG. 45D illustrates a cross-section of the fourth side surface SS4_2 of the second sub-substrate SSUB2.

Referring to FIG. 46A, the first side surface SS1_2 of the second sub-substrate SSUB2 may have a first sub-side surface SS11_2 in a flat or curved shape and a second sub-side surface SS12_2 in a curved shape with a varying radius of curvature. A length of the first sub-side surface SS11_2 of the second sub-substrate SSUB2 may be smaller than a length of the second sub-side surface SS12_2.

The first sub-side surface SS11_2 of the second sub-substrate SSUB2 may be connected to an upper surface US, and the second sub-side surface SS12_2 of the second sub-substrate SSUB2 may be connected to a lower surface BS. An angle between the first sub-side surface SS11_2 and the upper surface US of the second sub-substrate SSUB2 may be a right angle or an obtuse angle close to a right angle.

A curved shape of an upper part SS12_2U of the second sub-side surface SS12_2 of the second sub-substrate SSUB2 and a curved shape of a lower part SS12_2B of the second sub-side surface SS12_2 may be different from each other. The upper part SS12_2U of the second sub-side surface SS12_2 of the second sub-substrate SSUB2 refers to an area disposed above a center SS12_2C of the second sub-side surface SS12_2. The lower part SS12_2B of the second sub-side surface SS12_2 of the second sub-substrate SSUB2 refers to an area disposed below the center SS12_2C of the second sub-side surface SS12_2.

A radius of curvature of the upper part SS12_2U of the second sub-side surface SS12_2 of the second sub-substrate SSUB2 and a radius of curvature of the lower part SS12_2B of the second sub-side surface SS12_2 may be different from each other. For example, the radius of curvature of the lower part SS12_2B of the second sub-side surface SS12_2 of the second sub-substrate SSUB2 may be smaller than the radius of curvature of the upper part SS12_2U of the second sub-side surface SS12_2.

The radius of curvature of the upper part SS12_2U of the second sub-side surface SS12_2 of the second sub-substrate SSUB2 may be defined as a radius of curvature of a curve passing through the center SS12_2C of the second sub-side surface SS12_2, an upper end SS12_2UE of the second sub-side surface SS12_2, and an upper center SS12_2UC of the second sub-side surface SS12_2. The radius of curvature of the lower part SS12_2B of the second sub-side surface SS12_2 of the second sub-substrate SSUB2 may be defined as a radius of curvature of a curve passing through the center SS12_2C of the second sub-side surface SS12_2, a lower end SS12_2BE of the second sub-side surface SS12_2, and a lower center SS12_2BC of the second sub-side surface SS12_2.

In addition, a radius of curvature of a central area of the second sub-side surface SS12_2 of the second sub-substrate SSUB2 may be different from the radius of curvature of the upper part SS12_2U of the second sub-side surface SS12_2 of the second sub-substrate SSUB2 and the radius of curvature of the lower part SS12_2B of the second sub-side surface SS12_2. The radius of curvature of the central area of the second sub-side surface SS12_2 of the second sub-substrate SSUB2 may be defined as a radius of curvature of a curve passing through the center SS12_2C, the upper center SS12_2UC and the lower center SS12_2BC of the second sub-side surface SS12_2 of the second sub-substrate SSUB2.

In addition, a difference between a radius of curvature of an upper central area SS12_2UA of the second sub-side surface SS12_2 of the second sub-substrate SSUB2 and a radius of curvature of a lower central area SS12_2BA of the second sub-side surface SS12_2 may be smaller than a difference between the radius of curvature of the upper part SS12_2U of the second sub-side surface SS12_2 of the second sub-substrate SSUB2 and the radius of curvature of the lower part SS12_2B of the second sub-side surface SS12_2. The radius of curvature of the upper central area SS12_2UA of the second sub-side surface SS12_2 of the second sub-substrate SSUB2 and the radius of curvature of the lower central area SS12_2BA of the second sub-side surface SS12_2 may be substantially equal to each other. Alternatively, the difference between the radius of curvature of the upper central area SS12_2UA of the second sub-side surface SS12_2 of the second sub-substrate SSUB2 and the radius of curvature of the lower central area SS12_2BA of the second sub-side surface SS12_2 may be within 30 μm (e.g., may be about 30 μm or less).

The radius of curvature of the upper central area SS12_2UA of the second sub-side surface SS12_2 of the second sub-substrate SSUB2 may be defined as a radius of curvature of a curve passing through the center SS12_2C, the upper center SS12_2UC and a first point PP12_12 of the second sub-side surface SS12_2 of the second sub-substrate SSUB2. The radius of curvature of the lower central area SS12_2BA of the second sub-side surface SS12_2 of the second sub-substrate SSUB2 may be defined as a radius of curvature of a curve passing through the center SS12_2C, the lower center SS12_2BC and a second point PP12_22 of the second sub-side surface SS12_2 of the second sub-substrate SSUB2. The first point PP12_12 of the second sub-side surface SS12_2 of the second sub-substrate SSUB2 may be defined as a midpoint between the center SS12_2C and the upper center SS12_2UC of the second sub-side surface SS12_2 of the second sub-substrate SSUB2. The second point PP12_22 of the second sub-side surface SS12_2 of the second sub-substrate SSUB2 may be defined as a midpoint between the center SS12_2C and the lower center SS12_2BC of the second sub-side surface SS12_2 of the second sub-substrate SSUB2.

Referring to FIG. 46B, the second side surface SS2_2 of the second sub-substrate SSUB2 may have a third sub-side surface SS21_2 in a flat or curved shape and a fourth sub-side surface SS22_2 in a curved shape with a varying radius of curvature. A length of the third sub-side surface SS21_2 of the second sub-substrate SSUB2 may be smaller than a length of the fourth sub-side surface SS22_2.

The third sub-side surface SS21_2 of the second sub-substrate SSUB2 may be connected to the upper surface US, and the fourth sub-side surface SS22_2 of the second sub-substrate SSUB2 may be connected to the lower surface BS. An angle between the third sub-side surface SS21_2 and the upper surface US of the second sub-substrate SSUB2 may be a right angle or an obtuse angle close to a right angle.

A curved shape of an upper part SS22_2U of the fourth sub-side surface SS22_2 of the second sub-substrate SSUB2 and a curved shape of a lower part SS22_2B of the fourth sub-side surface SS22_2 may be different from each other. The upper part SS22_2U of the fourth sub-side surface SS22_2 of the second sub-substrate SSUB2 refers to an area disposed above a center SS22_2C of the fourth sub-side surface SS22_2. The lower part SS22_2B of the fourth sub-side surface SS22_2 of the second sub-substrate SSUB2 refers to an area disposed below the center SS22_2C of the fourth sub-side surface SS22_2.

A radius of curvature of the upper part SS22_2U of the fourth sub-side surface SS22_2 of the second sub-substrate SSUB2 and a radius of curvature of the lower part SS22_2B of the fourth sub-side surface SS22_2 may be different from each other. For example, the radius of curvature of the lower part SS22_2B of the fourth sub-side surface SS22_2 of the second sub-substrate SSUB2 may be smaller than the radius of curvature of the upper part SS22_2U of the fourth sub-side surface SS22_2.

The radius of curvature of the upper part SS22_2U of the fourth sub-side surface SS22_2 of the second sub-substrate SSUB2 may be defined as a radius of curvature of a curve passing through the center SS22_2C of the fourth sub-side surface SS22_2, an upper end SS22_2UE of the fourth sub-side surface SS22_2, and an upper center SS22_2UC of the fourth sub-side surface SS22_2. The radius of curvature of the lower part SS22_2B of the fourth sub-side surface SS22_2 of the second sub-substrate SSUB2 may be defined as a radius of curvature of a curve passing through the center SS22_2C of the fourth sub-side surface SS22_2, a lower end SS22_2BE of the fourth sub-side surface SS22_2, and a lower center SS22_2BC of the fourth sub-side surface SS22_2.

In addition, a radius of curvature of a central area of the fourth sub-side surface SS22_2 of the second sub-substrate SSUB2 may be different from the radius of curvature of the upper part SS22_2U of the fourth sub-side surface SS22_2 of the second sub-substrate SSUB2 and the radius of curvature of the lower part SS22_2B of the fourth sub-side surface SS22_2. The radius of curvature of the central area of the fourth sub-side surface SS22_2 of the second sub-substrate SSUB2 may be defined as a radius of curvature of a curve passing through the center SS22_2C, the upper center SS22_2UC and the lower center SS22_2BC of the fourth sub-side surface SS22_2 of the second sub-substrate SSUB2.

In addition, a difference between a radius of curvature of an upper central area SS22_2UA of the fourth sub-side surface SS22_2 of the second sub-substrate SSUB2 and a radius of curvature of a lower central area SS22_2BA of the fourth sub-side surface SS22_2 may be smaller than a difference between the radius of curvature of the upper part SS22_2U of the fourth sub-side surface SS22_2 of the second sub-substrate SSUB2 and the radius of curvature of the lower part SS22_2B of the fourth sub-side surface SS22_2. The radius of curvature of the upper central area SS22_2UA of the fourth sub-side surface SS22_2 of the second sub-substrate SSUB2 and the radius of curvature of the lower central area SS22_2BA of the fourth sub-side surface SS22_2 may be substantially equal to each other. Alternatively, the difference between the radius of curvature of the upper central area SS22_2UA of the fourth sub-side surface SS22_2 of the second sub-substrate SSUB2 and the radius of curvature of the lower central area SS22_2BA of the fourth sub-side surface SS22_2 may be within 30 μm (e.g., may be about 30 μm or less).

The radius of curvature of the upper central area SS22_2UA of the fourth sub-side surface SS22_2 of the second sub-substrate SSUB2 may be defined as a radius of curvature of a curve passing through the center SS22_2C, the upper center SS22_2UC and a first point PP22_12 of the fourth sub-side surface SS22_2 of the second sub-substrate SSUB2. The radius of curvature of the lower central area SS22_2BA of the fourth sub-side surface SS22_2 of the second sub-substrate SSUB2 may be defined as a radius of curvature of a curve passing through the center SS22_2C, the lower center SS22_2BC and a second point PP22_22 of the fourth sub-side surface SS22_2 of the second sub-substrate SSUB2. The first point PP22_12 of the fourth sub-side surface SS22_2 of the second sub-substrate SSUB2 may be defined as a midpoint between the center SS22_2C and the upper center SS22_2UC of the fourth sub-side surface SS22_2 of the second sub-substrate SSUB2. The second point PP22_22 of the fourth sub-side surface SS22_2 of the second sub-substrate SSUB2 may be defined as a midpoint between the center SS22_2C and the lower center SS22_2BC of the fourth sub-side surface SS22_2 of the second sub-substrate SSUB2.

Referring to FIG. 46C, the third side surface SS3_2 of the second sub-substrate SSUB2 may have a fifth sub-side surface SS31_2 in a flat or curved shape and a sixth sub-side surface SS32_2 in a curved shape with a varying radius of curvature. A length of the fifth sub-side surface SS31_2 may be smaller than a length of the sixth sub-side surface SS32_2.

The fifth sub-side surface SS31_2 of the second sub-substrate SSUB2 may be connected to the upper surface US, and the sixth sub-side surface SS32_2 of the second sub-substrate SSUB2 may be connected to the lower surface BS. An angle between the fifth sub-side surface SS31_2 and the upper surface US of the second sub-substrate SSUB2 may be a right angle or an obtuse angle close to a right angle.

A curved shape of an upper part SS32_2U of the sixth sub-side surface SS32_2 of the second sub-substrate SSUB2 and a curved shape of a lower part SS32_2B of the sixth sub-side surface SS32_2 may be different from each other. The upper part SS32_2U of the sixth sub-side surface SS32_2 of the second sub-substrate SSUB2 refers to an area disposed above a center SS32_2C of the sixth sub-side surface SS32_2. The lower part SS32_2B of the sixth sub-side surface SS32_2 of the second sub-substrate SSUB2 refers to an area disposed below the center SS32_2C of the sixth sub-side surface SS32_2.

A radius of curvature of the upper part SS32_2U of the sixth sub-side surface SS32_2 of the second sub-substrate SSUB2 and a radius of curvature of the lower part SS32_2B of the sixth sub-side surface SS32_2 may be different from each other. For example, the radius of curvature of the lower part SS32_2B of the sixth sub-side surface SS32_2 of the second sub-substrate SSUB2 may be smaller than the radius of curvature of the upper part SS32_2U of the sixth sub-side surface SS32_2.

The radius of curvature of the upper part SS32_2U of the sixth sub-side surface SS32_2 of the second sub-substrate SSUB2 may be defined as a radius of curvature of a curve passing through the center SS32_2C of the sixth sub-side surface SS32_2, an upper end SS32_2UE of the sixth sub-side surface SS32_2, and an upper center SS32_2UC of the sixth sub-side surface SS32_2. The radius of curvature of the lower part SS32_2B of the sixth sub-side surface SS32_2 of the second sub-substrate SSUB2 may be defined as a radius of curvature of a curve passing through the center SS32_2C of the sixth sub-side surface SS32_2, a lower end SS32_2BE of the sixth sub-side surface SS32_2, and a lower center SS32_2BC of the sixth sub-side surface SS32_2.

In addition, a radius of curvature of a central area of the sixth sub-side surface SS32_2 of the second sub-substrate SSUB2 may be different from the radius of curvature of the upper part SS32_2U of the sixth sub-side surface SS32_2 of the second sub-substrate SSUB2 and the radius of curvature of the lower part SS32_2B of the sixth sub-side surface SS32_2. The radius of curvature of the central area of the sixth sub-side surface SS32_2 of the second sub-substrate SSUB2 may be defined as a radius of curvature of a curve passing through the center SS32_2C, the upper center SS32_2UC and the lower center SS32_2BC of the sixth sub-side surface SS32_2 of the second sub-substrate SSUB2.

In addition, a difference between a radius of curvature of an upper central area SS32_2UA of the sixth sub-side surface SS32_2 of the second sub-substrate SSUB2 and a radius of curvature of a lower central area SS32_2BA of the sixth sub-side surface SS32_2 may be smaller than a difference between the radius of curvature of the upper part SS32_2U of the sixth sub-side surface SS32_2 of the second sub-substrate SSUB2 and the radius of curvature of the lower part SS32_2B of the sixth sub-side surface SS32_2. The radius of curvature of the upper central area SS32_2UA of the sixth sub-side surface SS32_2 of the second sub-substrate SSUB2 and the radius of curvature of the lower central area SS32_2BA of the sixth sub-side surface SS32_2 may be substantially equal to each other. Alternatively, the difference between the radius of curvature of the upper central area SS32_2UA of the sixth sub-side surface SS32_2 of the second sub-substrate SSUB2 and the radius of curvature of the lower central area SS32_2BA of the sixth sub-side surface SS32_2 may be within 30 μm (e.g., may be about 30 μm or less).

The radius of curvature of the upper central area SS32_2UA of the sixth sub-side surface SS32_2 of the second sub-substrate SSUB2 may be defined as a radius of curvature of a curve passing through the center SS32_2C, the upper center SS32_2UC and a first point PP32_12 of the sixth sub-side surface SS32_2 of the second sub-substrate SSUB2. The radius of curvature of the lower central area SS32_2BA of the sixth sub-side surface SS32_2 of the second sub-substrate SSUB2 may be defined as a radius of curvature of a curve passing through the center SS32_2C, the lower center SS32_2BC and a second point PP32_22 of the sixth sub-side surface SS32_2 of the second sub-substrate SSUB2. The first point PP32_12 of the sixth sub-side surface SS32_2 of the second sub-substrate SSUB2 may be defined as a midpoint between the center SS32_2C and the upper center SS32_2UC of the sixth sub-side surface SS32_2 of the second sub-substrate SSUB2. The second point PP32_22 of the sixth sub-side surface SS32_2 of the second sub-substrate SSUB2 may be defined as a midpoint between the center SS32_2C and the lower center SS32_2BC of the sixth sub-side surface SS32_2 of the second sub-substrate SSUB2.

Referring to FIG. 46D, the fourth side surface SS4_2 of the second sub-substrate SSUB2 may have a seventh sub-side surface SS41_2 in a flat or curved shape and an eighth sub-side surface SS42_2 in a curved shape with a varying radius of curvature. A length of the seventh sub-side surface SS41_2 of the second sub-substrate SSUB2 may be smaller than a length of the eighth sub-side surface SS42_2.

The seventh sub-side surface SS41_2 of the second sub-substrate SSUB2 may be connected to the upper surface US, and the eighth sub-side surface SS42_2 of the second sub-substrate SSUB2 may be connected to the lower surface BS. An angle between the seventh sub-side surface SS41_2 and the upper surface US of the second sub-substrate SSUB2 may be a right angle or an obtuse angle close to a right angle.

A curved shape of an upper part SS42_2U of the eighth sub-side surface SS42_2 of the second sub-substrate SSUB2 and a curved shape of a lower part SS42_2B of the eighth sub-side surface SS42_2 may be different from each other. The upper part SS42_2U of the eighth sub-side surface SS42_2 of the second sub-substrate SSUB2 refers to an area disposed above a center SS42_2C of the eighth sub-side surface SS42_2. The lower part SS42_2B of the eighth sub-side surface SS42_2 of the second sub-substrate SSUB2 refers to an area disposed below the center SS42_2C of the eighth sub-side surface SS42_2.

A radius of curvature of the upper part SS42_2U of the eighth sub-side surface SS42_2 of the second sub-substrate SSUB2 and a radius of curvature of the lower part SS42_2B of the eighth sub-side surface SS42_2 may be different from each other. For example, the radius of curvature of the lower part SS42_2B of the eighth sub-side surface SS42_2 of the second sub-substrate SSUB2 may be smaller than the radius of curvature of the upper part SS42_2U of the eighth sub-side surface SS42_2.

The radius of curvature of the upper part SS42_2U of the eighth sub-side surface SS42_2 of the second sub-substrate SSUB2 may be defined as a radius of curvature of a curve passing through the center SS42_2C of the eighth sub-side surface SS42_2, an upper end SS42_2UE of the eighth sub-side surface SS42_2, and an upper center SS42_2UC of the eighth sub-side surface SS42_2. The radius of curvature of the lower part SS42_2B of the eighth sub-side surface SS42_2 may be defined as a radius of curvature of a curve passing through the center SS42_2C of the eighth sub-side surface SS42_2, a lower end SS42_2BE of the eighth sub-side surface SS42_2, and a lower center SS42_2BC of the eighth sub-side surface SS42_2.

In addition, a radius of curvature of a central area of the eighth sub-side surface SS42_2 of the second sub-substrate SSUB2 may be different from the radius of curvature of the upper part SS42_2U of the eighth sub-side surface SS42_2 of the second sub-substrate SSUB2 and the radius of curvature of the lower part SS42_2B of the eighth sub-side surface SS42_2. The radius of curvature of the central area of the eighth sub-side surface SS42_2 of the second sub-substrate SSUB2 may be defined as a radius of curvature of a curve passing through the center SS42_2C, the upper center SS42_2UC and the lower center SS42_2BC of the eighth sub-side surface SS42_2 of the second sub-substrate SSUB2.

In addition, a difference between a radius of curvature of an upper central area SS42_2UA of the eighth sub-side surface SS42_2 of the second sub-substrate SSUB2 and a radius of curvature of a lower central area SS42_2BA of the eighth sub-side surface SS42_2 may be smaller than a difference between the radius of curvature of the upper part SS42_2U of the eighth sub-side surface SS42_2 of the second sub-substrate SSUB2 and the radius of curvature of the lower part SS42_2B of the eighth sub-side surface SS42_2. The radius of curvature of the upper central area SS42_2UA of the eighth sub-side surface SS42_2 of the second sub-substrate SSUB2 and the radius of curvature of the lower central area SS42_2BA of the eighth sub-side surface SS42_2 may be substantially equal to each other. Alternatively, the difference between the radius of curvature of the upper central area SS42_2UA of the eighth sub-side surface SS42_2 of the second sub-substrate SSUB2 and the radius of curvature of the lower central area SS42_2BA of the eighth sub-side surface SS42_2 may be within 30 μm (e.g., may be about 30 μm or less).

The radius of curvature of the upper central area SS42_2UA of the eighth sub-side surface SS42_2 of the second sub-substrate SSUB2 may be defined as a radius of curvature of a curve passing through the center SS42_2C, the upper center SS42_2UC and a first point PP42_12 of the eighth sub-side surface SS42_2 of the second sub-substrate SSUB2. The radius of curvature of the lower central area SS42_2BA of the eighth sub-side surface SS42_2 of the second sub-substrate SSUB2 may be defined as a radius of curvature of a curve passing through the center SS42_2C, the lower center SS42_2BC and a second point PP42_22 of the eighth sub-side surface SS42_2 of the second sub-substrate SSUB2. The first point PP42_12 of the eighth sub-side surface SS42_2 of the second sub-substrate SSUB2 may be defined as a midpoint between the center SS42_2C and the upper center SS42_2UC of the eighth sub-side surface SS42_2 of the second sub-substrate SSUB2. The second point PP42_22 of the eighth sub-side surface SS42_2 of the second sub-substrate SSUB2 may be defined as a midpoint between the center SS42_2C and the lower center SS42_2BC of the eighth sub-side surface SS42_2 of the second sub-substrate SSUB2.

Referring to FIGS. 46A through 46D, the length of the first sub-side surface SS11_2 of the first side surface SS1_2 of the second sub-substrate SSUB2, the length of the third sub-side surface SS21_2 of the second side surface SS2_2, the length of the fifth sub-side surface SS31_2 of the third side surface SS3_2, and the length of the seventh sub-side surface SS41_2 of the fourth side surface SS4_2 may be similar to each other.

For example, a difference between the length of the first sub-side surface SS11_2 of the first side surface SS1_2 of the second sub-substrate SSUB2 and the length of the third sub-side surface SS21_2 of the second side surface SS2_2 of the second sub-substrate SSUB2 may be less than about 10 μm. A difference between the length of the first sub-side surface SS11_2 of the first side surface SS1_2 of the second sub-substrate SSUB2 and the length of the fifth sub-side surface SS31_2 of the third side surface SS3_2 of the second sub-substrate SSUB2 may be less than about 10 μm. A difference between the length of the first sub-side surface SS11_2 of the first side surface SS1_2 of the second sub-substrate SSUB2 and the length of the seventh sub-side surface SS41_2 of the fourth side surface SS4_2 of the second sub-substrate SSUB2 may be less than about 10 μm. A difference between the length of the third sub-side surface SS21_2 of the second side surface SS2_2 of the second sub-substrate SSUB2 and the length of the fifth sub-side surface SS31_2 of the third side surface SS3_2 of the second sub-substrate SSUB2 may be less than about 10 μm. A difference between the length of the third sub-side surface SS21_2 of the second side surface SS2_2 of the second sub-substrate SSUB2 and the length of the seventh sub-side surface SS41_2 of the fourth side surface SS4_2 of the second sub-substrate SSUB2 may be less than about 10 μm. A difference between the length of the fifth sub-side surface SS31_2 of the third side surface SS3_2 of the second sub-substrate SSUB2 and the length of the seventh sub-side surface SS41_2 of the fourth side surface SS4_2 of the second sub-substrate SSUB2 may be less than about 10 μm.

The radius of curvature of the upper part SS12_2U of the second sub-side surface SS12_2 of the first side surface SS1_2 of the second sub-substrate SSUB2, the radius of curvature of the upper part SS22_2U of the fourth sub-side surface SS22_2 of the second side surface SS2_2, the radius of curvature of the upper part SS32_2U of the sixth sub-side surface SS32_2 of the third side surface SS3_2, and the radius of curvature of the upper part SS42_2U of the eighth sub-side surface SS42_2 of the fourth side surface SS4_2 may be similar to each other.

For example, a difference between the radius of curvature of the upper part SS12_2U of the second sub-side surface SS12_2 of the first side surface SS1_2 of the second sub-substrate SSUB2 and the radius of curvature of the upper part SS22_2U of the fourth sub-side surface SS22_2 of the second side surface SS2_2 of the second sub-substrate SSUB2 may be less than about 30 μm. A difference between the radius of curvature of the upper part SS12_2U of the second sub-side surface SS12_2 of the first side surface SS1_2 of the second sub-substrate SSUB2 and the radius of curvature of the upper part SS32_2U of the sixth sub-side surface SS32_2 of the third side surface SS3_2 of the second sub-substrate SSUB2 may be less than about 30 μm. A difference between the radius of curvature of the upper part SS12_2U of the second sub-side surface SS12_2 of the first side surface SS1_2 of the second sub-substrate SSUB2 and the radius of curvature of the upper part SS42_2U of the eighth sub-side surface SS42_2 of the fourth side surface SS4_2 of the second sub-substrate SSUB2 may be less than about 30 μm. A difference between the radius of curvature of the upper part SS22_2U of the fourth sub-side surface SS22_2 of the second side surface SS2_2 of the second sub-substrate SSUB2 and the radius of curvature of the upper part SS32_2U of the sixth sub-side surface SS32_2 of the third side surface SS3_2 of the second sub-substrate SSUB2 may be less than about 30 μm. A difference between the radius of curvature of the upper part SS22_2U of the fourth sub-side surface SS22_2 of the second side surface SS2_2 of the second sub-substrate SSUB2 and the radius of curvature of the upper part SS42_2U of the eighth sub-side surface SS42_2 of the fourth side surface SS4_2 of the second sub-substrate SSUB2 may be less than about 30 μm. A difference between the radius of curvature of the upper part SS32_2U of the sixth sub-side surface SS32_2 of the third side surface SS3_2 of the second sub-substrate SSUB2 and the radius of curvature of the upper part SS42_2U of the eighth sub-side surface SS42_2 of the fourth side surface SS4_2 of the second sub-substrate SSUB2 may be less than about 30 μm.

As illustrated in FIGS. 46A through 46D, a difference in radius of curvature between the side surfaces SS1_2, SS2_2, SS3_2 and SS4_2 of the second sub-substrate SSUB2 of the display panel 100 may be insignificant. Therefore, uniform mechanical strength can be maintained according to the positions of the side surfaces SS1_2, SS2_2, SS3_2 and SS4_2 of the second sub-substrate SSUB2 of the display panel 100.

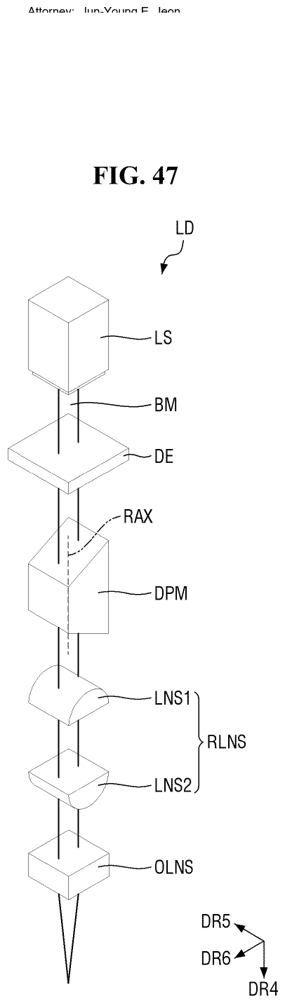

FIG. 47 is a perspective view of a laser device LD according to one or more embodiments of the present disclosure.

Referring to FIG. 47, the laser device LD according to the one or more embodiments includes a light source LS, a diffractive element DE, a Dove prism DPM, a relay lens RLNS, and an objective lens OLNS.

As the light source LS, any of various known suitable laser generators may be used. The light source LS may emit a laser beam BM. The light source LS may emit the beam BM continuously or discontinuously. The light source LS may output a single pulse laser beam BM or a burst pulse laser beam BM including a plurality of pulses.

The pulse duration, burst pulse, pulse energy, repetition rate, etc. of the laser beam BM may be adjusted by the light source LS. For example, the pulse duration (or pulse width) of the laser beam BM may be about 3 picoseconds (ps) to about 10 picoseconds (ps). The burst pulse of the laser beam BM may be in a range of 1 to 10 pulses. When the burst pulse of the laser beam BM is 1 pulse, it may be a single pulse. The pulse energy of the laser beam BM may be in a range of about 2 μJ/spot to about 4 μJ/spot. The repetition rate of the laser beam BM may be in a range of about 10 KHz to about 500 KHz.

Various laser beams may be used as the laser beam BM according to one or more embodiments of the present disclosure. However, in the present disclosure, the laser beam BM may be an infrared Bessel beam having a wavelength band in a range of about 1,000 nm to about 1,100 nm.

The diffractive element DE includes diffractive patterns for causing the laser beam BM incident on the diffractive element DE to be focused on laser spots (multi spots). The diffractive element DE may be a diffractive optical element with fixed diffractive patterns or a spatial light modulator that can actively change diffractive patterns.

The prism DPM may be disposed between the diffractive element DE and the relay lens RLNS. The prism DPM may be a Dove prism with a trapezoidal cross section, but embodiments of the present disclosure are not limited thereto.

The prism DPM may be rotated by a rotational motor to rotate a laser beam. The rotation of the laser beam refers to rotating an image phase of the laser beam. The prism DPM may be configured to be rotated clockwise or counterclockwise about a longitudinal rotation axis by the rotational motor. The longitudinal rotation axis RAX may be a rotation axis in a fourth direction DR4. The rotational motor may rotate the prism DPM in a range of 0 to 180 degrees about the longitudinal rotation axis RAX. Various known suitable motors such as a hollow motor, a stepping motor, a servo motor, and/or a brushless motor may be used as the rotational motor.

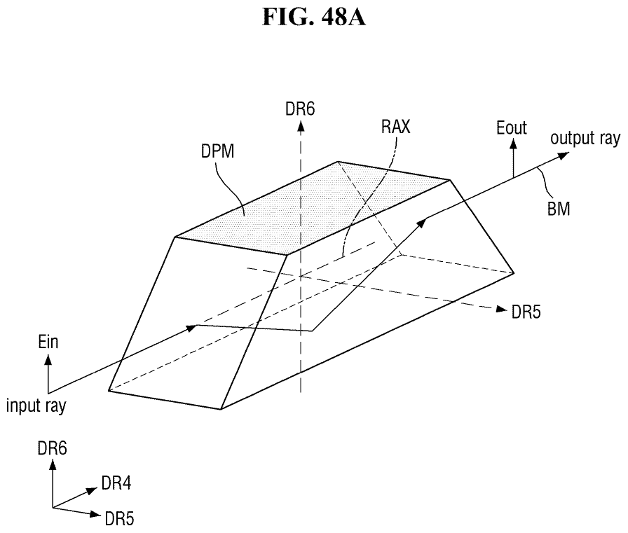

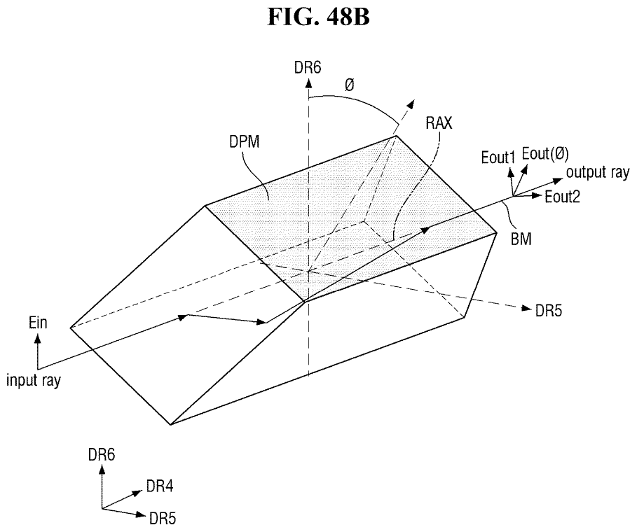

When the prism DPM is a Dove prism having trapezoidal cross sections as illustrated in FIGS. 48A and 48B, a laser beam undergoes two refractions and one total reflection within the prism DPM. Therefore, a rotation angle of the laser beam may be twice a rotation angle of the prism DPM.

The relay lens RLNS may be disposed between the prism DPM and the objective lens OLNS. The relay lens RLNS includes a first lens LNS1 and a second lens LNS2. The first lens LNS1 may be disposed adjacent to the prism DPM, and the second lens LNS2 may be disposed adjacent to the objective lens OLNS. The first lens LNS1 may be a convex lens convex toward the prism DPM, and the second lens LNS2 may be a convex lens convex toward the objective lens OLNS. The relay lens RLNS may relay light at a ratio of n:1 or at a ratio of 1:n, where n is a positive integer.

The objective lens OLNS may focus the laser beam BM, which passes through the relay lens RLNS, at a suitable distance (e.g., a predetermined distance).

The light source LS, the diffractive element DE, the Dove prism DPM, the relay lens RLNS, and the objective lens OLNS of the laser device LD may be arranged side by side in (e.g., may be aligned along) the fourth direction DR4.

FIGS. 48A and 48B are example diagrams for explaining light output from a prism DPM when the prism DPM is rotated by @.

Referring to FIGS. 48A and 48B, the prism DPM may be a Dove prism having trapezoidal cross sections. In this case, the prism DPM has two trapezoidal cross sections, each having a pair of opposite sides extending in the fourth direction DR4.

The fourth direction DR4 is a direction in which the opposite sides of the trapezoidal cross sections of the prism DPM extend, and a fifth direction DR5 is a direction in which sides connecting the trapezoidal cross sections of the prism DPM extend. The fifth direction DR5 may be perpendicular to the fourth direction DR4. A sixth direction DR6 may be perpendicular to the fourth direction DR4 and the fifth direction DR5 and may be a height direction of the prism DPM illustrated in FIG. 48A. In FIGS. 48A and 48B, an arrow extending in the fourth direction DR4 is an optical axis of the laser beam BM and indicates a direction in which the laser beam BM travels.

The prism DPM may rotate about a rotation axis RAX extending in the fourth direction DR4. The rotation axis RAX of the prism DPM may pass through a center of the prism DPM. FIG. 48B illustrates the prism DPM rotated by a suitable angle (e.g., a predetermined angle) @ in the sixth direction DR6 compared to the prism DPM illustrated in FIG. 48A.

As illustrated in FIG. 48A, when a polarization direction of an input ray Ein is the sixth direction DR6 and when the height direction of the prism DPM is the sixth direction DR6, a ray Eout output from the prism DPM also has the sixth direction DR6 as its polarization direction.

As illustrated in FIG. 48B, when a polarization direction of an input ray Ein is the sixth direction DR6 and when the height direction of the prism DPM is rotated by a suitable (e.g., a predetermined angle) ¢ with respect to the sixth direction DR6 in a plane defined by the fourth direction DR4 and the sixth direction DR6, a ray Eout output from the prism DPM includes a polarization component Eout1 in the fourth direction DR4 and a polarization component Eout2 in the fifth direction DR5. Therefore, as the prism DPM rotates, a circularly or elliptically polarized ray Eout (@) having a different polarization from the input ray Ein may be output.

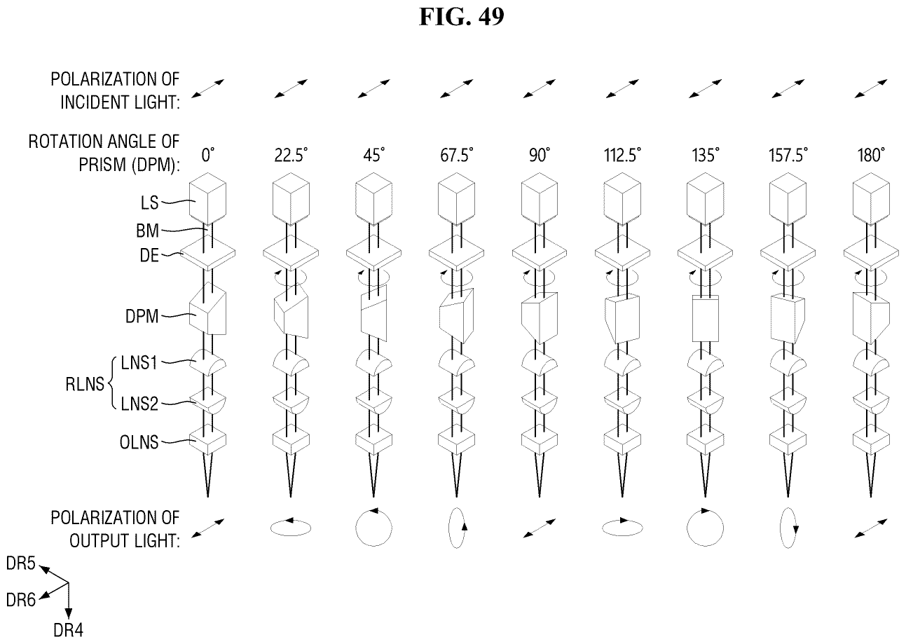

FIG. 49 is an example diagram illustrating the polarization of output light according to the rotation of the laser device LD in the one or more embodiments of FIG. 47.

Referring to FIG. 49, when the laser device LD rotates, the light source LS, the diffractive element DE, the relay lens RLNS and the objective lens OLNS do not rotate, and only the prism DPM rotates. Therefore, regardless of the rotation of the laser device LD, the light source LS outputs a linearly polarized laser beam BM whose polarization direction is the sixth direction DR6.

The prism DPM may rotate from 0 degrees to 180 degrees about the rotation axis RAX (e.g., see FIG. 47) with respect to the sixth direction DR6 in a plane defined by the fourth direction DR4 and the sixth direction DR6. Because the rotation angle of a laser beam is twice the rotation angle of the prism DPM, when the prism DPM rotates from 0 degrees to 180 degrees, the laser beam may rotate from 0 degrees to 360 degrees.

In a case where the light source LS outputs a linearly polarized laser beam BM whose polarization direction is the sixth direction DR6, the polarization direction of a laser beam output from the laser device LD according to the degree of rotation of the prism DPM in a clockwise direction with respect to the sixth direction DR6 will now be described in detail. As illustrated in FIG. 49, when the prism DPM is at 0 degrees with respect to the sixth direction DR6, the light source LS, the diffractive element DE, the prism DPM, the relay lens RLNS, and the objective lens OLNS are aligned in the sixth direction DR6. In addition, when the prism DPM is rotated 22.5 degrees clockwise with respect to the sixth direction DR6, the light source LS, the diffractive element DE, the relay lens RLNS and the objective lens OLNS are aligned in the sixth direction DR6, and the prism DPM is at 22.5 degrees clockwise with respect to the sixth direction DR6.

In addition, although the prism DPM rotates clockwise about the rotation axis RAX in FIG. 49, embodiments of the present disclosure are not limited thereto. That is, the prism DPM may also rotate counterclockwise about the rotation axis RAX.

First, when the prism DPM is at 0 degrees with respect to the sixth direction DR6, linearly polarized light having a polarization direction of the sixth direction DR6 and incident on the prism DPM is output as is. Therefore, the laser device LD may output the linearly polarized light having the polarization direction of the sixth direction DR6 and output from the light source LS as is.

When the prism DPM is rotated 22.5 degrees clockwise with respect to the sixth direction DR6, linearly polarized light having a polarization direction of the sixth direction DR6 and incident on the prism DPM is converted into elliptically polarized light having a polarization component in the fifth direction DR5 and a polarization component in the sixth direction DR6. Here, the polarization component in the sixth direction DR6 may be greater than the polarization component in the fifth direction DR5.

When the prism DPM is rotated 45 degrees clockwise with respect to the sixth direction DR6, linearly polarized light having a polarization direction of the sixth direction DR6 and incident on the prism DPM is converted into circularly polarized light having a polarization component in the fifth direction DR5 and a polarization component in the sixth direction DR6. Here, the polarization component in the fifth direction DR5 and the polarization component in the sixth direction DR6 may be substantially the same as each other.

When the prism DPM is rotated 67.5 degrees clockwise with respect to the sixth direction DR6, linearly polarized light having a polarization direction of the sixth direction DR6 and incident on the prism DPM is converted into elliptically polarized light having a polarization component in the fifth direction DR5 and a polarization component in the sixth direction DR6. Here, the polarization component in the sixth direction DR6 may be smaller than the polarization component in the fifth direction DR5.

When the prism DPM is rotated 90 degrees clockwise with respect to the sixth direction DR6, linearly polarized light having a polarization direction of the sixth direction DR6 and incident on the prism DPM is output as is. Therefore, the laser device LD may output the linearly polarized light having the polarization direction of the sixth direction DR6 and output from the light source LS as is.

When the prism DPM is rotated 112.5 degrees clockwise with respect to the sixth direction DR6, linearly polarized light having a polarization direction of the sixth direction DR6 and incident on the prism DPM is converted into elliptically polarized light having a polarization component in the sixth direction DR6 and a polarization component in a direction opposite to the fifth direction DR5. Here, the polarization component in the direction opposite to the fifth direction DR5 may be greater than the polarization component in the sixth direction DR6.

When the prism DPM is rotated 135 degrees clockwise with respect to the sixth direction DR6, linearly polarized light having a polarization direction of the sixth direction DR6 and incident on the prism DPM is converted into circularly polarized light having a polarization component in the sixth direction DR6 and a polarization component in the direction opposite to the fifth direction DR5. Here, the polarization component in the direction opposite to the fifth direction DR5 and the polarization component in the sixth direction DR6 may be substantially the same as each other.

When the prism DPM is rotated 157.5 degrees clockwise with respect to the sixth direction DR6, linearly polarized light having a polarization direction of the sixth direction DR6 and incident on the prism DPM is converted into elliptically polarized light having a polarization component in the sixth direction DR6 and a polarization component in the direction opposite to the fifth direction DR5. Here, the polarization component in the direction opposite to the fifth direction DR5 may be smaller than the polarization component in the sixth direction DR6.

When the prism DPM is rotated 180 degrees clockwise with respect to the sixth direction DR6, linearly polarized light having a polarization direction of the sixth direction DR6 and incident on the prism DPM is output as is. Therefore, the laser device LD may output the linearly polarized light having the polarization direction of the sixth direction DR6 and output from the light source LS as is.

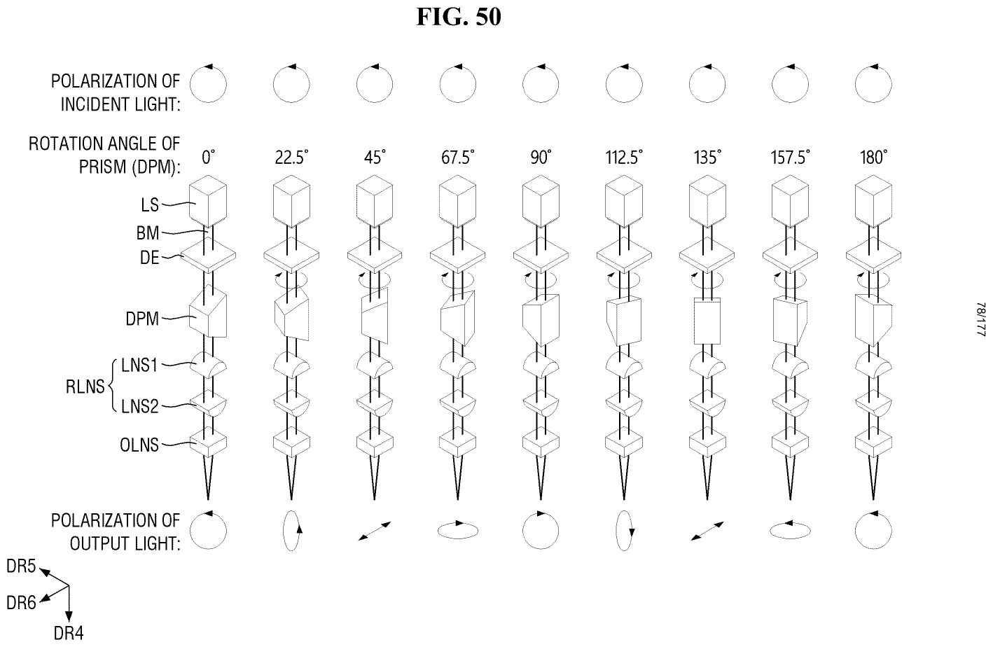

FIG. 50 is an example diagram illustrating the polarization of output light according to the rotation of the laser device LD in the one or more embodiments of FIG. 47.

Referring to FIG. 50, when the laser device LD rotates, the light source LS, the diffractive element DE, the relay lens RLNS and the objective lens OLNS do not rotate, and only the prism DPM rotates. Therefore, regardless of the rotation of the laser device LD, the light source LS outputs a circularly polarized laser beam BM having a polarization component in the fifth direction DR5 and a polarization component in the sixth direction DR6.

The prism DPM may rotate about the rotation axis RAX (e.g., see FIG. 47) at intervals of 22.5 degrees from 0 degrees to 180 degrees with respect to the sixth direction DR6 in a plane defined by the fourth direction DR4 and the sixth direction DR6. Because the rotation angle of a laser beam is twice the rotation angle of the prism DPM, when the prism DPM rotates from 0 degrees to 180 degrees, the laser beam may rotate from 0 degrees to 360 degrees.

In a case where the light source LS outputs a circularly polarized laser beam BM having a polarization component in the fifth direction DR5 and a polarization component in the sixth direction DR6, the polarization direction of a laser beam output from the laser device LD according to the degree of rotation of the prism DPM in the clockwise direction with respect to the sixth direction DR6 will now be described in detail. As illustrated in FIG. 50, when the prism DPM is at 0 degrees with respect to the sixth direction DR6, the light source LS, the diffractive element DE, the prism DPM, the relay lens RLNS, and the objective lens OLNS are aligned in the sixth direction DR6. In addition, when the prism DPM is rotated 22.5 degrees clockwise with respect to the sixth direction DR6, the light source LS, the diffractive element DE, the relay lens RLNS and the objective lens OLNS are aligned in the sixth direction DR6, and the prism DPM is at 22.5 degrees clockwise with respect to the sixth direction DR6.

In addition, although the prism DPM rotates clockwise about the rotation axis RAX in FIG. 50, embodiments of the present disclosure are not limited thereto. That is, the prism DPM may also rotate counterclockwise about the rotation axis RAX.

First, when the prism DPM is at 0 degrees with respect to the sixth direction DR6, circularly polarized light having a polarization component in the fifth direction DR5 and a polarization component in the sixth direction DR6 and incident on the prism DPM is output as is. Therefore, the laser device LD may output the circularly polarized light having the polarization component in the fifth direction DR5 and the polarization component in the sixth direction DR6 and output from the light source LS as is. When the prism DPM is rotated 22.5 degrees clockwise with respect to the sixth direction DR6, circularly polarized light having a polarization component in the fifth direction DR5 and a polarization component in the sixth direction DR6 and incident on the prism DPM is converted into elliptically polarized light having a polarization component in the fifth direction DR5 and a polarization component in the sixth direction DR6. Here, the polarization component in the sixth direction DR6 may be smaller than the polarization component in the fifth direction DR5.

When the prism DPM is rotated 45 degrees clockwise with respect to the sixth direction DR6, circularly polarized light having a polarization component in the fifth direction DR5 and a polarization component in the sixth direction DR6 and incident on the prism DPM is converted into linearly polarized light having a polarization direction of the fifth direction DR5.

When the prism DPM is rotated 67.5 degrees clockwise with respect to the sixth direction DR6, circularly polarized light having a polarization component in the fifth direction DR5 and a polarization component in the sixth direction DR6 and incident on the prism DPM is converted into elliptically polarized light having a polarization component in the fifth direction DR5 and a polarization component in a direction opposite to the sixth direction DR6. Here, the polarization component in the direction opposite to the sixth direction DR6 may be smaller than the polarization component in the fifth direction DR5.

When the prism DPM is rotated 90 degrees clockwise with respect to the sixth direction DR6, circularly polarized light having a polarization component in the fifth direction DR5 and a polarization component in the sixth direction DR6 and incident on the prism DPM is converted into circularly polarized light having a polarization component in the fifth direction DR5 and a polarization component in the direction opposite to the sixth direction DR6. Here, the polarization component in the fifth direction DR5 and the polarization component in the direction opposite to the sixth direction DR6 may be substantially the same as each other.

When the prism DPM is rotated 112.5 degrees clockwise with respect to the sixth direction DR6, circularly polarized light having a polarization component in the fifth direction DR5 and a polarization component in the sixth direction DR6 and incident on the prism DPM is converted into elliptically polarized light having a polarization component in the fifth direction DR5 and a polarization component in the direction opposite to the sixth direction DR6. Here, the polarization component in the direction opposite to the sixth direction DR6 may be greater than the polarization component in the fifth direction DR5.

When the prism DPM is rotated 135 degrees clockwise with respect to the sixth direction DR6, circularly polarized light having a polarization component in the fifth direction DR5 and a polarization component in the sixth direction DR6 and incident on the prism DPM is converted into linearly polarized light whose polarization direction is the direction opposite to the sixth direction DR6.

When the prism DPM is rotated 157.5 degrees clockwise with respect to the sixth direction DR6, circularly polarized light having a polarization component in the fifth direction DR5 and a polarization component in the sixth direction DR6 and incident on the prism DPM is converted into elliptically polarized light having a polarization component in the direction opposite to the sixth direction DR6 and a polarization component in the direction opposite to the fifth direction DR5. Here, the polarization component in the direction opposite to the sixth direction DR6 may be greater than the polarization component in the direction opposite to the fifth direction DR5.

When the prism DPM is rotated 180 degrees clockwise with respect to the sixth direction DR6, circularly polarized light having a polarization component in the fifth direction DR5 and a polarization component in the sixth direction DR6 and incident on the prism DPM is converted into circularly polarized light having a polarization component in the direction opposite to the sixth direction DR6 and a polarization component in the direction opposite to the fifth direction DR5. Here, the polarization component in the direction opposite to the fifth direction DR5 and the polarization component in the direction opposite to the sixth direction DR6 may be substantially the same as each other.

As illustrated in FIGS. 49 and 50, the polarization of the laser beam BM output from the laser device LD may be classified into linear polarization, circular polarization, and elliptical polarization depending on the rotation angle of the prism DPM.

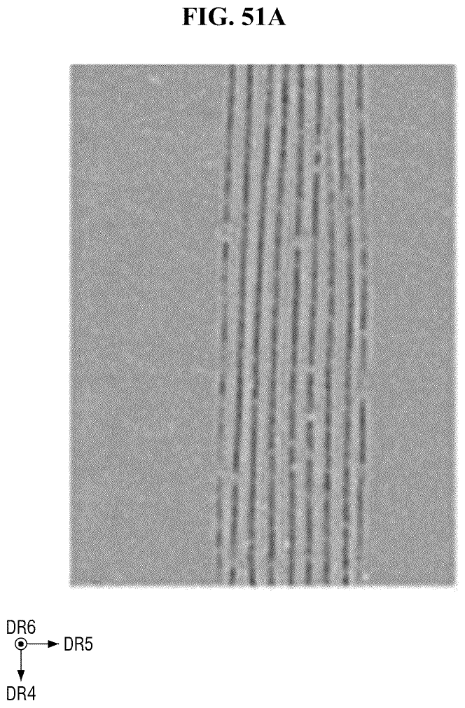

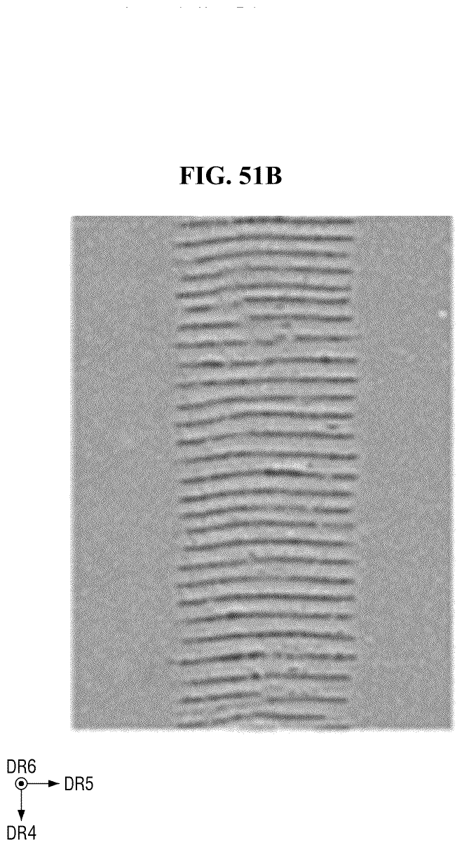

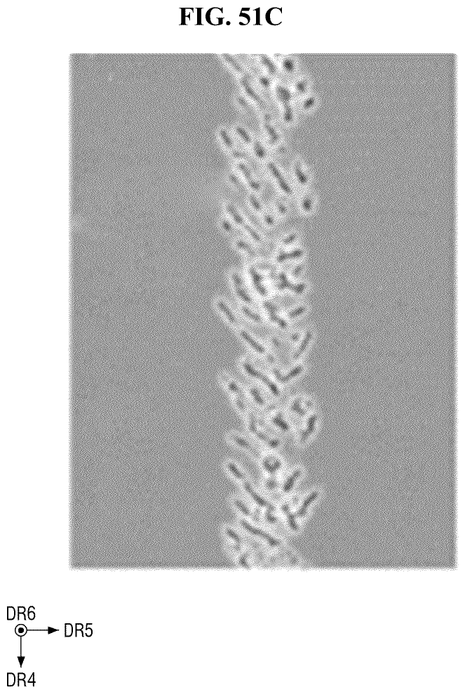

FIGS. 51A through 51C are example views of laser processing patterns according to the traveling direction and polarization direction of a laser beam.

Referring to FIG. 51A, when a scanning direction of a laser beam BM is the fourth direction DR4 and a polarization direction of the laser beam BM is the fifth direction DR5, the processability of a substrate SUB may increase in the fourth direction DR4.

Referring to FIG. 51B, when the scanning direction of the laser beam BM and the polarization direction of the laser beam BM are the fourth direction DR4, the processability of the substrate SUB may increase in the fifth direction DR5.

Referring to FIG. 51C, when the scanning direction of the laser beam BM is the fourth direction DR4, but when the laser beam BM has circular polarization, it is difficult to consider that the processability of the substrate SUB increases in any direction.

The scanning direction of the laser beam BM may be a laser sketching direction of the laser beam BM.

In summary, the laser device LD may rotate while emitting the laser beam BM to the substrate SUB of a display panel 100 in order to process side surfaces SS1 through SS4 of the substrate SUB of the display panel 100, a hole TH of the substrate SUB, and/or a bending area BA of the substrate SUB.

There may be a difference in the processability of the substrate SUB of the display panel 100 depending on whether the laser beam BM is linearly polarized, circularly polarized, or elliptically polarized. That is, there may be a difference between the shapes, for example, radii of curvature of the side surfaces SS1 through SS4 of the substrate SUB of the display panel 100 depending on whether the laser beam BM is linearly polarized, circularly polarized, or elliptically polarized. Therefore, mechanical strength may vary according to the positions of the side surfaces SS1 through SS4 of the substrate SUB of the display panel 100. In this case, it may be difficult to ensure that the side surfaces SS1 through SS4 of the substrate SUB of the display panel 100 have uniform quality against external impacts.

Alternatively, there may be a difference between the shapes, for example, radii of curvature of side surfaces SSH1 through SSH4 of the hole TH of the substrate SUB of the display panel 100 depending on whether the laser beam BM is linearly polarized, circularly polarized, or elliptically polarized. Therefore, mechanical strength may vary according to the positions of the side surfaces SSH1 through SSH4 of the hole TH of the substrate SUB of the display panel 100.

Alternatively, there may be a difference between the shapes, for example, radii of curvature of side surfaces SS1_1, SS2_1, SS3_1 and SS4_1 of a first sub-substrate SSUB1 of the display panel 100 and side surfaces SS1_2, SS2_2, SS3_2 and SS4_2 of a second sub-substrate SSUB2, that are divided by the bending area BA, depending on whether the laser beam BM is linearly polarized, circularly polarized, or elliptically polarized. Therefore, mechanical strength may vary according to the positions of the side surfaces SS1_1, SS2_1, SS3_1 and SS4_1 of the first sub-substrate SSUB1 of the display panel 100 and the side surfaces SS1_2, SS2_2, SS3_2 and SS4_2 of the second sub-substrate SSUB2.

Therefore, in order to maintain uniform shapes of the side surfaces SS1 through SS4 of the substrate SUB of the display panel 100, the side surfaces SSH1 through SSH4 of the hole TH, and the side surfaces SS1_1, SS2_1, SS3_1 and SS4_1 of the first sub-substrate SSUB1 and the side surfaces SS1_2, SS2_2, SS3_2 and SS4_2 of the second sub-substrate SSUB2 of the display panel 100 that are separated by the bending area BA, it is desirable to maintain the polarization of the laser beam BM output from the laser device LD as only one of linear polarization, circular polarization, and elliptical polarization.

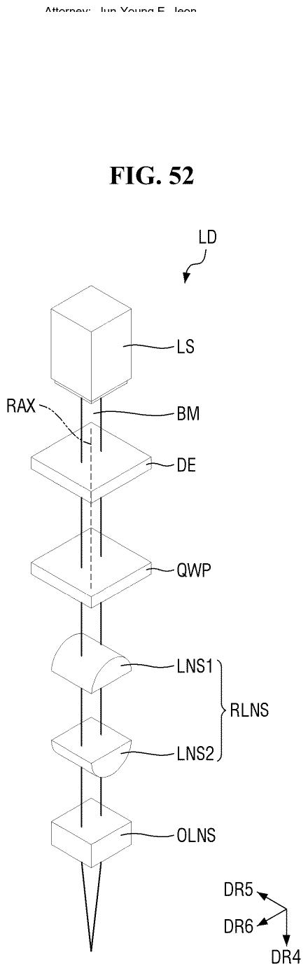

Laser devices LD according to one or more embodiments of the present disclosure that can maintain the polarization of a laser beam BM as elliptical polarization regardless of the rotation of the laser devices LD will now be described in detail with reference to FIGS. 52 through 57.

FIG. 52 is a perspective view of a laser device LD according to one or more embodiments of the present disclosure.

The one or more embodiments of FIG. 52 are different from the one or more embodiments of FIG. 47 in that a prism DPM is omitted and a phase retardation plate QWP is included and that a diffractive element DE and the phase retardation plate QWP are configured to be rotatable. In one or more embodiments, the diffractive element DE and the phase retardation plate QWP may be configured to be rotated by the same or different (or separate) rotation motors. In one or more other embodiments, only the diffractive element DE may be configured to be rotatable. In FIG. 52, a redundant description of elements and features identical to those of the one or more embodiments of FIG. 47 may be omitted.

Referring to FIG. 52, the diffractive element DE may be configured to be rotated clockwise or counterclockwise about a rotation axis RAX extending in the fourth direction DR4 by a rotational motor. The rotation axis RAX of the diffractive element DE may pass through a center of the diffractive element DE. The rotational motor is configured to rotate the diffractive element DE about the rotation axis RAX extending in the fourth direction DR4. The rotational motor may rotate the diffractive element DE by a desired angle in the range of 0 to 360 degrees. Various suitable known motors such as a hollow motor, a stepping motor, a servo motor, and/or a brushless motor may be used as the rotational motor.

The phase retardation plate QWP may be a λ/4 plate which retards the phase of incident light by λ/4. Because the phase retardation plate QWP retards the phase of a laser beam BM output from the diffractive element DE by λ/4, the laser device LD may output the laser beam BM elliptically polarized by the phase retardation plate QWP.

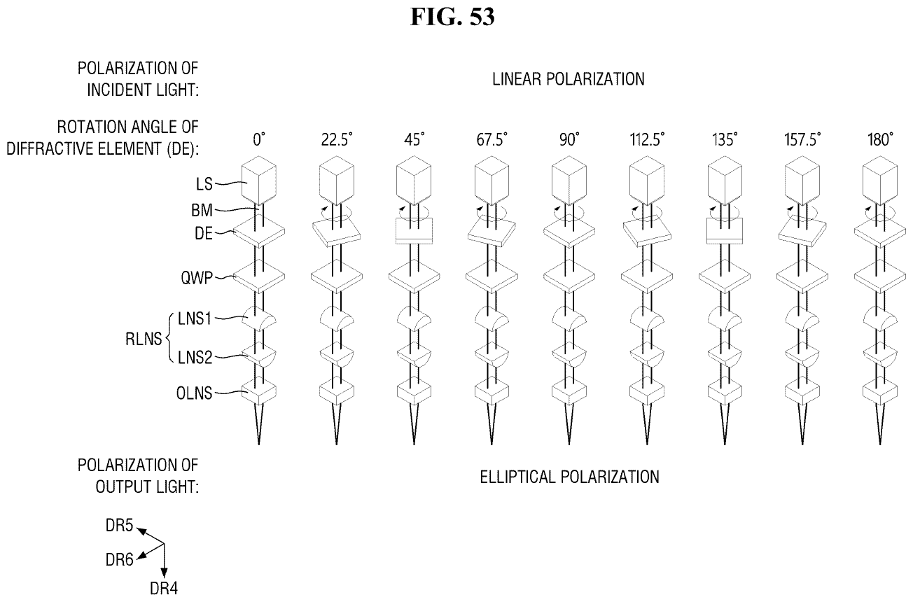

FIG. 53 is an example diagram illustrating the polarization of output light according to the rotation of the laser device LD in the one or more embodiments of FIG. 52.

Referring to FIG. 53, when the laser device LD rotates, a light source LS, the phase retardation plate QWP, a relay lens RLNS and an objective lens OLNS do not rotate, and only the diffractive element DE rotates. Therefore, regardless of the rotation of the laser device LD, the light source LS outputs a linearly polarized laser beam BM whose polarization direction is the sixth direction DR6. The diffractive element DE may rotate about the rotation axis RAX (e.g., see FIG. 52) from 0 degrees to 360 degrees with respect to the sixth direction DR6 in a plane defined by the fourth direction DR4 and the sixth direction DR6.

Because the phase retardation plate QWP retards the phase of an incident linearly polarized, elliptically polarized, or circularly polarized laser beam BM by λ/4, the laser beam BM output from the phase retardation plate QWP has elliptical polarization. Therefore, when the diffractive element DE is rotated by 0, 22.5, 45, 67.5, 90, 112.5, 135, 157.5, and 180 degrees with respect to the sixth direction DR6, the laser device LD outputs elliptically polarized light. That is, regardless of the rotation of the diffractive element DE, the laser device LD outputs elliptically polarized light.

As illustrated in FIG. 53, the laser device LD according to the one or more embodiments omits the prism DPM and instead rotates the diffractive element DE to prevent the polarization of the laser beam BM from being dependent on the rotation angle of the laser device LD (i.e., from being dependent on the rotation angle of the diffractive element DE). Therefore, even if the light source LS outputs the laser beam BM having linear polarization, the laser device LD may output only the laser beam BM having elliptical polarization despite the rotation of the laser device LD. Therefore, it may be possible to reduce or minimize a difference in the processing of the substrate SUB of the display panel 100 according to the polarization of the laser beam BM.

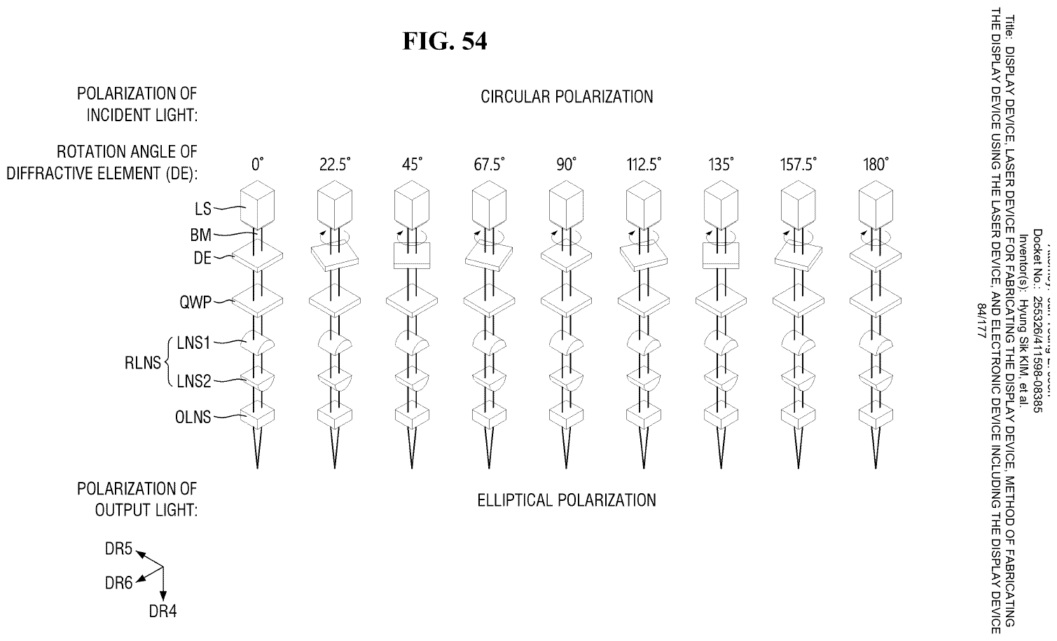

FIG. 54 is an example diagram illustrating the polarization of output light according to the rotation of the laser device LD in the one or more embodiments of FIG. 52.

Referring to FIG. 54, when the laser device LD rotates, the light source LS, the phase retardation plate QWP, the relay lens RLNS and the objective lens OLNS do not rotate, and only the diffractive element DE rotates. Therefore, regardless of the rotation of the laser device LD, the light source LS outputs a laser beam BM having circular polarization. The diffractive element DE may rotate about the rotation axis RAX (e.g., see FIG. 52) from 0 degrees to 360 degrees with respect to the sixth direction DR6 in a plane defined by the fourth direction DR4 and the sixth direction DR6.

Because the phase retardation plate QWP retards the phase of an incident linearly polarized, elliptically polarized, or circularly polarized laser beam BM by λ/4, the laser beam BM output from the phase retardation plate QWP has elliptical polarization. Therefore, when the diffractive element DE is rotated by 0, 22.5, 45, 67.5, 90, 112.5, 135, 157.5, and 180 degrees with respect to the sixth direction DR6, the laser device LD outputs elliptically polarized light. That is, regardless of the rotation of the diffractive element DE, the laser device LD outputs elliptically polarized light.

As illustrated in FIG. 54, the laser device LD according to the one or more embodiments omits the prism DPM and instead rotates the diffractive element DE to prevent the polarization of the laser beam BM from being dependent on the rotation angle of the laser device LD (i.e., being dependent on the rotation angle of the diffractive element DE). Therefore, even if the light source LS outputs the laser beam BM having circular polarization, the laser device LD may output only the laser beam BM having elliptical polarization despite the rotation of the laser device LD. Therefore, it may be possible to reduce or minimize a difference in the processing of the substrate SUB of the display panel 100 according to the polarization of the laser beam BM.

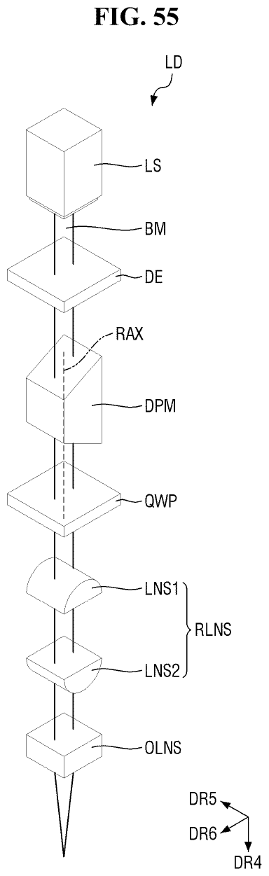

FIG. 55 is a perspective view of a laser device LD according to one or more embodiments of the present disclosure.

The one or more embodiments of the present disclosure of FIG. 55 are different from the one or more embodiments of FIG. 47 in that the laser device LD includes a phase retardation plate QWP disposed between a prism DPM and a relay lens RLNS. In FIG. 55, a redundant description of elements and features identical to those of the one or more embodiments of FIG. 47 may be omitted.

Referring to FIG. 55, the phase retardation plate QWP may be a λ/4 plate which retards the phase of incident light by λ/4. Because the phase retardation plate QWP retards the phase of a laser beam BM output from the prism DPM by λ/4, the laser device LD may output the laser beam BM having elliptical polarization.

The phase retardation plate QWP may be configured to be rotated clockwise or counterclockwise about a rotation axis RAX extending in the fourth direction DR4 by a rotational motor. The rotation axis RAX of the phase retardation plate QWP may pass through a center of the phase retardation plate QWP. The rotational motor may rotate the phase retardation plate QWP in the range of 0 degrees to 180 degrees about the rotation axis RAX extending in the fourth direction DR4. Various known suitable motors such as a hollow motor, a stepping motor, a servo motor, and/or a brushless motor may be used as the rotational motor.

A rotation angle of the prism DPM and a rotation angle of the phase retardation plate QWP may be substantially equal to each other. The prism DPM and the phase retardation plate QWP may be concurrently (e.g., simultaneously) rotated by one rotational motor. Alternatively, the prism DPM and the phase retardation plate QWP may be rotated by separate rotational motors, respectively.

When the prism DPM is a Dove prism having trapezoidal cross sections as illustrated in FIGS. 48A and 48B, a laser beam undergoes two refractions and one total reflection within the prism DPM. Therefore, a rotation angle of the laser beam may be twice the rotation angle of the prism DPM and the rotation angle of the phase retardation plate QWP.

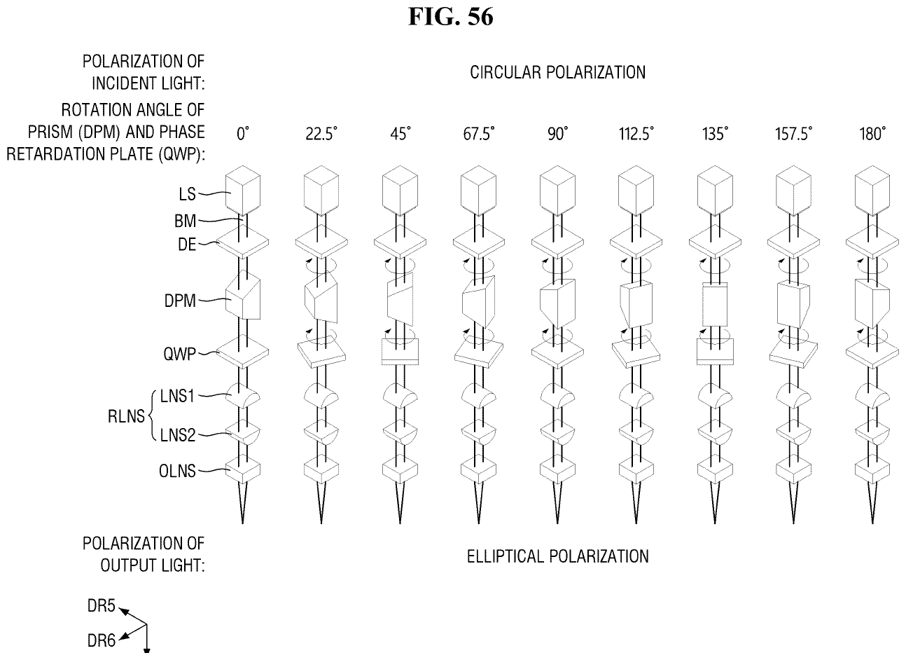

FIG. 56 is an example diagram illustrating the polarization of output light according to the rotation of the laser device LD in the one or more embodiments of FIG. 55.

Referring to FIG. 56, when the laser device LD rotates, a light source LS, a diffractive element DE, the relay lens RLNS and an objective lens OLNS do not rotate, and only the prism DPM and the phase retardation plate QWP rotate. Therefore, regardless of the rotation of the laser device LD, the light source LS outputs a laser beam BM having circular polarization.

The prism DPM and the phase retardation plate QWP may rotate about the rotation axis RAX (e.g., see FIG. 55) from 0 degrees to 180 degrees with respect to the sixth direction DR6 in a plane defined by the fourth direction DR4 and the sixth direction DR6. Because the rotation angle of a laser beam is twice the rotation angle of the prism DPM and the rotation angle of the phase retardation plate QWP, when the prism DPM and the phase retardation plate QWP rotate from 0 degrees to 180 degrees, the laser beam may rotate from 0 degrees to 360 degrees.

In FIG. 56, when the prism DPM is at 0 degrees with respect to the sixth direction DR6, the light source LS, the diffractive element DE, the prism DPM, the phase retardation plate QWP, the relay lens RLNS, and the objective lens OLNS are aligned in the sixth direction DR6. In addition, when the prism DPM and the phase retardation plate QWP are rotated 22.5 degrees clockwise with respect to the sixth direction DR6, the light source LS, the diffractive element DE, the relay lens RLNS and the objective lens OLNS are aligned in the sixth direction DR6, and the prism DPM and the phase retardation plate QWP are at 22.5 degrees clockwise with respect to the sixth direction DR6. In addition, although the prism DPM rotates and the phase retardation plate QWP rotate clockwise about the rotation axis RAX in FIG. 56, embodiments of the present disclosure are not limited thereto. That is, the prism DPM and the phase retardation plate QWP may also rotate counterclockwise about the rotation axis RAX.

Because the phase retardation plate QWP retards the phase of an incident linearly polarized, elliptically polarized, or circularly polarized laser beam BM by λ/4, the laser beam BM output from the phase retardation plate QWP has elliptical polarization. Therefore, when the prism DPM and the phase retardation plate QWP are rotated by 0, 22.5, 45, 67.5, 90, 112.5, 135, 157.5, and 180 degrees with respect to the sixth direction DR6, the laser device LD outputs elliptically polarized light. That is, regardless of the rotation of the diffractive element DE, the laser device LD outputs elliptically polarized light.

As illustrated in FIG. 56, because the phase retardation plate QWP disposed between the prism DPM and the relay lens RLNS retards the phase of a linearly polarized, elliptically polarized, or circularly polarized laser beam BM output from the prism DPM by λ/4, the laser beam BM output from the phase retardation plate QWP has elliptical polarization. Accordingly, the laser device LD may output only the laser beam BM having elliptical polarization despite the rotation of the laser device LD. Therefore, it may be possible to reduce or minimize a difference in the processing of the substrate SUB of the display panel 100 according to the polarization of the laser beam BM.

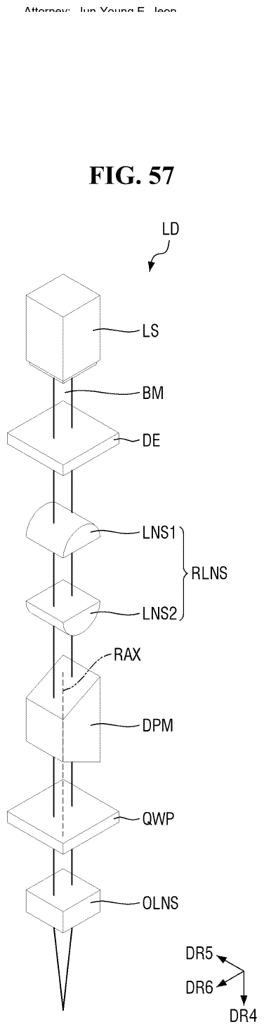

FIG. 57 is a perspective view of a laser device LD according to one or more embodiments of the present disclosure.

The one or more embodiments of FIG. 57 are different from the one or more embodiments of FIG. 55 only in that a relay lens RLNS is disposed between a diffractive element DE and a prism DPM. Therefore, a detailed description of FIG. 57 is omitted.

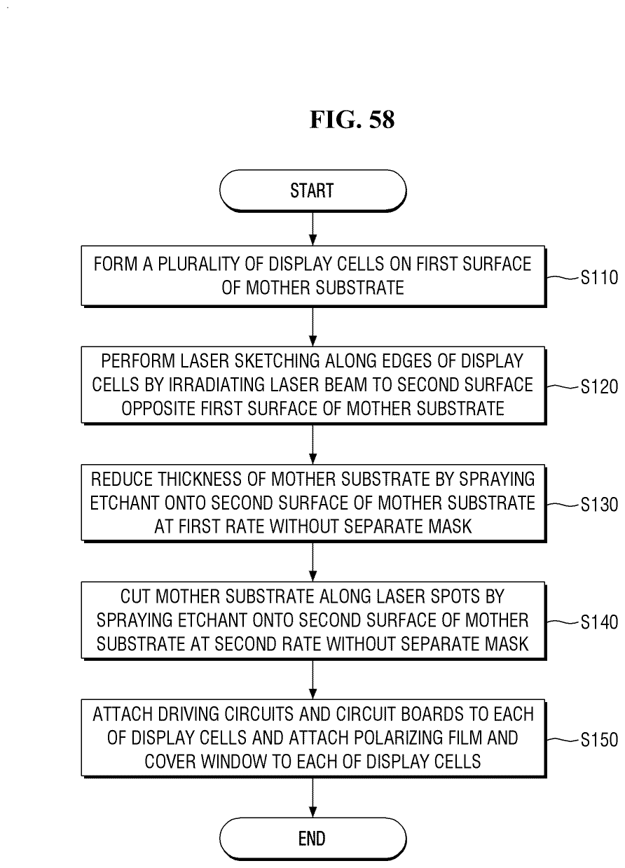

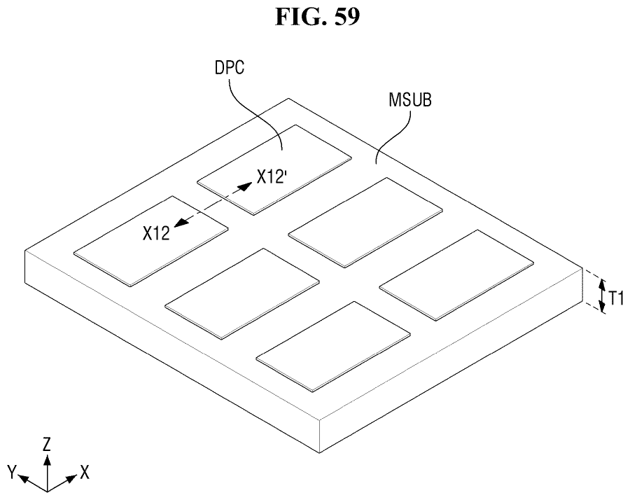

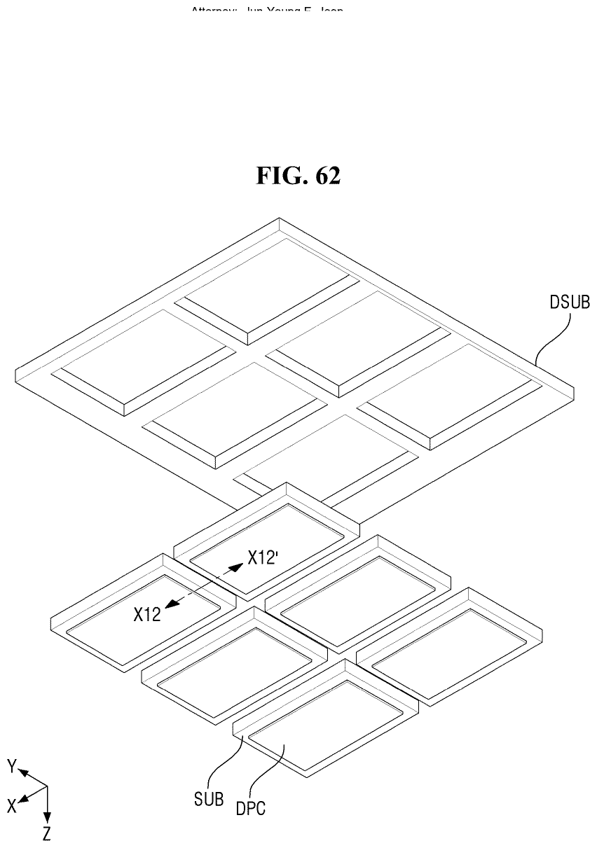

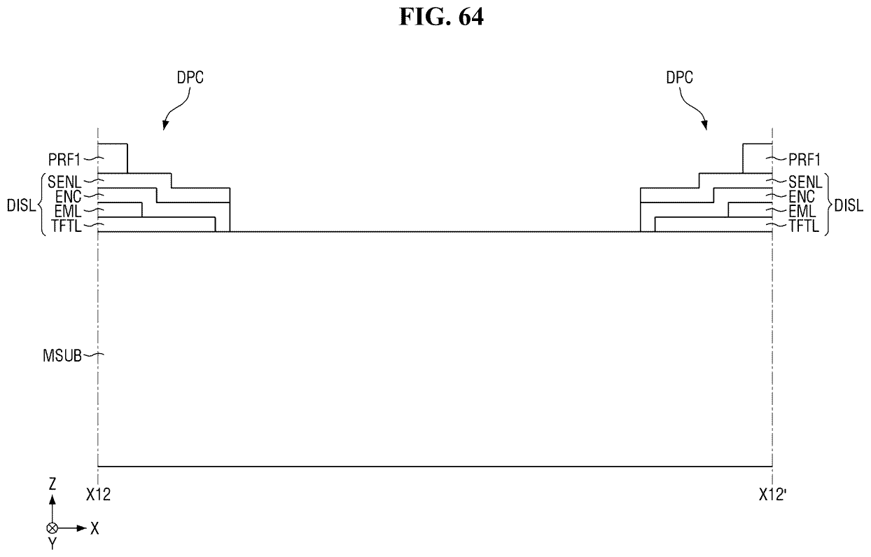

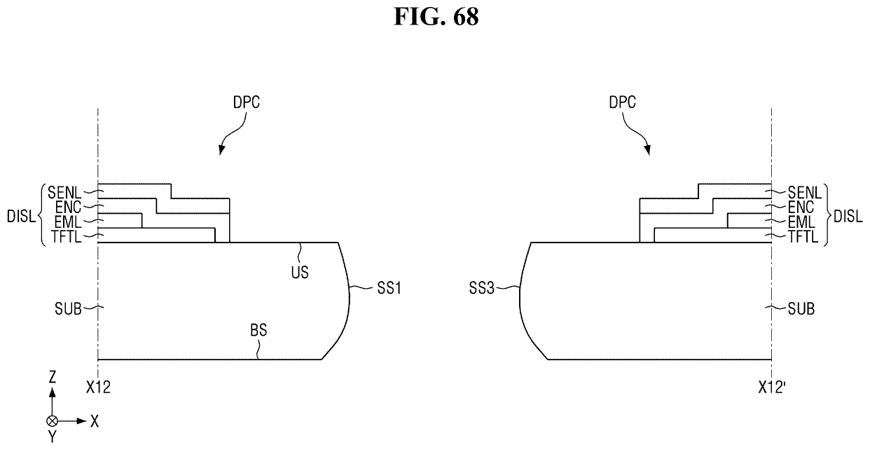

FIG. 58 is a flowchart illustrating a method of fabricating a display device according to one or more embodiments of the present disclosure. FIGS. 59 through 63 are perspective views for explaining the method of fabricating the display device according to one or more embodiments of the present disclosure. FIGS. 64 through 68 are cross-sectional views taken along the line X12-X12′ of FIGS. 59 through 62 to explain the method of fabricating the display device according to one or more embodiments of the present disclosure.

FIGS. 59 through 63 are perspective views of a mother substrate MSUB and a plurality of display cells DPC disposed on the mother substrate MSUB. FIGS. 64 through 68 illustrate an example of cross sections of the mother substrate MSUB and the display cells DPC taken along the line X12-X12′ of FIGS. 59 through 62. A method of fabricating the side surfaces SS1 through SS4 of the substrate SUB described with reference to FIGS. 25A through 25D will now be described in detail with reference to FIGS. 59 through 68.

First, as illustrated in FIGS. 59 and 64, a plurality of display cells DPC is formed on a first surface of the mother substrate MSUB (e.g., see operation S110 in FIG. 58).

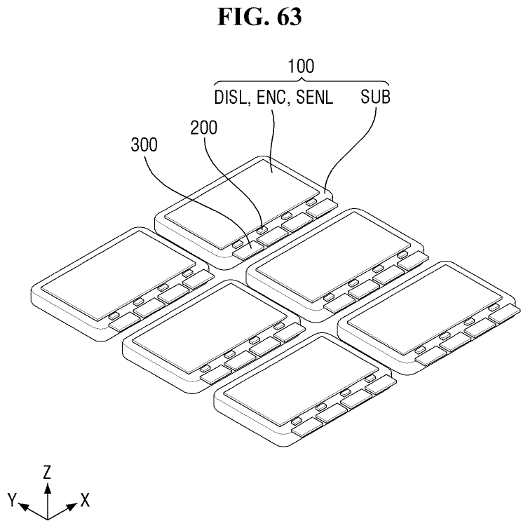

A display layer DISL of each of the display cells DPC is formed on the first surface of the mother substrate MSUB. The display layer DISL includes a thin-film transistor layer TFTL, a light emitting element layer EML, an encapsulation layer ENC, and a sensor electrode layer SENL. FIG. 63 indicates the encapsulation layer ENC and the sensor layer SENL separately from the display layer DISL, In various embodiments of the present disclosure, the encapsulation layer ENC and the sensor layer SENL may be described as a part of the display layer DISL or as separate layers without being limited to any particular description (e.g., also see FIG. 9A).

Next, a plurality of first protective films PRF1 is attached on the display cells DPC (e.g., see FIG. 64).

For example, a first protective film layer is attached to cover the display cells DPC and the mother substrate MSUB exposed between the display cells DPC. Then, a portion of the first protective film layer which is disposed on the mother substrate MSUB is removed so that a plurality of first protective films PRF1 is disposed on the display cells DPC, respectively. That is, portions remaining after the first protective film layer is partially removed may be the first protective films PRF1. Therefore, the first protective films PRF1 may be disposed on the display cells DPC, respectively. That is, the first protective films PRF1 may be disposed to correspond one-to-one to the display cells DPC.

The first protective films PRF1 may be buffer films for protecting the display cells DPC from external shock. The first protective films PRF1 may be made of a transparent material, for example.

Next, the display cells DPC are tested using a test device. After a probe is connected to a plurality of test pads provided in each of the display cells DPC, a lighting test of each of the display cells DPC may be performed.

If the lighting test is performed after the display cells DPC are separated from the mother substrate MSUB by a cutting process, an additional process is used to remove the test pads after the completion of the lighting test. On the other hand, if the lighting test is performed on the mother substrate MSUB, the test pads are removed when the display cells DPC are separated from the mother substrate MSUB through laser irradiation and etching. Therefore, if the lighting test is performed on the mother substrate MSUB, an additional process for removing the test pads is not used.

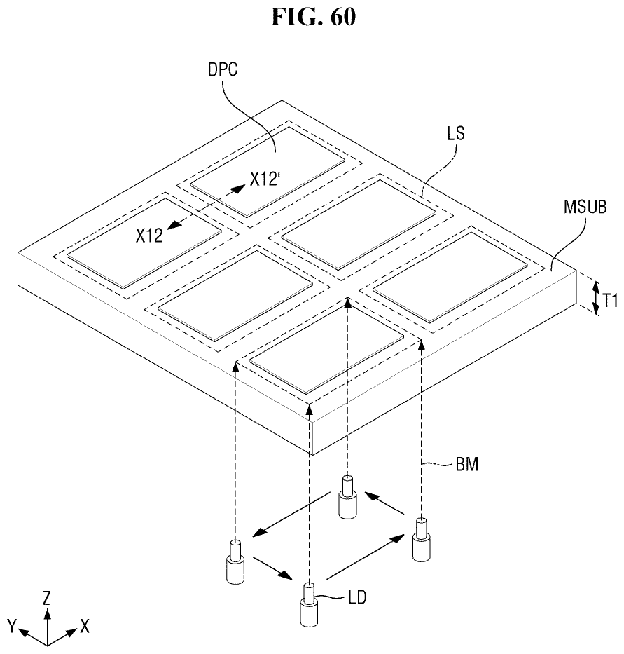

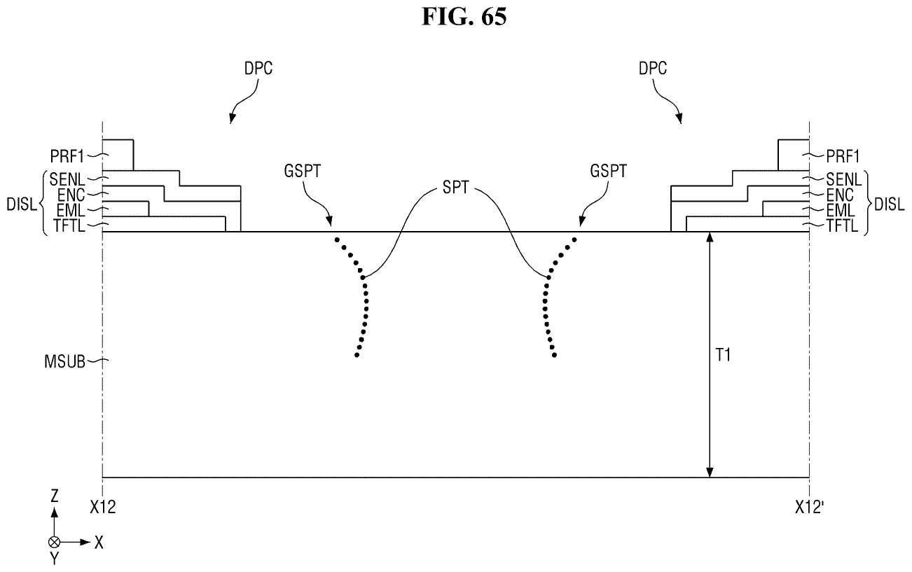

Second, as illustrated in FIGS. 60 and 65, laser sketching LS or laser modulation is performed along edges of the display cells DPC by irradiating a laser beam BM onto a second surface opposite the first surface of the mother substrate MSUB (e.g., see operation S120 in FIG. 58).

The laser beam BM may be output from the laser device LD according to any one of the embodiments described with reference to FIGS. 52 through 57.

Referring to FIGS. 60 and 65, the laser beam BM may be irradiated onto the second surface of the mother substrate MSUB. However, embodiments of the present disclosure are not limited thereto. The laser beam BM may also be irradiated onto the first surface of the mother substrate MSUB.

The laser sketching LS refers to forming a plurality of spot groups GSPT, each including a plurality of laser spots SPT. The laser sketching LS may be defined as forming a plurality of laser spots SPT along the edges (or peripheries) of the display cells DPC by irradiating the laser beam BM.

The laser device LD forms a first group of laser spots SPT by irradiating the laser beam BM, moves a suitable distance (e.g., a predetermined distance), and then forms a second group of laser spots SPT by irradiating the laser beam BM. That is, the laser device LD completes a laser sketch LS by forming a group of laser spots SPT by irradiating the laser beam BM after moving the laser device LD by every suitable distance (e.g., every predetermined distance). The suitable distance (e.g., the predetermined distance) may be a distance between the first group of laser spots SPT and the second group of laser spots SPT in a scanning direction of the laser device LD and may be in a range of about 2 μm to about 7 μm.

When a length of the mother substrate MSUB in the third direction (Z-axis direction) is about 500 μm, a length in which a plurality of laser spots SPT is arranged in the third direction (Z-axis direction) may be in a range of about 200 μm to 300 μm. That is, the length in which the laser spots SPT are arranged in the third direction (Z-axis direction) may be in a range of about 0.4 to about 0.6 of the length of the mother substrate MSUB in the third direction (Z-axis direction). The length of the mother substrate MSUB in the third direction (Z-axis direction or the thickness direction)) may be a thickness of the mother substrate MSUB.

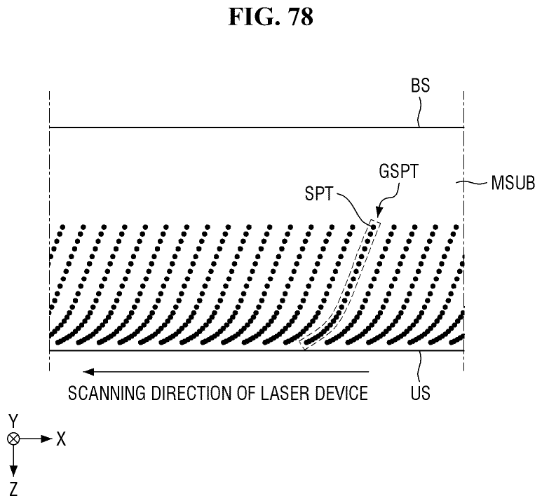

In a plane defined by the first direction (X-axis direction) and the third direction (Z-axis direction), the side surfaces SS1 through SS4 of the substrate SUB according to the one or more embodiments of FIGS. 25A through 25D have a curved shape. Therefore, the laser spots SPT may also be arranged in a curved shape in the plane defined by the first direction (X-axis direction) and the third direction (Z-axis direction). The arrangement of the laser spots SPT formed on the mother substrate MSUB by the laser device LD so that the side surfaces SS1 through SS4 of the substrate SUB according to the one or more embodiments of FIGS. 25A through 25D can have a curved shape in the plane defined by the first direction (X-axis direction) and the third direction (Z-axis direction) will be described in detail later with reference to FIG. 78.

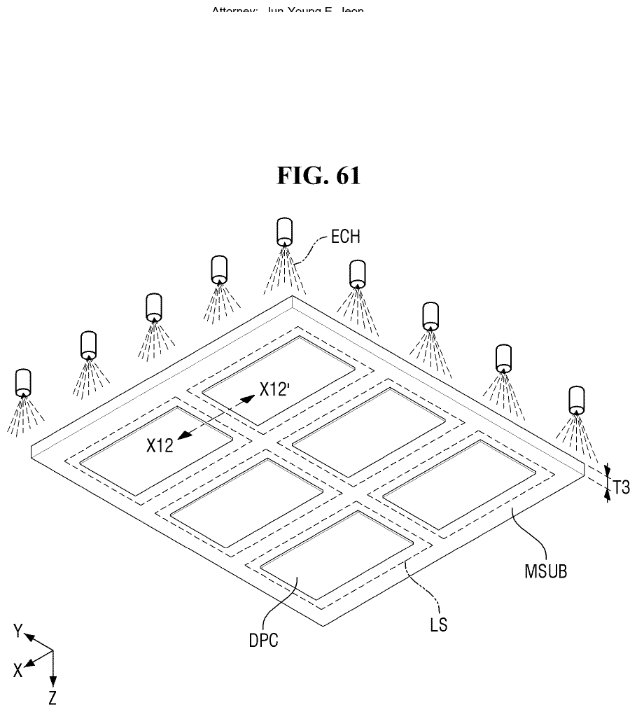

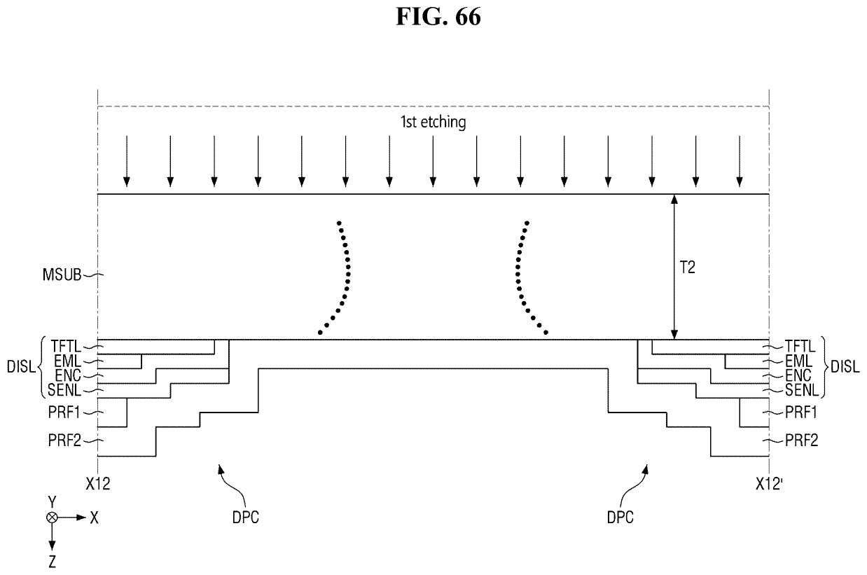

Third, as illustrated in FIGS. 61 and 66, the thickness of the mother substrate MSUB is reduced by spraying an etchant onto the second surface of the mother substrate MSUB at a first rate without a separate mask (e.g., see operation S130 in FIG. 58).

Before the etchant is sprayed onto the second surface of the mother substrate MSUB, a second protective film PRF2 is attached onto the first protective films PRF1.

The second protective film PRF2 may be attached onto the first protective films PRF1 and the first surface of the mother substrate MSUB exposed without being covered by the first protective films PRF1. The second protective film PRF2 may be an acid-proof film for protect the display cells DPC from the etchant during a process of etching the mother substrate MSUB.

When the etchant is sprayed onto the second surface of the mother substrate MSUB, the thickness of the mother substrate MSUB may be reduced from a first thickness T1 to a second thickness T2. Because the mother substrate MSUB is etched without a mask, isotropic etching in which all areas of the second surface of the mother substrate MSUB are uniformly etched may be performed.

The first rate may be in a range of about 7 μm/min to about 10 μm/min. That is, the thickness of the mother substrate MSUB may be reduced by about 7 μm to about 10 μm for about 1 minute by the etchant. When the thickness of the mother substrate MSUB is about 500 μm, the thickness of the mother substrate MSUB reduced by the first rate may be in a range of about 200 μm to about 250 μm, but embodiments of the present disclosure are not limited thereto.

Fourth, as illustrated in FIGS. 61, 62, 67 and 68, the mother substrate MSUB is cut along the laser spots SPT by spraying an etchant onto the second surface of the mother substrate MSUB at a second rate without a separate mask (e.g., see operation S140 in FIG. 58).

The laser spots SPT may include physical holes formed by the laser beam BM and areas located around the physical holes and having physical properties changed by the laser beam BM. Alternatively, the laser spots SPT may not include physical holes and may only be areas having physical properties changed by the laser beam BM. Therefore, an etch rate by the etchant in the laser spots SPT may be higher than an etch rate by the etchant in other areas of the mother substrate MSUB not irradiated with the laser beam.

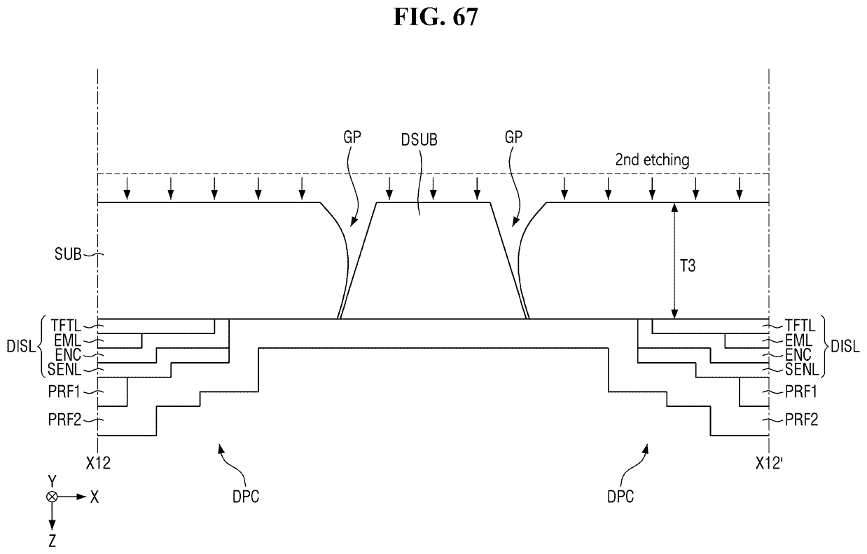

When the thickness of the mother substrate MSUB is reduced from the second thickness T2 to a third thickness T3 by the etchant and then the etchant penetrates into the laser spots SPT formed by the laser beam BM, there may be a difference in etch rate between an area where the laser spots SPT are formed and an area where the laser spots SPT are not formed. That is, the mother substrate MSUB may be anisotropically etched so that the etch rate in the area where the laser spots SPT are formed is faster than the etch rate in the area where the laser spots SPT are not formed. Accordingly, as illustrated in FIG. 67, a gap GP may be formed between a bottom surface BS of a substrate SUB separated from the mother substrate MSUB and a dummy substrate DSUB.

The second rate may be lower than the first rate. For example, the second rate may be, but is not limited to, in a range of about 1 μm/min to about 5 μm/min. That is, the thickness of the mother substrate MSUB may be reduced by about 1 μm to about 5 μm for about 1 minute by the etchant. The thickness of the mother substrate MSUB reduced by the second rate may be in a range of about 50 μm to about 100 μm, but embodiments of the present disclosure are not limited thereto.

As the second rate decreases by 1 μm/min, a length of the gap GP in the first direction (X-axis direction) may increase by 20 μm to 30 μm. The etch rate can be adjusted by changing the etchant, adjusting an etch temperature, and/or adjusting the concentration of an etch material.

When a thickness T3 of the substrate SUB in the third direction (Z-axis direction) is about 200 μm, a maximum length of the gap GP in the third direction (Z-axis direction) may be in a range of about 100 μm to about 150 μm. That is, the maximum length of the gap GP in the third direction (Z-axis direction) may be in a range of about 0.5 times to about 0.75 times the thickness T3 of the substrate SUB in the third direction (Z-axis direction).

The roughness of at least a portion of each of side surfaces SS1 and SS3 of the substrate SUB that is exposed to the gap GP and healed by the etchant may be smaller than the roughness of the other portion of each of the side surfaces SS1 and SS3 of the substrate SUB that is not exposed to the gap GP. As the second rate decreases, the gap GP increases. Accordingly, the area of at least a portion of each of the side surfaces SS1 and SS3 of the substrate SUB that is healed by the etchant may increase. Therefore, a length of at least a portion of each of the side surfaces SS1 and SS3 of the substrate SUB that is etched by the etchant may be in a range of about 0.5 times to about 0.8 times a total length of each of the side surfaces SS1 and SS3.

A distance between the lower surface BS of the substrate SUB and the dummy substrate DSUB is greater than a distance between an upper surface US of the substrate SUB and the dummy substrate DSUB. Therefore, the dummy substrate DSUB may be separated from the substrate SUB in a direction opposite to the third direction (Z-axis direction) in order to reduce, minimize, or prevent damage to the side surfaces of the substrate SUB by the dummy substrate DSUB when the dummy substrate DSUB is separated from the substrate SUB.

As described above, as the etchant penetrates into the laser spots SPT formed by the laser beam BM, the substrate SUB may be separated along the laser sketch LS. That is, the substrate SUB of each of the display cells DPC may be separated from the dummy substrate DSUB. In addition, after the etching process is completed, the second protective film PRF2 may be detached.

Fifth, as illustrated in FIG. 63, driving circuits 200 and circuit boards 300 are attached to each of the display cells DPC, and a polarizing film PF and a cover window CW are attached to each of the display cells DPC (e.g., see operation S150 in FIG. 58).

As described above, it is possible to reduce the thickness of the mother substrate MSUB and separate the substrate SUB of each of the display cells DPC from the mother substrate MSUB by using an etching process. Therefore, the efficiency of the fabrication process can be increased (or improved).

In addition, the laser device LD may output the laser beam BM such that a plurality of laser spots SPT is disposed along a curve in a plane defined by the first direction (X-axis direction) and the third direction (Z-axis direction). In this case, the side surfaces SS1 through SS4 of each of the display cells DPC may be etched into a curved shape by spraying an etchant. That is, because the side surfaces SS1 through SS4 of each of the display cells DPC can have a curved shape without a separate polishing process, the efficiency of the fabrication process can be increased (or improved).

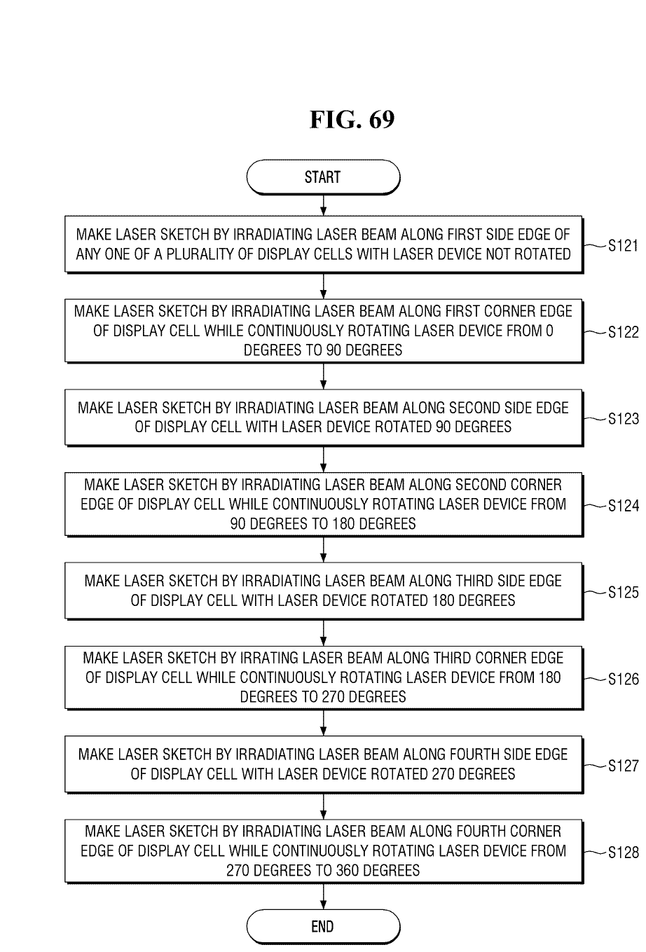

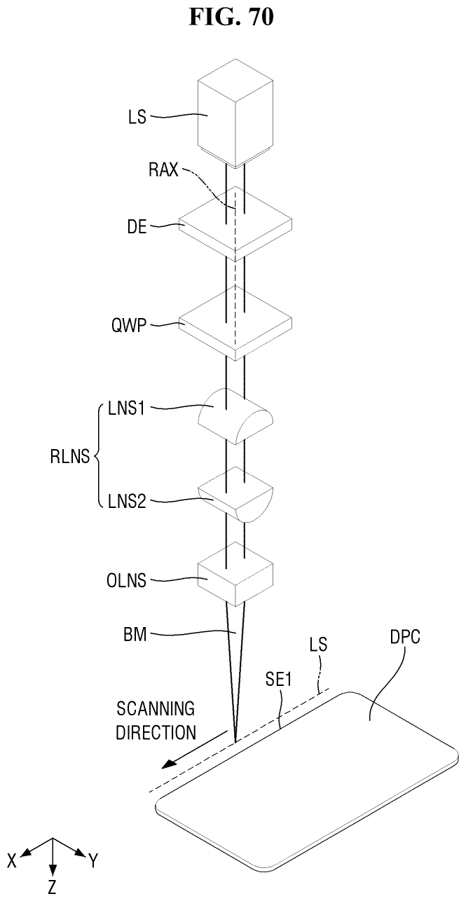

FIG. 69 is a flowchart illustrating the operation S120 of FIG. 58 in detail according to one or more embodiments of the present disclosure. FIGS. 70 through 77 are example views illustrating the rotation of the laser device LD according to the one or more embodiments of FIGS. 52 through 54 for a laser sketch surrounding the edges of a display cell DPC.

In FIGS. 70 through 77, a first side edge SE1 of the display cell DPC is a left edge of the display cell DPC, a second side edge SE2 of the display cell DPC is a lower edge of the display cell DPC, a third side edge SE3 of the display cell DPC is a right edge of the display cell DPC, and a fourth side edge SE4 of the display cell DPC is an upper edge of the display cell DPC. However, embodiments of the present disclosure are not limited thereto.

Laser sketching of the display cell DPC in the operation S120 of FIG. 58 will now be described in detail with reference to FIGS. 69 through 77.

First, as illustrated in FIG. 70, with the laser device LD not rotated, a laser beam BM is irradiated along the first side edge SE1 of any one of a plurality of display cells DPC to make a laser sketch LS (e.g., see operation S121 in FIG. 69).

The laser device LD scans the laser beam BM from an end of the first side edge SE1 of the display cell DPC to the other end. That is, a scanning direction of the laser device LD may be parallel to the first direction (X-axis direction). Because the laser device LD irradiates the laser beam BM while moving in a straight line, a scanning speed of the laser device LD may be in a range of 10 mm/sec to 500 mm/sec.

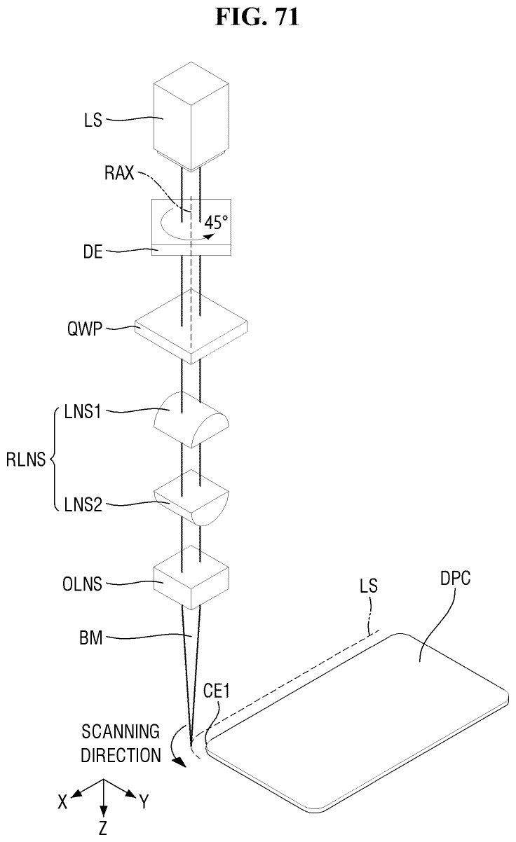

Second, as illustrated in FIG. 71, the laser device LD makes a laser sketch LS by irradiating the laser beam BM along a first corner edge CE1 of the display cell DPC while continuously rotating counterclockwise from 0 degrees to 90 degrees (e.g., see operation S122 in FIG. 69).

The first corner edge CE1 may be disposed between the first side edge SE1 and the second side edge SE2 of the display cell DPC. The laser device LD scans the laser beam BM at the first corner edge CE1 of the display cell DPC from the first side edge SE1 to the second side edge SE2. Because the laser device LD irradiates the laser beam BM while moving in a curve, the scanning speed of the laser device LD may be about 10 mm/sec to about 100 mm/sec. The scanning speed of the laser device LD at the first side edge SE1 of the display cell DPC may be faster than the scanning speed of the laser device LD at the first corner edge CE1 of the display cell DPC.

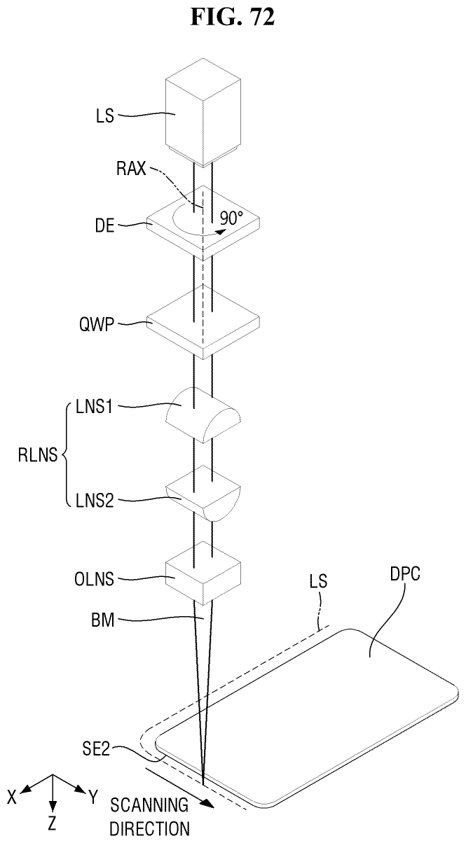

Third, as illustrated in FIG. 72, with the laser device LD rotated 90 degrees counterclockwise, the laser beam BM is irradiated along the second side edge SE2 of the display cell DPC to make a laser sketch LS (e.g., see operation S123 in FIG. 69).

The laser device LD outputs the laser beam BM from an end of the second side edge SE2 of the display cell DPC to the other end. That is, the scanning direction of the laser device LD may be parallel to the second direction (Y-axis direction). Because the scanning direction of the laser device LD is a straight line, the scanning speed of the laser device LD may be in a range of about 10 mm/sec to about 500 mm/sec.

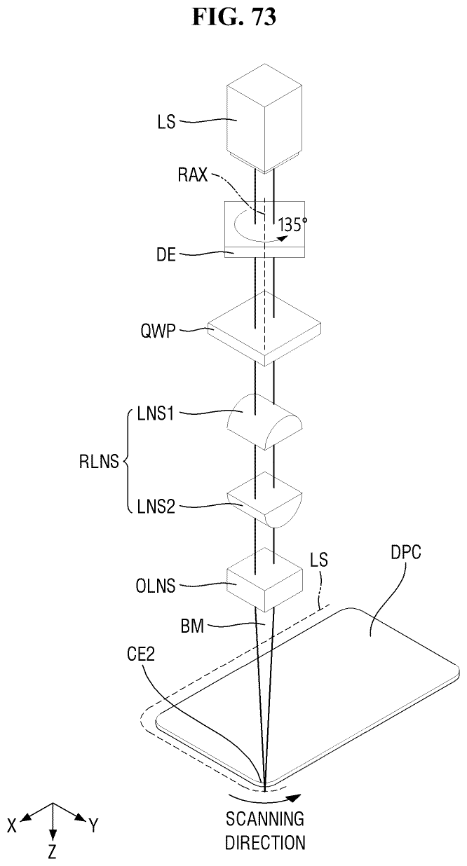

Fourth, as illustrated in FIG. 73, the laser device LD makes a laser sketch LS by irradiating the laser beam BM along a second corner edge CE2 of the display cell DPC while continuously rotating counterclockwise from 90 degrees to 180 degrees (e.g., see operation S124 in FIG. 69).

The second corner edge CE2 may be disposed between the second side edge SE2 and the third side edge SE3 of the display cell DPC. The laser device LD scans the laser beam BM at the second corner edge CE2 of the display cell DPC from the second side edge SE2 toward the third side edge SE3. Because the scanning direction of the laser device LD is a curve, the scanning speed of the laser device LD may be in a range of about 10 mm/sec to about 100 mm/sec. The scanning speed of the laser device LD at the second side edge SE2 of the display cell DPC may be faster than the scanning speed of the laser device LD at the second corner edge CE2 of the display cell DPC.

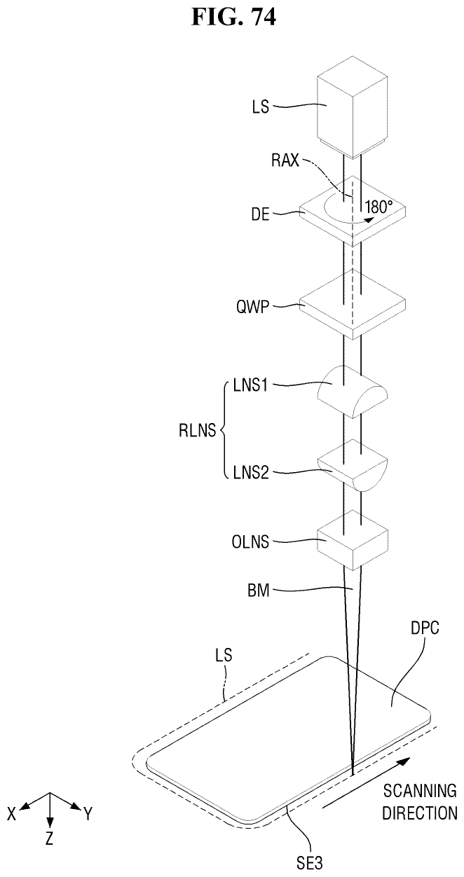

Fifth, as illustrated in FIG. 74, with the laser device LD rotated 180 degrees counterclockwise, the laser beam BM is irradiated along the third side edge SE3 of the display cell DPC to make a sketch LS (e.g., see operation S125 in FIG. 69).

The laser device LD outputs the laser beam BM from an end of the third side edge SE3 of the display cell DPC to the other end. That is, the scanning direction of the laser device LD may be parallel to the first direction (X-axis direction). Because the scanning direction of the laser device LD is a straight line, the scanning speed of the laser device LD may be in a range of about 10 mm/sec to about 500 mm/sec.

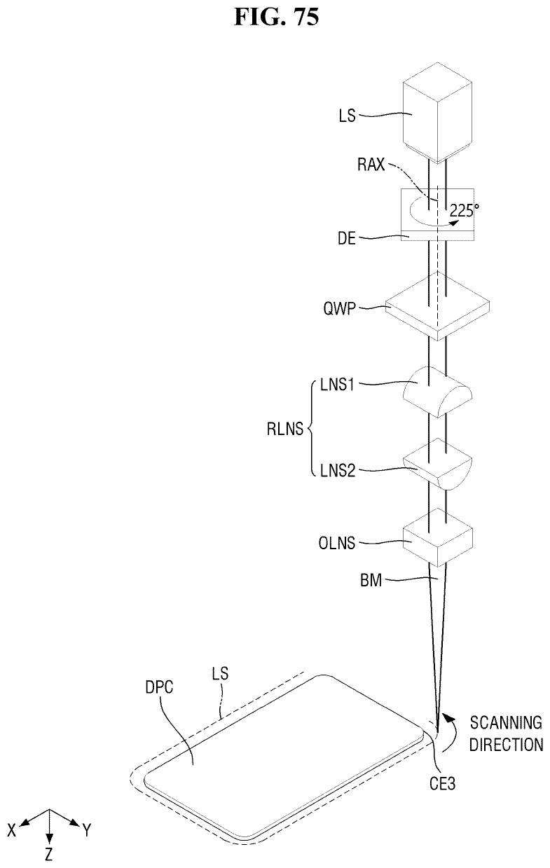

Sixth, as illustrated in FIG. 75, the laser device LD makes a laser sketch LS by irradiating the laser beam BM along a third corner edge CE3 of the display cell DPC while continuously rotating counterclockwise from 180 degrees to 270 degrees (e.g., see operation S126 in FIG. 69).

The third corner edge CE3 may be disposed between the third side edge SE3 and the fourth side edge SE4 of the display cell DPC. The laser device LD scans the laser beam BM at the third corner edge CE3 of the display cell DPC from the third side edge SE3 toward the fourth side edge SE4. Because the scanning direction of the laser device LD is a curve, the scanning speed of the laser device LD may be in a range of about 10 mm/sec to about 100 mm/sec. The scanning speed of the laser device LD at the third side edge SE3 of the display cell DPC may be faster than the scanning speed of the laser device LD at the third corner edge CE3 of the display cell DPC.

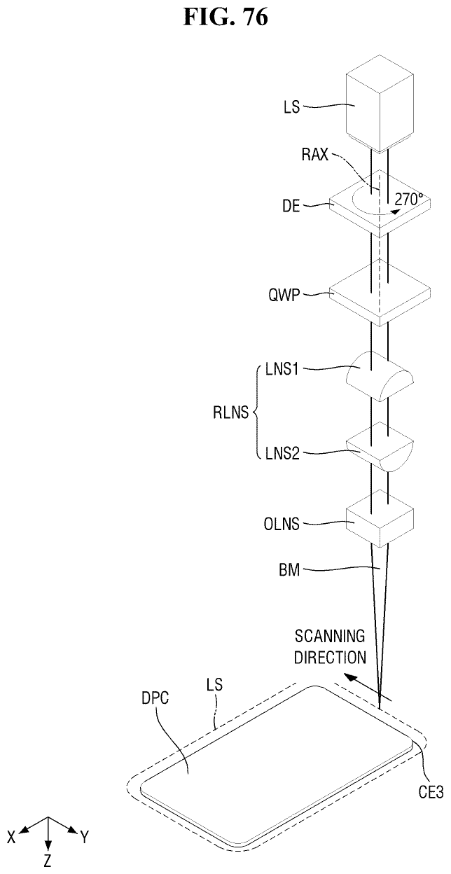

Seventh, as illustrated in FIG. 76, with the laser device LD rotated 270 degrees counterclockwise, the laser beam BM is irradiated along the fourth side edge SE4 of the display cell DPC to make a laser sketch LS (e.g., see operation S127 in FIG. 69).

The laser device LD outputs the laser beam BM from an end of the fourth side edge SE4 of the display cell DPC to the other end. That is, the scanning direction of the laser device LD may be parallel to the second direction (Y-axis direction). Because the scanning direction of the laser device LD is a straight line, the scanning speed of the laser device LD may be in a range of about 10 mm/sec to about 500 mm/sec.

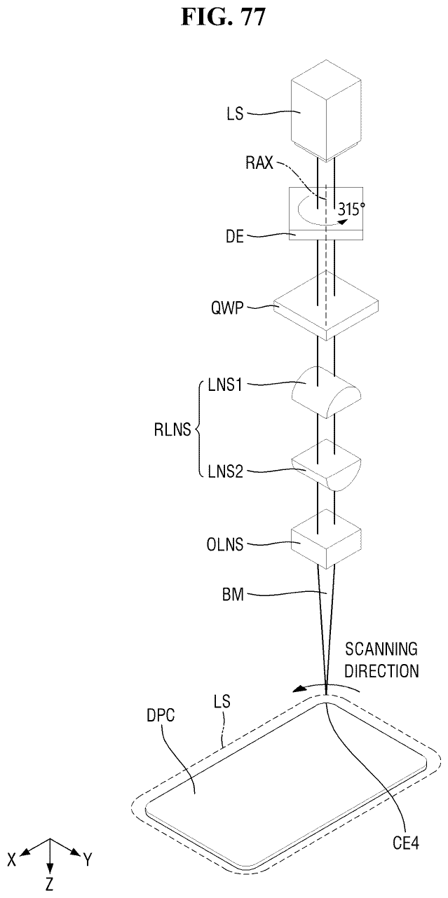

Eighth, as illustrated in FIG. 77, the laser device LD makes a laser sketch LS by irradiating the laser beam BM along a fourth corner edge CE4 of the display cell DPC while continuously rotating counterclockwise from 270 degrees to 360 degrees (e.g., see operation S128 in FIG. 69).

The fourth corner edge CE4 may be disposed between the fourth side edge SE4 and the first side edge SE1 of the display cell DPC. The laser device LD scans the laser beam BM at the fourth corner edge CE4 of the display cell DPC from the fourth side edge SE4 toward the first side edge SE1. Because the scanning direction of the laser device LD is a curve, the scanning speed of the laser device LD may be in a range of about 10 mm/sec to about 100 mm/sec. The scanning speed of the laser device LD at the fourth side edge SE4 of the display cell DPC may be faster than the scanning speed of the laser device LD at the fourth corner edge CE4 of the display cell DPC.

As illustrated in FIGS. 53 and 54, the phase retardation plate QWP retards the phase of an incident linearly polarized, elliptically polarized, or circularly polarized laser beam BM by λ/4. Therefore, the laser beam BM output from the phase retardation plate QWP has elliptical polarization. Accordingly, the laser device LD outputs elliptically polarized light regardless of the rotation of the laser device LD.

As illustrated in FIGS. 69 through 77, a laser sketch is made by irradiating the elliptically polarized laser beam BM in a counterclockwise direction along the first side edge SE1, the first corner edge CE1, the second side edge SE2, the second corner edge CE2, the third side edge SE3, the third corner edge CE3, the fourth side edge ES4, and the fourth corner edge CE4 of the display cell DPC. Therefore, it may be possible to reduce, minimize, or prevent a difference in processability of the substrate SUB of a display panel 100. Accordingly, it may be possible to reduce, minimize, or prevent a difference in the shapes, for example, radii of curvature of the side surfaces SS1 through SS4 of the substrate SUB of the display panel 100 or a difference in mechanical strength according to the positions of the side surfaces SS1 through SS4 of the substrate SUB. Therefore, the side surfaces SS1 through SS4 of the substrate SUB of the display panel 100 can have uniform quality against external impacts.

FIG. 78 is a side view illustrating the arrangement of laser spots SPT formed along the scanning direction of a laser beam. FIG. 78 illustrates laser spots SPT formed along the third side edge SE3 of the display cell DPC by the laser beam BM of the laser device LD.

Referring to FIG. 78, a plurality of spot groups GSPT is disposed at suitable intervals (e.g., predetermined intervals) in the first direction (X-axis direction). Each of the spot groups GSPT may include the same number of laser spots SPT. A distance between spot groups GSPT neighboring each other in the first direction (X-axis direction) among the spot groups GSPT may be in a range of about 2 μm to about 7 μm. The spot groups GPST neighboring each other in the first direction (X-axis direction) may overlap each other in the third direction (Z-axis direction). A distance between adjacent laser spots SPT in each of the spot groups GSPT may be in a range of about 3 μm to about 20 μm.

In each of the spot groups GSPT, the laser spots SPT may be arranged in the first direction (X-axis direction) from a lower surface BS toward an upper surface US of the mother substrate MSUB. That is, among the laser spots SPT in each of the spot groups GSPT, a laser spot SPT disposed closest to the upper surface US of the mother substrate MSUB may protrude in the first direction (X-axis direction) more than a laser spot SPT disposed closest to the lower surface BS of the mother substrate MSUB.

The laser device LD is placed above the lower surface BS of the mother substrate MSUB and forms a plurality of spot groups GSPT by radiating a laser beam BM to the mother substrate MSUB. Therefore, when a laser spot SPT disposed closest to the upper surface of the mother substrate MSUB among the laser spots SPT in each of the spot groups GSPT is formed, if the laser spots SPT of a neighboring spot group GSPT are already formed, the laser spot SPT disposed closest to the upper surface US of the mother substrate MSUB may be interfered with by the laser spots SPT of the neighboring spot group GSPT. Therefore, the scanning direction of the laser device LD may be determined by taking this into account. For example, as illustrated in FIG. 78, the scanning direction of the laser device LD may be set to the first direction (X-axis direction) so that the laser spot SPT disposed closest to the upper surface of the mother substrate MSUB in a spot group GSPT currently being formed by the laser device LD does not overlap, in the third direction (Z-axis direction), the laser spots SPT of each of other spot groups GSPT which have already been formed.

Alternatively, among the laser spots SPT in each of the spot groups GSPT, a laser spot SPT disposed closest to the upper surface of the mother substrate MSUB may protrude in a direction opposite to the first direction (X-axis direction) more than a laser spot SPT disposed closest to the lower surface of the mother substrate MSUB. In this case, the scanning direction of the laser device LD may be set to the direction opposite to the first direction (X-axis direction) so that the laser spot SPT disposed closest to the upper surface of the mother substrate MSUB in a spot group GSPT currently being formed by the laser device LD does not overlap, in the third direction (Z-axis direction), the laser spots SPT in each of other spot groups GSPT which have already been formed.

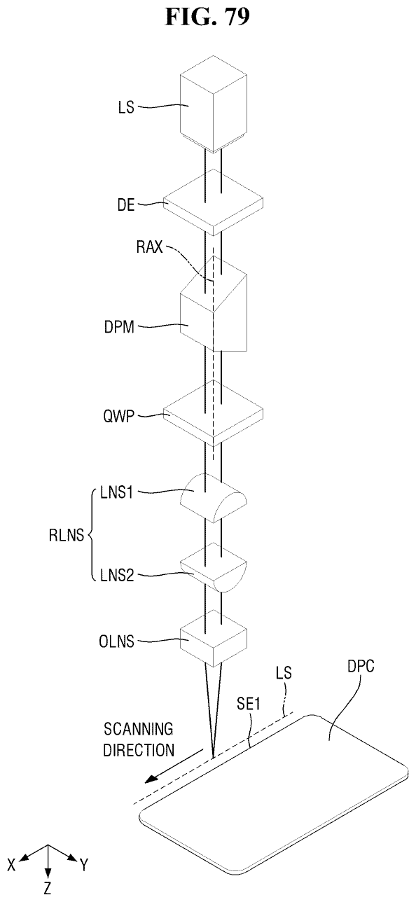

FIGS. 79 through 86 are example views illustrating the rotation of the laser device LD according to the one or more embodiments of FIGS. 55 and 56 for a laser sketch surrounding the edges of a display cell DPC.

In FIGS. 79 through 86, a first side edge SE1 of the display cell DPC is a left edge of the display cell DPC, a second side edge SE2 of the display cell DPC is a lower edge of the display cell DPC, a third side edge SE3 of the display cell DPC is a right edge of the display cell DPC, and a fourth side edge SE4 of the display cell DPC is an upper edge of the display cell DPC. However, embodiments of the present disclosure are not limited thereto.

First, as illustrated in FIG. 79, with the laser device LD not rotated, a laser beam BM is irradiated along the first side edge SE1 of any one of a plurality of display cells DPC to make a laser sketch LS.

The laser device LD scans the laser beam BM from an end of the first side edge SE1 of the display cell DPC to the other end. That is, a scanning direction of the laser device LD may be parallel to the first direction (X-axis direction). Because the laser device LD irradiates the laser beam BM while moving in a straight line, a scanning speed of the laser device LD may be in a range of about 10 mm/sec to about 500 mm/sec.

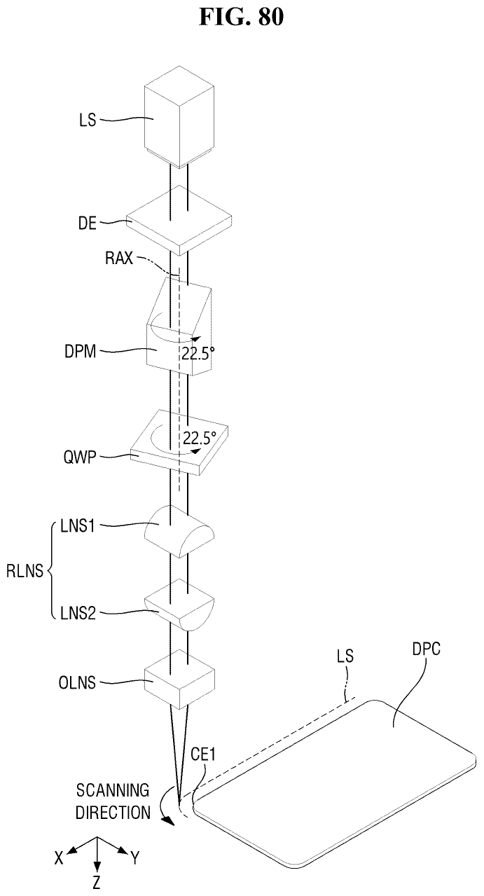

Second, as illustrated in FIG. 80, the laser device LD makes a laser sketch LS by irradiating the laser beam BM along a first corner edge CE1 of the display cell DPC while continuously rotating counterclockwise from 0 degrees to 45 degrees. In FIG. 80, the laser device LD is rotated 22.5 degrees counterclockwise.

When the prism DPM is a Dove prism having trapezoidal cross sections as illustrated in FIGS. 48A and 48B, the rotation angle of the laser beam BM is twice the rotation angle of the prism DPM. Therefore, when the prism DPM continuously rotates from 0 degrees to 45 degrees, the laser beam BM continuously rotates from 0 degrees to 90 degrees.

The first corner edge CE1 may be disposed between the first side edge SE1 and the second side edge SE2 of the display cell DPC. The laser device LD scans the laser beam BM at the first corner edge CE1 of the display cell DPC from the first side edge SE1 to the second side edge SE2. Because the laser device LD irradiates the laser beam BM while moving in a curve, the scanning speed of the laser device LD may be in a range of about 10 mm/sec to about 100 mm/sec. The scanning speed of the laser device LD at the first side edge SE1 of the display cell DPC may be faster than the scanning speed of the laser device LD at the first corner edge CE1 of the display cell DPC.

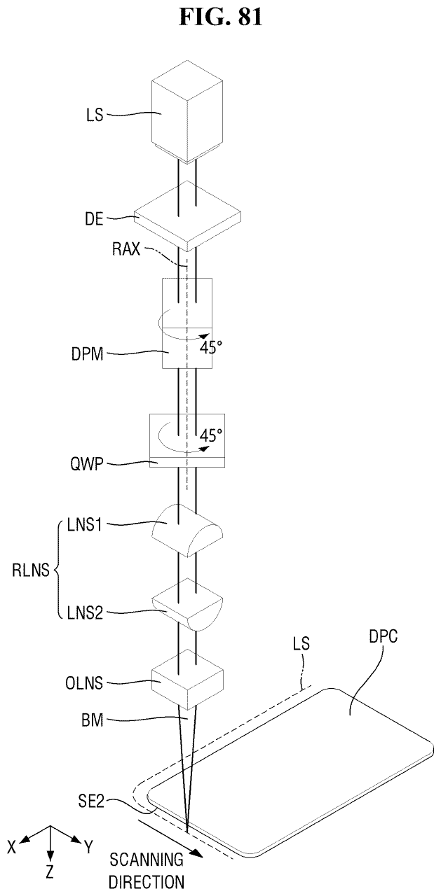

Third, as illustrated in FIG. 81, with the laser device LD rotated 45 degrees counterclockwise, the laser beam BM is irradiated along the second side edge SE2 of the display cell DPC to make a laser sketch LS.

When the prism DPM is a Dove prism having trapezoidal cross sections as illustrated in FIGS. 48A and 48B, the rotation angle of the laser beam BM is twice the rotation angle of the prism DPM. Therefore, when the prism DPM is rotated 45 degrees, the laser beam BM may be rotated 90 degrees.

The laser device LD outputs the laser beam BM from an end of the second side edge SE2 of the display cell DPC to the other end. That is, the scanning direction of the laser device LD may be parallel to the second direction (Y-axis direction). Because the scanning direction of the laser device LD is a straight line, the scanning speed of the laser device LD may be in a range of about 10 mm/sec to about 500 mm/sec.

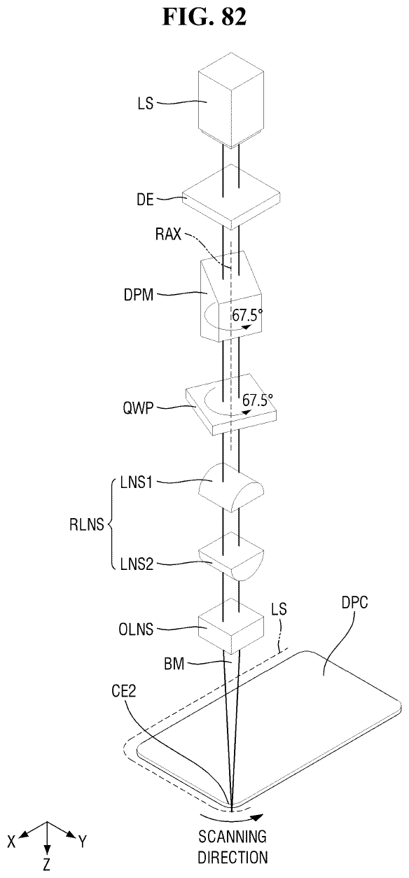

Fourth, as illustrated in FIG. 82, the laser device LD makes a laser sketch LS by irradiating the laser beam BM along a second corner edge CE2 of the display cell DPC while continuously rotating counterclockwise from 45 degrees to 90 degrees. In FIG. 82, the laser device LD is rotated 67.5 degrees counterclockwise.

When the prism DPM is a Dove prism having trapezoidal cross sections as illustrated in FIGS. 48A and 48B, the rotation angle of the laser beam BM is twice the rotation angle of the prism DPM. Therefore, when the prism DPM continuously rotates from 45 degrees to 90 degrees, the laser beam BM continuously rotates from 90 degrees to 180 degrees.

The second corner edge CE2 may be disposed between the second side edge SE2 and the third side edge SE3 of the display cell DPC. The laser device LD scans the laser beam BM at the second corner edge CE2 of the display cell DPC from the second side edge SE2 toward the third side edge SE3. Because the scanning direction of the laser device LD is a curve, the scanning speed of the laser device LD may be in a range of about 10 mm/sec to about 100 mm/sec. The scanning speed of the laser device LD at the second side edge SE2 of the display cell DPC may be faster than the scanning speed of the laser device LD at the second corner edge CE2 of the display cell DPC.

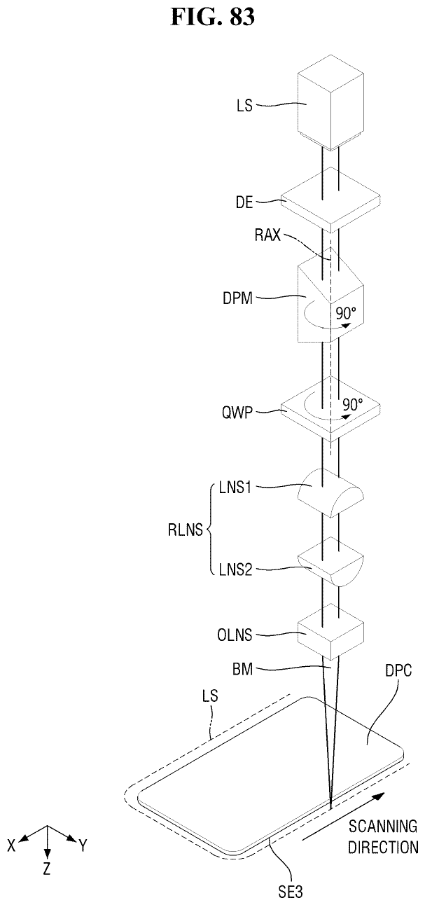

Fifth, as illustrated in FIG. 83, with the laser device LD rotated 90 degrees counterclockwise, the laser beam BM is irradiated along the third side edge SE3 of the display cell DPC to make a sketch LS.

When the prism DPM is a Dove prism having trapezoidal cross sections as illustrated in FIGS. 48A and 48B, the rotation angle of the laser beam BM is twice the rotation angle of the prism DPM. Therefore, when the prism DPM is rotated 90 degrees, the laser beam BM may be rotated 180 degrees.

The laser device LD outputs the laser beam BM from an end of the third side edge SE3 of the display cell DPC to the other end. That is, the scanning direction of the laser device LD may be parallel to the first direction (X-axis direction). Because the scanning direction of the laser device LD is a straight line, the scanning speed of the laser device LD may be in a range of about 10 mm/sec to about 500 mm/sec.

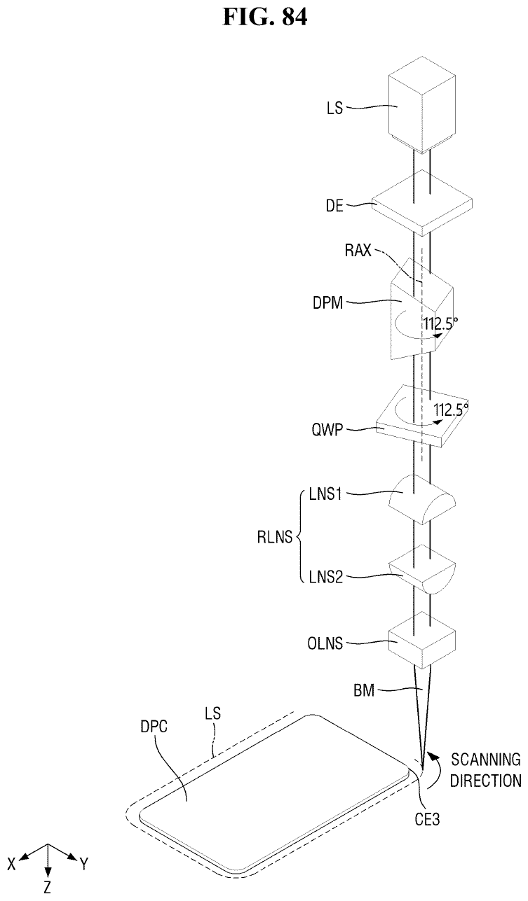

Sixth, as illustrated in FIG. 84, the laser device LD makes a laser sketch LS by irradiating the laser beam BM along a third corner edge CE3 of the display cell DPC while continuously rotating counterclockwise from 90 degrees to 135 degrees. In FIG. 84, the laser device LD is rotated 112.5 degrees counterclockwise.

When the prism DPM is a Dove prism having trapezoidal cross sections as illustrated in FIGS. 48A and 48B, the rotation angle of the laser beam BM is twice the rotation angle of the prism DPM. Therefore, when the prism DPM continuously rotates from 90 degrees to 135 degrees, the laser beam BM continuously rotates from 180 degrees to 270 degrees.

The third corner edge CE3 may be disposed between the third side edge SE3 and the fourth side edge SE4 of the display cell DPC. The laser device LD scans the laser beam BM at the third corner edge CE3 of the display cell DPC from the third side edge SE3 toward the fourth side edge SE4. Because the scanning direction of the laser device LD is a curve, the scanning speed of the laser device LD may be in a range of about 10 mm/sec to about 100 mm/sec. The scanning speed of the laser device LD at the third side edge SE3 of the display cell DPC may be faster than the scanning speed of the laser device LD at the third corner edge CE3 of the display cell DPC.

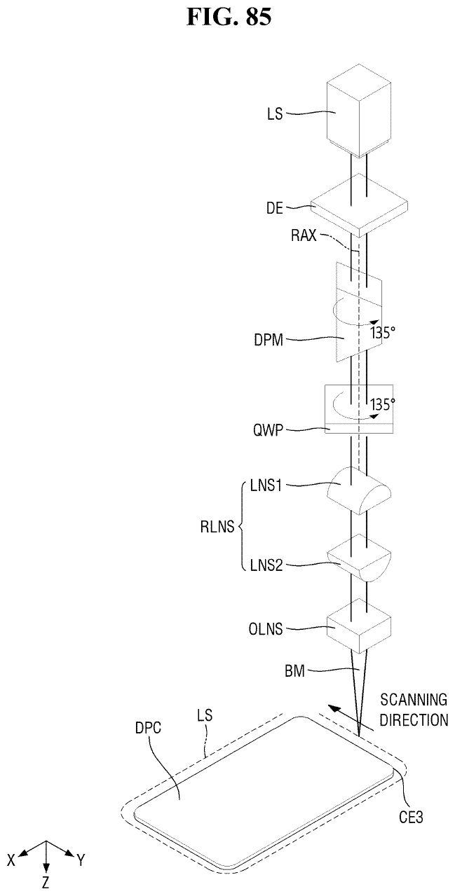

Seventh, as illustrated in FIG. 85, with the laser device LD rotated 135 degrees counterclockwise, the laser beam BM is irradiated along the fourth side edge SE4 of the display cell DPC to make a laser sketch LS.

When the prism DPM is a Dove prism having trapezoidal cross sections as illustrated in FIGS. 48A and 48B, the rotation angle of the laser beam BM is twice the rotation angle of the prism DPM. Therefore, when the prism DPM is rotated 135 degrees, the laser beam BM may be rotated 270 degrees.

The laser device LD outputs the laser beam BM from an end of the fourth side edge SE4 of the display cell DPC to the other end. That is, the scanning direction of the laser device LD may be parallel to the second direction (Y-axis direction). Because the scanning direction of the laser device LD is a straight line, the scanning speed of the laser device LD may be in a range of about 10 mm/sec to about 500 mm/sec.

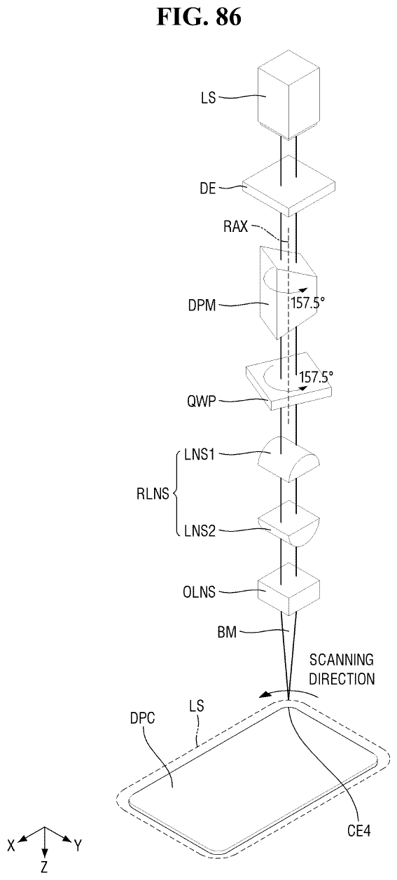

Eighth, as illustrated in FIG. 86, the laser device LD makes a laser sketch LS by irradiating the laser beam BM along a fourth corner edge CE4 of the display cell DPC while continuously rotating counterclockwise from 135 degrees to 180 degrees.

When the prism DPM is a Dove prism having trapezoidal cross sections as illustrated in FIGS. 48A and 48B, the rotation angle of the laser beam BM is twice the rotation angle of the prism DPM. Therefore, when the prism DPM continuously rotates from 135 degrees to 180 degrees, the laser beam BM continuously rotates from 270 degrees to 360 degrees.

The fourth corner edge CE4 may be disposed between the fourth side edge SE4 and the first side edge SE1 of the display cell DPC. The laser device LD scans the laser beam BM at the fourth corner edge CE4 of the display cell DPC from the fourth side edge SE4 toward the first side edge SE1. Because the scanning direction of the laser device LD is a curve, the scanning speed of the laser device LD may be 10 to 100 mm/sec. The scanning speed of the laser device LD at the fourth side edge SE4 of the display cell DPC may be faster than the scanning speed of the laser device LD at the fourth corner edge CE4 of the display cell DPC.

As illustrated in FIG. 56, the phase retardation plate QWP retards the phase of an incident linearly polarized, elliptically polarized, or circularly polarized laser beam BM by λ/4. Therefore, the laser beam BM output from the phase retardation plate QWP has elliptical polarization. Accordingly, the laser device LD outputs elliptically polarized light regardless of the rotation of the laser device LD.

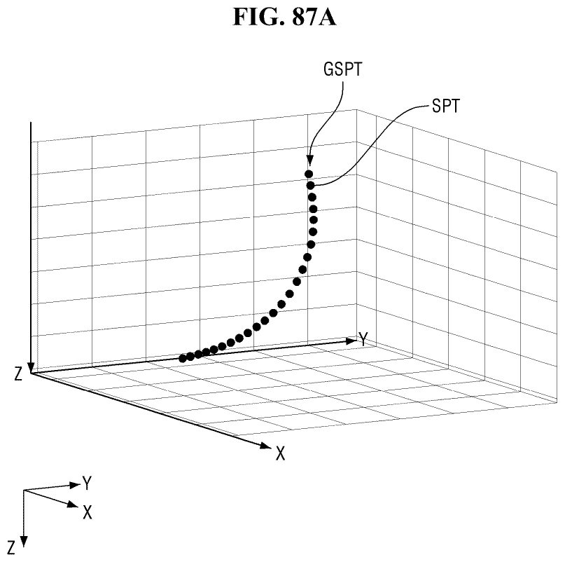

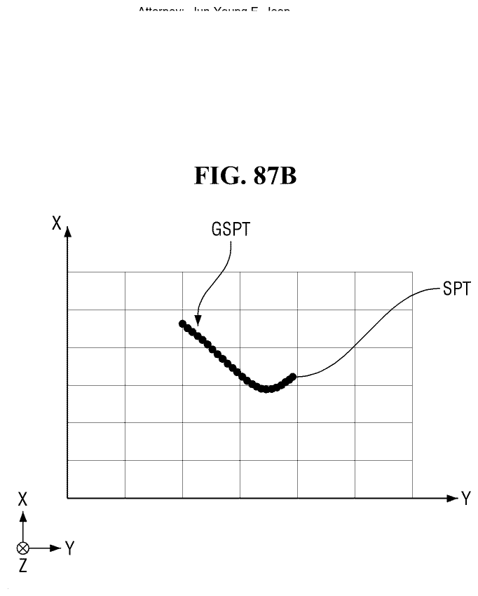

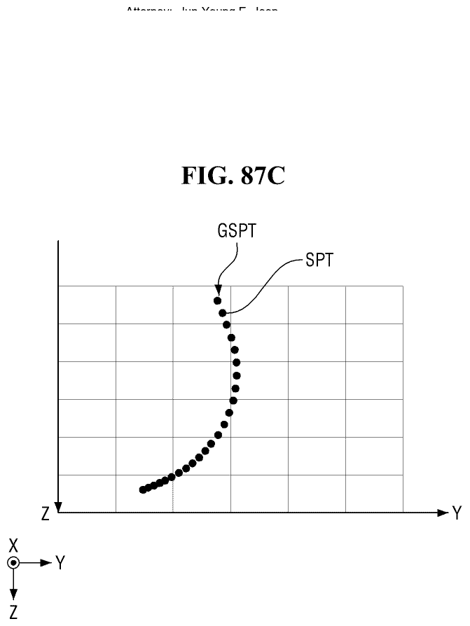

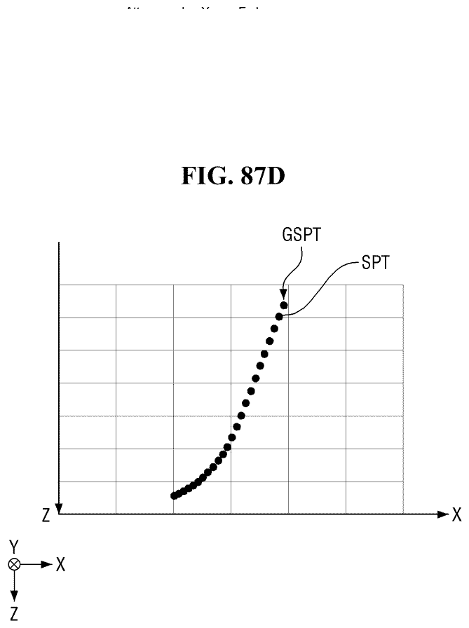

As illustrated in FIGS. 76 through 86, a laser sketch is made by irradiating the elliptically polarized laser beam BM in the counterclockwise direction along the first side edge SE1, the first corner edge CE1, the second side edge SE2, the second corner edge CE2, the third side edge SE3, the third corner edge CE3, the fourth side edge ES4, and the fourth corner edge CE4 of the display cell DPC. Therefore, it may be possible to reduce, minimize, or prevent a difference in processability of the substrate SUB of a display panel 100. Accordingly, it may be possible to reduce, minimize, or prevent a difference in the shapes, for example, radii of curvature of the side surfaces SS1 through SS4 of the substrate SUB of the display panel 100 or a difference in mechanical strength according to the positions of the side surfaces SS1 through SS4 of the substrate SUB. Therefore, the side surfaces SS1 through SS4 of the substrate SUB of the display panel 100 can have uniform quality against external impacts. FIGS. 87A through 87D are example diagrams illustrating the arrangement of laser spots irradiated by a laser device according to one or more embodiments in an XYZ plane, an XY plane, an XZ plane, and a YZ plane. FIGS. 87A through 87D illustrate a plurality of laser spots SPT of a spot group GSPT, which is formed along the third side edge SE3 of a display cell DPC as illustrated in FIGS. 74 and 83, in the XYZ plane, the XY plane, the XZ plane, and the YZ plane.

Referring to FIGS. 87A through 87D, a length in the first direction (X-axis direction) of the laser spots SPT arranged in the spot group GPST may be in a range of 0 μm to about 150 μm. A length in the second direction (Y-axis direction) of the laser spots SPT arranged in the spot group GPST may be in a range of 0 μm to about 150 μm. The laser spots SPT arranged in the spot group GPST may not overlap each other in the third direction (Z-axis direction). Therefore, any one of the length in the first direction (X-axis direction) and the length in the second direction (Y-axis direction) of the laser spots SPT arranged in the spot group GPST may not be 0 μm.

When the length of the mother substrate MSUB in the third direction (Z-axis direction) is about 500 μm, a length in which the laser spots SPT of the spot group GPST are arranged in the third direction (Z-axis direction) may be in a range of about 200 μm to about 300 μm. That is, the length in which the laser spots SPT of the spot group GPST are arranged in the third direction (Z-axis direction) may be in a range of about 0.4 to about 0.6 of the length of the mother substrate MSUB in the third direction (Z-axis direction). The length of the mother substrate MSUB in the third direction (Z-axis direction) may be the thickness of the mother substrate MSUB.

The arrangement forms of the laser spots SPT of the spot group GSPT in the XYZ plane, the XY plane, the XZ plane, and the YZ plane illustrated in FIGS. 87A through 87D are only an example, and it should be noted that embodiments of the present disclosure are not limited thereto.

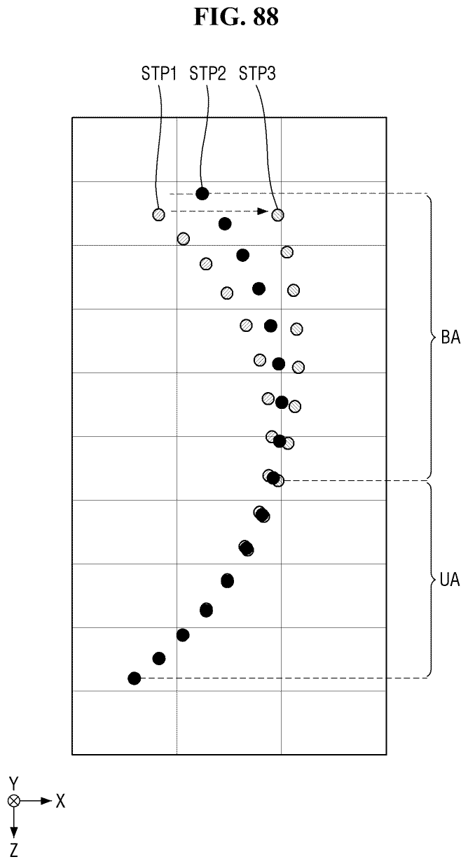

FIG. 88 is an example diagram for explaining the arrangement of laser spots irradiated by a laser device according to one or more embodiments of the present disclosure in the XZ plane in detail.

Referring to FIG. 88, the XZ plane may be defined as a two-dimensional (2D) plane defined by the first direction (X-axis direction) and the third direction (Z-axis direction). FIG. 88 illustrates first laser spots SPT1 having a first radius of curvature, second laser spots SPT2 having a second radius of curvature, and third laser spots SPT3 having a third radius of curvature. The first radius of curvature may be smaller than the second radius of curvature, and the second radius of curvature may be smaller than the third radius of curvature.

In a first area UA, the laser spots SPT may be arranged like the first laser spots SPT1 having the first radius of curvature. In a second area BA, the laser spots SPT may be arranged like the second laser spots SPT2 having the second radius of curvature or the third laser spots SPT3 having the third radius of curvature. The first area UA may be an area corresponding to half of the laser spots SPT that are adjacent to the upper surface US of the mother substrate MSUB, and the second area BA may be an area corresponding to half of the laser spots SPT that are adjacent to the lower surface BS of the mother substrate MSUB.

As the radius of curvature of the laser spots SPT arranged in the second area BA increases, the area of a gap GP between a substrate SUB and a dummy substrate DSUB formed by etching may decrease.

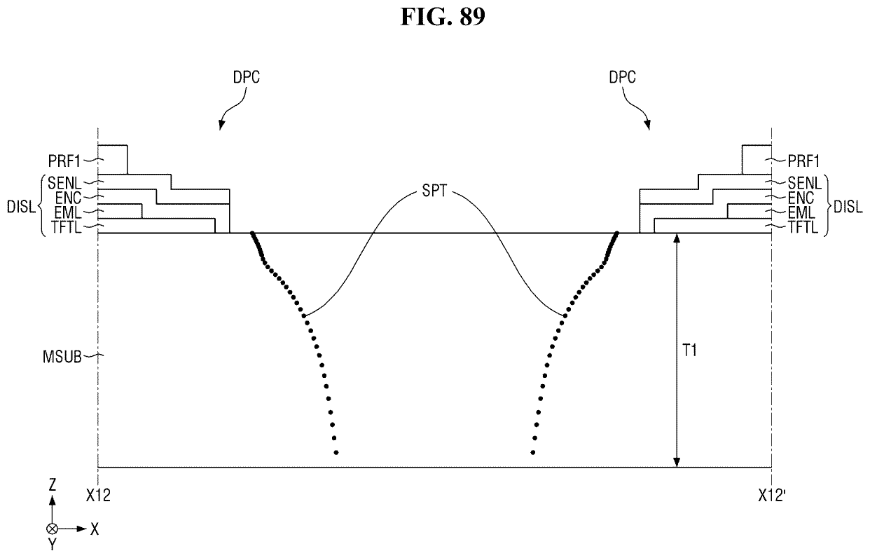

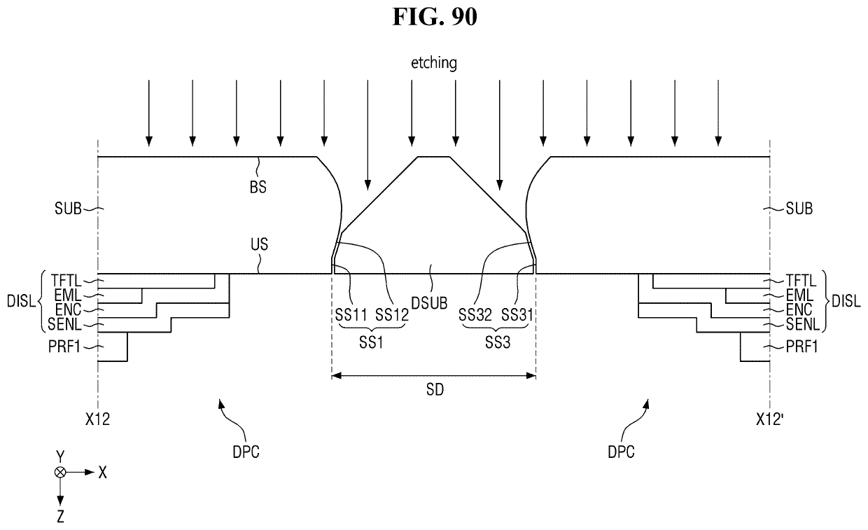

Because the radius of curvature of the laser spots SPT arranged in the first area UA is different from the radius of curvature of the laser spots SPT arranged in the second area BA, the arrangement of the laser spots SPT in the first area UA and the arrangement of the laser spots SPT in the second area BA may be asymmetrical. FIGS. 89 and 90 are cross-sectional views taken along the line X12-X12′ of FIGS. 59 through 62 to explain a method of fabricating a display device according to one or more embodiments of the present disclosure. FIGS. 89 and 90 illustrate an example of cross sections taken along the line X12-X12′ of FIGS. 59 through 62 in operations S120 through S140.

Cross-sectional shapes of side surfaces SS1 through SS4 of a substrate SUB depend on the arrangement form of laser spots SPT. A method of fabricating the side surfaces SS1 through SS4 of the substrate SUB according to the one or more embodiments of FIGS. 26A through 26D will now be described with reference to FIGS. 89 and 90.

As illustrated in FIG. 89, a length in which a plurality of laser spots SPT is arranged in the third direction (Z-axis direction) may be substantially equal to a length of a mother substrate MSUB in the third direction (Z-axis direction). For example, if the length of the mother substrate MSUB in the third direction (Z-axis direction) is about 500 μm, the length in which the laser spots SPT are arranged in the third direction (Z-axis direction) may be about 500 μm.

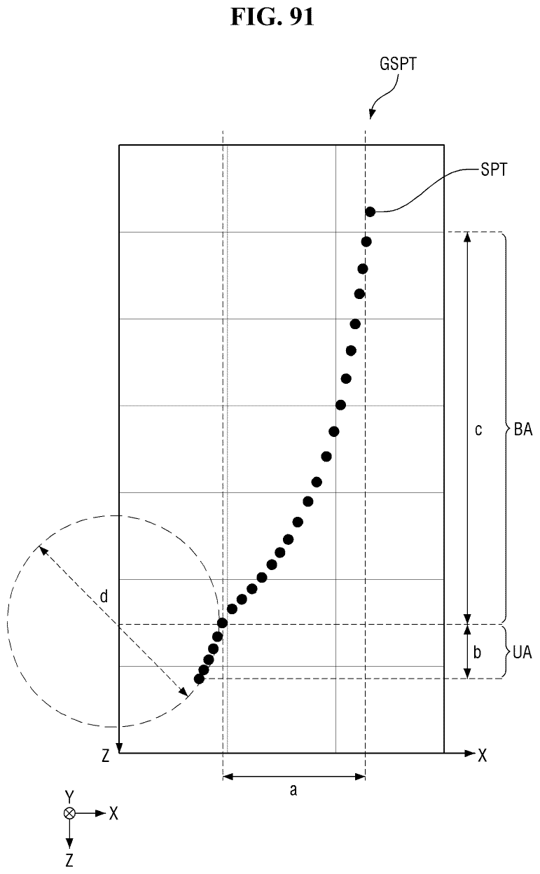

In a plane defined by the first direction (X-axis direction) and the third direction (Z-axis direction), each of the side surfaces SS1 through SS4 of the substrate SUB according to the one or more embodiments of FIGS. 26A through 26D has two sub-side surfaces. To this end, the laser spots SPT may be divided and arranged in two areas having two radii of curvature in the plane defined by the first direction (X-axis direction) and the third direction (Z-axis direction). The arrangement of the laser spots SPT formed on the mother substrate MSUB by a laser device LD so that each of the side surfaces SS1 through SS4 of the substrate SUB according to the one or more embodiments of FIGS. 26A through 26D can have two sub-side surfaces in the plane defined by the first direction (X-axis direction) and the third direction (Z-axis direction) will be described in detail later with reference to FIG. 91.

As illustrated in FIG. 90, because the length in which the laser spots SPT are arranged in the third direction (Z-axis direction) is substantially equal to the length of the mother substrate MSUB in the third direction (Z-axis direction), an etchant can penetrate directly into the laser spots SPT. Therefore, the area of a gap GP between a lower surface BS of the substrate SUB separated from the mother substrate MSUB and a dummy substrate DSUB may be larger than that of the one or more embodiments of FIG. 67. Accordingly, the area of at least a portion of each of the side surfaces SS1 and SS3 of the substrate SUB that is healed by the etchant may also be larger than that of the one or more embodiments of FIG. 67. In addition, due to the increased gap GP, damage to the side surfaces of the substrate SUB by the dummy substrate DSUB when the dummy substrate DSUB is separated from the substrate SUB may be reduced compared to the one or more embodiments of FIG. 67.

FIG. 91 is an example diagram illustrating laser spots irradiated by a laser device according to one or more embodiments of the present disclosure. FIG. 91 illustrates laser spots SPT in an XZ plane formed to form a first side surface SS1 of the substrate SUB in FIGS. 89 and 90.

Referring to FIG. 91, the XZ plane may be defined as a 2D plane defined by the first direction (X-axis direction) and the third direction (Z-axis direction). In the XZ plane, the laser spots SPT include a first area UA having a first radius of curvature and a second area BA having a second radius of curvature. The second radius of curvature may be smaller than the first radius of curvature. The first area UA may be an upper area of the mother substrate MSUB, and the second area BA may be a lower area of the mother substrate MSUB.

A distance between the laser spots SPT in the second area BA may be greater than a distance between the laser spots SPT in the first area UA. The distance between the laser spots SPT in the second area BA may increase from bottom to top. The distance between the laser spots SPT in the first area UA and the second area BA may be in a range of about 3 μm to about 20 μm.

A length a of the second area BA in the first direction (X-axis direction) may be in a range of about 80 μm to about 150 μm. A length b of the first area UA in the third direction (Z-axis direction) may be smaller than a length c of the second area BA in the third direction (Z-axis direction). For example, when the thickness of the mother substrate MSUB is about 500 μm, the length b of the first area UA in the third direction (Z-axis direction) may be in a range of about 30 μm to about 70 μm, and the length c of the second area BA in the third direction (Z-axis direction) may be in a range of about 430 μm to about 470 μm. The second radius of curvature d may be in a range of about 200 μm to about 600 μm.

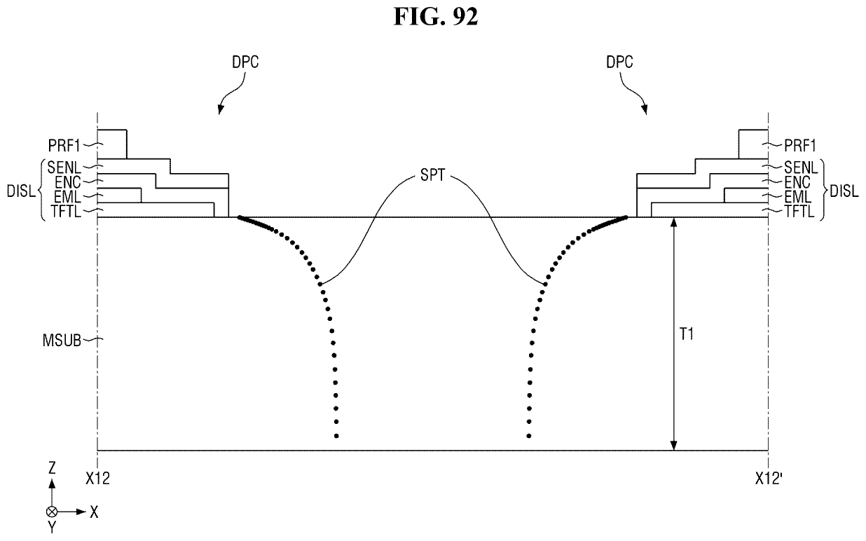

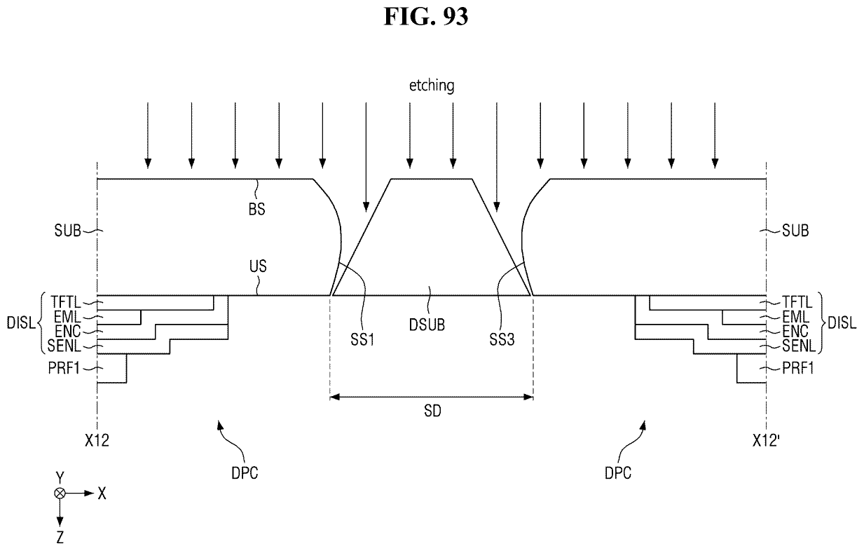

As illustrated in FIGS. 89 through 91, the laser spots SPT in the first area UA and the laser spots SPT in the second area BA not only have different radii of curvature, but also are arranged at different intervals. Therefore, a first sub-side surface SS11 having a different curved or flat shape from a second sub-side surface SS12 may be formed in the first side surface SS1. In addition, when the distance between the laser spots SPT in the first area UA is small, the energy density irradiated to the mother substrate MSUB is high. Therefore, even if an etchant does not penetrate up to an upper surface US of the mother substrate MSUB, the first side surface SS1 of the substrate SUB and the dummy substrate DSUB can be separated. Alternatively, the first side surface SS1 of the substrate SUB and the dummy substrate DSUB can be separated by only a small amount of etchant penetrating into the laser spots SPT. Therefore, it may be possible to reduce, minimize, or prevent the invasion of the etchant into a display layer DISL of a display cell DPC disposed on an upper surface of the substrate SUB. FIGS. 92 and 93 are cross-sectional views taken along the line X12-X12′ of FIGS. 59 through 62 to explain a method of fabricating a display device according to one or more embodiments of the present disclosure. FIGS. 92 and 93 illustrate an example of cross sections taken along the line X12-X12′ of FIGS. 59 through 62 in operations S120 through S140.

Cross-sectional shapes of side surfaces SS1 through SS4 of a substrate SUB depend on the arrangement form of laser spots SPT. A method of fabricating the side surfaces SS1 through SS4 of the substrate SUB according to the one or more embodiments of FIGS. 25A through 25D will now be described with reference to FIGS. 92 and 93.

As illustrated in FIG. 92, a length in which a plurality of laser spots SPT is arranged in the third direction (Z-axis direction) may be substantially equal to a length of a mother substrate MSUB in the third direction (Z-axis direction). For example, if the length of the mother substrate MSUB in the third direction (Z-axis direction) is about 500 μm, the length in which the laser spots SPT are arranged in the third direction (Z-axis direction) may be about 500 μm.

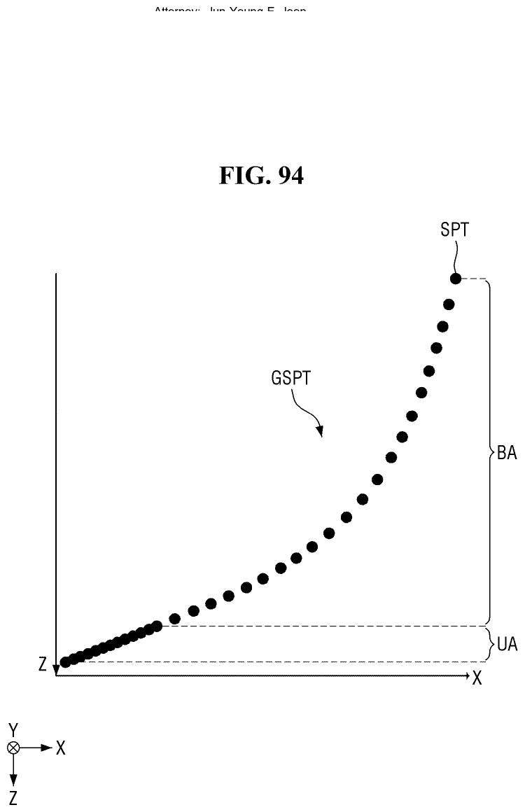

In a plane defined by the first direction (X-axis direction) and the third direction (Z-axis direction), the side surfaces SS1 through SS4 of the substrate SUB according to the one or more embodiments of FIGS. 25A through 25D have a curved shape. Therefore, the laser spots SPT may be arranged in a curved shape in the plane defined by the first direction (X-axis direction) and the third direction (Z-axis direction). The arrangement of the laser spots SPT formed on the mother substrate MSUB by a laser device LD so that the side surfaces SS1 through SS4 of the substrate SUB according to the one or more embodiments of FIGS. 25A through 25D can have a curved shape in the plane defined by the first direction (X-axis direction) and the third direction (Z-axis direction) will be described in detail later with reference to FIG. 94.

As illustrated in FIG. 93, because the length in which the laser spots SPT are arranged in the third direction (Z-axis direction) is substantially equal to the length of the mother substrate MSUB in the third direction (Z-axis direction), an etchant can penetrate directly into the laser spots SPT. Therefore, the area of a gap GP between a lower surface BS of the substrate SUB separated from the mother substrate MSUB and a dummy substrate DSUB may be larger than that of the one or more embodiments of FIG. 67. Accordingly, the area of at least a portion of each of the side surfaces SS1 and SS3 of the substrate SUB that is healed by the etchant may also be larger than that of the one or more embodiments of FIG. 67. In addition, due to the increased gap GP, damage to the side surfaces of the substrate SUB by the dummy substrate DSUB when the dummy substrate DSUB is separated from the substrate SUB may be reduced compared to the one or more embodiments of FIG. 67.

FIG. 94 is an example diagram illustrating laser spots irradiated by a laser device according to one or more embodiments of the present disclosure. FIG. 94 illustrates laser spots SPT in an XZ plane formed to form a first side surface SS1 of the substrate SUB in FIGS. 92 and 93.

Referring to FIG. 94, the XZ plane may be defined as a 2D plane defined by the first direction (X-axis direction) and the third direction (Z-axis direction). In the XZ plane, the laser spots SPT include a first area UA having a smaller distance than a suitable distance (e.g., a predetermined distance) and a second area BA having a greater distance than the suitable distance (e.g., the predetermined distance). That is, the distance between laser spots SPT in the first area UA may be smaller than the distance between laser spots SPT in the second area BA. The first area UA may be an upper area of the mother substrate MSUB, and the second area BA may be a lower area of the mother substrate MSUB.

As illustrated in FIGS. 92 through 94, when the distance between the laser spots SPT in the first area UA is small, the energy density irradiated to the mother substrate MSUB is high. Therefore, even if an etchant does not penetrate up to an upper surface US of the mother substrate MSUB, the first side surface SS1 of the substrate SUB and the dummy substrate DSUB can be separated. Alternatively, the first side surface SS1 of the substrate SUB and the dummy substrate DSUB can be separated by only a small amount of etchant penetrating into the laser spots SPT. Therefore, it may be possible to reduce, minimize, or prevent the invasion of the etchant into a display layer DISL of a display cell DPC disposed on an upper surface of the substrate SUB.

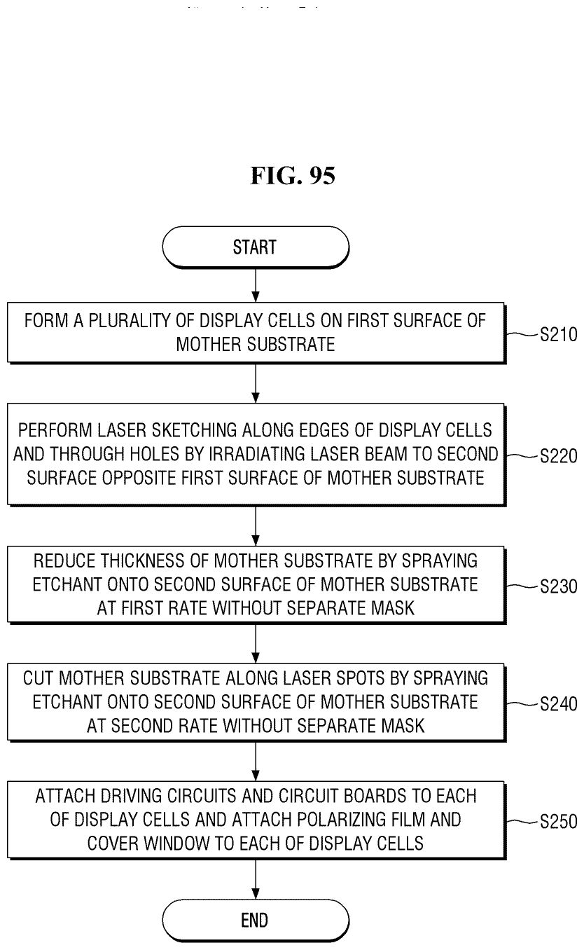

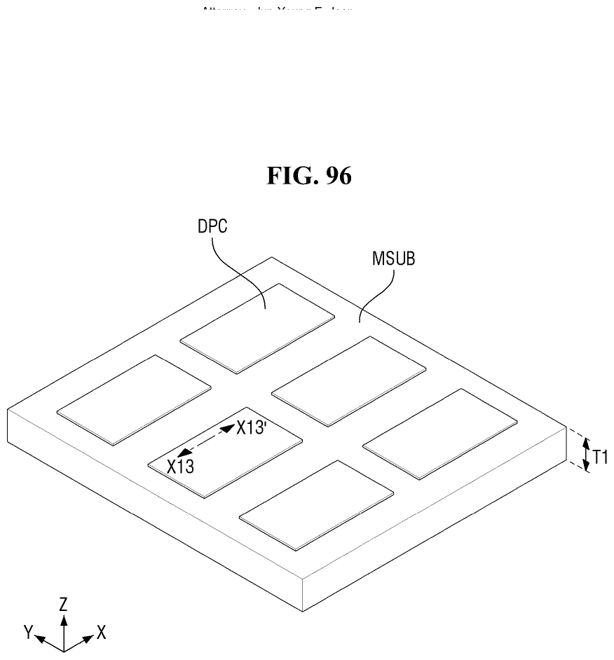

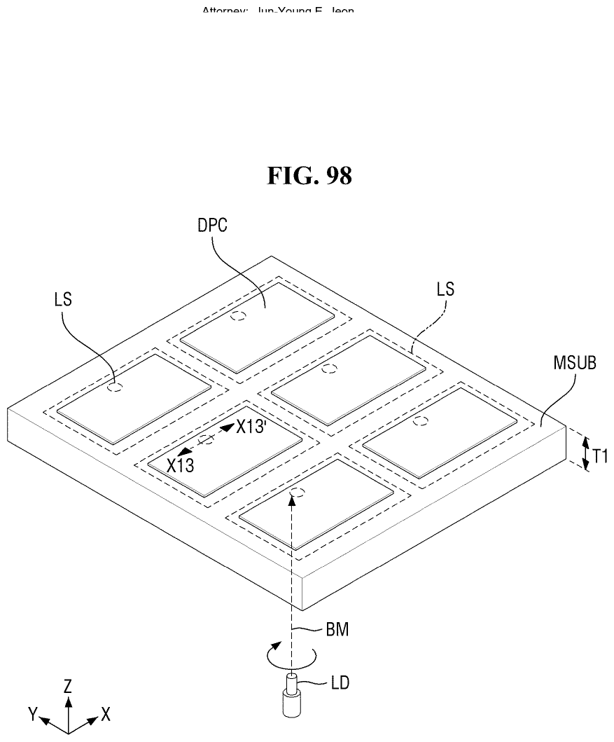

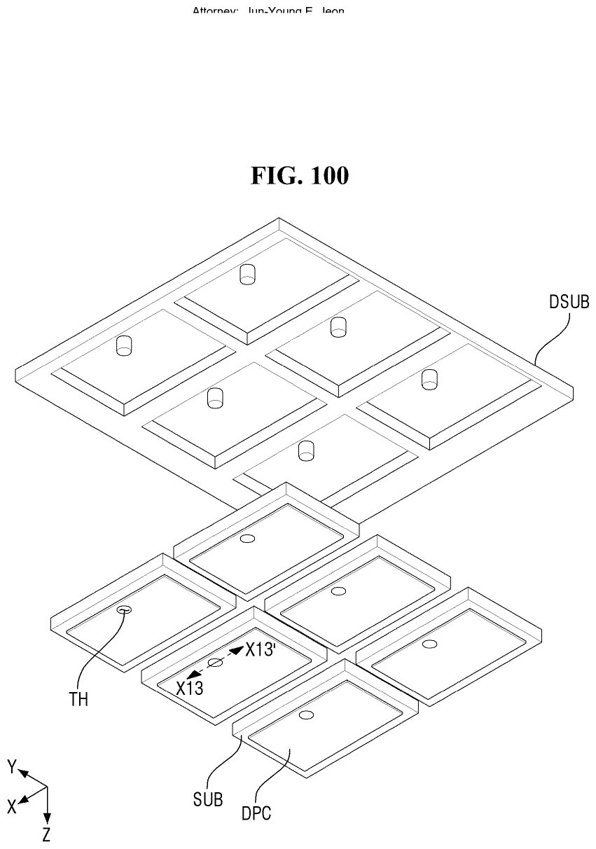

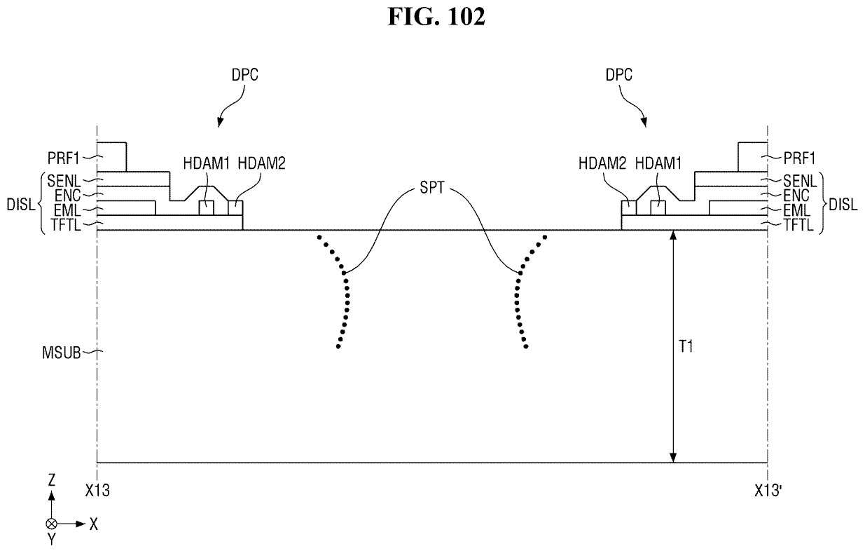

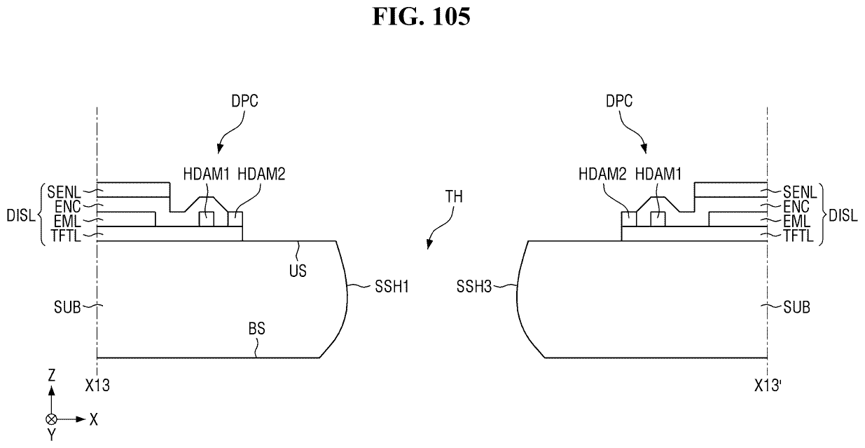

FIG. 95 is a flowchart illustrating a method of fabricating a display device according to one or more embodiments of the present disclosure. FIGS. 96 through 101 are perspective views for explaining the method of fabricating the display device according to the one or more embodiments. FIGS. 102 through 105 are cross-sectional views taken along the line X13-X13′ of FIGS. 96 through 100 to explain the method of fabricating the display device according to one or more embodiments of the present disclosure.

FIGS. 96 through 101 are perspective views of a mother substrate MSUB and a plurality of display cells DPC. FIGS. 102 through 105 illustrate an example of cross sections of the mother substrate MSUB and the display cells DPC taken along the line X13-X13′ of FIGS. 96 through 100.

A method of fabricating the hole side surfaces SSH1 through SSH4 of the through hole TH of the substrate SUB described with reference to FIGS. 35A through 35D will now be described in detail with reference to FIGS. 96 through 101.

First, as illustrated in FIGS. 96 and 102, a plurality of display cells DPC is formed on a first surface of the mother substrate MSUB (e.g., see operation S210 in FIG. 95).

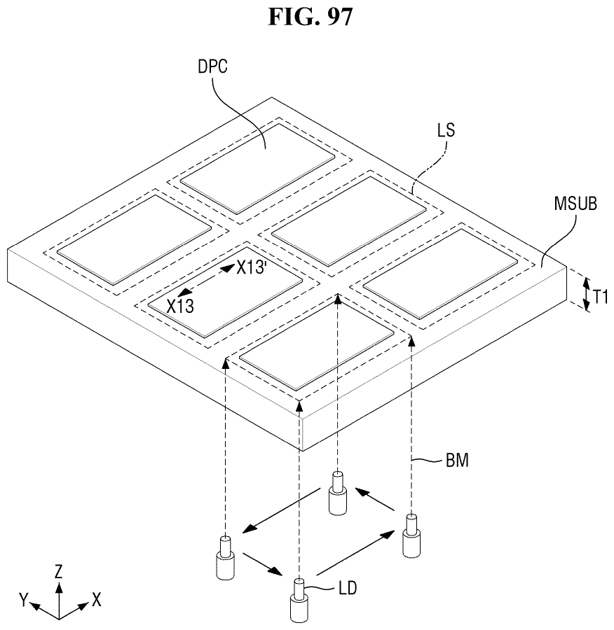

Second, as illustrated in FIGS. 97, 98 and 102, laser sketching LS or laser modulation is performed along edges of the display cells DPC and through holes TH by irradiating a laser beam onto a second surface opposite the first surface of the mother substrate MSUB (e.g., see operation S220 in FIG. 95).

The laser beam BM may be output from the laser device LD according to any one of the embodiments described with reference to FIGS. 52 through 57.

The laser sketching LS refers to forming a plurality of spot groups GSPT, each including a plurality of laser spots SPT. The laser sketching LS may be defined as forming a plurality of laser spots SPT along the edges of the display cells DPC and the through holes TH by irradiating the laser beam BM.

While a scanning direction of the laser device LD for laser sketching along the edges of each of the display cells DPC is a counterclockwise direction, a scanning direction of the laser device LD for laser sketching along the edges of each of the through holes TH may be a clockwise direction. However, embodiments of the present disclosure are not limited thereto, and the scanning direction of the laser device LD may be set in consideration of whether laser spots SPT are interfered with by other laser spots SPT when they are formed, as described with reference to FIG. 78.

When a length of the mother substrate MSUB in the third direction (Z-axis direction) is about 500 μm, a length in which a plurality of laser spots SPT is arranged in the third direction (Z-axis direction) may be in a range of about 200 μm to about 300 μm. That is, the length in which the laser spots SPT are arranged in the third direction (Z-axis direction) may be in a range of about 0.4 to about 0.6 of the length of the mother substrate MSUB in the third direction (Z-axis direction).

In a plane defined by the first direction (X-axis direction) and the third direction (Z-axis direction), the hole side surfaces SSH1 through SSH4 of the through hole TH of the substrate SUB according to the one or more embodiments of FIGS. 35A through 35D have a curved shape. Therefore, the laser spots SPT may also be arranged in a curved shape in the plane defined by the first direction (X-axis direction) and the third direction (Z-axis direction). The arrangement of the laser spots SPT formed on the mother substrate MSUB by the laser device LD so that the hole side surfaces SSH1 through SSH4 of the through hole TH of the substrate SUB according to the one or more embodiments of FIGS. 35A through 35D can have a curved shape in the plane defined by the first direction (X-axis direction) and the third direction (Z-axis direction) has already been described with reference to FIGS. 87A through 87D and 88.

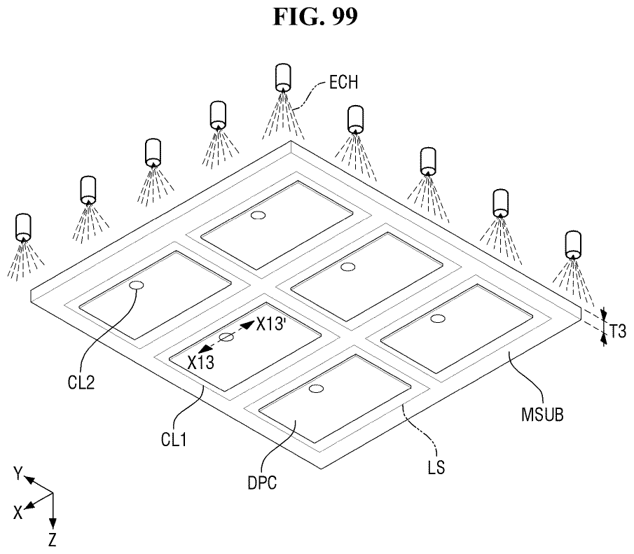

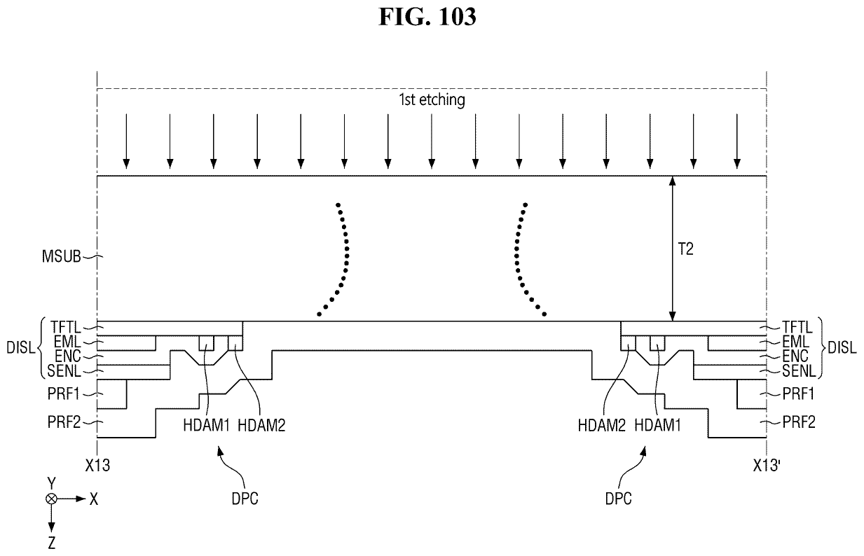

Third, as illustrated in FIGS. 99 and 103, a thickness of the mother substrate MSUB is reduced by spraying an etchant onto the second surface of the mother substrate MSUB at a first rate without a separate mask (e.g., see operation S230 in FIG. 95).

Fourth, as illustrated in FIGS. 99, 100, 104 and 105, the mother substrate MSUB is cut along the laser spots SPT by spraying an etchant onto the second surface of the mother substrate MSUB at a second rate without a separate mask (e.g., see operation S240 in FIG. 95).

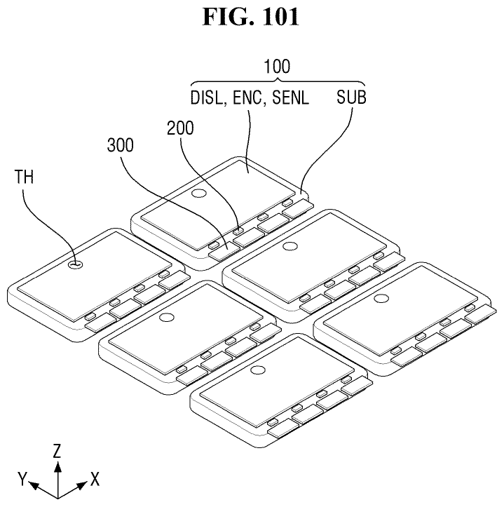

Fifth, as illustrated in FIG. 101, driving circuits 200 and circuit boards 300 are attached to each of the display cells DPC, and a polarizing film PF and a cover window CW are attached to each of the display cells DPC (e.g., see operation S250 in FIG. 95).

As described above, it is possible to reduce the thickness of the mother substrate MSUB and separate the substrate SUB of each of the display cells DPC from the mother substrate MSUB by using a laser and etching process. Therefore, the efficiency of the fabrication process can be increased.

In addition, the laser device LD may output the laser beam BM such that a plurality of laser spots SPT is disposed along a curve in a plane defined by the first direction (X-axis direction) and the third direction (Z-axis direction). In this case, the hole side surfaces SSH1 through SSH4 of the through hole TH of each of the display cells DPC may be etched into a curved shape having a curvature by spraying an etchant. That is, because the hole side surfaces SSH1 through SSH4 of the through hole TH of each of the display cells DPC can have a curved shape without a separate polishing process, the efficiency of the fabrication process can be increased.

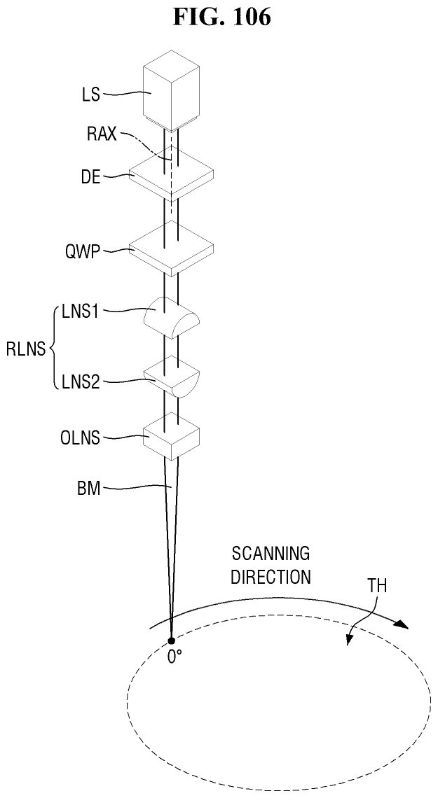

FIGS. 106 through 109 are example views illustrating the rotation of the laser device LD according to the one or more embodiments of FIGS. 52 through 54 for a laser sketch surrounding edges of a through hole TH of a display cell DPC.

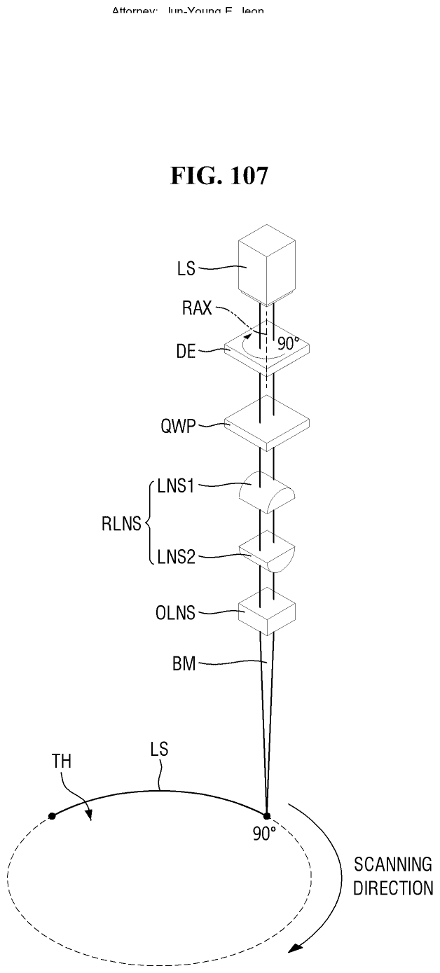

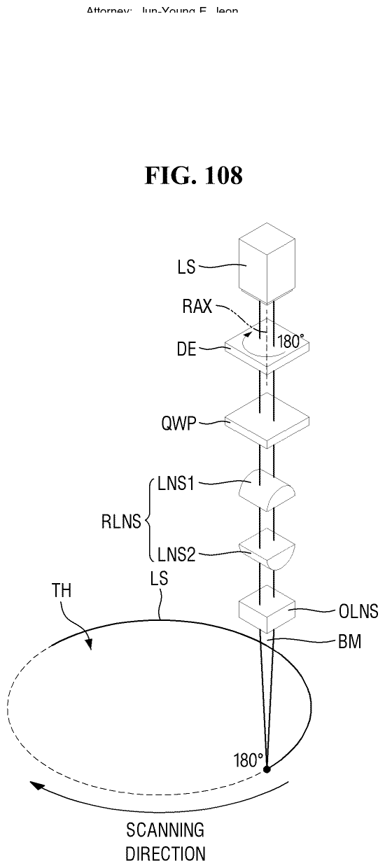

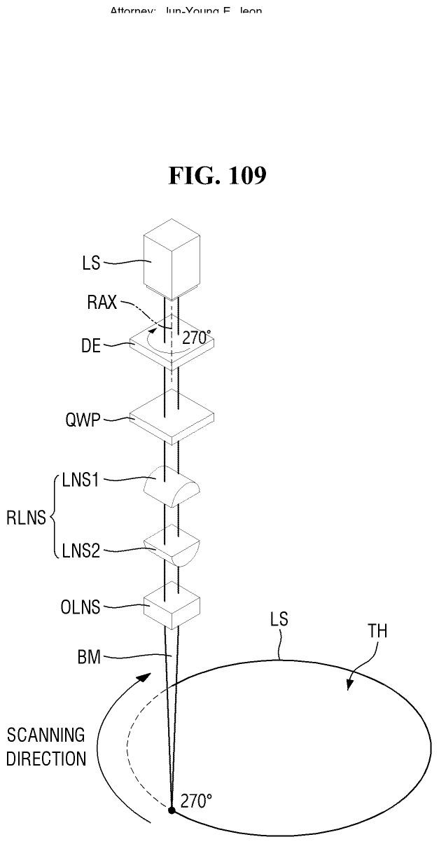

FIG. 106 illustrates a case where the laser device LD is not rotated. FIG. 107 illustrates a state where the laser device LD is rotated 90 degrees clockwise. FIG. 108 illustrates a state where the laser device LD is rotated 180 degrees clockwise. FIG. 109 illustrates a state where the laser device LD is rotated 270 degrees clockwise.

Laser sketching of the through hole TH of the display cell DPC will now be described in detail with reference to FIGS. 106 through 109.

First, as illustrated in FIGS. 106 and 107, the laser device LD makes a laser sketch LS by irradiating a laser beam BM along a first edge of the through hole TH of the display cell DPC while continuously rotating clockwise from 0 degrees to 90 degrees. Because the laser device LD irradiates the laser beam BM while moving in a curve, a scanning speed of the laser device LD may be 10 to 100 mm/sec. The scanning speed of the laser device LD at a first side edge SE1, a second side edge SE2, a third side edge SE3 and a fourth side edge SE4 of the display cell DPC may be faster than the scanning speed of the laser device LD at the first edge of the through hole TH. In addition, the scanning speed of the laser device LD at a first corner edge CE1, a second corner edge CE2, a third corner edge CE3 and a fourth corner edge CE4 of the display cell DPC may be substantially the same as the scanning speed of the laser device LD at the first edge of the through hole TH. Second, as illustrated in FIGS. 107 and 108, the laser device LD makes a laser sketch LS by irradiating the laser beam BM along a second edge of the through hole TH of the display cell DPC while continuously rotating clockwise from 90 degrees to 180 degrees. Because the laser device LD irradiates the laser beam BM while moving in a curve, the scanning speed of the laser device LD may be in a range of about 10 mm/sec to about 100 mm/sec. The scanning speed of the laser device LD at the first side edge SE1, the second side edge SE2, the third side edge SE3 and the fourth side edge SE4 of the display cell DPC may be faster than the scanning speed of the laser device LD at the second edge of the through hole TH. In addition, the scanning speed of the laser device LD at the first corner edge CE1, the second corner edge CE2, the third corner edge CE3 and the fourth corner edge CE4 of the display cell DPC may be substantially the same as the scanning speed of the laser device LD at the second edge of the through hole TH.

Third, as illustrated in FIGS. 108 and 109, the laser device LD makes the laser sketch LS by irradiating the laser beam BM along a third edge of the through hole TH of the display cell DPC while continuously rotating clockwise from 180 degrees to 270 degrees. Because the laser device LD irradiates the laser beam BM while moving in a curve, the scanning speed of the laser device LD may be in a range of about 10 mm/sec to about 100 mm/sec. The scanning speed of the laser device LD at the first side edge SE1, the second side edge SE2, the third side edge SE3 and the fourth side edge SE4 of the display cell DPC may be faster than the scanning speed of the laser device LD at the third edge of the through hole TH. In addition, the scanning speed of the laser device LD at the first corner edge CE1, the second corner edge CE2, the third corner edge CE3 and the fourth corner edge CE4 of the display cell DPC may be substantially the same as the scanning speed of the laser device LD at the third edge of the through hole TH.

Fourth, as illustrated in FIGS. 109 and 106, the laser device LD makes a laser sketch LS by irradiating the laser beam BM along a fourth edge of the through hole TH of the display cell DPC while continuously rotating clockwise from 270 degrees to 360 degrees. Because the laser device LD irradiates the laser beam BM while moving in a curve, the scanning speed of the laser device LD may be in a range of about 10 mm/sec to about 100 mm/sec. The scanning speed of the laser device LD at the first side edge SE1, the second side edge SE2, the third side edge SE3 and the fourth side edge SE4 of the display cell DPC may be faster than the scanning speed of the laser device LD at the fourth edge of the through hole TH. In addition, the scanning speed of the laser device LD at the first corner edge CE1, the second corner edge CE2, the third corner edge CE3 and the fourth corner edge CE4 of the display cell DPC may be substantially the same as the scanning speed of the laser device LD at the fourth edge of the through hole TH.

As illustrated in FIGS. 106 through 109, a laser sketch is made by irradiating an elliptically polarized laser beam BM in the clockwise direction along the edges of the through hole TH of the display cell DPC. Therefore, it may be possible to reduce, minimize, or prevent a difference in processability of the substrate SUB of a display panel 100. Accordingly, it may be possible to reduce, minimize, or prevent a difference in the shapes, for example, radii of curvature of the hole side surfaces SSH1 through SSH4 of the substrate SUB of the display panel 100 or a difference in mechanical strength according to the positions of the hole side surfaces SSH1 through SSH4 of the substrate SUB. Therefore, the hole side surfaces SSH1 through SSH4 of the substrate SUB of the display panel 100 can have uniform quality against external impacts.

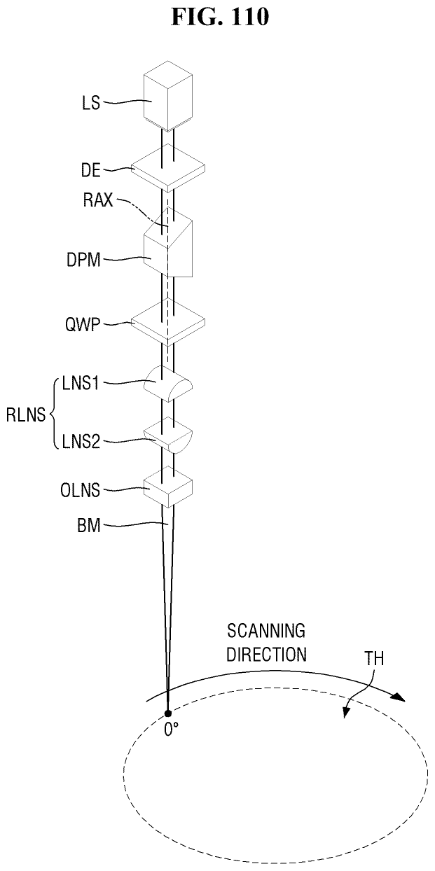

FIGS. 110 through 113 are example views illustrating the rotation of the laser device LD according to the one or more embodiments of FIGS. 55 and 56 for a laser sketch surrounding edges of a through hole TH of a display cell DPC.

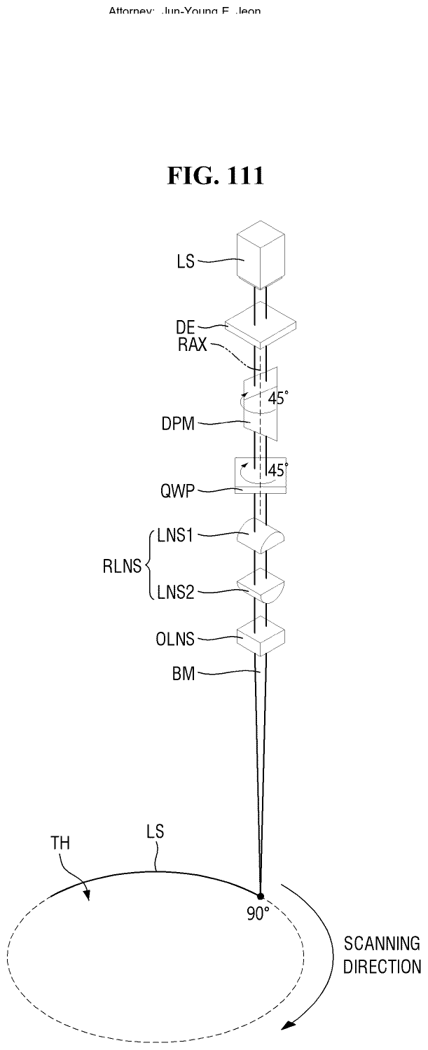

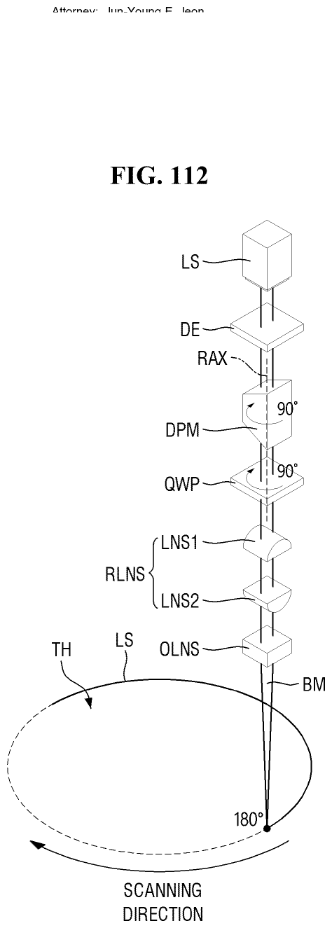

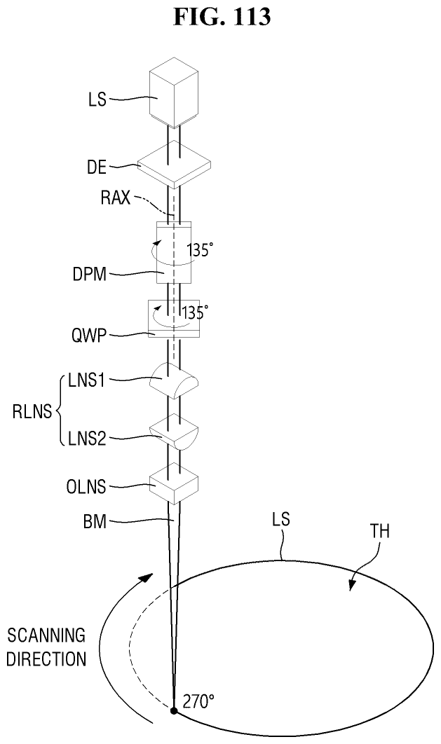

FIG. 110 illustrates a case where the laser device LD is not rotated. FIG. 111 illustrates a case where the laser device LD is rotated 45 degrees clockwise. FIG. 112 illustrates a case where the laser device LD is rotated 90 degrees clockwise. FIG. 113 illustrates a case where the laser device LD is rotated 135 degrees clockwise.

Laser sketching of the through hole TH of the display cell DPC will now be described in detail with reference to FIGS. 110 through 113.

First, as illustrated in FIGS. 110 and 111, the laser device LD makes a laser sketch LS by irradiating a laser beam BM along a first edge of the through hole TH of the display cell DPC while continuously rotating clockwise from 0 degrees to 45 degrees. When the prism DPM is a Dove prism having trapezoidal cross sections as illustrated in FIGS. 48A and 48B, the rotation angle of the laser beam BM is twice the rotation angle of the prism DPM. Therefore, when the prism DPM continuously rotates from 0 degrees to 45 degrees, the laser beam BM continuously rotates from 45 degrees to 90 degrees.

Because the laser device LD irradiates the laser beam BM while moving in a curve, a scanning speed of the laser device LD may be in a range of about 10 mm/sec to about 100 mm/sec. The scanning speed of the laser device LD at a first side edge SE1, a second side edge SE2, a third side edge SE3 and a fourth side edge SE4 of the display cell DPC may be faster than the scanning speed of the laser device LD at the first edge of the through hole TH. In addition, the scanning speed of the laser device LD at a first corner edge CE1, a second corner edge CE2, a third corner edge CE3 and a fourth corner edge CE4 of the display cell DPC may be substantially the same as the scanning speed of the laser device LD at the first edge of the through hole TH.

Second, as illustrated in FIGS. 111 and 112, the laser device LD makes a laser sketch LS by irradiating the laser beam BM along a second edge of the through hole TH of the display cell DPC while continuously rotating clockwise from 45 degrees to 90 degrees. When the prism DPM is a Dove prism having trapezoidal cross sections as illustrated in FIGS. 48A and 48B, the rotation angle of the laser beam BM is twice the rotation angle of the prism DPM. Therefore, when the prism DPM continuously rotates from 45 degrees to 90 degrees, the laser beam BM continuously rotates from 90 degrees to 180 degrees.

Because the laser device LD irradiates the laser beam BM while moving in a curve, the scanning speed of the laser device LD may be in a range of about 10 mm/sec to about 100 mm/sec. The scanning speed of the laser device LD at the first side edge SE1, the second side edge SE2, the third side edge SE3 and the fourth side edge SE4 of the display cell DPC may be faster than the scanning speed of the laser device LD at the second edge of the through hole TH. In addition, the scanning speed of the laser device LD at the first corner edge CE1, the second corner edge CE2, the third corner edge CE3 and the fourth corner edge CE4 of the display cell DPC may be substantially the same as the scanning speed of the laser device LD at the second edge of the through hole TH.

Third, as illustrated in FIGS. 112 and 113, the laser device LD makes a laser sketch LS by irradiating the laser beam BM along a third edge of the through hole TH of the display cell DPC while continuously rotating clockwise from 90 degrees to 135 degrees. When the prism DPM is a Dove prism having trapezoidal cross sections as illustrated in FIGS. 48A and 48B, the rotation angle of the laser beam BM is twice the rotation angle of the prism DPM. Therefore, when the prism DPM continuously rotates from 90 degrees to 135 degrees, the laser beam BM continuously rotates from 180 degrees to 270 degrees.

Because the laser device LD irradiates the laser beam BM while moving in a curve, the scanning speed of the laser device LD may be in a range of about 10 mm/sec to about 100 mm/sec. The scanning speed of the laser device LD at the first side edge SE1, the second side edge SE2, the third side edge SE3 and the fourth side edge SE4 of the display cell DPC may be faster than the scanning speed of the laser device LD at the third edge of the through hole TH. In addition, the scanning speed of the laser device LD at the first corner edge CE1, the second corner edge CE2, the third corner edge CE3 and the fourth corner edge CE4 of the display cell DPC may be substantially the same as the scanning speed of the laser device LD at the third edge of the through hole TH.

Fourth, as illustrated in FIG. 113, the laser device LD makes a laser sketch LS by irradiating the laser beam BM along a fourth edge of the through hole TH of the display cell DPC while continuously rotating clockwise from 135 degrees to 180 degrees. When the prism DPM is a Dove prism having trapezoidal cross sections as illustrated in FIGS. 48A and 48B, the rotation angle of the laser beam BM is twice the rotation angle of the prism DPM. Therefore, when the prism DPM continuously rotates from 135 degrees to 180 degrees, the laser beam BM continuously rotates from 270 degrees to 360 degrees.

Because the laser device LD irradiates the laser beam BM while moving in a curve, the scanning speed of the laser device LD may be in a range of about 10 mm/sec to about 100 mm/sec. The scanning speed of the laser device LD at the first side edge SE1, the second side edge SE2, the third side edge SE3 and the fourth side edge SE4 of the display cell DPC may be faster than the scanning speed of the laser device LD at the fourth edge of the through hole TH. In addition, the scanning speed of the laser device LD at the first corner edge CE1, the second corner edge CE2, the third corner edge CE3 and the fourth corner edge CE4 of the display cell DPC may be substantially the same as the scanning speed of the laser device LD at the fourth edge of the through hole TH.

As illustrated in FIGS. 110 through 113, a laser sketch is made by irradiating an elliptically polarized laser beam BM in the clockwise direction along the edges of the through hole TH of the display cell DPC. Therefore, it may be possible to reduce, minimize, or prevent a difference in processability of the substrate SUB of a display panel 100. Accordingly, it may be possible to reduce, minimize, or prevent a difference in the shapes, for example, radii of curvature of the hole side surfaces SSH1 through SSH4 of the substrate SUB of the display panel 100 or a difference in mechanical strength according to the positions of the hole side surfaces SSH1 through SSH4 of the substrate SUB. Therefore, the hole side surfaces SSH1 through SSH4 of the substrate SUB of the display panel 100 can have uniform quality against external impacts.

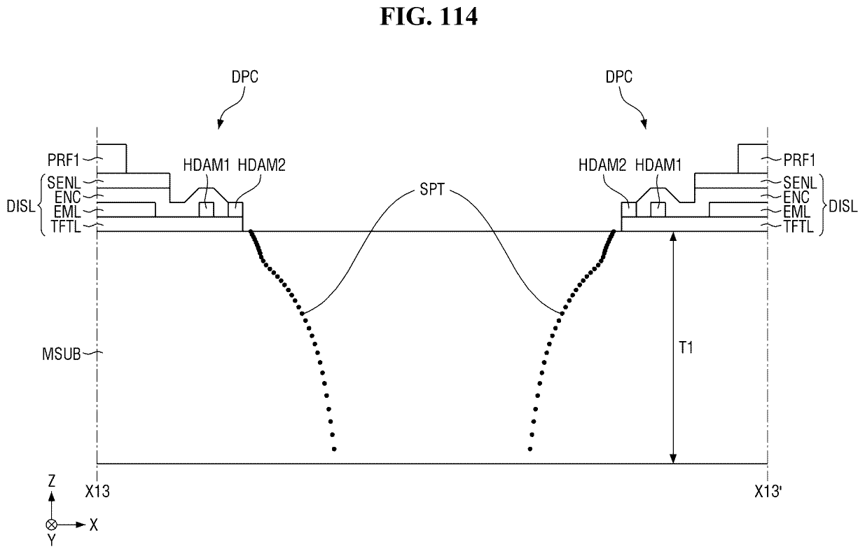

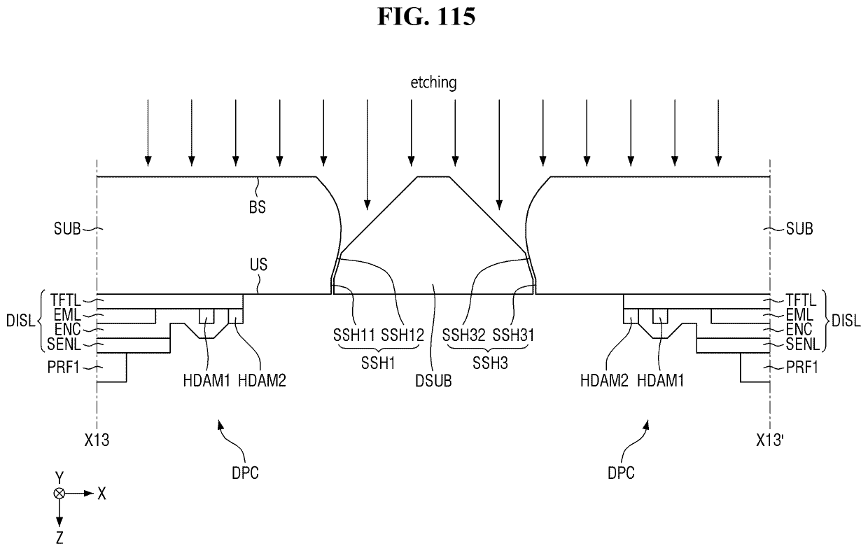

FIGS. 114 and 115 are cross-sectional views taken along the line X13-X13′ of FIGS. 96 through 100 to explain a method of fabricating a display device according to one or more embodiments of the present disclosure. FIGS. 114 and 115 illustrate an example of cross sections taken along the line X13-X13′ of FIGS. 96 through 100 in operations S220 through S240 of FIG. 95.

Cross-sectional shapes of hole side surfaces SSH1 through SSH4 of a through hole TH of a substrate SUB depend on the arrangement form of laser spots SPT. A method of fabricating the hole side surfaces SSH1 through SSH4 of the through hole TH of the substrate SUB according to the one or more embodiments of FIGS. 36A through 36D will now be described with reference to FIGS. 114 and 115.

As illustrated in FIG. 114, a length in which a plurality of laser spots SPT is arranged in the third direction (Z-axis direction) may be substantially equal to a length of a mother substrate MSUB in the third direction (Z-axis direction). For example, if the length of the mother substrate MSUB in the third direction (Z-axis direction) is about 500 μm, the length in which the laser spots SPT are arranged in the third direction (Z-axis direction) may be about 500 μm.

In a plane defined by the first direction (X-axis direction) and the third direction (Z-axis direction), each of the hole side surfaces SSH1 through SSH4 of the through hole TH of the substrate SUB according to the one or more embodiments of FIGS. 36A through 36D has two sub-side surfaces. To this end, the laser spots SPT may be divided and arranged in two areas having two radii of curvature in the plane defined by the first direction (X-axis direction) and the third direction (Z-axis direction).

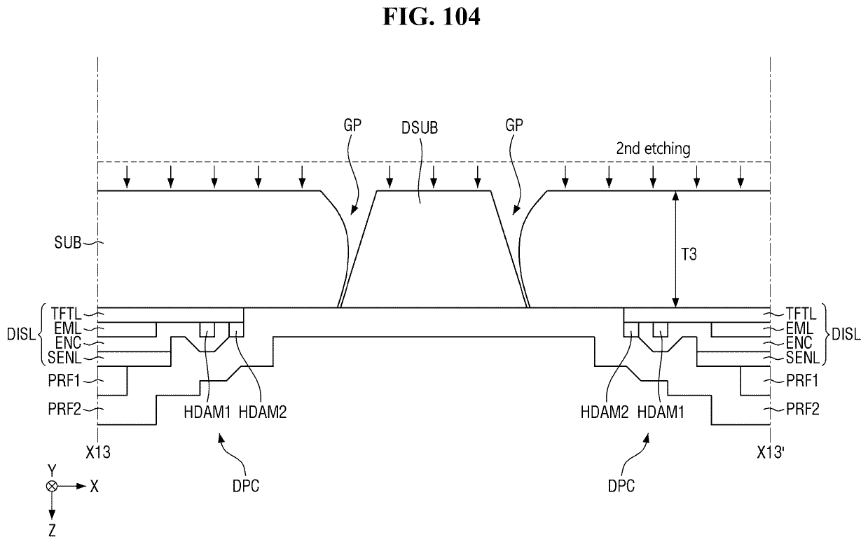

As illustrated in FIG. 115, because the length in which the laser spots SPT are arranged in the third direction (Z-axis direction) is substantially equal to the length of the mother substrate MSUB in the third direction (Z-axis direction), an etchant can penetrate directly into the laser spots SPT. Therefore, the area of a gap GP between a lower surface BS of the substrate SUB separated from the mother substrate MSUB and a dummy substrate DSUB may be larger than that of the one or more embodiments of FIG. 104. Accordingly, the area of at least a portion of each of the hole side surfaces SSH1 and SSH3 of the through hole TH of the substrate SUB that is healed by the etchant may also be larger than that of the one or more embodiments of FIG. 104. In addition, due to the increased gap GP, damage to side surfaces of the substrate SUB by the dummy substrate DSUB when the dummy substrate DSUB is separated from the substrate SUB may be reduced compared to the one or more embodiments of FIG. 104.

In addition, the arrangement of the laser spots SPT formed on the mother substrate MSUB by a laser device LD so that each of the hole side surfaces SSH1 through SSH4 of the through hole TH of the substrate SUB according to the one or more embodiments of FIGS. 36A through 36D can have two sub-side surfaces in the plane defined by the first direction (X-axis direction) and the third direction (Z-axis direction) has already been described above with reference to FIG. 91. As illustrated in FIGS. 91, 114 and 115, laser spots SPT in a first area UA and laser spots SPT in a second area BA not only have different radii of curvature, but also are arranged at different intervals. Therefore, a first sub-hole side surface SSH11 having a different curved or flat shape from a second sub-hole side surface SSH12 may be formed in a first hole side surface SSH1. In addition, when a distance between the laser spots SPT in the first area UA is small, the energy density irradiated to the mother substrate MSUB is high. Therefore, even if an etchant does not penetrate up to an upper surface US of the mother substrate MSUB, the first sub-hole side surface SSH11 of the first hole side surface SSH1 of the substrate SUB and the dummy substrate DSUB can be separated. Alternatively, the first sub-hole side surface SSH11 of the first hole side surface SSH1 of the substrate SUB and the dummy substrate DSUB can be separated by only a small amount of etchant penetrating into the laser spots SPT. Therefore, it may be possible to reduce, minimize, or prevent the invasion of the etchant into a display layer DISL of a display cell DPC disposed on an upper surface of the substrate SUB.

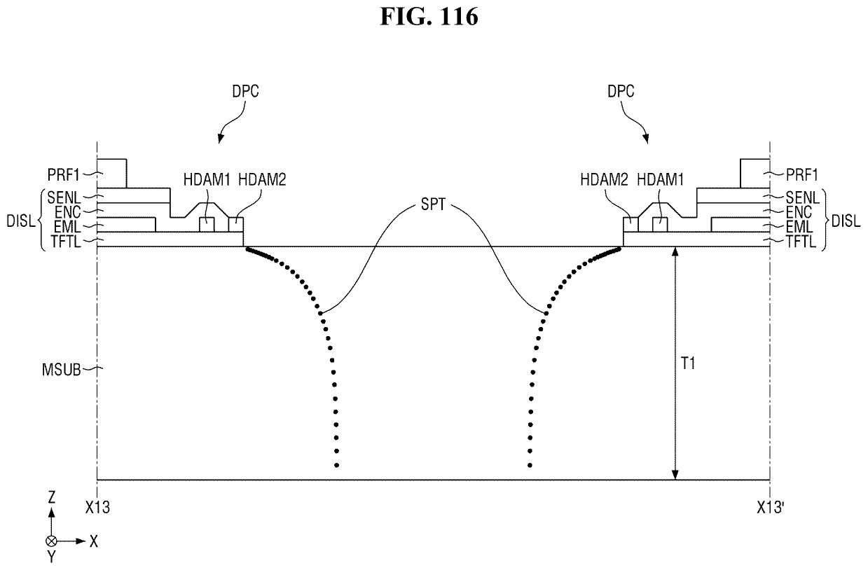

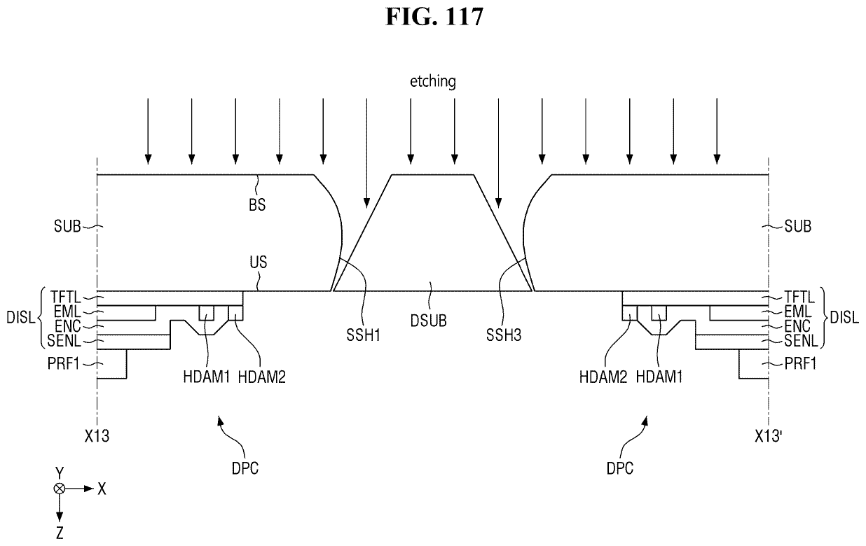

FIGS. 116 and 117 are cross-sectional views taken along the line X13-X13′ of FIGS. 96 through 100 to explain a method of fabricating a display device according to one or more embodiments of the present disclosure. FIGS. 116 and 117 illustrate an example of cross sections taken along the line X13-X13′ of FIGS. 96 through 100 in operations S220 through S240 of FIG. 95.

Cross-sectional shapes of hole side surfaces SSH1 through SSH4 of a through hole TH of a substrate SUB depend on the arrangement form of laser spots SPT. A method of fabricating the hole side surfaces SSH1 through SSH4 of the through hole TH of the substrate SUB according to the one or more embodiments of FIGS. 35A through 35D will now be described with reference to FIGS. 116 and 117.

As illustrated in FIG. 116, a length in which a plurality of laser spots SPT is arranged in the third direction (Z-axis direction) may be substantially equal to a length of a mother substrate MSUB in the third direction (Z-axis direction). For example, if the length of the mother substrate MSUB in the third direction (Z-axis direction) is about 500 μm, the length in which the laser spots SPT are arranged in the third direction (Z-axis direction) may be about 500 μm.

In a plane defined by the first direction (X-axis direction) and the third direction (Z-axis direction), the hole side surfaces SSH1 through SSH4 of the through hole TH of the substrate SUB according to the one or more embodiments of FIGS. 35A through 35D have a curved shape. Therefore, the laser spots SPT may also be arranged in a curved shape in the plane defined by the first direction (X-axis direction) and the third direction (Z-axis direction).

As illustrated in FIG. 117, because the length in which the laser spots SPT are arranged in the third direction (Z-axis direction) is substantially equal to the length of the mother substrate MSUB in the third direction (Z-axis direction), an etchant can penetrate directly into the laser spots SPT. Therefore, the area of a gap GP between a lower surface BS of the substrate SUB separated from the mother substrate MSUB and a dummy substrate DSUB may be larger than that of the one or more embodiments of FIG. 104. Accordingly, the area of at least a portion of each of the hole side surfaces SSH1 and SSH3 of the through hole TH of the substrate SUB that is healed by the etchant may also be larger than that of the one or more embodiments of FIG. 104. In addition, due to the increased gap GP, damage to side surfaces of the substrate SUB by the dummy substrate DSUB when the dummy substrate DSUB is separated from the substrate SUB may be reduced compared to the one or more embodiments of FIG. 104.

The arrangement of the laser spots SPT formed on the mother substrate MSUB by a laser device LD so that the hole side surfaces SSH1 through SSH4 of the through hole TH of the substrate SUB according to the one or more embodiments of FIGS. 35A through 35D can have a curved shape in the plane defined by the first direction (X-axis direction) and the third direction (Z-axis direction) has already been described above with reference to FIG. 94. As illustrated in FIGS. 94, 116 and 117, when a distance between laser spots SPT in a first area UA is small, the energy density irradiated to the mother substrate MSUB is high. Therefore, even if an etchant does not penetrate up to an upper surface US of the mother substrate MSUB, a first hole side surface SSH1 of the substrate SUB and the dummy substrate DSUB can be separated. Alternatively, the first hole side surface SSH1 of the substrate SUB and the dummy substrate DSUB can be separated by only a small amount of etchant penetrating into the laser spots SPT. Therefore, it may be possible to reduce, minimize, or prevent the invasion of the etchant into a display layer DISL of a display cell DPC disposed on an upper surface of the substrate SUB.

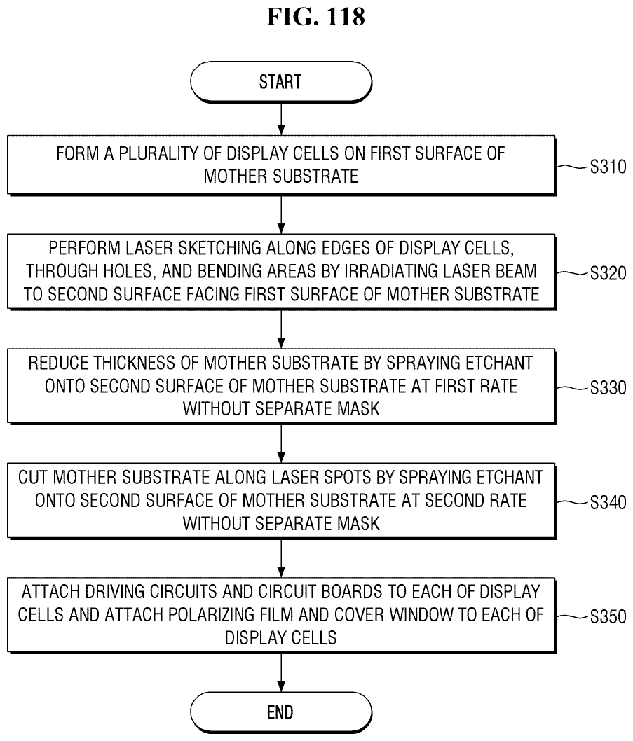

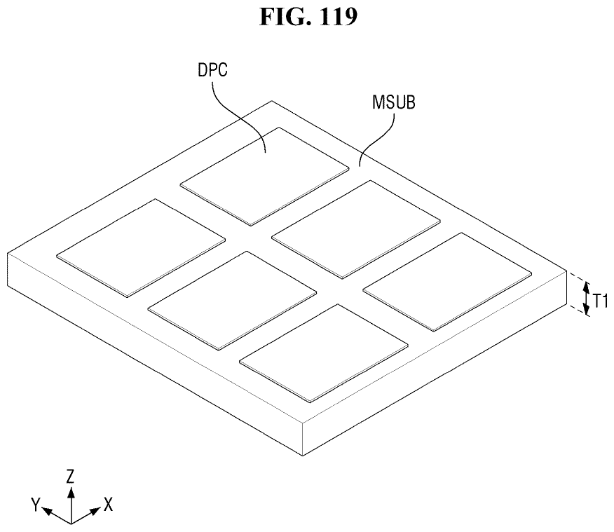

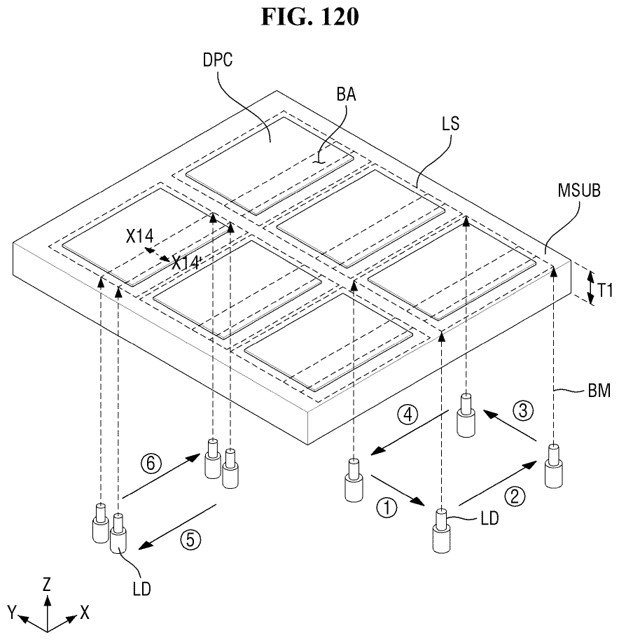

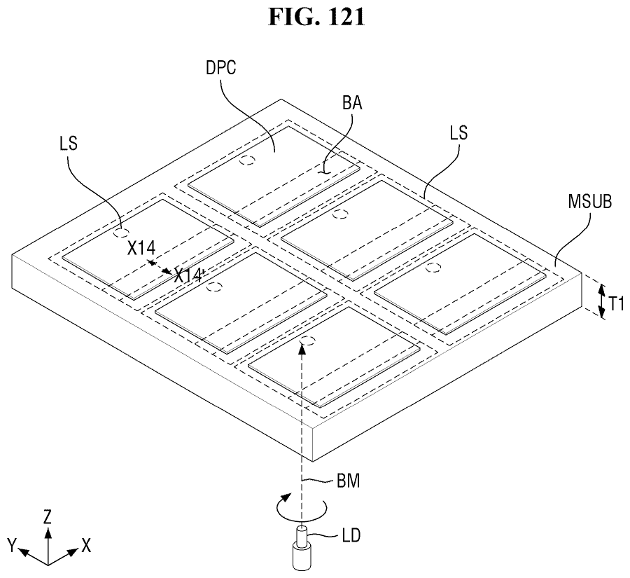

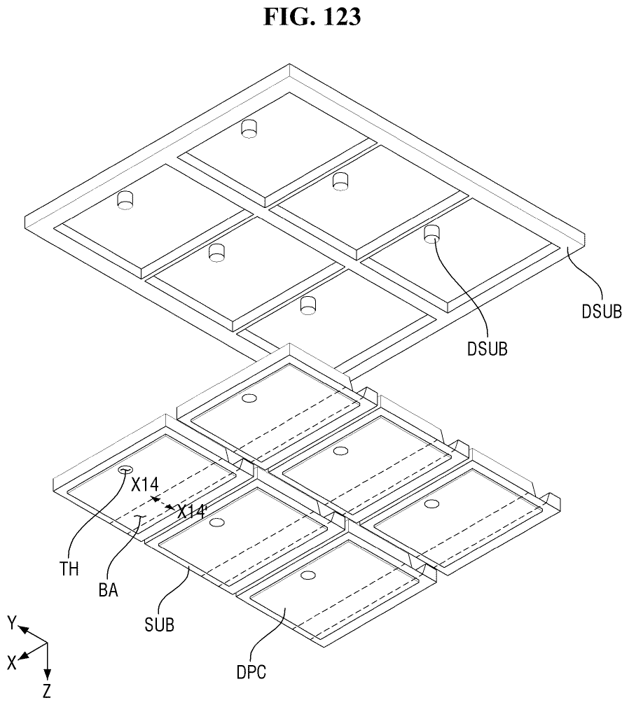

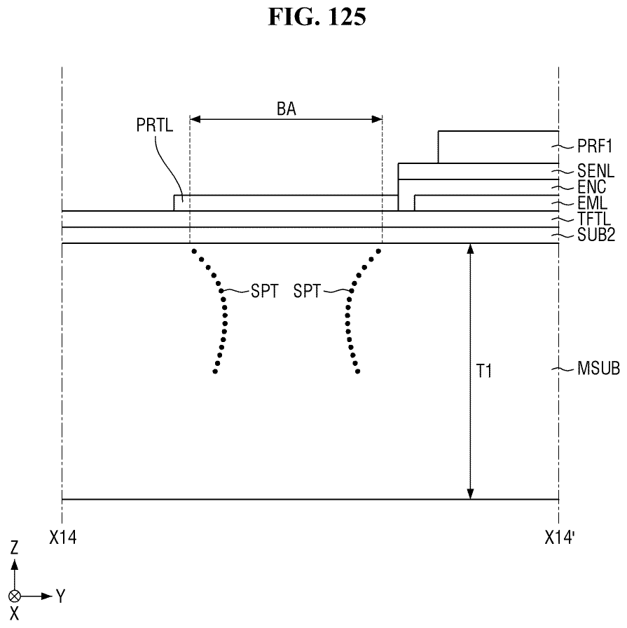

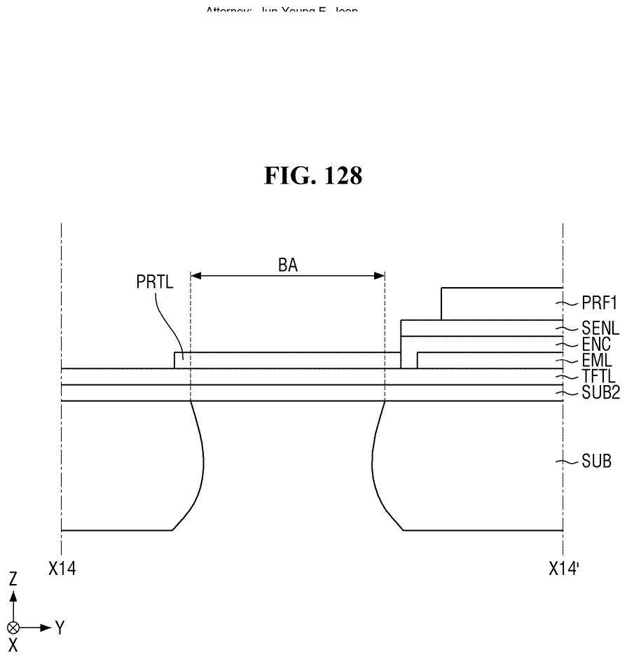

FIG. 118 is a flowchart illustrating a method of fabricating a display device according to one or more embodiments of the present disclosure. FIGS. 119 through 124 are perspective views for explaining the method of fabricating the display device according to one or more embodiments of the present disclosure. FIGS. 125 through 128 are cross-sectional views taken along the line X14-X14′ of FIGS. 120 through 123 to explain the method of fabricating the display device according to one or more embodiments of the present disclosure.

FIGS. 119 through 124 are perspective views of a mother substrate MSUB and a plurality of display cells DPC disposed on the mother substrate MSUB. FIGS. 125 through 128 illustrate an example of cross sections of the mother substrate MSUB and the display cells DPC taken along the line X14-X14′ of FIGS. 120 through 123.

A method of fabricating the first through fourth side surfaces SS1_1, SS2_1, SS3_1 and SS4_1 of the first sub-substrate SSUB1 and the first through fourth side surfaces SS1_2, SS2_2, SS3_2 and SS4_2 of the second sub-substrate SSUB2 described with reference to FIGS. 43A through 43D and 44A through 44D will now be described in detail with reference to FIGS. 118 through 128.

First, as illustrated in FIGS. 119 and 125, a plurality of display cells DPC is formed on a first surface of the mother substrate MSUB (e.g., see operation S310 in FIG. 118).

Second, as illustrated in FIGS. 120, 121 and 125, laser sketching LS or laser modulation is performed along edges of the display cells DPC, through holes TH, and bending areas BA by irradiating a laser beam onto a second surface opposite the first surface of the mother substrate MSUB (e.g., see operation S320 in FIG. 118).

The laser beam BM may be output from the laser device LD according to any one of the embodiments described with reference to FIGS. 52 through 57.

The laser sketching LS refers to forming a plurality of spot groups GSPT, each including a plurality of laser spots SPT. The laser sketching LS may be defined as forming a plurality of laser spots SPT along the edges of the display cells DPC, the through holes TH, and the bending areas BA by irradiating the laser beam BM.

When a length of the mother substrate MSUB in the third direction (Z-axis direction) is about 500 μm, a length in which a plurality of laser spots SPT is arranged in the third direction (Z-axis direction) may be in a range of about 200 μm to about 300 μm. That is, the length in which the laser spots SPT are arranged in the third direction (Z-axis direction) may be in a range of about 0.4 to about 0.6 of the length of the mother substrate MSUB in the third direction (Z-axis direction).

In a plane defined by the first direction (X-axis direction) and the third direction (Z-axis direction), the side surfaces SS1_1, SS2_1, SS3_1 and SS4_1 of the first sub-substrate SSUB1 of a substrate SUB and the side surfaces SS1_2, SS2_2, SS3_2 and SS4_2 of the second sub-substrate SSUB2 according to the one or more embodiments of FIGS. 43A through 43D and 44A through 44D have a curved shape. Therefore, the laser spots SPT may also be arranged in a curved shape in the plane defined by the first direction (X-axis direction) and the third direction (Z-axis direction). The arrangement of the laser spots SPT formed on the mother substrate MSUB by the laser device LD so that the side surfaces SS1_1, SS2_1, SS3_1 and SS4_1 of the first sub-substrate SSUB1 and the side surfaces SS1_2, SS2_2, SS3_2 and SS4_2 of the second sub-substrate SSUB2 according to the one or more embodiments of FIGS. 43A through 43D and 44A through 44D can have a curved shape in the plane defined by the first direction (X-axis direction) and the third direction (Z-axis direction) has already been described above with reference to FIGS. 87A through 87D and 88.

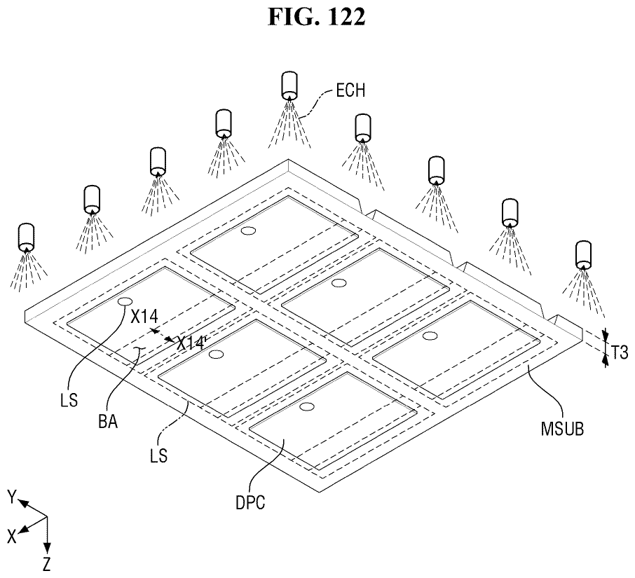

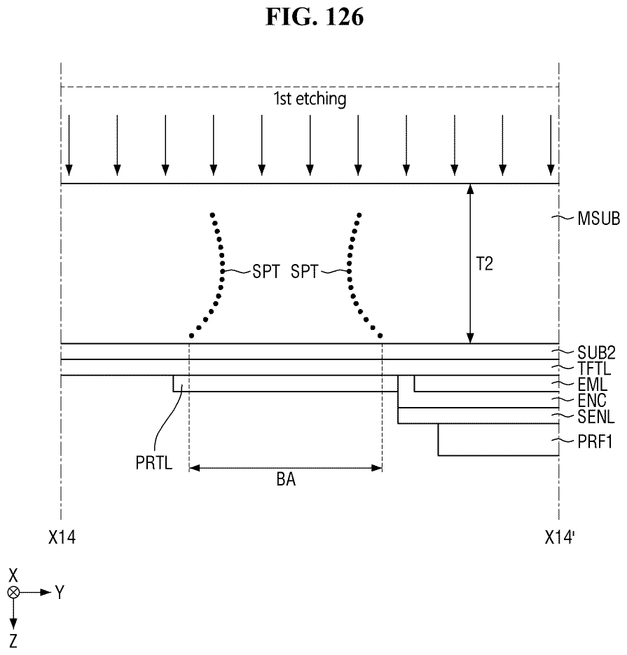

Third, as illustrated in FIGS. 122 and 126, a thickness of the mother substrate MSUB is reduced by spraying an etchant onto the second surface of the mother substrate MSUB at a first rate without a separate mask (e.g., see operation S330 in FIG. 118).

Fourth, as illustrated in FIGS. 122, 123, 127 and 128, the mother substrate MSUB is cut along the laser spots SPT by spraying an etchant onto the second surface of the mother substrate MSUB at a second rate without a separate mask (e.g., see operation S340 in FIG. 118).

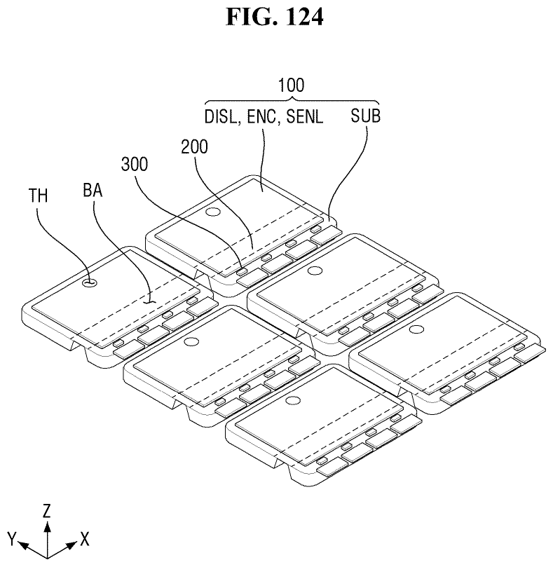

Fifth, as illustrated in FIG. 124, driving circuits 200 and circuit boards 300 are attached to each of the display cells DPC, and a polarizing film PF and a cover window CW are attached to each of the display cells DPC (e.g., see operation S350 in FIG. 118).

As described above, it is possible not only to reduce the thickness of the mother substrate MSUB and separate each of the display cells DPC from the mother substrate MSUB but also to form the through holes TH and the bending areas BA by using a laser and etching process. Therefore, the efficiency of the fabrication process can be increased.

In addition, the laser device LD may output the laser beam BM such that a plurality of laser spots SPT is disposed along a curve in a plane defined by the first direction (X-axis direction) and the third direction (Z-axis direction). In this case, the side surfaces SS1_1, SS2_1, SS3_1 and SS4_1 of the first sub-substrate SSUB1 and the side surfaces SS1_2, SS2_2, SS3_2 and SS4_2 of the second sub-substrate SSUB2 of each of the display cells DPC may be etched into a curved shape having a curvature by spraying an etchant. That is, because the side surfaces SS1_1, SS2_1, SS3_1 and SS4_1 of the first sub-substrate SSUB1 and the side surfaces SS1_2, SS2_2, SS3_2 and SS4_2 of the second sub-substrate SSUB2 of each of the display cells DPC can have a curved shape without a separate polishing process, the efficiency of the fabrication process can be increased.

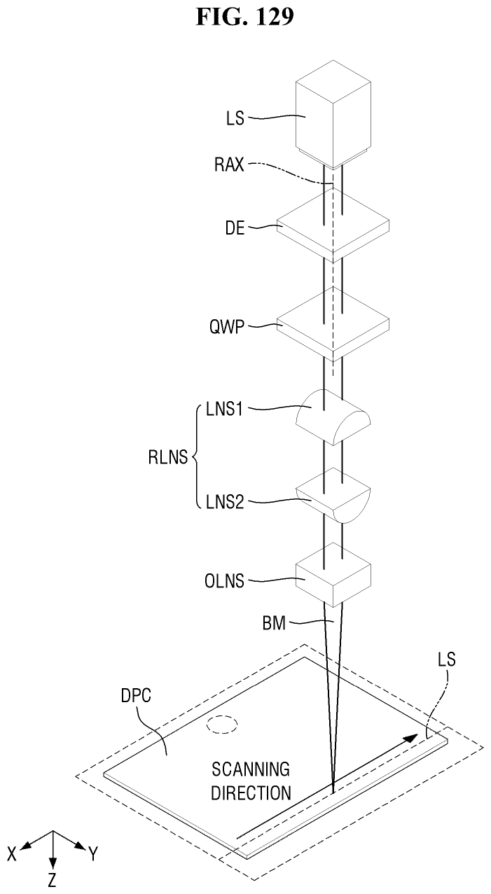

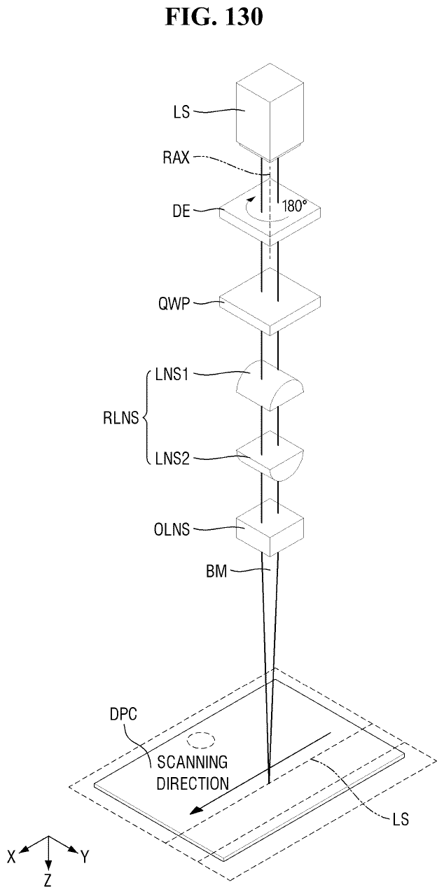

FIGS. 129 and 130 are example views illustrating the rotation of the laser device LD according to the one or more embodiments of FIGS. 52 through 54 for laser sketching of a bending area BA of a display cell DPC. The laser sketching LS of the bending area BA of the display cell DPC will now be described in detail with reference to FIGS. 129 and 130.

First, the laser sketching LS of edges of the display cell DPC may be performed as described with reference to FIGS. 70 through 77.

Next, as illustrated in FIG. 129, with the laser device LD rotated by 0 degrees, a laser beam BM is irradiated along an edge of the bending area BA to make a laser sketch LS. The edge of the bending area BA may be an edge of a second sub-substrate SSUB2 which faces a first sub-substrate SSUB1.

The laser device LD outputs the laser beam BM from an end of the edge of the bending area BA to the other end. That is, a scanning direction of the laser device LD may be parallel to the first direction (X-axis direction). Because the scanning direction of the laser device LD is a straight line, a scanning speed of the laser device LD may be in a range of about 10 mm/sec to about 500 mm/sec.

Next, as illustrated in FIG. 130, with the laser device LD rotated 180 degrees clockwise, the laser beam BM is irradiated along the other edge of the bending area BA to make a laser sketch LS. The other edge of the bending area BA may be an edge of the first sub-substrate SSUB1 which faces the second sub-substrate SSUB2.

The laser device LD outputs the laser beam BM from an end of the other edge of the bending area BA to the other end. That is, the scanning direction of the laser device LD may be parallel to the first direction (X-axis direction). Because the scanning direction of the laser device LD is a straight line, the scanning speed of the laser device LD may be in a range of about 10 mm/sec to about 500 mm/sec.

As illustrated in FIGS. 129 and 130, a laser sketch is made by irradiating an elliptically polarized laser beam BM along a first side edge SE1, a second side edge SE2, a third side edge SE3 and a fourth side edge ES4 of the display cell DPC and an edge and the other edge of the bending area BA. Therefore, it may be possible to reduce, minimize, or prevent a difference in processability of a substrate SUB of a display panel 100. Accordingly, it may be possible to reduce, minimize, or prevent a difference in the shapes, for example, radii of curvature of side surfaces SS1_1, SS2_1, SS3_1 and SS4_1 of the first sub-substrate SSUB1 and side surfaces SS1_2, SS2_2, SS3_2 and SS4_2 of the second sub-substrate SSUB2 or a difference in mechanical strength according to the positions of the side surfaces SS1_1, SS2_1, SS3_1 and SS4_1 of the first sub-substrate SSUB1 and the side surfaces SS1_2, SS2_2, SS3_2 and SS4_2 of the second sub-substrate SSUB2. Therefore, the side surfaces SS1_1, SS2_1, SS3_1 and SS4_1 of the first sub-substrate SSUB1 and the side surfaces SS1_2, SS2_2, SS3_2 and SS4_2 of the second sub-substrate SSUB2 of the display panel 100 can have uniform quality against external impacts.

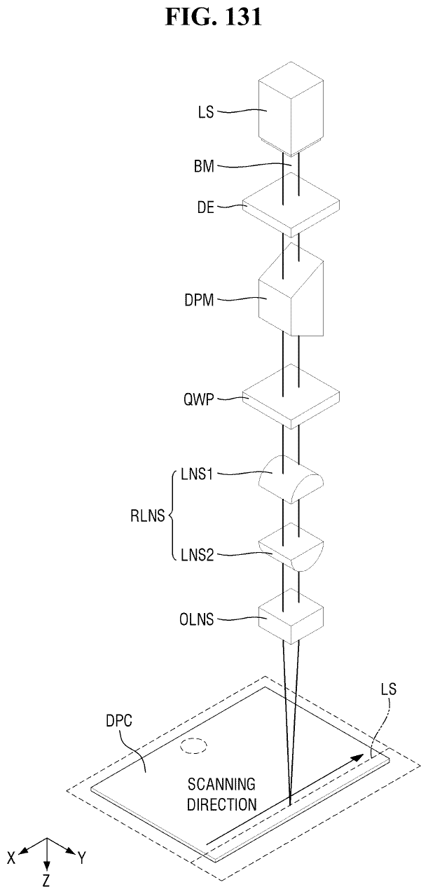

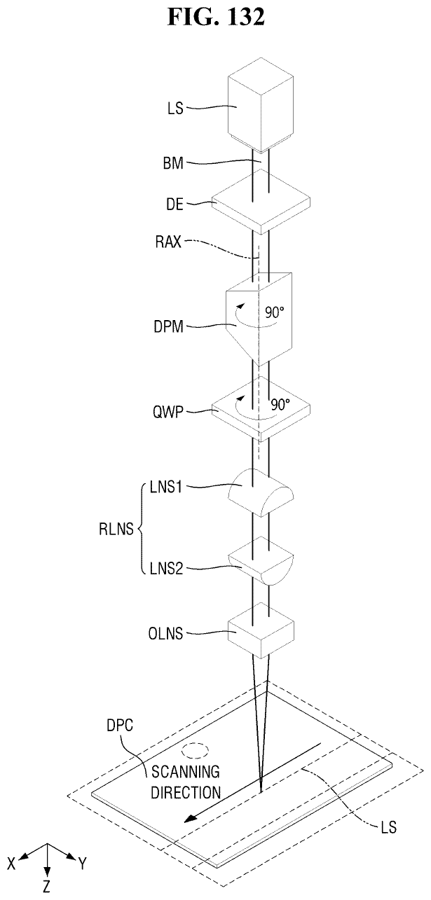

FIGS. 131 and 132 are example views illustrating the rotation of the laser device LD according to the one or more embodiments of FIGS. 55 and 56 for laser sketching of a bending area BA of a display cell DPC. The laser sketching LS of the bending area BA of the display cell DPC will now be described in detail with reference to FIGS. 131 and 132.

First, the laser sketching LS of edges of the display cell DPC may be performed as described with reference to FIGS. 79 through 86.

Next, as illustrated in FIG. 131, with the laser device LD rotated by 0 degrees, a laser beam BM is irradiated along an edge of the bending area BA to make a laser sketch LS. The edge of the bending area BA may be an edge of a second sub-substrate SSUB2 which faces a first sub-substrate SSUB1.

The laser device LD outputs the laser beam BM from an end of the edge of the bending area BA to the other end. That is, a scanning direction of the laser device LD may be parallel to the first direction (X-axis direction). Because the scanning direction of the laser device LD is a straight line, a scanning speed of the laser device LD may be in a range of about 10 mm/sec to about 500 mm/sec.

Next, as illustrated in FIG. 130, with the laser device LD rotated 90 degrees clockwise, the laser beam BM is irradiated along the other edge of the bending area BA to make a laser sketch LS. The other edge of the bending area BA may be an edge of the first sub-substrate SSUB1 which faces the second sub-substrate SSUB2.

When the prism DPM is a Dove prism having trapezoidal cross sections as illustrated in FIGS. 48A and 48B, the rotation angle of the laser beam BM is twice the rotation angle of the prism DPM. Therefore, when the prism DPM is rotated 90 degrees, the laser beam BM may be rotated 180 degrees.

The laser device LD outputs the laser beam BM from an end of the other edge of the bending area BA to the other end. That is, the scanning direction of the laser device LD may be parallel to the first direction (X-axis direction). Because the scanning direction of the laser device LD is a straight line, the scanning speed of the laser device LD may be in a range of about 10 mm/sec to about 500 mm/sec.

As illustrated in FIGS. 131 and 132, a laser sketch is made by irradiating an elliptically polarized laser beam BM along a first side edge SE1, a second side edge SE2, a third side edge SE3 and a fourth side edge ES4 of the display cell DPC and an edge and the other edge of the bending area BA. Therefore, it may be possible to reduce, minimize, or prevent a difference in processability of a substrate SUB of a display panel 100. Accordingly, it may be possible to reduce, minimize, or prevent a difference in the shapes, for example, radii of curvature of side surfaces SS1_1, SS2_1, SS3_1 and SS4_1 of the first sub-substrate SSUB1 and side surfaces SS1_2, SS2_2, SS3_2 and SS4_2 of the second sub-substrate SSUB2 or a difference in mechanical strength according to the positions of the side surfaces SS1_1, SS2_1, SS3_1 and SS4_1 of the first sub-substrate SSUB1 and the side surfaces SS1_2, SS2_2, SS3_2 and SS4_2 of the second sub-substrate SSUB2. Therefore, the side surfaces SS1_1, SS2_1, SS3_1 and SS4_1 of the first sub-substrate SSUB1 and the side surfaces SS1_2, SS2_2, SS3_2 and SS4_2 of the second sub-substrate SSUB2 of the display panel 100 can have uniform quality against external impacts.

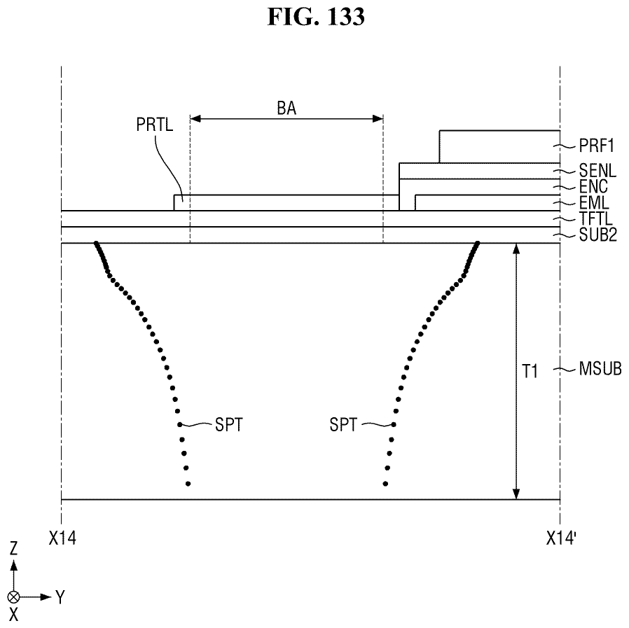

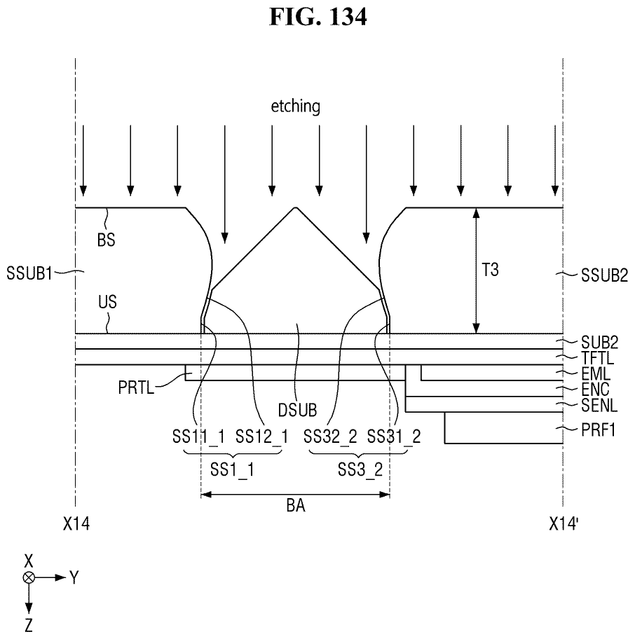

FIGS. 133 and 134 are cross-sectional views taken along the line X14-X14′ of FIGS. 120 through 123 to explain a method of fabricating a display device according to one or more embodiments of the present disclosure. FIGS. 133 and 134 illustrate an example of cross sections taken along the line X14-X14′ of FIGS. 120 through 123 in operations S320 through S340 of FIG. 118.

Cross-sectional shapes of first through fourth side surfaces SS1_1, SS2_1, SS3_1 and SS4_1 of a first sub-substrate SSUB1 and first through fourth side surfaces SS1_2, SS2_2, SS3_2 and SS4_2 of a second sub-substrate SSUB2 depend on the arrangement form of laser spots SPT. A method of fabricating the first through fourth side surfaces SS1_1, SS2_1, SS3_1 and SS4_1 of the first sub-substrate SSUB1 and the first through fourth side surfaces SS1_2, SS2_2, SS3_2 and SS4_2 of the second sub-substrate SSUB2 according to the one or more embodiments of FIGS. 45A through 45D and 46A through 46D will now be described with reference to FIGS. 133 and 134.

As illustrated in FIG. 133, a length in which a plurality of laser spots SPT is arranged in the third direction (Z-axis direction) may be substantially equal to a length of a mother substrate MSUB in the third direction (Z-axis direction). For example, if the length of the mother substrate MSUB in the third direction (Z-axis direction) is about 500 μm, the length in which the laser spots SPT are arranged in the third direction (Z-axis direction) may be about 500 μm.

In a plane defined by the first direction (X-axis direction) and the third direction (Z-axis direction), each of the first through fourth side surfaces SS1_1, SS2_1, SS3_1 and SS4_1 of the first sub-substrate SSUB1 and the first through fourth side surfaces SS1_2, SS2_2, SS3_2 and SS4_2 of the second sub-substrate SSUB2 according to the one or more embodiments of FIGS. 45A through 45D and 46A through 46D has two sub-side surfaces. To this end, the laser spots SPT may be divided and arranged in two areas having two radii of curvature in the plane defined by the first direction (X-axis direction) and the third direction (Z-axis direction).

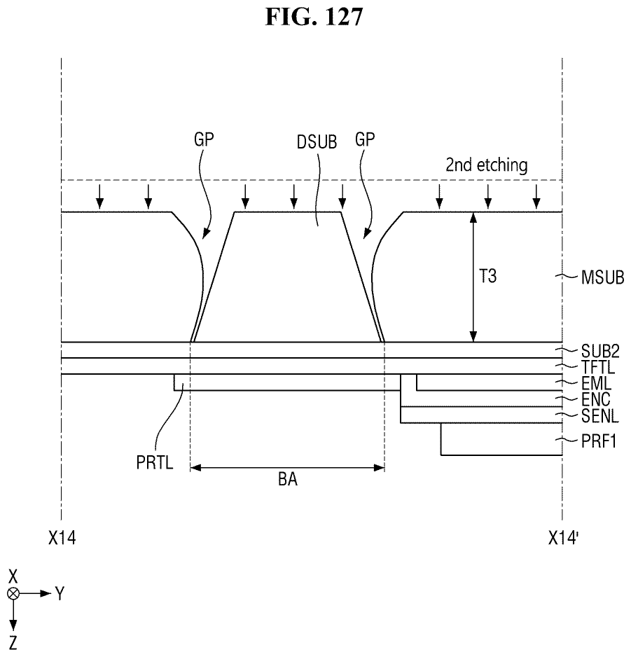

As illustrated in FIG. 134, because the length in which the laser spots SPT are arranged in the third direction (Z-axis direction) is substantially equal to the length of the mother substrate MSUB in the third direction (Z-axis direction), an etchant can penetrate directly into the laser spots SPT. Therefore, the area of a gap GP between a lower surface BS of a substrate SUB separated from the mother substrate MSUB and a dummy substrate DSUB may be larger than that of the one or more embodiments of FIG. 127. Accordingly, the area of at least a portion of each of the first through fourth side surfaces SS1_1, SS2_1, SS3_1 and SS4_1 of the first sub-substrate SSUB1 and the first through fourth side surfaces SS1_2, SS2_2, SS3_2 and SS4_2 of the second sub-substrate SSUB2 that is healed by the etchant may also be larger than that of the one or more embodiments of FIG. 127. In addition, due to the increased gap GP, damage to side surfaces of the substrate SUB by the dummy substrate DSUB when the dummy substrate DSUB is separated from the substrate SUB may be reduced compared to the one or more embodiments of FIG. 127.

The arrangement of the laser spots SPT formed on the mother substrate MSUB by a laser device LD so that each of the first through fourth side surfaces SS1_1, SS2_1, SS3_1 and SS4_1 of the first sub-substrate SSUB1 and the first through fourth side surfaces SS1_2, SS2_2, SS3_2 and SS4_2 of the second sub-substrate SSUB2 according to the one or more embodiments of FIGS. 45A through 45D and 46A through 46D can have two sub-side surfaces in the plane defined by the first direction (X-axis direction) and the third direction (Z-axis direction) has already been described above with reference to FIG. 91. As illustrated in FIGS. 91, 133 and 134, laser spots SPT in a first area UA and laser spots SPT in a second area BA not only have different radii of curvature, but also are arranged at different intervals. Therefore, a first sub-side surface SS11_1 having a different curved or flat shape from a second sub-side surface SS12_1 may be formed in the first side surface SS1_1 of the first sub-substrate SSUB1. In addition, when a distance between the laser spots SPT in the first area UA is small, the energy density irradiated to the mother substrate MSUB is high. Therefore, even if an etchant does not penetrate up to an upper surface US of the mother substrate MSUB, the first sub-side surface SS11_1 of the first side surface SS1_1 of the first sub-substrate SSUB1 and the dummy substrate DSUB can be separated. Alternatively, the first sub-side surface SS11_1 of the first side surface SS1_1 of the first sub-substrate SUB1 and the dummy substrate DSUB can be separated by only a small amount of etchant penetrating into the laser spots SPT. Therefore, it may be possible to reduce, minimize, or prevent the invasion of the etchant into a display layer DISL of the display cell DPC disposed on an upper surface of the first sub-substrate SSUB1.

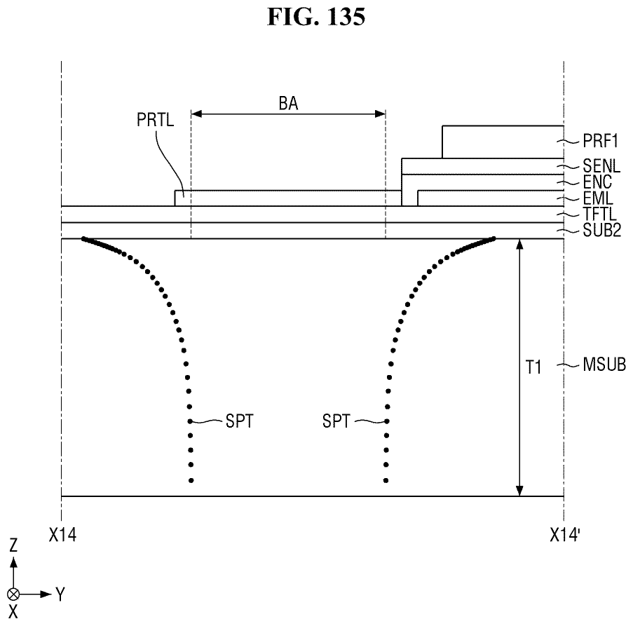

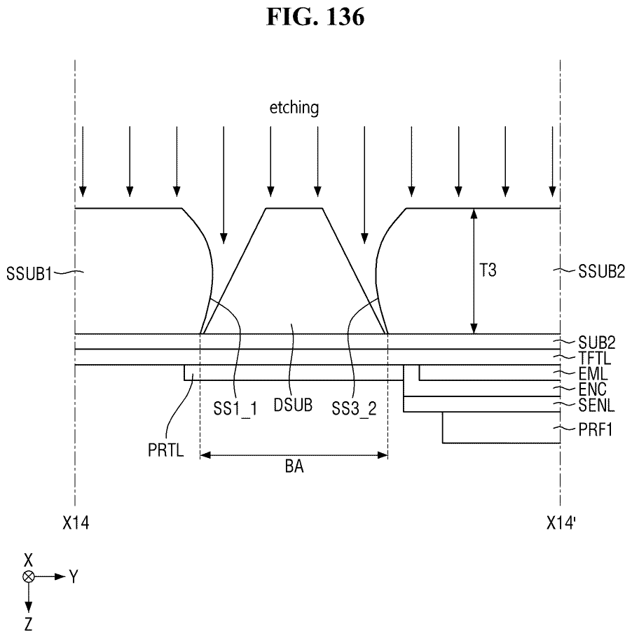

FIGS. 135 and 136 are cross-sectional views taken along line X14-X14′ to explain a method of fabricating a display device according to one or more embodiments of the present disclosure. FIGS. 135 and 136 illustrate an example of cross sections taken along line X14-X14′ in operations S320 through S340 of FIG. 118.

Cross-sectional shapes of first through fourth side surfaces SS1_1, SS2_1, SS3_1 and SS4_1 of a first sub-substrate SSUB1 and first through fourth side surfaces SS1_2, SS2_2, SS3_2 and SS4_2 of a second sub-substrate SSUB2 depend on the arrangement form of laser spots SPT. A method of fabricating the first through fourth side surfaces SS1_1, SS2_1, SS3_1 and SS4_1 of the first sub-substrate SSUB1 and the first through fourth side surfaces SS1_2, SS2_2, SS3_2 and SS4_2 of the second sub-substrate SSUB2 according to the one or more embodiments of FIGS. 43A through 43D and 44A through 44D will now be described with reference to FIGS. 135 and 136.

As illustrated in FIG. 135, a length in which a plurality of laser spots SPT is arranged in the third direction (Z-axis direction) may be substantially equal to a length of a mother substrate MSUB in the third direction (Z-axis direction). For example, if the length of the mother substrate MSUB in the third direction (Z-axis direction) is about 500 μm, the length in which the laser spots SPT are arranged in the third direction (Z-axis direction) may be about 500 μm.

In a plane defined by the first direction (X-axis direction) and the third direction (Z-axis direction), the first through fourth side surfaces SS1_1, SS2_1, SS3_1 and SS4_1 of the first sub-substrate SSUB1 and the first through fourth side surfaces SS1_2, SS2_2, SS3_2 and SS4_2 of the second sub-substrate SSUB2 according to the one or more embodiments of FIGS. 43A through 43D and 44A through 44D have a curved shape. Therefore, the laser spots SPT may also be arranged in a curved shape in the plane defined by the first direction (X-axis direction) and the third direction (Z-axis direction).

As illustrated in FIG. 136, because the length in which the laser spots SPT are arranged in the third direction (Z-axis direction) is substantially equal to the length of the mother substrate MSUB in the third direction (Z-axis direction), an etchant can penetrate directly into the laser spots SPT. Therefore, the area of a gap GP between a lower surface BS of a substrate SUB separated from the mother substrate MSUB and a dummy substrate DSUB may be larger than that of the one or more embodiments of FIG. 127. Accordingly, the area of at least a portion of each of the first through fourth side surfaces SS1_1, SS2_1, SS3_1 and SS4_1 of the first sub-substrate SSUB1 and the first through fourth side surfaces SS1_2, SS2_2, SS3_2 and SS4_2 of the second sub-substrate SSUB2 that is healed by the etchant may also be larger than that of the one or more embodiments of FIG. 127. In addition, due to the increased gap GP, damage to side surfaces of the substrate SUB by the dummy substrate DSUB when the dummy substrate DSUB is separated from the substrate SUB may be reduced compared to the one or more embodiments of FIG. 127.

The arrangement of the laser spots SPT formed on the mother substrate MSUB by a laser device LD so that the first through fourth side surfaces SS1_1, SS2_1, SS3_1 and SS4_1 of the first sub-substrate SSUB1 and the first through fourth side surfaces SS1_2, SS2_2, SS3_2 and SS4_2 of the second sub-substrate SSUB2 according to the one or more embodiments of FIGS. 43A through 43D and 44A through 44D can have a curved shape in the plane defined by the first direction (X-axis direction) and the third direction (Z-axis direction) has already been described above with reference to FIG. 94. As illustrated in FIGS. 94, 135 and 136, when a distance between laser spots SPT in a first area UA is small, the energy density irradiated to the mother substrate MSUB is high. Therefore, even if an etchant does not penetrate up to an upper surface US of the mother substrate MSUB, the first side surface SS1_1 of the first sub-substrate SSUB1 and the dummy substrate DSUB can be separated.

Alternatively, the first side surface SS1_1 of the first sub-substrate SSUB1 and the dummy substrate DSUB can be separated by only a small amount of etchant penetrating into the laser spots SPT. Therefore, it may be possible to reduce, minimize, or prevent the invasion of the etchant into a display layer DISL of the display cell DPC disposed on an upper surface of the substrate SUB.

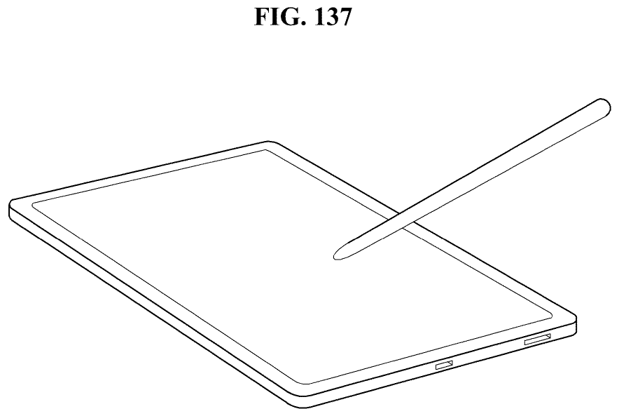

FIG. 137 is an example view of an electronic device including a display device according to one or more embodiments of the present disclosure. In FIG. 137, a tablet to which a display device 10 according to one or more embodiments has been applied is illustrated as an example of the electronic device.

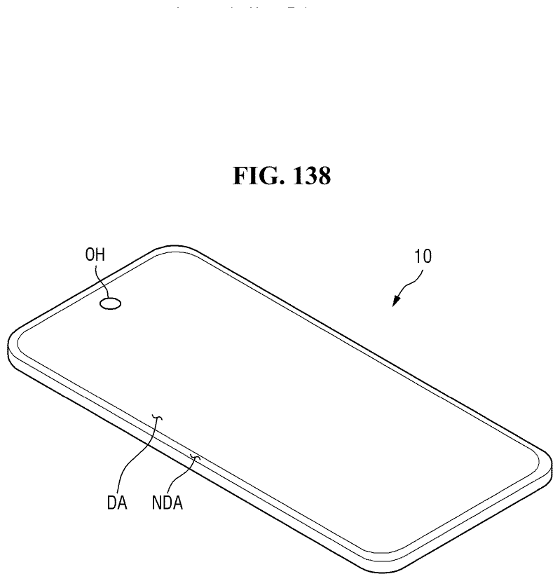

FIG. 138 is an example view of an electronic device including a display device according to one or more embodiments of the present disclosure. In FIG. 138, a smartphone to which a display device 10 according to one or more embodiments has been applied is illustrated as an example of the electronic device.

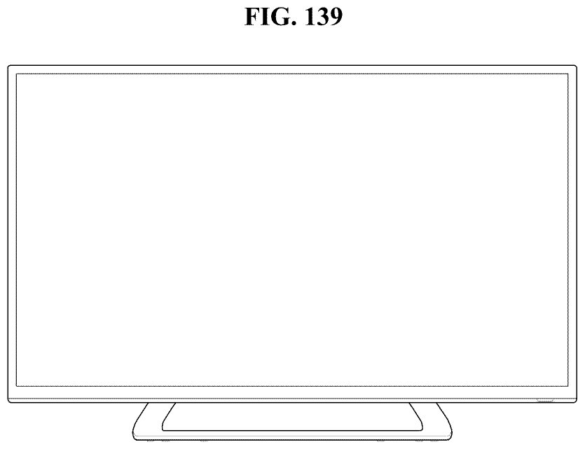

FIG. 139 is an example view of an electronic device including a display device according to one or more embodiments of the present disclosure. In FIG. 139, a TV to which a display device according to one or more embodiments has been applied is illustrated as an example of the electronic device.

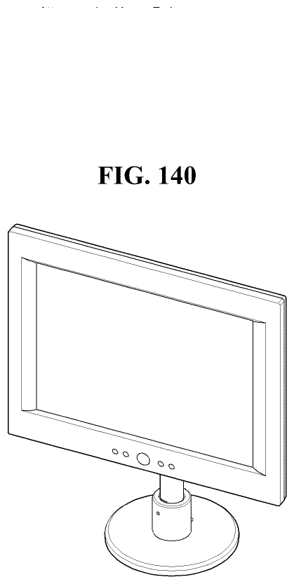

FIG. 140 is an example view of an electronic device including a display device according to one or more embodiments of the present disclosure. In FIG. 140, a monitor to which a display device according to one or more embodiments has been applied is illustrated as an example of the electronic device.

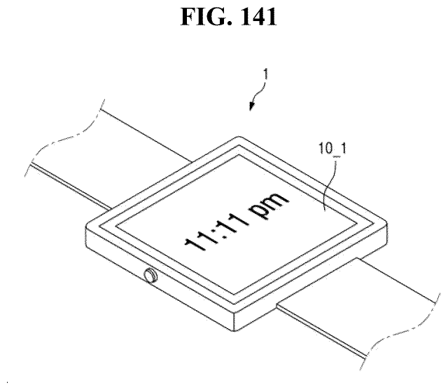

FIG. 141 is an example view of an electronic device including a display device 10_1 according to one or more embodiments of the present disclosure.

Referring to FIG. 141, the display device 10_1 according to the one or more embodiments may be applied to a smart watch 1 that is one of smart devices. The planar shape of a watch display portion of the smart watch 1 may follow the planar shape of the display device 10_1. For example, when the display device 10_1 according to the one or more embodiments has a rectangular planar shape, the watch display portion of the smart watch 1 may have a rectangular planar shape. Alternatively, when the display device 10_1 according to the one or more embodiments has a circular or elliptical planar shape, the watch display portion of the smart watch 1 may have a circular or elliptical planar shape. However, embodiments of the present disclosure are not limited thereto, and the watch display portion of the smart watch 1 may also not follow the planar shape of the display device 10_1.

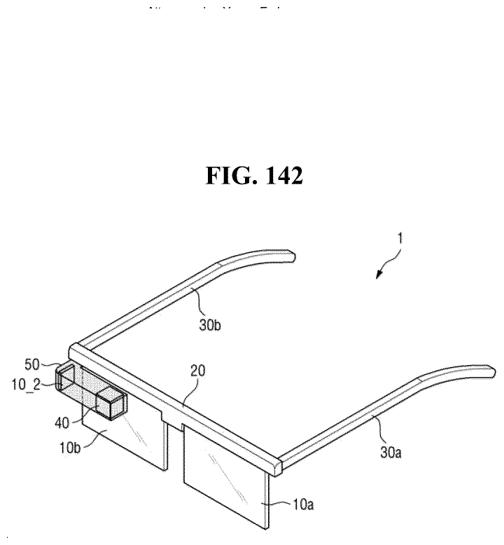

FIG. 142 is an example view of a virtual reality (VR) device including a display device 10_2 according to one or more embodiments of the present disclosure. FIG. 142 illustrates an example of the VR device 1 to which the display device 10_2 according to the one or more embodiments has been applied.

Referring to FIG. 142, the VR device 1 according to the one or more embodiments may be a device in the form of glasses. The VR device 1 according to the one or more embodiments may include the display device 10_2, a left lens 10a, a right lens 10b, a support frame 20, eyeglass frame legs 30a and 30b, a reflective member 40, and a display device housing 50.

In FIG. 142, the VR device 1 including the eyeglass frame legs 30a and 30b is illustrated as an example. However, the VR device 1 according to the one or more embodiments may also be applied to a head-mounted display including a head-mounted band, which can be mounted on the head, instead of the eyeglass frame legs 30a and 30b.

The display device housing 50 may include the display device 10_2 and the reflective member 40. An image displayed on the display device 10_2 may be reflected by the reflective member 40 and provided to a user's right eye through the right lens 10b. Accordingly, the user may view a VR image displayed on the display device 10_2 through the right eye.

Although the display device housing 50 is disposed at a right end of the support frame 20 in FIG. 142, embodiments of the present disclosure are not limited thereto. For example, the display device housing 50 may also be disposed at a left end of the support frame 20. In this case, an image displayed on the display device 10_2 may be reflected by the reflective member 40 and provided to the user's left eye through the left lens 10a. Accordingly, the user may view a VR image displayed on the display device 10_2 through the left eye. Alternatively, the display device housing 50 may be disposed at both the right end and the left end of the support frame 20. In this case, the user may view a VR image displayed on the display device 10_2 through both the left eye and the right eye.

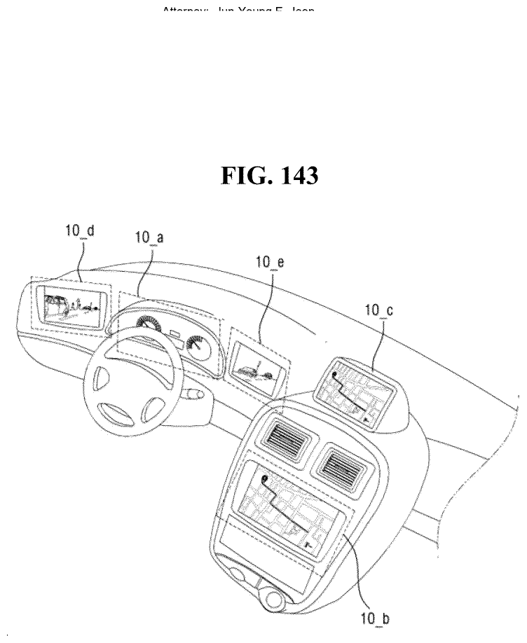

FIG. 143 is an example view illustrating a vehicle dashboard and a center fascia including a display device according to one or more embodiments of the present disclosure. FIG. 143 illustrates a vehicle to which display devices 10_a through 10_e according to one or more embodiments have been applied.

Referring to FIG. 143, display devices 10_a through 10_c according to one or more embodiments may be applied to a dashboard of a vehicle, a center fascia of the vehicle, or a center information display (CID) disposed on the dashboard of the vehicle. In addition, display devices 10_d and 10_e according to one or more embodiments may be applied to room mirror displays that replace side mirrors of the vehicle. In one or more other embodiments, two or more of the display devices 10_a, 10_b, 10_c, 10_d, and 10_e may be formed as a single integrated device fabricated according to described embodiments of the present disclosure.

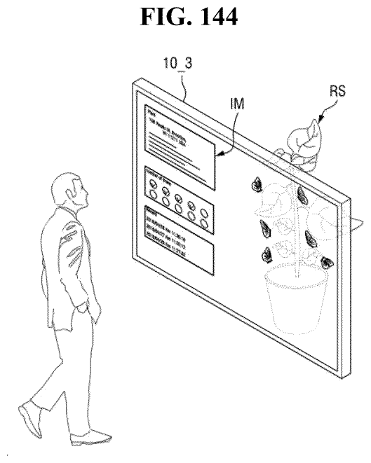

FIG. 144 is an example view of a transparent display device including a display device 10_3 according to one or more embodiments of the present disclosure.

Referring to FIG. 144, the display device 10_3 according to the one or more embodiments may be applied to a transparent display device. The transparent display device may transmit light while displaying an image IM. Therefore, a user located in front of the transparent display device cannot only view the image IM displayed on the display device 10_3 but also view an object RS or the background located behind the transparent display device. When the display device 10_3 is applied to the transparent display device, a substrate SUB of the display device 10_3 may include a light transmitting portion that can transmit light or may be made of a material that can transmit light.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a glass substrate comprising a first surface, a second surface opposite the first surface, and a plurality of side surfaces located between the first surface and the second surface; and
a light emitting element layer on the first surface of the glass substrate and comprising light emitting elements configured to emit light,
wherein the side surfaces of the glass substrate comprise a first side surface and a second side surface, the first side surface comprising a first upper part extending from a first center at a center of the first side surface to an upper end of the first side surface, the first upper part having a first upper center at a center between the first center and the upper end of the first side surface, the second side surface comprising a second upper part extending from a second center at a center of the second side surface to an upper end of the second side surface, the second upper part having a second upper center at a center between the second center and the upper end of the second side surface, and
wherein a radius of curvature of a curve passing through the first center, the first upper center, and the upper end of the first side surface is defined as a first upper radius of curvature, a radius of curvature of a curve passing through the second center, the second upper center, and the upper end of the second side surface is defined as a second upper radius of curvature, and a difference between the first upper radius of curvature and the second upper radius of curvature is about 30 μm or less.

2. The display device of claim 1, wherein the first side surface further comprises a first lower part extending from the first center to a lower end of the first side surface, the first lower part having a first lower center at a center between the first center and the lower end of the first side surface, and
wherein a radius of curvature of a curve passing through the first center, the first lower center, and the lower end of the first side surface is defined as a first lower radius of curvature, and the first lower radius of curvature is different from the first upper radius of curvature.

3. The display device of claim 2, wherein the first lower radius of curvature is smaller than the first upper radius of curvature.

4. The display device of claim 1, wherein the side surfaces of the glass substrate further comprise a third side surface comprising a third upper part extending from a third center at a center of the third side surface to an upper end of the third side surface, the third upper part having a third upper center at a center between the third center and the upper end of the third side surface, and
wherein a radius of curvature of a curve passing through the third center, the third upper center, and the upper end of the third side surface is defined as a third upper radius of curvature, a difference between the first upper radius of curvature and the third upper radius of curvature is about 30 μm or less, and a difference between the second upper radius of curvature and the third upper radius of curvature is about 30 μm or less.

5. The display device of claim 4, wherein the second side surface further comprises a second lower part extending from the second center to a lower end of the second side surface, the second lower part having a second lower center at a center between the second center and the lower end of the second side surface, and
wherein a radius of curvature of a curve passing through the second center, the second lower center, and the lower end of the second side surface is defined as a second lower radius of curvature, and the second lower radius of curvature is different from the second upper radius of curvature.

6. The display device of claim 5, wherein the second lower radius of curvature is smaller than the second upper radius of curvature.

7. The display device of claim 4, wherein the side surfaces of the glass substrate further comprise a fourth side surface comprising a fourth upper part extending from a fourth center at a center of the fourth side surface to an upper end of the fourth side surface, the fourth upper part having a fourth upper center at a center between the fourth center and the upper end of the fourth side surface, and
wherein a radius of curvature of a curve passing through the fourth center, the fourth upper center, and the upper end of the fourth side surface is defined as a fourth upper radius of curvature, a difference between the first upper radius of curvature and the fourth upper radius of curvature is about 30 μm or less, a difference between the second upper radius of curvature and the fourth upper radius of curvature is about 30 μm or less, and a difference between the third upper radius of curvature and the fourth upper radius of curvature is about 30 μm or less.

8. The display device of claim 7, wherein the third side surface further comprises a third lower part extending from the third center to a lower end of the third side surface, the third lower part having a third lower center at a center between the third center and the lower end of the third side surface, and
wherein a radius of curvature of a curve passing through the third center, the third lower center, and the lower end of the third side surface is defined as a third lower radius of curvature, and the third lower radius of curvature is different from the third upper radius of curvature.

9. The display device of claim 8, wherein the third lower radius of curvature is smaller than the third upper radius of curvature.

10. The display device of claim 1, wherein the glass substrate further comprises a through hole penetrating the first surface and the second surface, the through hole being defined by at least one hole side surface comprising a first hole side surface, the first hole side surface comprising a first hole upper part extending from a first hole center at a center of the first hole side surface to an upper end of the first hole side surface, the first hole upper part having a first hole upper center at a center between the first hole center and the upper end of the first hole side surface, and
wherein a radius of curvature of a curve passing through the first hole center, the first hole upper center, and the upper end of the first hole side surface is defined as a first hole upper radius of curvature, a difference between the first upper radius of curvature and the first hole upper radius of curvature is about 30 μm or less, and a difference between the second upper radius of curvature and the first hole upper radius of curvature is about 30 μm or less.

11. The display device of claim 10, wherein the first hole side surface further comprises a first hole lower part extending from the first hole center to a lower end of the first hole side surface, the first hole lower part having a first hole lower center at a center between the first hole center and the lower end of the first hole side surface, and
wherein a radius of curvature of a curve passing through the first hole center, the first hole lower center, and the lower end of the first hole side surface is defined as a first hole lower radius of curvature, and the first hole lower radius of curvature is different from the first hole upper radius of curvature.

12. The display device of claim 11, wherein the first hole lower radius of curvature is smaller than the first hole upper radius of curvature.

13. The display device of claim 10, wherein the at least one hole side surface further comprises a second hole side surface comprising a second hole upper part extending from a second hole center at a center of the second hole side surface to an upper end of the second hole side surface, the second hole upper part having a second hole upper center at a center between the second hole center and the upper end of the second hole side surface, and
wherein a radius of curvature of a curve passing through the second hole center, the second hole upper center, and the upper end of the second hole side surface is defined as a second hole upper radius of curvature, and a difference between the first hole upper radius of curvature and the second hole upper radius of curvature is about 30 μm or less.

14. The display device of claim 13, wherein a difference between the first upper radius of curvature and the second hole upper radius of curvature is about 30 μm or less, and a difference between the second upper radius of curvature and the second hole upper radius of curvature is about 30 μm or less.

15. The display device of claim 13, the second hole side surface further comprising a second hole lower part extending from the second hole center to a lower end of the second hole side surface, the second hole lower part having a second hole lower center at a center between the second hole center and the lower end of the second hole side surface, and
wherein a radius of curvature of a curve passing through the second hole center, the second hole lower center, and the lower end of the second hole side surface is defined as a second hole lower radius of curvature, and the second hole lower radius of curvature is different from the second hole upper radius of curvature.

16. The display device of claim 15, wherein the second hole lower radius of curvature is smaller than the second hole upper radius of curvature.

17. A display device comprising:
a glass substrate comprising a first surface, a second surface opposite the first surface, and a plurality of side surfaces located between the first surface and the second surface; and
a light emitting element layer on the first surface of the glass substrate and comprising light emitting elements configured to emit light,
wherein each of the side surfaces of the glass substrate comprises a first sub-side surface having a flat shape and a second sub-side surface having a curved shape, a length of the second sub-side surface is greater than a length of the first sub-side surface, the first sub-side surface is in contact with the first surface, and the second sub-side surface is in contact with the second surface.

18. The display device of claim 17, wherein the second sub-side surface comprises an upper part and a lower part, the upper part extending from a center of the second sub-side surface to an upper end of the second sub-side surface, the upper part having an upper center at a center between the center of the second sub-side surface and the upper end of the second sub-side surface, the lower part extending from the center of the second sub-side surface to a lower end of the second sub-side surface, the lower part having a lower center at a center between the center of the second sub-side surface and the lower end of the second sub-side surface, and
wherein a radius of curvature of a curve passing through the center of the second sub-side surface, the upper center, and the upper end of the second sub-side surface is defined as an upper radius of curvature, a radius of curvature of a curve passing through the center of the second sub-side surface, the lower center, and the lower end of the second sub-side surface is defined as a lower radius of curvature, and the lower radius of curvature is different from the upper radius of curvature.

19. The display device of claim 18, wherein the lower radius of curvature is smaller than the upper radius of curvature.

20. The display device of claim 18, wherein the glass substrate further comprises a through hole penetrating the first surface and the second surface,
wherein the through hole is defined by a hole side surface, the hole side surface comprising a hole upper part and a hole lower part, the hole upper part extending from a center of the hole side surface to an upper end of the hole side surface, the hole upper part having a hole upper center at a center between the center of the hole side surface and the upper end of the hole side surface, the hole lower part extending from the center of the hole side surface to a lower end of the hole side surface, the hole lower part having a hole lower center at a center between the center of the hole side surface and the lower end of the hole side surface, and
wherein a radius of curvature of a curve passing through the center of the hole side surface, the hole upper center, and the upper end of the hole side surface is defined as a hole upper radius of curvature, a radius of curvature of a curve passing through the center of the hole side surface, the hole lower center, and the lower end of the hole side surface is defined as a hole lower radius of curvature, and the hole lower radius of curvature is different from the hole upper radius of curvature.

21. The display device of claim 20, wherein the hole lower radius of curvature is smaller than the hole upper radius of curvature.

22. The display device of claim 20, wherein a difference between the upper radius of curvature and the hole upper radius of curvature is about 30 μm or less.

23. A display device comprising:
a first substrate comprising a first surface and a second surface opposite the first surface;
a second substrate on the first surface of the first substrate; and
a light emitting element layer on a surface of the second substrate and comprising light emitting elements configured to emit light,
wherein the first substrate is made of glass, the second substrate is made of polymer resin, the first substrate comprises a first sub-substrate and a second sub-substrate spaced from each other, the first sub-substrate comprising a first side surface and a second side surface located between the first surface and the second surface, the first side surface comprising a first upper part extending from a first center at a center of the first side surface to an upper end of the first side surface, the first upper part having a first upper center at a center between the first center and the upper end of the first side surface, the second side surface comprising a second upper part extending from a second center at a center of the second side surface to an upper end of the second side surface, the second upper part having a second upper center at a center between the second center and the upper end of the second side surface, and
wherein a radius of curvature of a curve passing through the first center, the first upper center, and the upper end of the first side surface is defined as a first upper radius of curvature, a radius of curvature of a curve passing through the second center, the second upper center, and the upper end of the second side surface is defined as a second upper radius of curvature, and a difference between the first upper radius of curvature and the second upper radius of curvature is about 30 μm or less.

24. The display device of claim 23, wherein an area of the first sub-substrate is larger than an area of the second sub-substrate.

25. The display device of claim 23, wherein the first side surface further comprises a first lower part extending from the first center to a lower end of the first side surface, the first lower part having a first lower center at a center between the first center and the lower end of the first side surface, and
wherein a radius of curvature of a curve passing through the first center, the first lower center, and the lower end of the first side surface is defined as a first lower radius of curvature, and the first lower radius of curvature is different from the first upper radius of curvature.

26. The display device of claim 25, wherein the first lower radius of curvature is smaller than the first upper radius of curvature.

27. The display device of claim 23, wherein the second sub-substrate comprises a third side surface and a fourth side surface located between the first surface and the second surface, the third side surface comprising a third upper part extending from a third center at a center of the third side surface to an upper end of the third side surface, the third upper part having a third upper center at a center between the third center and the upper end of the third side surface, and
wherein a radius of curvature of a curve passing through the third center, the third upper center, and the upper end of the third side surface is defined as a third upper radius of curvature, a difference between the first upper radius of curvature and the third upper radius of curvature is about 30 μm or less, and a difference between the second upper radius of curvature and the third upper radius of curvature is about 30 μm or less.

28. The display device of claim 27, wherein the fourth side surface comprises a fourth upper part extending from a fourth center at a center of the fourth side surface to an upper end of the fourth side surface, the fourth upper part having a fourth upper center at a center between the fourth center and the upper end of the fourth side surface,
wherein a radius of curvature of a curve passing through the fourth center, the fourth upper center, and the upper end of the fourth side surface is defined as a fourth upper radius of curvature, and a difference between the third upper radius of curvature and the fourth upper radius of curvature is about 30 μm or less.

29. The display device of claim 28, wherein a difference between the first upper radius of curvature and the fourth upper radius of curvature is about 30 μm or less, and a difference between the second upper radius of curvature and the fourth upper radius of curvature is about 30 μm or less.

30. The display device of claim 27, wherein the first substrate further comprises a through hole penetrating the first surface and the second surface, the through hole being defined by a hole side surface, the hole side surface comprising a hole upper part extending from a hole center at a center of the hole side surface to an upper end of the hole side surface, the hole upper part having a hole upper center at a center between the hole center and the upper end of the hole side surface, and
wherein a radius of curvature of a curve passing through the center of the hole side surface, the hole upper center, and the upper end of the hole side surface is defined as a hole upper radius of curvature, and a difference between the first upper radius of curvature and the hole upper radius of curvature is about 30 μm or less, a difference between the second upper radius of curvature and the hole upper radius of curvature is about 30 μm or less, and a difference between the third upper radius of curvature and the hole upper radius of curvature is about 30 μm or less.

31. The display device of claim 30,
wherein the hole side surface further comprises a hole lower part extending from a hole center at a center of the hole side surface to a lower end of the hole side surface, the hole lower part having a hole lower center at a center between the hole center and the lower end of the hole side surface, and
wherein a radius of curvature of a curve passing through the center of the hole side surface, the hole lower center, and the lower end of the hole side surface is defined as a hole lower radius of curvature, and the hole lower radius of curvature is different from the hole upper radius of curvature.

32. The display device of claim 31, wherein the hole lower radius of curvature is smaller than the hole upper radius of curvature.

33. A display device comprising:
a first substrate comprising a first surface and a second surface opposite the first surface;
a second substrate on the first surface of the first substrate; and
a light emitting element layer on a surface of the second substrate and comprising light emitting elements configured to emit light,
wherein the first substrate comprises glass, the second substrate comprises polymer resin, the first substrate comprises a first sub-substrate and a second sub-substrate spaced from each other, each of a plurality of side surfaces of the first sub-substrate comprises a first sub-side surface having a flat shape and a second sub-side surface having a curved shape, a length of the second sub-side surface is greater than a length of the first sub-side surface, the first sub-side surface is in contact with the first surface, and the second sub-side surface is in contact with the second surface.

34. The display device of claim 33, wherein the second sub-side surface comprises a first upper part and a first lower part, the first upper part extending from a center of the second sub-side surface to an upper end of the second sub-side surface, the first upper part having a first upper center at a center between the center of the second sub-side surface and the upper end of the second sub-side surface, the first lower part extending from the center of the second sub-side surface to a lower end of the second sub-side surface, the first lower part having a first lower center at a center between the center of the second sub-side surface and the lower end of the second sub-side surface, and
wherein a radius of curvature of a curve passing through the center of the second sub-side surface, the first upper center, and the upper end of the second sub-side surface is defined as a first upper radius of curvature, a radius of curvature of a curve passing through the center of the second sub-side surface, the first lower center, and the lower end of the second sub-side surface is defined as a first lower radius of curvature, and the first lower radius of curvature is different from the first upper radius of curvature.

35. The display device of claim 34, wherein the first lower radius of curvature is smaller than the first upper radius of curvature.

36. The display device of claim 34, wherein each of a plurality of side surfaces of the second sub-substrate comprises a third sub-side surface having a flat shape and a fourth sub-side surface having a curved shape, a length of the fourth sub-side surface is greater than a length of the third sub-side surface, the third sub-side surface is in contact with the first surface, and the fourth sub-side surface is in contact with the second surface.

37. The display device of claim 36, wherein the fourth sub-side surface comprises a second upper part and a second lower part, the second upper part extending from a center of the fourth sub-side surface to an upper end of the fourth sub-side surface, the second upper part having a second upper center at a center between the center of the fourth sub-side surface and the upper end of the fourth sub-side surface, the second lower part extending from the center of the fourth sub-side surface to a lower end of the fourth sub-side surface, the second lower part having a second lower center at a center between the center of the fourth sub-side surface and the lower end of the fourth sub-side surface, and
wherein a radius of curvature of a curve passing through the center of the fourth sub-side surface, the second upper center, and the upper end of the fourth sub-side surface is defined as a second upper radius of curvature, a radius of curvature of a curve passing through the center of the fourth sub-side surface, the second lower center, and the lower end of the fourth sub-side surface is defined as a second lower radius of curvature, and the second lower radius of curvature is different from the second upper radius of curvature.

38. The display device of claim 37, wherein the second lower radius of curvature is smaller than the second upper radius of curvature.

39. The display device of claim 37, wherein a difference between the first upper radius of curvature and the second upper radius of curvature is about 30 μm or less.

40. The display device of claim 37, wherein the first substrate further comprises a through hole penetrating the first surface and the second surface,
wherein the through hole is defined by a hole side surface, the hole side surface comprising a hole upper part and a hole lower part, the hole upper part extending from a center of the hole side surface to an upper end of the hole side surface, the hole upper part having a hole upper center at a center between the center of the hole side surface and the upper end of the hole side surface, the hole lower part extending from the center of the hole side surface to a lower end of the hole side surface, the hole lower part having a hole lower center at a center between the center of the hole side surface and the lower end of the hole side surface, and
wherein a radius of curvature of a curve passing through the center of the hole side surface, the hole upper center, and the upper end of the hole side surface is defined as a hole upper radius of curvature, a radius of curvature of a curve passing through the center of the hole side surface, the hole lower center, and the lower end of the hole side surface is defined as a hole lower radius of curvature, and the hole lower radius of curvature is different from the hole upper radius of curvature.

41. The display device of claim 40, wherein the hole lower radius of curvature is smaller than the hole upper radius of curvature.

42. The display device of claim 40, wherein a difference between the first upper radius of curvature and the hole upper radius of curvature is about 30 μm or less, and a difference between the second upper radius of curvature and the hole upper radius of curvature is about 30 μm or less.

43. A laser device comprising:
a light source configured to output a laser beam;
a diffractive element comprising diffractive patterns configured to diffract the laser beam;
a phase retardation plate configured to retard a phase of the laser beam incident from the diffractive element; and
an objective lens configured to focus the laser beam incident from the phase retardation plate,
wherein the diffractive element is configured to rotate.

44. The laser device of claim 43, wherein the light source is configured to output a laser beam having linear polarization or circular polarization, and the laser beam to be output from the objective lens has elliptical polarization.

45. The laser device of claim 43, wherein the phase retardation plate comprises a quarter-wave (λ/4) plate.

46. The laser device of claim 43, further comprising a relay lens configured to relay the laser beam diffracted by the diffractive patterns.

47. The laser device of claim 46, wherein the relay lens is located between the phase retardation plate and the objective lens.

48. The laser device of claim 46, wherein the relay lens is located between the light source and the diffractive element.

49. A laser device comprising:
a light source configured to output a laser beam;
a diffractive element comprising diffractive patterns configured to diffract the laser beam;
a prism configured to rotate to rotate the laser beam incident from the diffractive element;
a phase retardation plate configured to retard a phase of the laser beam incident from the prism; and
an objective lens configured to focus the laser beam incident from the phase retardation plate,
wherein the prism and the phase retardation plate rotate concurrently.

50. The laser device of claim 49, wherein the prism is a Dove prism having trapezoidal cross sections.

51. The laser device of claim 49, wherein the light source is configured to output a laser beam having circular polarization, and the laser beam to pass through the objective lens has elliptical polarization.

52. The laser device of claim 49, wherein the phase retardation plate is a λ/4 plate.

53. The laser device of claim 49, further comprising a relay lens configured to relay the laser beam diffracted by the diffractive patterns.

54. The laser device of claim 53, wherein the relay lens is located between the phase retardation plate and the objective lens.

55. The laser device of claim 53, wherein the relay lens is located between the diffractive element and the prism.

56. A method of fabricating a display device, the method comprising:
forming a plurality of display cells on a first surface of a mother substrate;
forming a plurality of laser spots along edges of the display cells by irradiating a laser beam using a laser device on a second surface opposite the first surface of the mother substrate;
reducing a thickness of the mother substrate by spraying an etchant onto the second surface of the mother substrate at a first rate without a mask; and
reducing the thickness of the mother substrate by spraying the etchant onto the second surface of the mother substrate at a second rate without the mask,
wherein the first rate is faster than the second rate.

57. The method of claim 56, wherein the first rate is in a range of 7 μm/min to 10 μm/min, and the second rate is in a range of 1 μm/min to 5 μm/min.

58. The method of claim 56, wherein pulse duration of the laser beam is in a range of 3 ps to 10 ps.

59. The method of claim 56, wherein a burst pulse of the laser beam is in a range of 1 pulse to 10 pulses.

60. The method of claim 56, wherein pulse energy of the laser beam is in a range of 2 μJ/spot to 4 μJ/spot.

61. The method of claim 56, wherein a repetition rate of the laser beam is in a range of about 10 kHz to about 500 KHz.

62. The method of claim 56, wherein a length in which the laser spots are arranged in a thickness direction of the mother substrate is in a range of about 0.4 to about 0.6 of the thickness of the mother substrate.

63. The method of claim 56, wherein the laser spots comprise a first group of laser spots and a second group of laser spots spaced from each other in a scanning direction of the laser device, and a distance between the first group of laser spots and the second group of laser spots in the scanning direction of the laser device is in a range of 2 μm to 7 μm.

64. The method of claim 56, wherein in a two-dimensional (2D) plane defined by a thickness direction of the mother substrate and a direction of one side of the mother substrate, an arrangement of laser spots in a first area and an arrangement of laser spots in a second area from among the laser spots are asymmetrical.

65. The method of claim 64, wherein a radius of curvature of a curve formed by the laser spots in the first area and a radius of curvature of a curve formed by the laser spots in the second area are different from each other.

66. The method of claim 64, wherein a radius of curvature of the curve formed by the laser spots in the first area and a radius of curvature of the curve formed by the laser spots in the second area are in a range of 100 μm to 300 μm.

67. The method of claim 56, wherein a length in which the laser spots are arranged in a thickness direction of the mother substrate is equal to the thickness of the mother substrate.

68. The method of claim 56, wherein in a 2D plane defined by a thickness direction of the mother substrate and a direction of one side of the mother substrate, the laser spots comprise laser spots in a first area and laser spots in a second area.

69. The method of claim 68, wherein a radius of curvature of a curve formed by the laser spots in the first area is smaller than a radius of curvature of a curve formed by the laser spots in the second area.

70. The method of claim 68, wherein a distance between the laser spots in the second area is greater than a distance between the laser spots in the first area.

71. The method of claim 68, wherein a distance between the laser spots in the second area increases from bottom to top.

72. The method of claim 68, wherein a distance between the laser spots is in a range of 3 μm to 20 μm.

73. The method of claim 68, wherein a length of the second area in the thickness direction of the mother substrate is greater than a length of the first area in the thickness direction of the mother substrate.

74. The method of claim 68, wherein a length of the second area in the direction of the one side of the mother substrate is in a range of 80 μm to 150 μm, the length of the second area in the thickness direction of the mother substrate is in a range of 430 μm to 470 μm, the length of the first area is in a range of 30 μm to 70 μm, and a radius of curvature of the first area is in a range of 200 μm to 600 μm.

75. The method of claim 56, wherein the forming of the laser spots along the edges of the display cells by irradiating the laser beam of the laser device on the second surface opposite the first surface of the mother substrate comprises:
scanning a laser beam in a first direction along a first side edge of one of the display cells;
scanning the laser beam along a first corner edge between the first side edge and a second side edge of the one of the display cells while continuously rotating the laser device from 0 degrees to a first angle; and
scanning the laser beam in a second direction intersecting the first direction along the second side edge of the one of the display cells with the laser device rotated at the first angle.

76. The method of claim 75, wherein an elliptically polarized laser beam is applied to the first side edge, the first corner edge, and the second side edge of the one of the display cells.

77. The method of claim 56, wherein the forming of the laser spots along the edges of the display cells by irradiating the laser beam on the second surface opposite the first surface of the mother substrate comprises forming a plurality of laser spots along an edge of a through hole to penetrate the first surface and the second surface of the mother substrate along with the display cells by irradiating the laser beam of the laser device on the second surface of the mother substrate.

78. The method of claim 77, comprising:
irradiating the laser beam using the laser device along the edges of the display cells while rotating the laser device in one of a clockwise direction or a counterclockwise direction; and
irradiating the laser beam using the laser device along the edge of the through hole while rotating the laser device in an other of the clockwise direction or the counterclockwise direction.

79. The method of claim 77, wherein in the forming of the laser spots along the edge of the through hole to penetrate the first surface and the second surface of the mother substrate along with the display cells by irradiating the laser beam of the laser device on the second surface of the mother substrate, the laser device scans the laser beam along the edge of the through hole while continuously rotating from 0 degrees to 360 degrees.

80. The method of claim 78, wherein an elliptically polarized laser beam is applied at the edge of the through hole.

81. An electronic device comprising a display device for displaying an image, wherein the display device comprises:
a glass substrate comprising a first surface, a second surface opposite the first surface, and a plurality of side surfaces located between the first surface and the second surface; and
a light emitting element layer on the first surface of the glass substrate and comprising light emitting elements configured to emit light,
wherein the side surfaces of the glass substrate comprise a first side surface and a second side surface, the first side surface comprising a first upper part extending from a first center at a center of the first side surface to an upper end of the first side surface, the first upper part having a first upper center at a center between the first center and the upper end of the first side surface, the second side surface comprising a second upper part extending from a second center at a center of the second side surface to an upper end of the second side surface, the second upper part having a second upper center at a center between the second center and the upper end of the second side surface, and
wherein a radius of curvature of a curve passing through the first center, the first upper center, and the upper end of the first side surface is defined as a first upper radius of curvature, a radius of curvature of a curve passing through the second center, the second upper center, and the upper end of the second side surface is defined as a second upper radius of curvature, and a difference between the first upper radius of curvature and the second upper radius of curvature is about 30 μm or less.
